(19) United States
(12) Patent Application Publication
(10) Pub. No.: US 2025/0122422 A1
(43) Pub. Date: Apr. 17, 2025

(54) CYCLIC TETRADENTATE METAL PLATINUM (II) COMPLEX PHOSPHORESCENT MATERIAL AND USE THEREOF

(71) Applicants: ZHEJIANG UNIVERSITY OF TECHNOLOGY, Hangzhou (CN); ZHEJIANG HUAXIAN PHOTOELECTRICITY TECHNOLOGY CO., LTD, Jiaxing (CN)

(72) Inventors: Guijie LI, Hangzhou (CN); Yulu SUN, Hangzhou (CN); Yuanbin SHE, Hangzhou (CN); Huanhuan YAO, Hangzhou (CN); Xiaoyu ZHAO, Jiaxing (CN)

(73) Assignees: ZHEJIANG UNIVERSITY OF TECHNOLOGY, Hangzhou (CN); ZHEJIANG HUAXIAN PHOTOELECTRICITY TECHNOLOGY CO.,LTD, Jiaxing (CN)

(21) Appl. No.: 18/795,515

(22) Filed: Aug. 6, 2024

(30) Foreign Application Priority Data
Sep. 18, 2023 (CN) 2023111997268

(51) Int. Cl. C09K 11/06; H10K 50/11; H10K 85/30

(52) U.S. Cl. CPC C09K 11/06; H10K 50/11; H10K 85/346; C09K 2211/185

(57) ABSTRACT

The present invention relates to a phosphorescent material and the use thereof, and more particularly to a cyclic tetradentate metal platinum (II) complex phosphorescent material and the use thereof. The present invention provides a cyclic tetradentate metal platinum (II) complex phosphorescent material based on 8-phenylquinoline, benzoxazole, and phenoxy groups. It is a novel tetradentate platinum (II) complex with a 6/6/6 metal fused ring structure. The phosphorescent material of the tetradentate fused ring structure system of the present invention has the characteristics of easy modulation of HOMO and LUMO orbital energy levels and strong luminescence. It has good chemical stability and thermal stability and is easy to fabricate evaporation-type OLED devices. The organic electroluminescent device fabricated using the compound of the present invention as a light-emitting layer can reduce the start-up voltage and remarkably improve the external quantum efficiency.

### CROSS-REFERENCE TO RELATED APPLICATIONS

The application claims priority to Chinese patent application No. 2023111997268, filed on Sep. 18, 2023, the entire contents of which are incorporated herein by reference.

### TECHNICAL FIELD

The present invention relates to a phosphorescent material and the use thereof, and more particularly to a cyclic tetradentate metal platinum (II) complex phosphorescent material and the use thereof.

### BACKGROUND

For organic light-emitting diode (OLED), electrons and holes are injected from the cathode and anode, respectively, during the application of the device, and are recombined through hopping transport into the light-emitting layer. The transition of the excited state to the ground state undergoes a radiative transition. Compared with the traditional LCD, OLED has more advanced brightness, low energy consumption, fast response, and other excellent performance. It can be used to make displays and is widely used in demonstration, lighting, military, space, and other fields.

In electroluminescence, 25% singlet excitons and 75% triplet excitons are formed according to spin statistics. At the beginning of the development, the main fluorescent materials were used, and theoretically only 25% of the single-line state excitons could be applied, resulting in extremely low external quantum efficiency, which severely limited the development of OLEDs. Phosphorescent materials break the transition forbidden and achieve 100% exciton utilization by introducing heavy metal atoms to induce a self-selective orbital coupling effect. In general, a cyclic metal platinum (II) complex phosphorescent material is formed by coordinating a ligand and a metal platinum atom, and modifying the chemical structure of the ligand can change the luminescent properties of the metal complex. Compared with bidentate and tridentate ligand structures, tetradentate complexes can suppress vibrational coupling, reduce nonradiative transitions, improve the luminescence quantum efficiency, and achieve efficient phosphorescent emission. Although many structures of cyclic tetradentate metal platinum (II) complexes have been reported, efficient, stable, and high-brightness platinum (II) complexes need to be developed. Therefore, the development of novel cyclic tetradentate metal platinum (II) complexes is still the top priority in the field of OLED.

### SUMMARY

In order to develop a wider variety of phosphorescent materials with higher performance, it is an object of the present invention to provide a cyclic tetradentate metal platinum (II) complex phosphorescent material and uses thereof. The present invention develops a new 6/6/6 metal fused-ring structure based on a tetradentate ligand of 8-phenylquinoline, benzoxazole, and phenoxy groups, resulting in a novel tetradentate platinum (II) complex containing the 6/6/6 metal fused-ring structure. The complex provided can be prepared as an organic electroluminescent device as a light-emitting layer so that the device has excellent properties. It can increase the external quantum efficiency and reduce the start-up voltage in organic electroluminescent devices.

In order to achieve the technical objectives above, the technical solution of the present invention is as follows.

The present invention provides a cyclic tetradentate metal platinum (II) complex phosphorescent material having the general structure shown in formula (I):

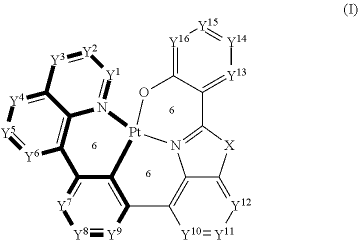

where X is selected from NR′, S or O; where R′ is selected from hydrogen, halogen, substituted or unsubstituted C1-C30 alkyl, substituted or unsubstituted C1-C30 cycloalkyl, substituted or unsubstituted C6-C30 aryl, and combination thereof;
Y¹-Y¹⁶ are each independently selected from CR¹-CR¹⁶ or N, and the Y¹-Y¹⁶ are not N at the same time; where R¹-R¹⁶ are each independently selected from hydrogen, halogen, substituted or unsubstituted C1-C60 alkyl, substituted or unsubstituted C1-C60 cycloalkyl, substituted or unsubstituted C1-C60 heterocycloalkyl, substituted or unsubstituted C6-C60 aryl, substituted or unsubstituted C6-C18 arylamine, substituted or unsubstituted C18-C60 arylsilyl, and combination thereof; and the heteroatom is selected from O and N.

Optionally, R′ is selected from hydrogen, F, substituted or unsubstituted C1-C10 alkyl, substituted or unsubstituted C1-C10 cycloalkyl, substituted or unsubstituted C6-C30 aryl, substituted or unsubstituted C6-C30 azaaryl, and combination thereof.

Optionally, R′ is selected from hydrogen, F, methyl, ethyl, propyl, isopropyl, t-butyl, cyclopropyl, cyclobutyl, cyclopentyl, cyclohexyl, phenyl, biphenyl, triaryl, naphthyl, pyridyl, and combination thereof.

Optionally, R¹-R¹⁶ are each independently selected from hydrogen, F, substituted or unsubstituted C1-C30 alkyl, substituted or unsubstituted C1-C30 cycloalkyl, substituted or unsubstituted C1-C30 N heterocycloalkyl, substituted or unsubstituted C6-C30 aryl, substituted or unsubstituted C12-C18 arylamine, substituted or unsubstituted C18 arylsilyl, and combination thereof.

Optionally, R¹-R¹⁶ are each independently selected from hydrogen, F, methyl, ethyl, propyl, isopropyl, t-butyl, heptyl, cyclopropyl, cyclobutyl, cyclopentyl, cyclohexyl, phenyl, biphenyl, triaryl, naphthyl, pyridyl, quinolinyl, benzofuranyl, dibenzofuranyl, triarylsilane, diphenylamine, diphenylamine oxide, and combination thereof.

Optionally, two or more adjacent R¹-R¹⁶ are each independently or selectively linked to form a condensed ring.

Optionally, at least one of R′ and R¹-R¹⁶ is hydrogen.

Preferably, the cyclic tetradentate metal platinum (II) complex phosphorescent material is any one of the following structural formulae:

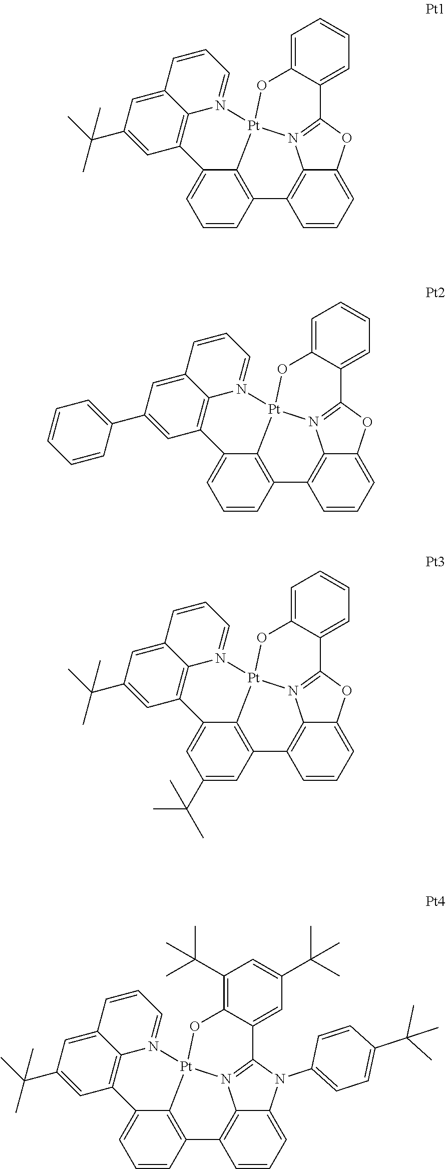

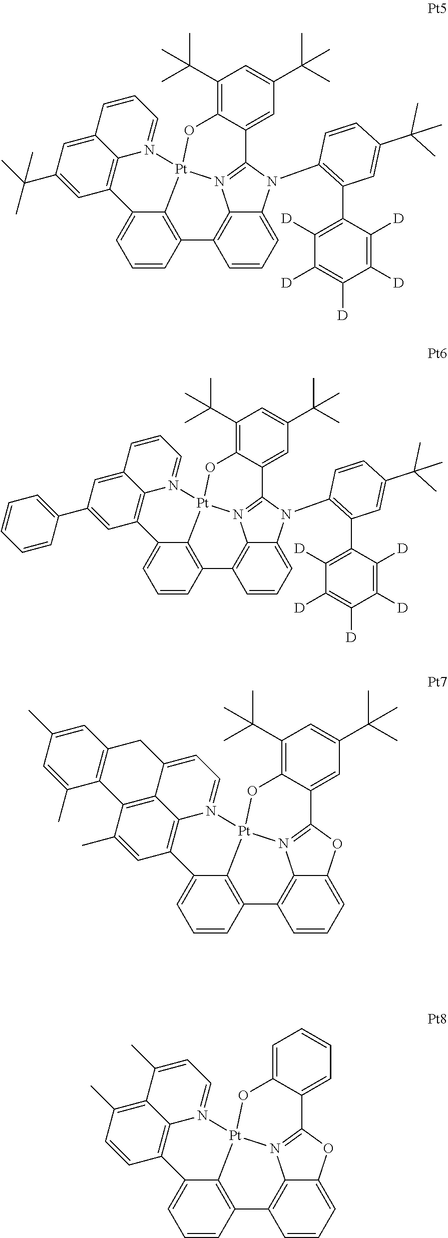

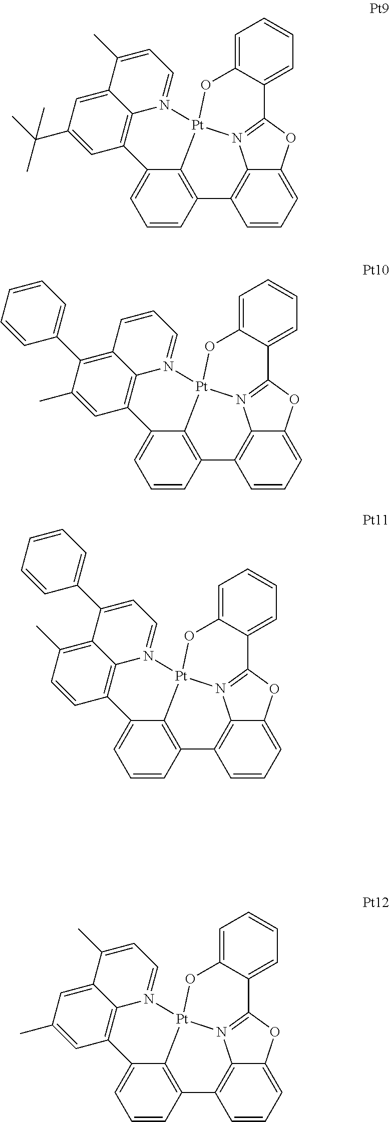

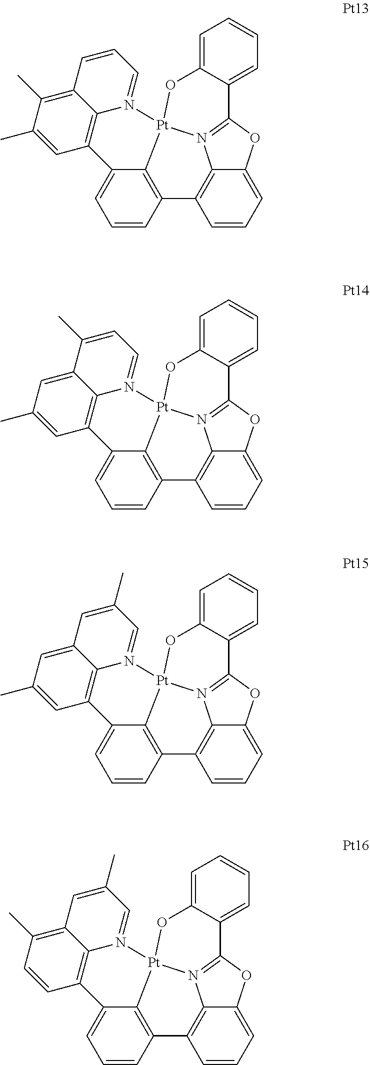

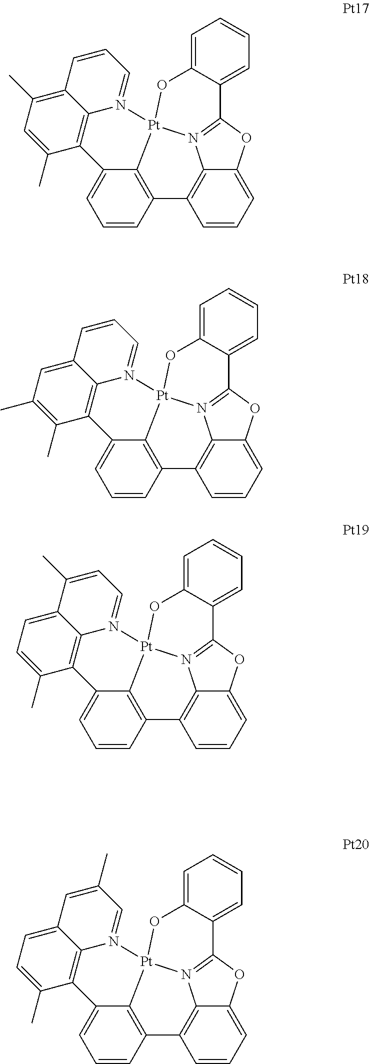

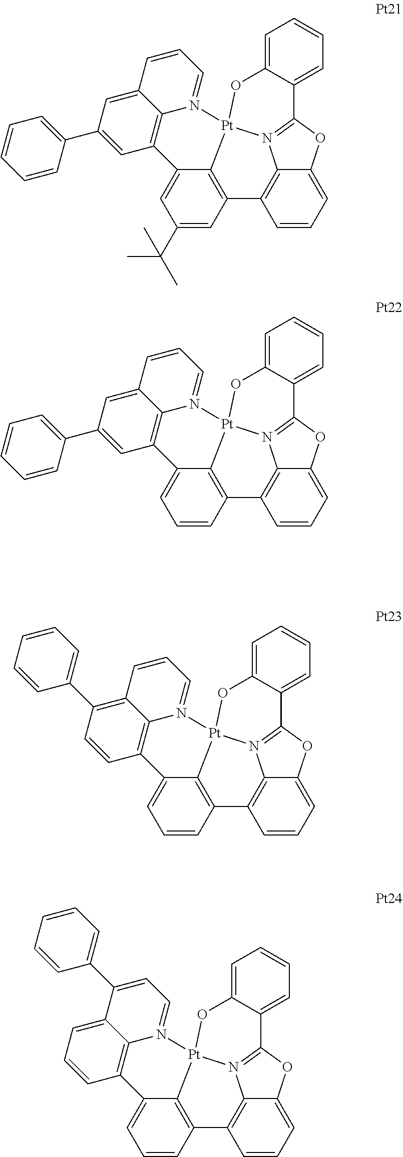

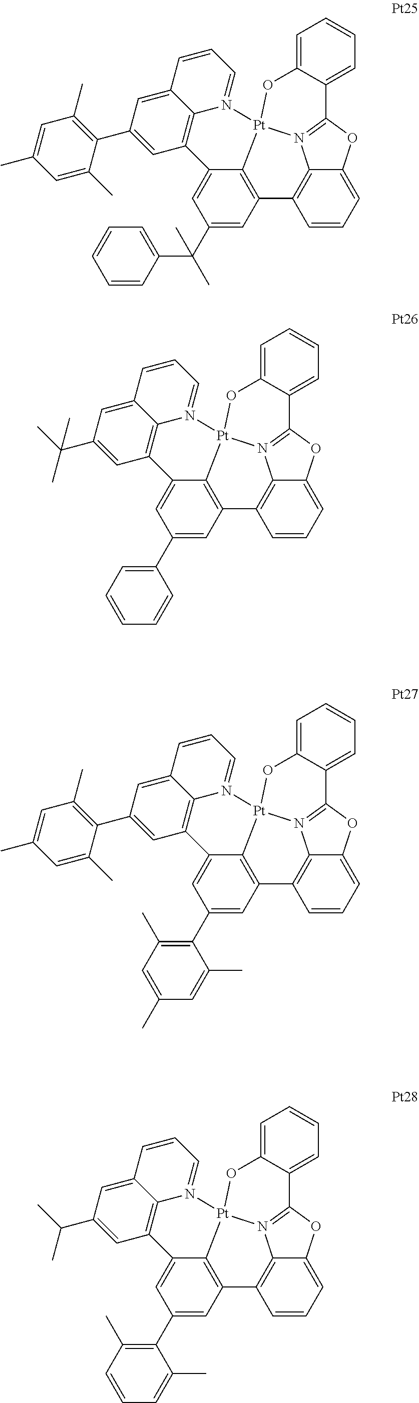

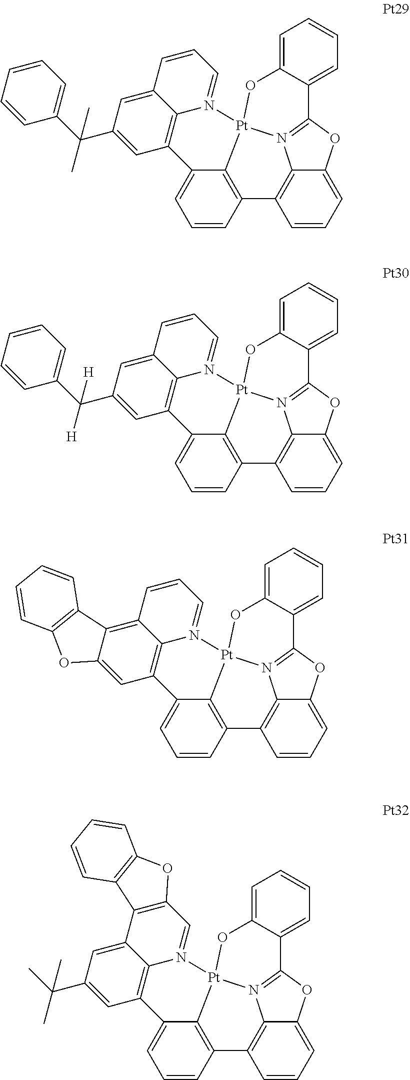

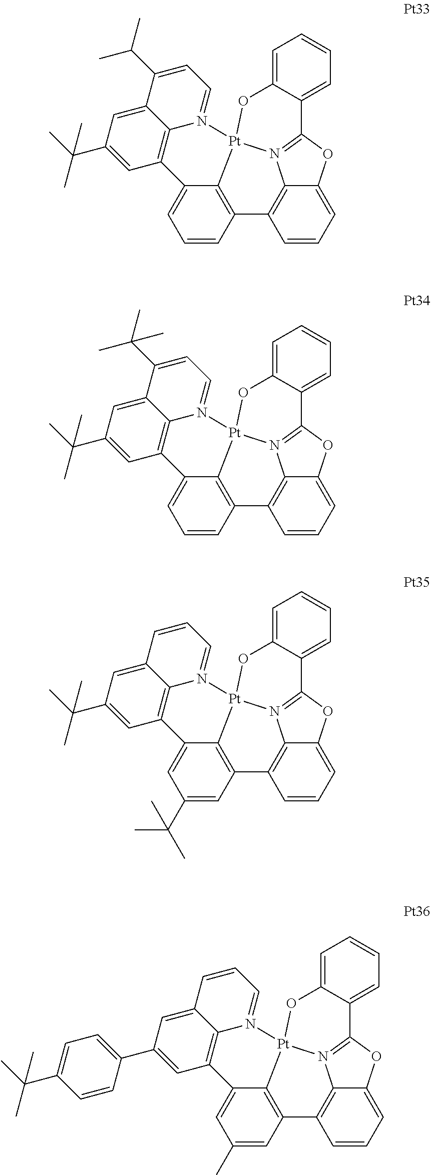

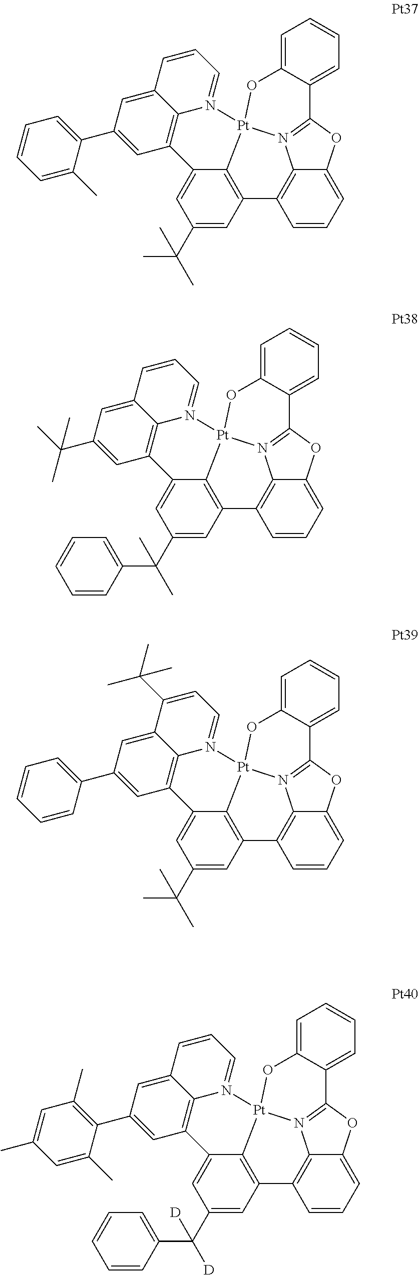

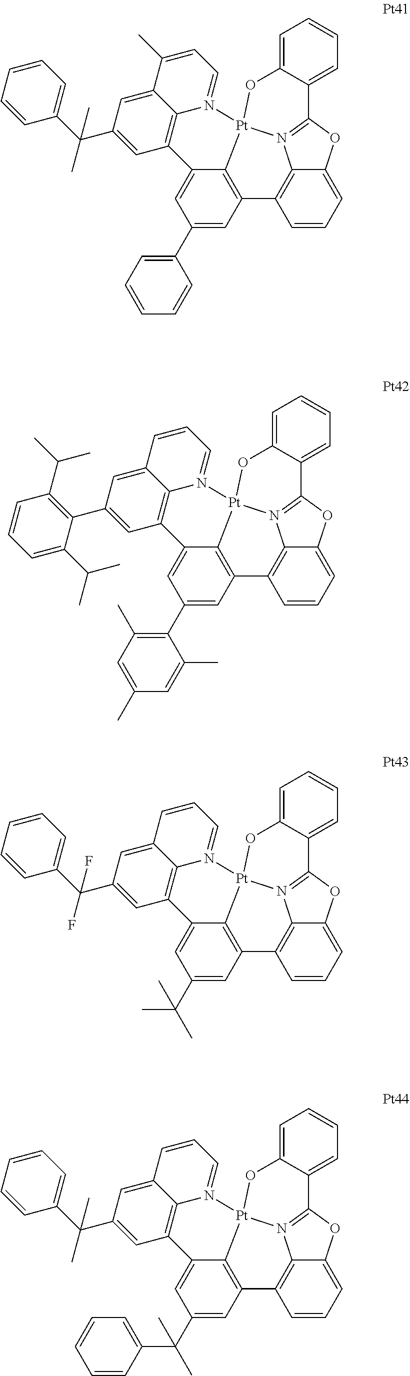

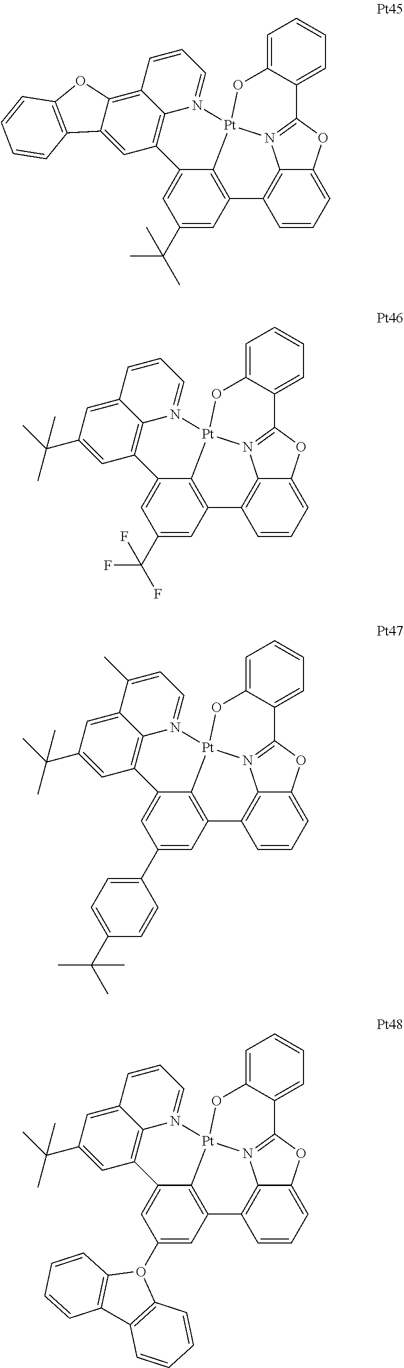

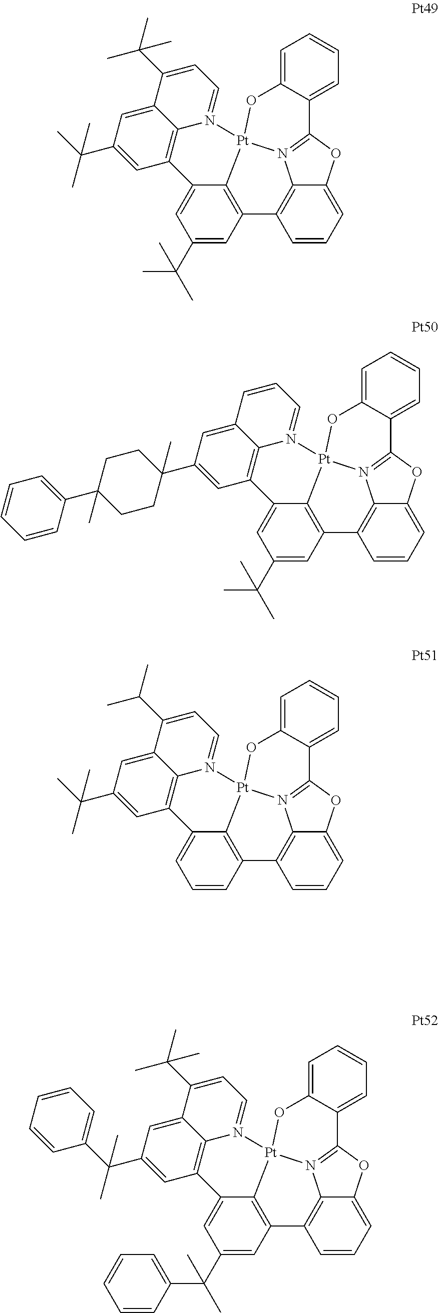

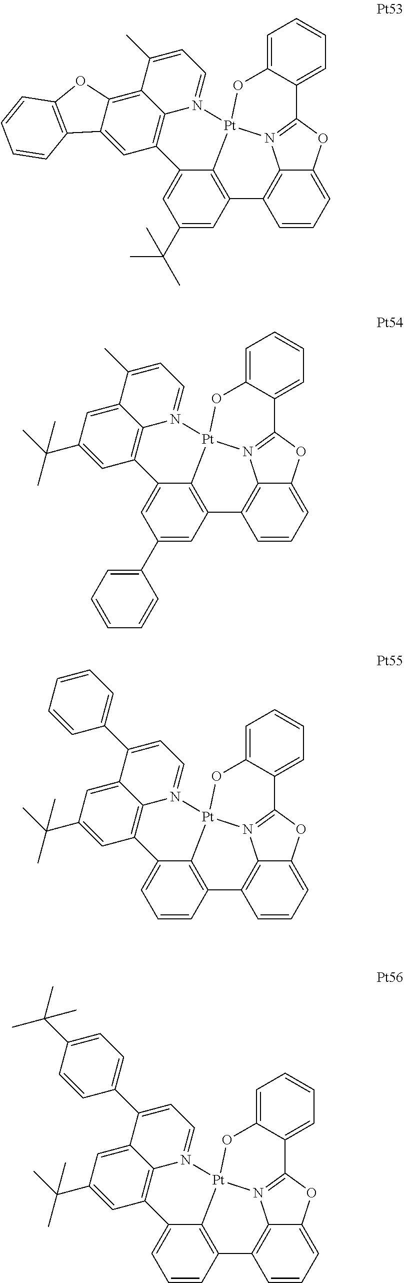

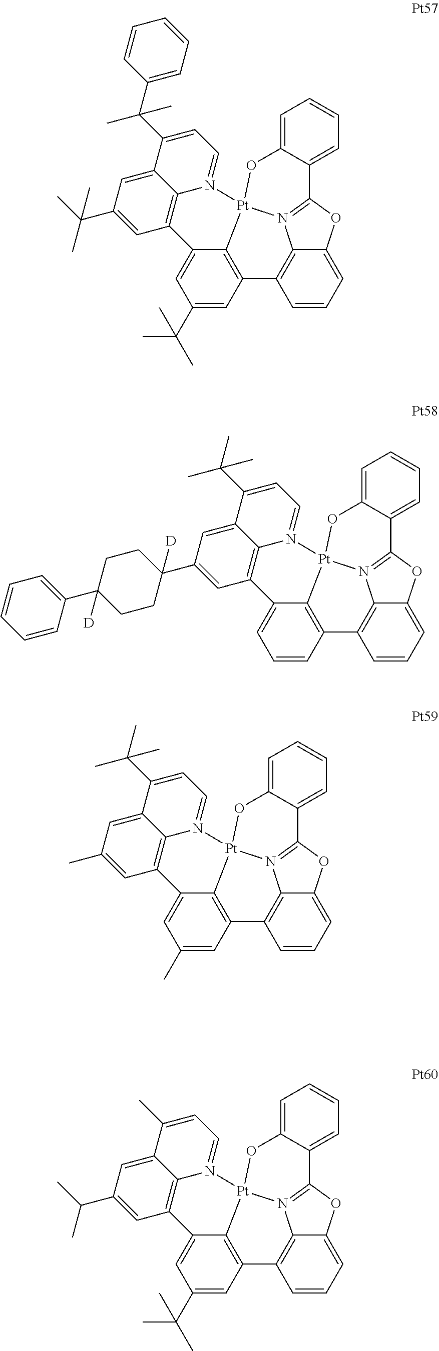

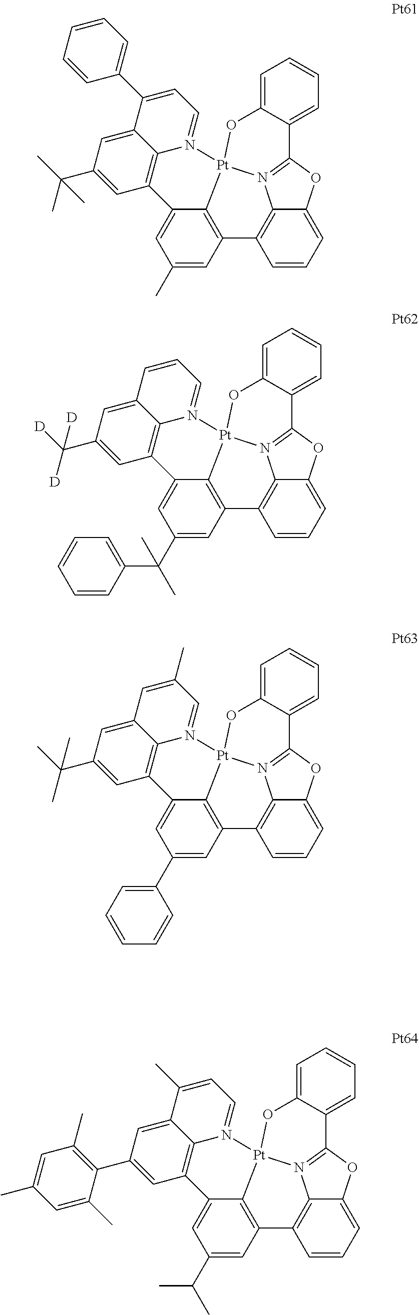

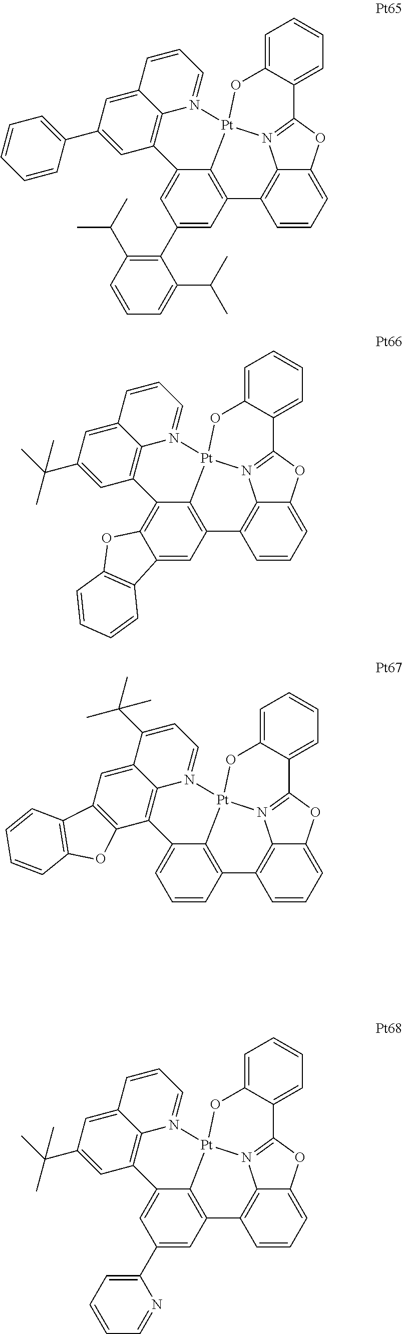

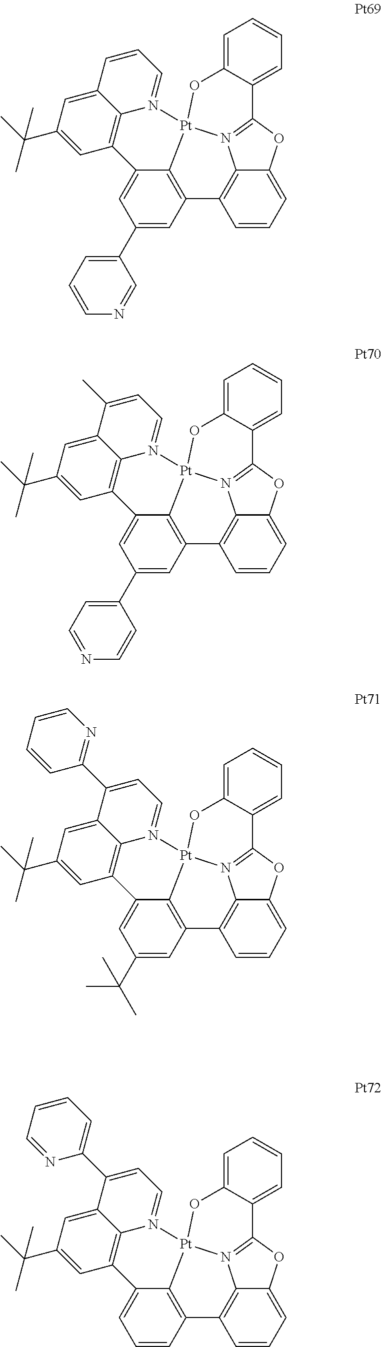

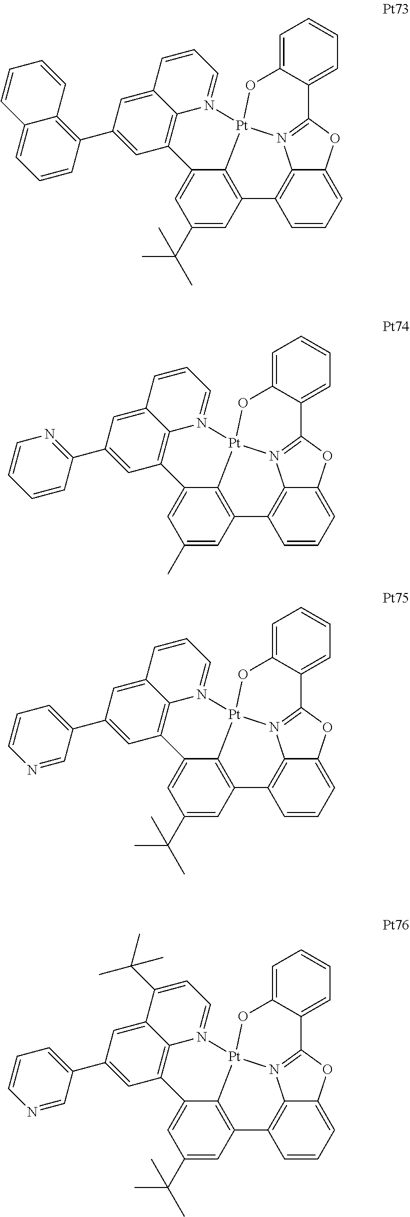

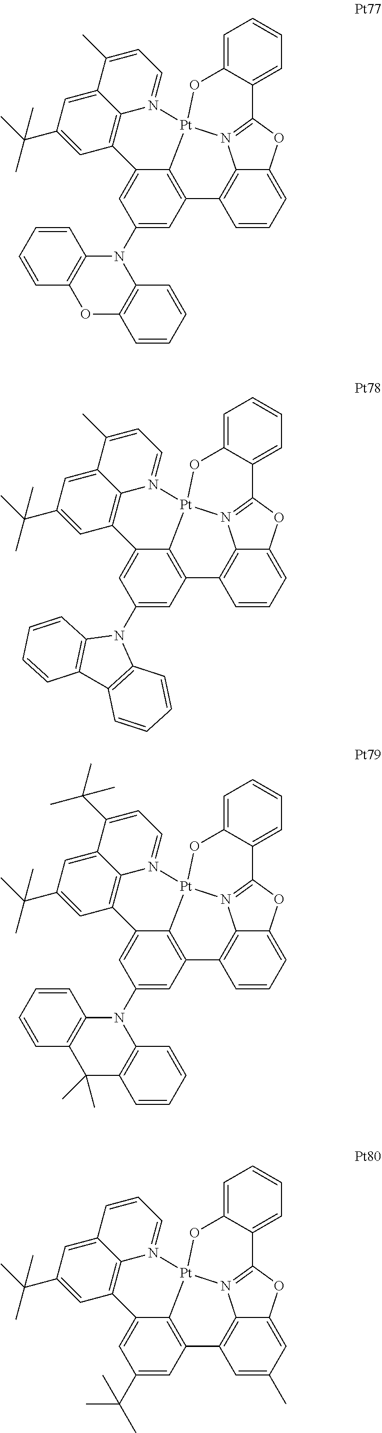

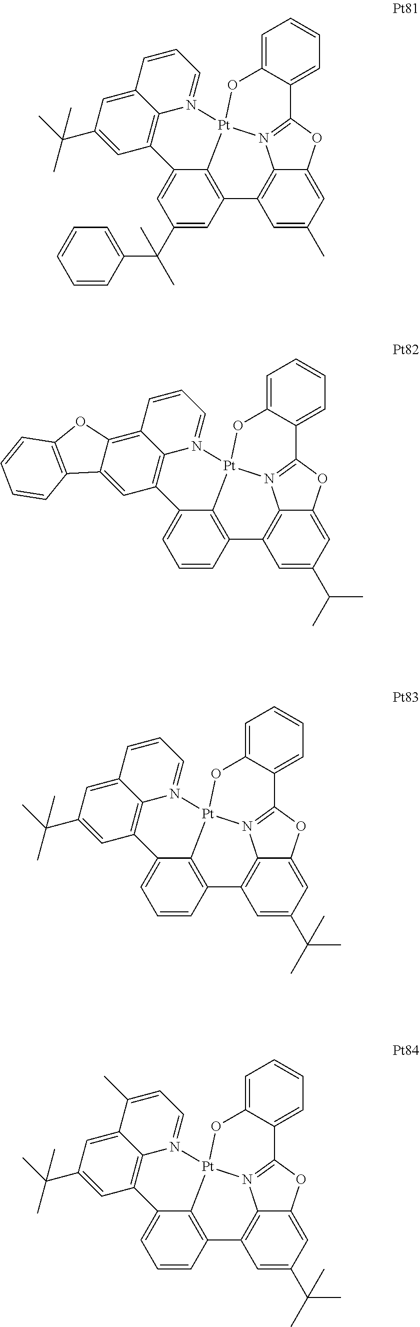

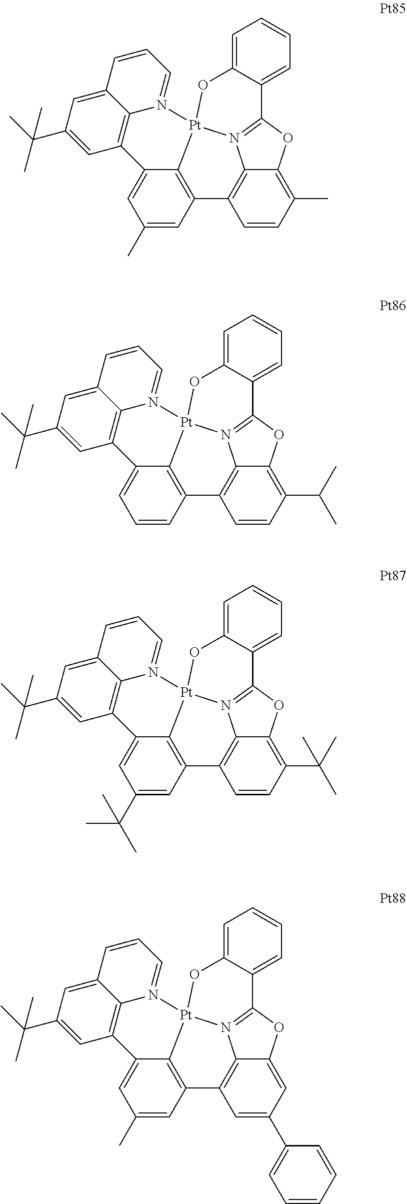

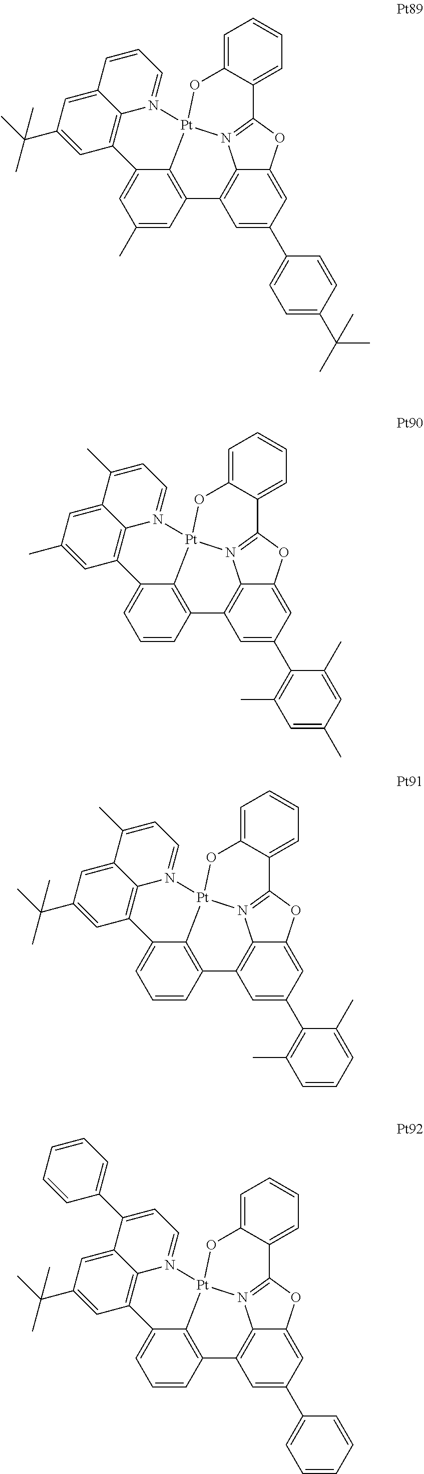

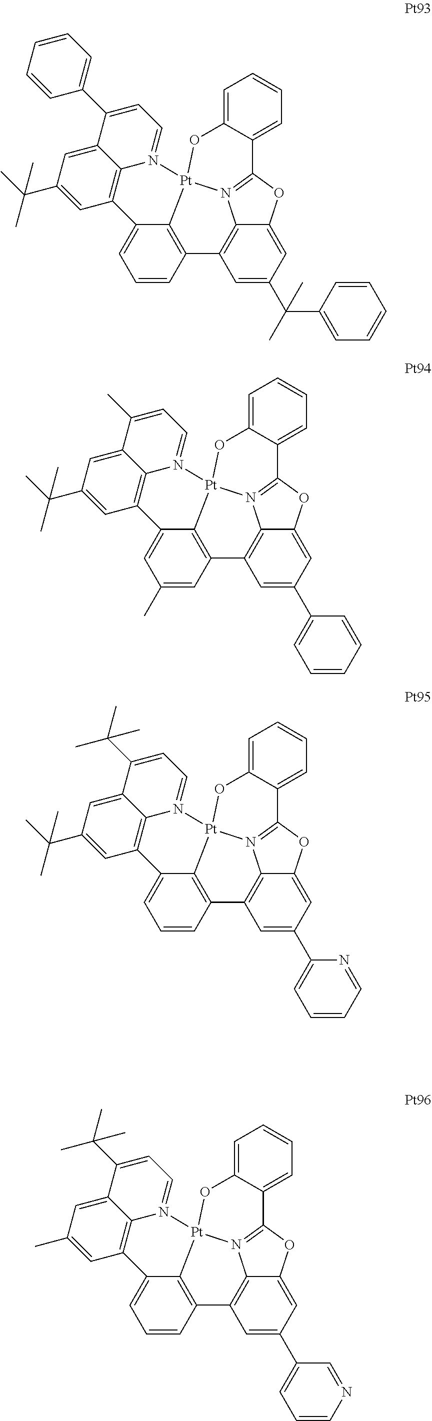

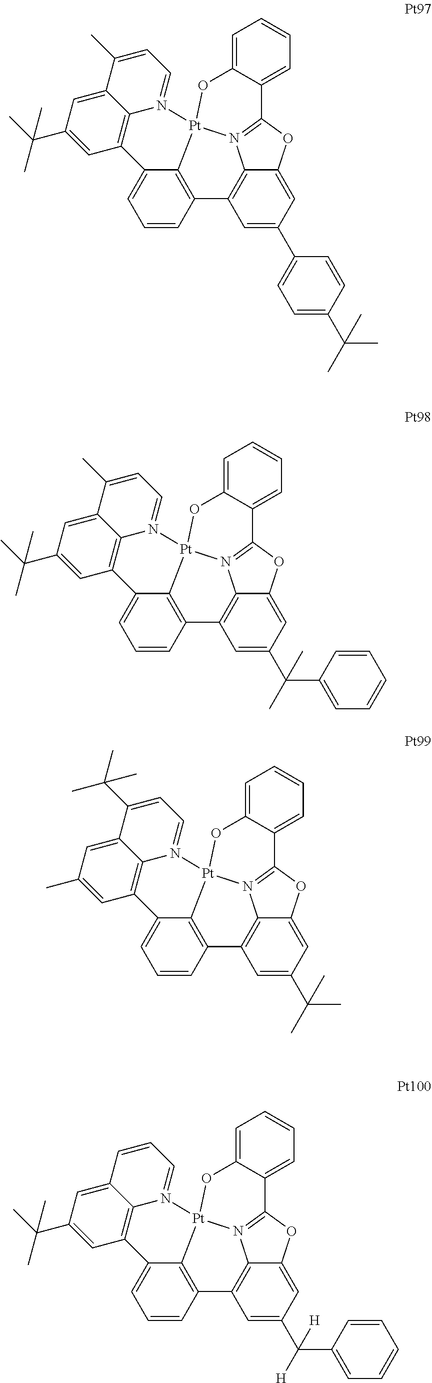

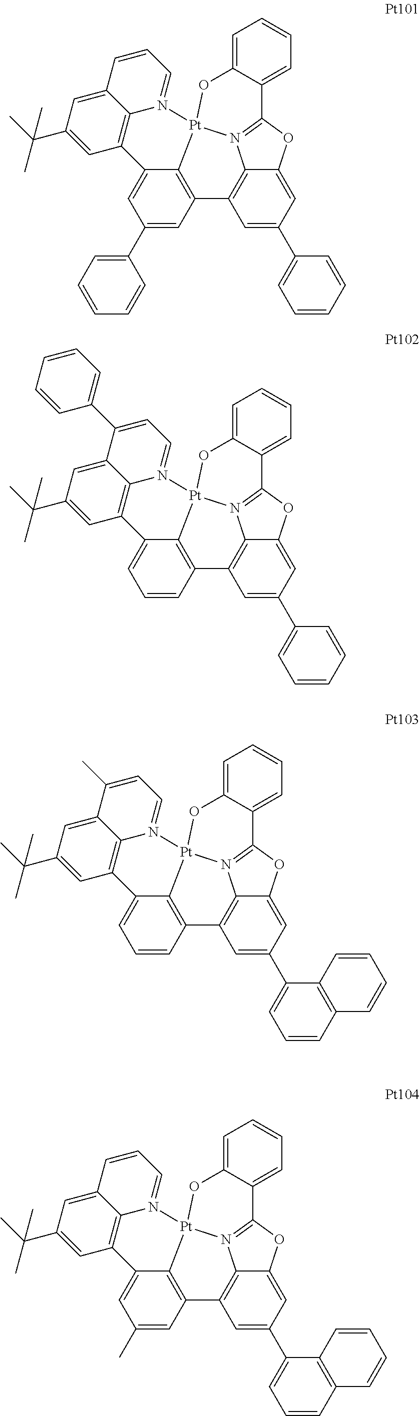

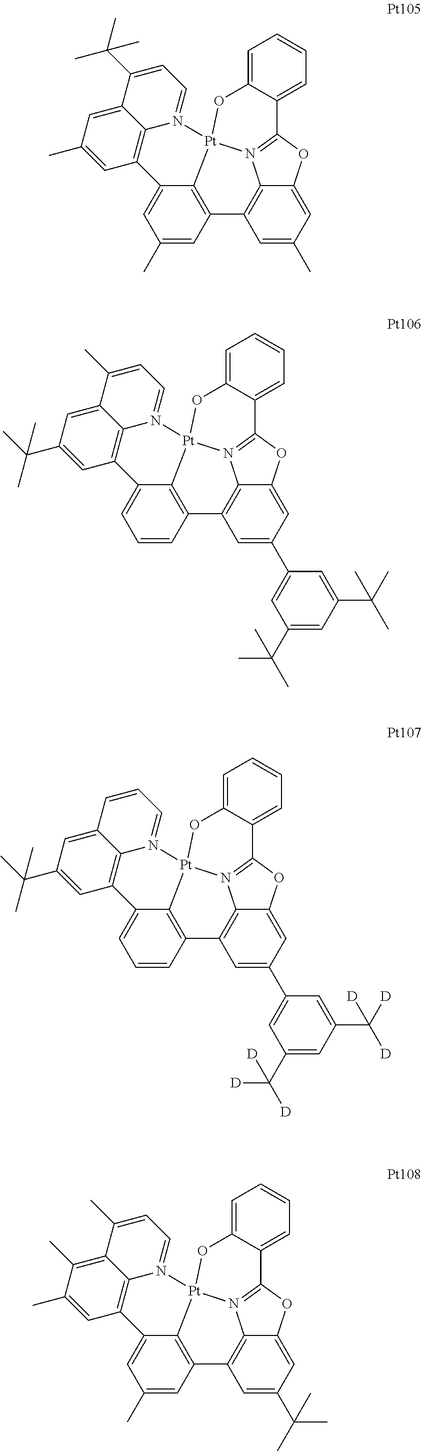

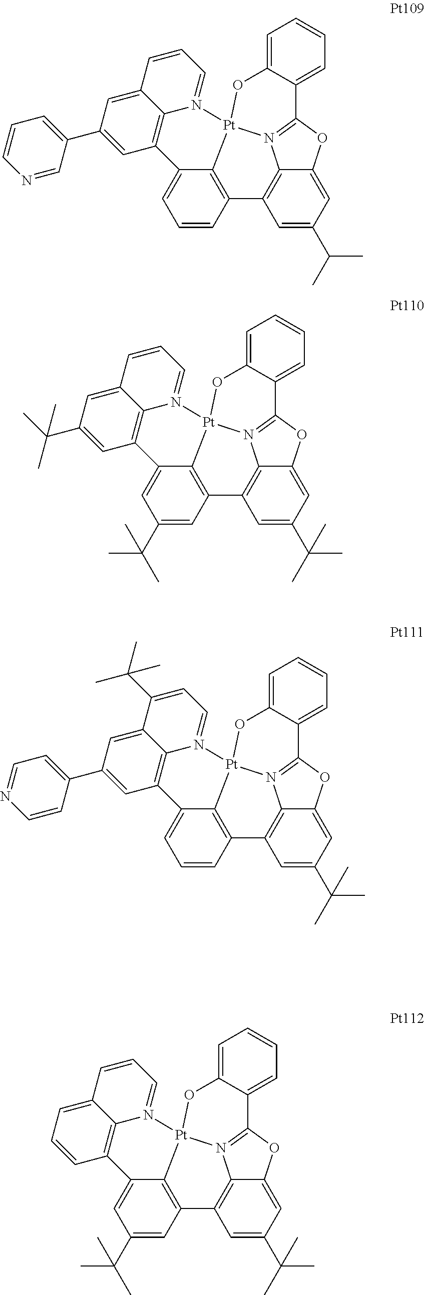

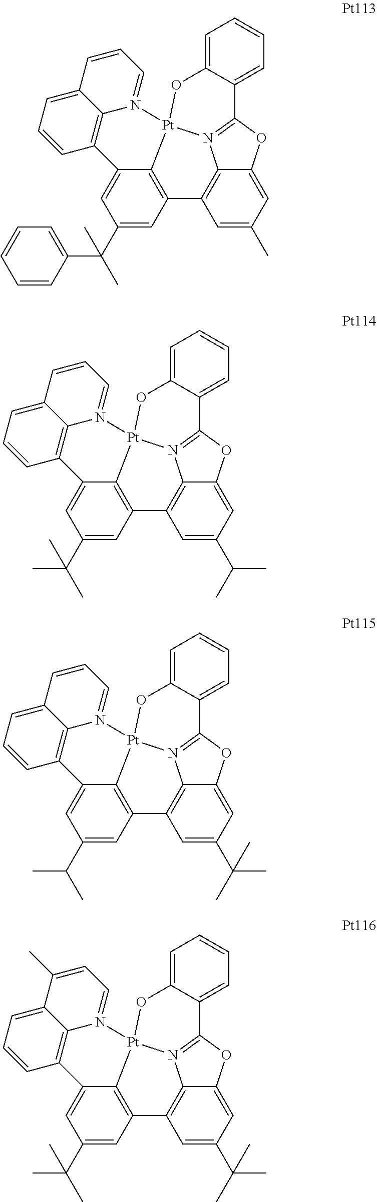

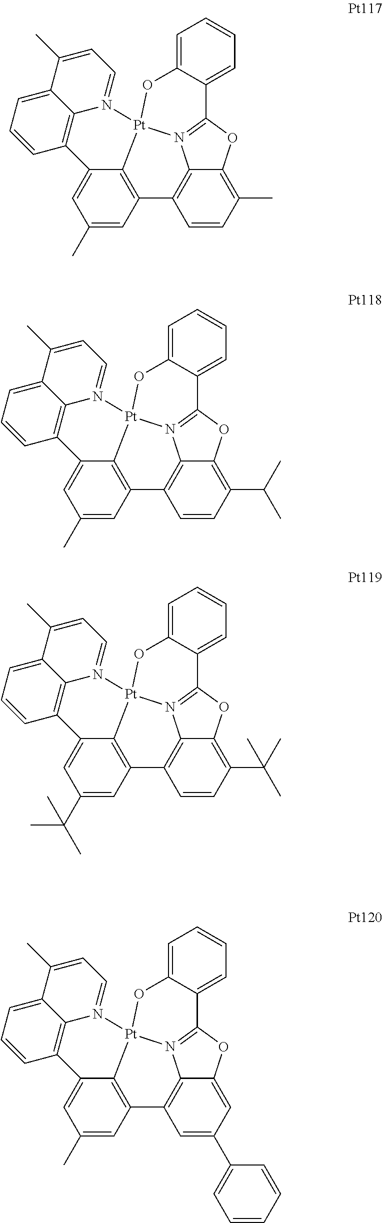

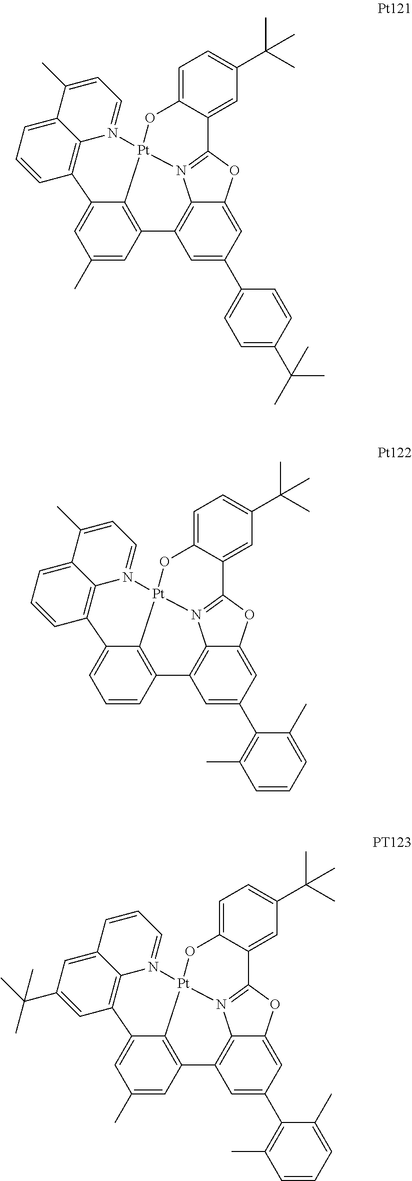

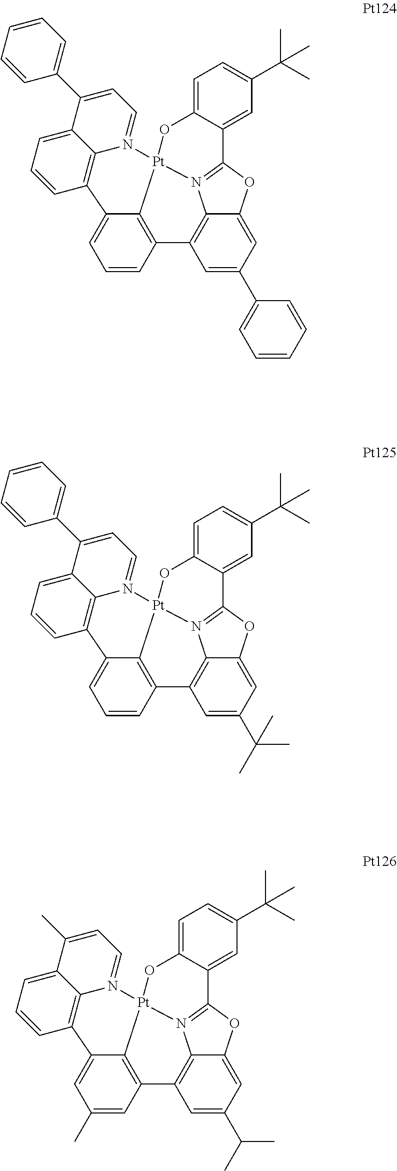

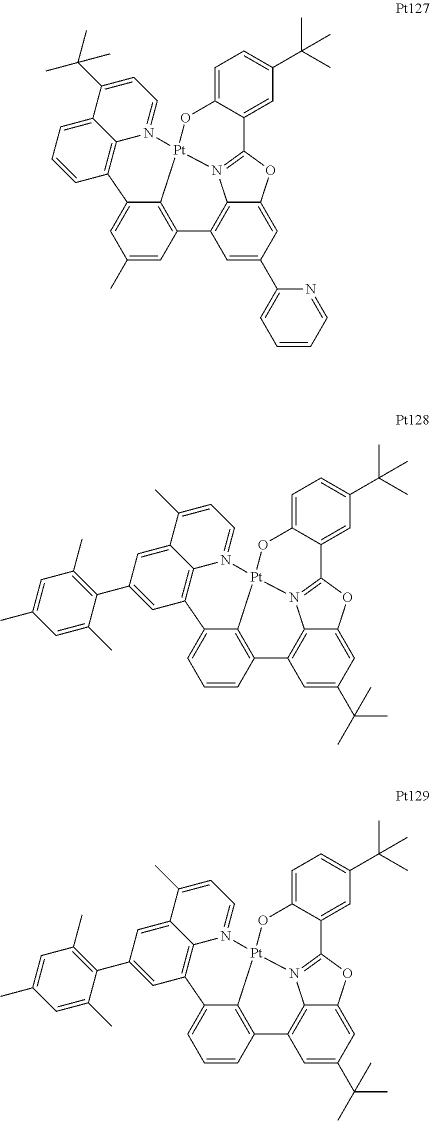

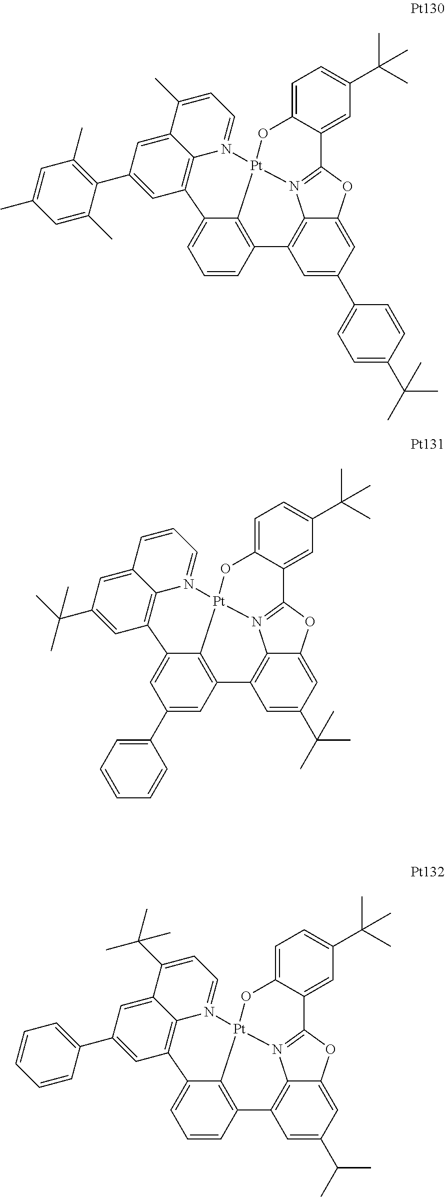

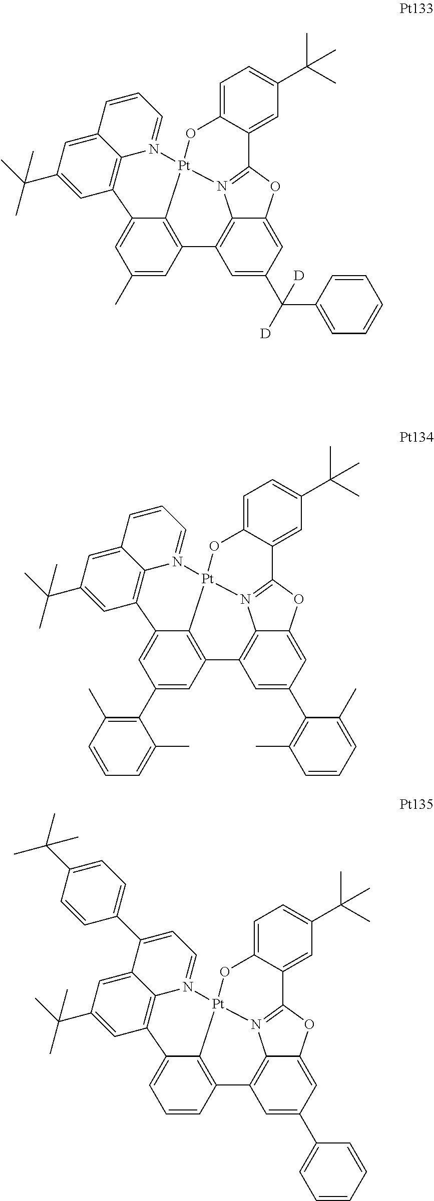

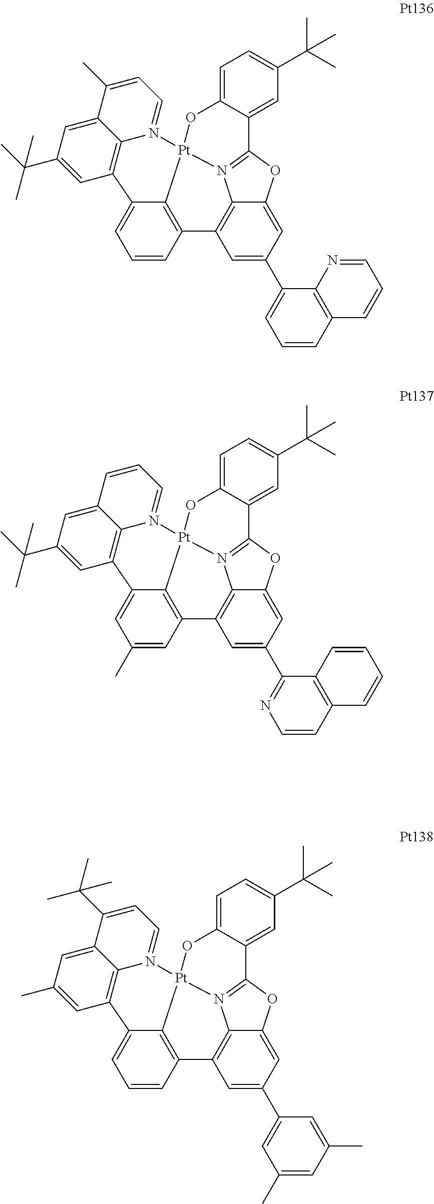

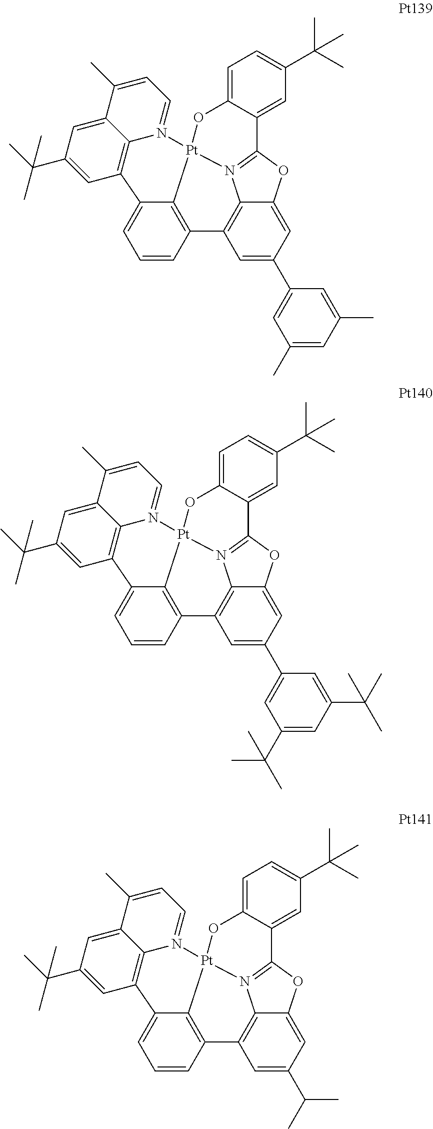

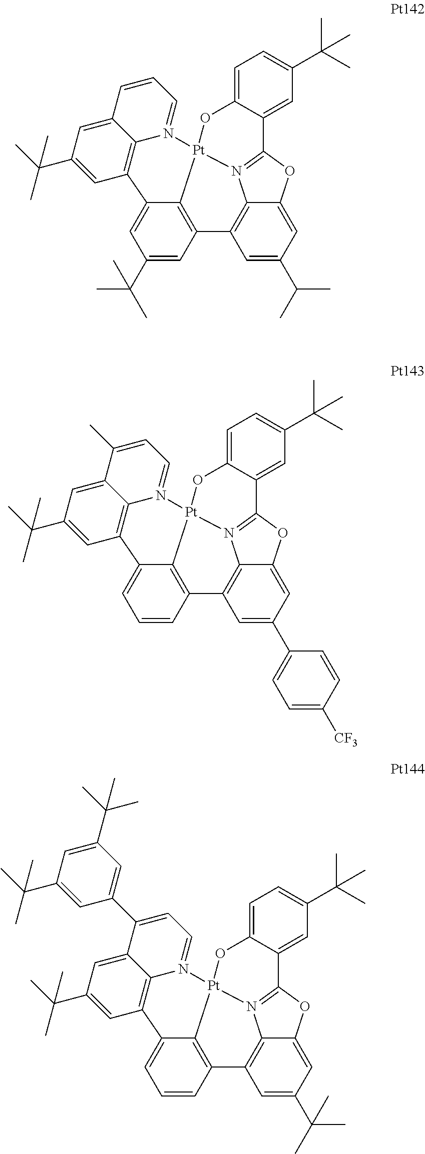

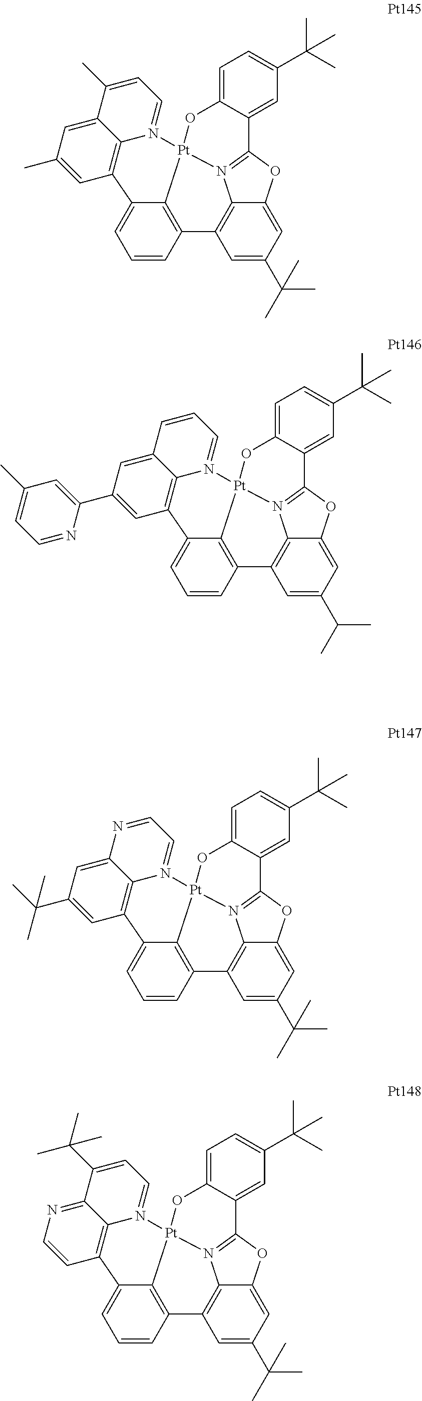

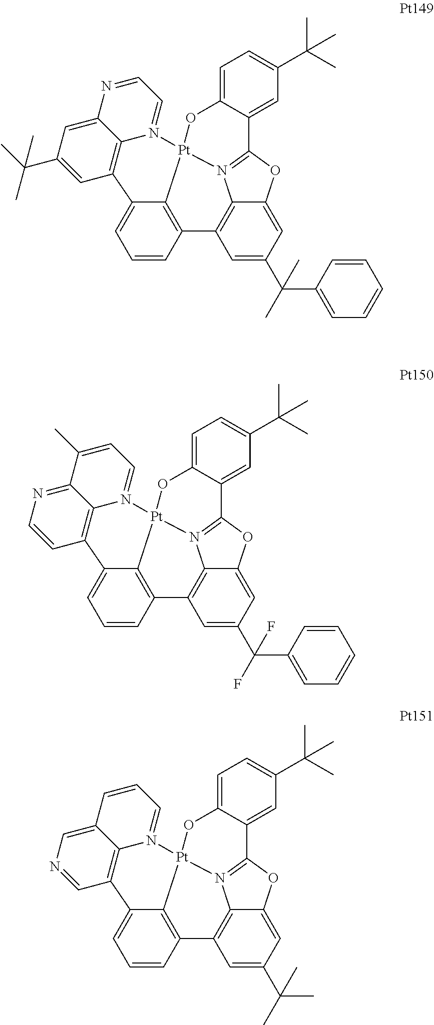

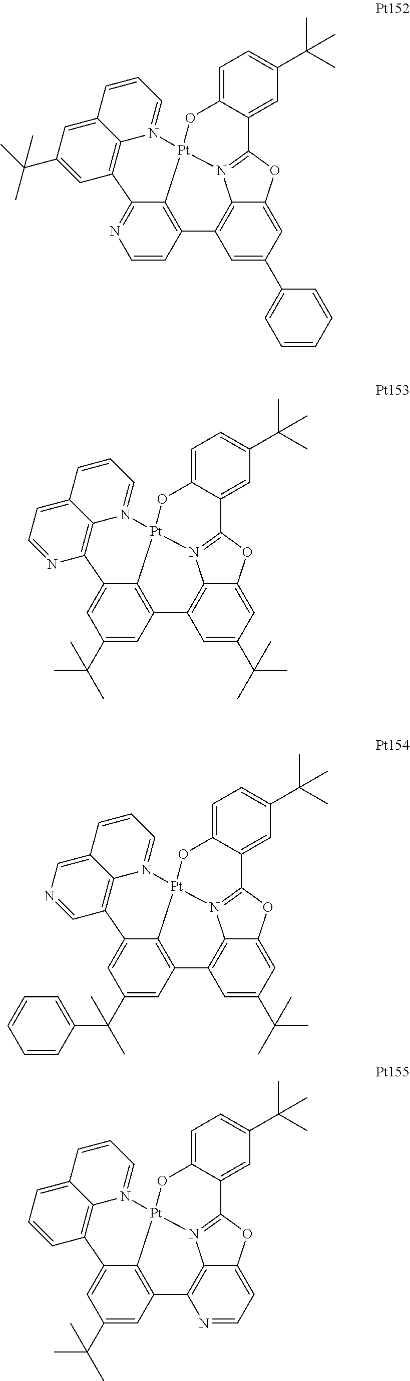

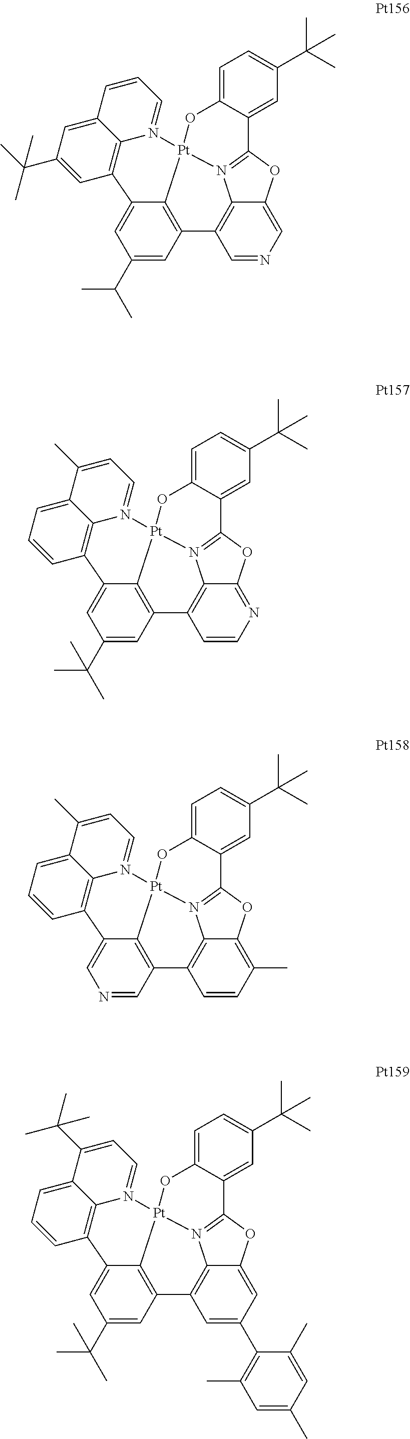

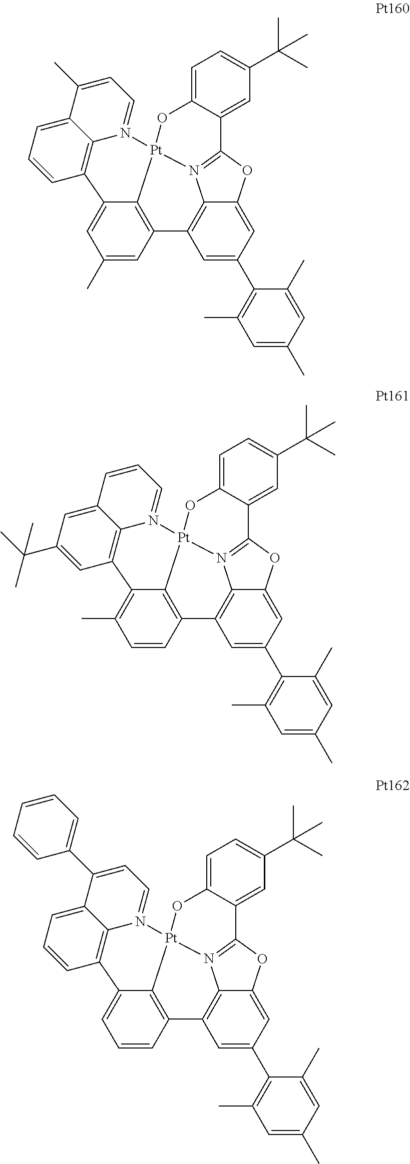

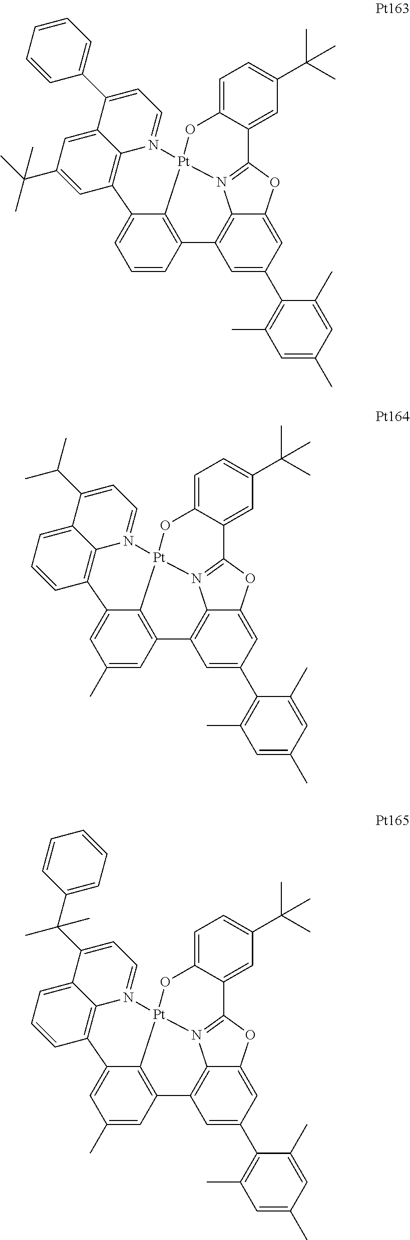

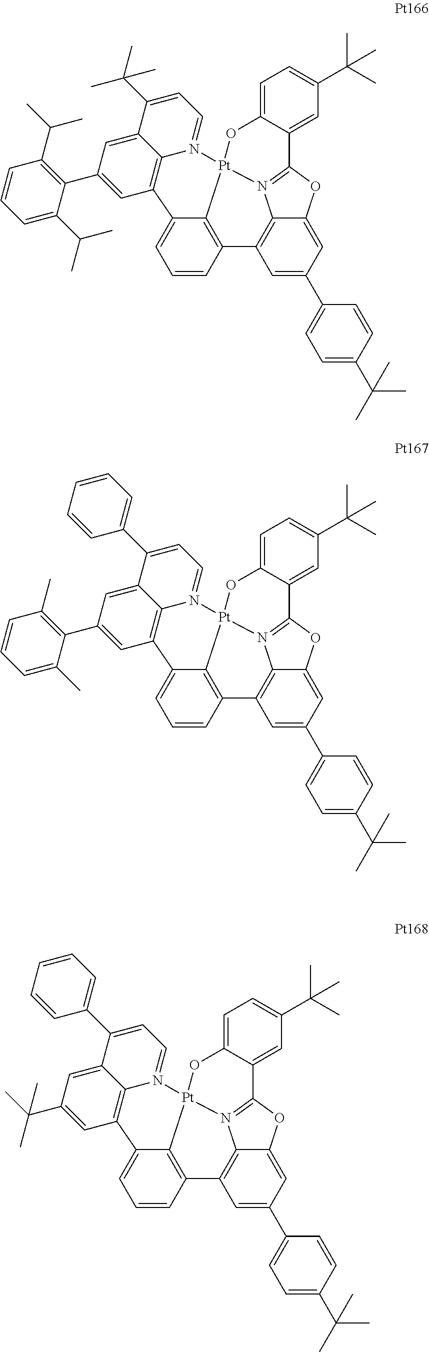

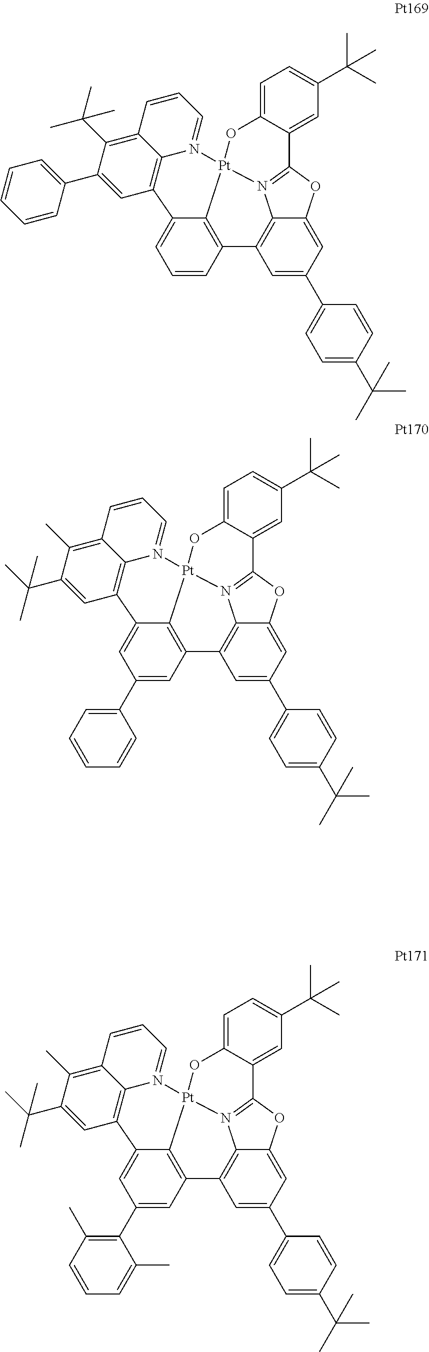

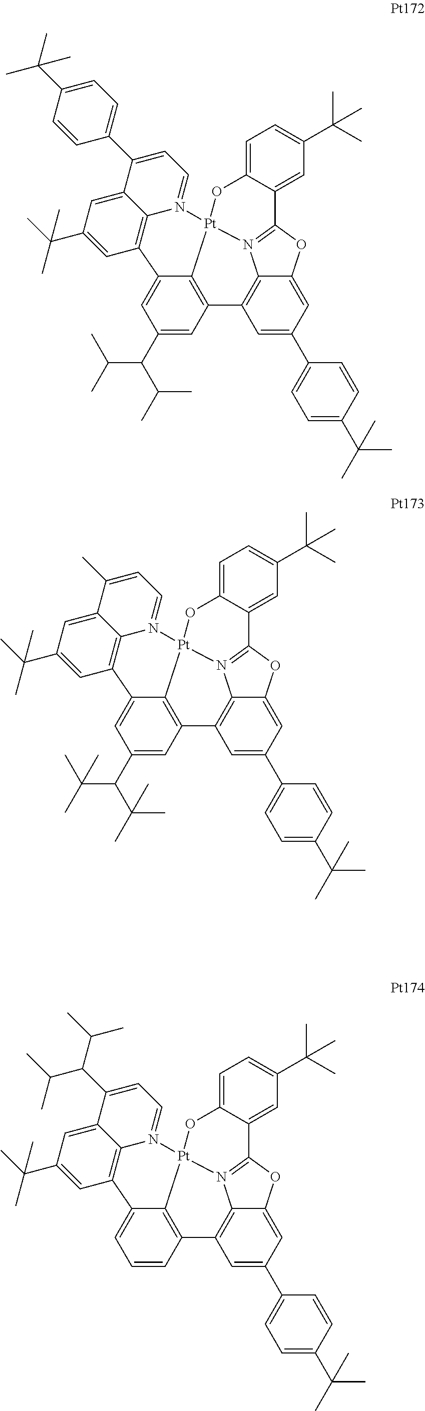

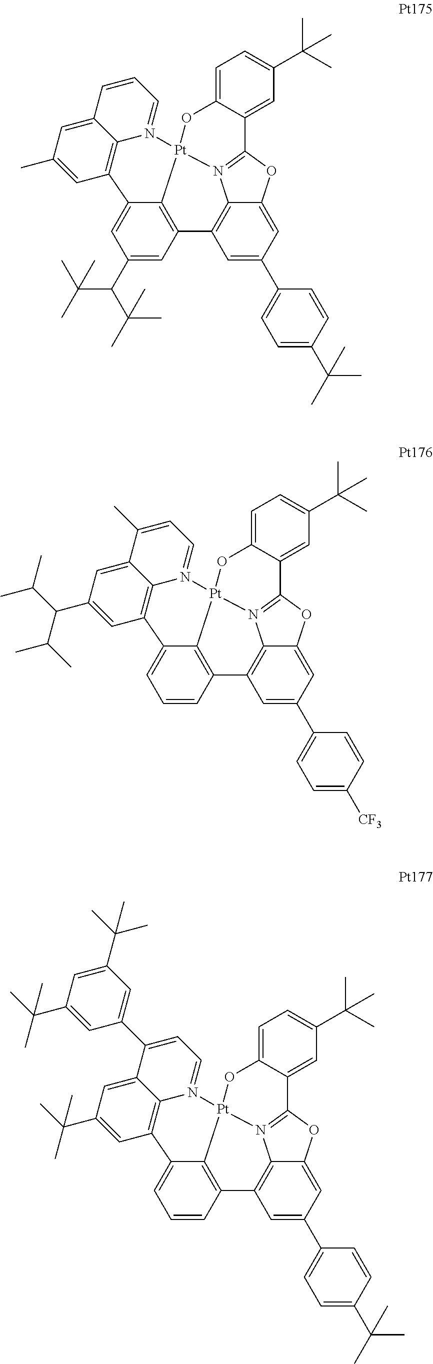

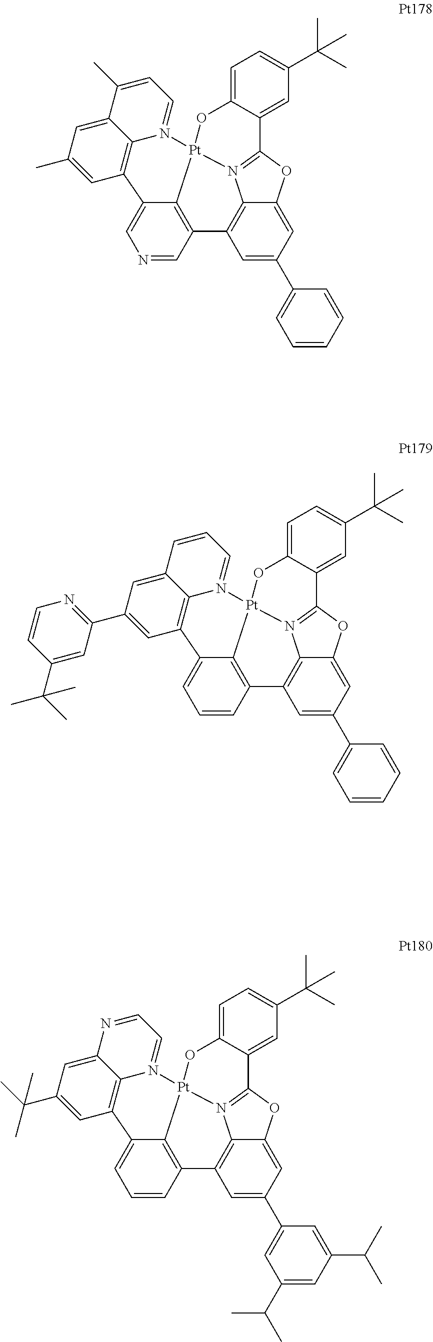

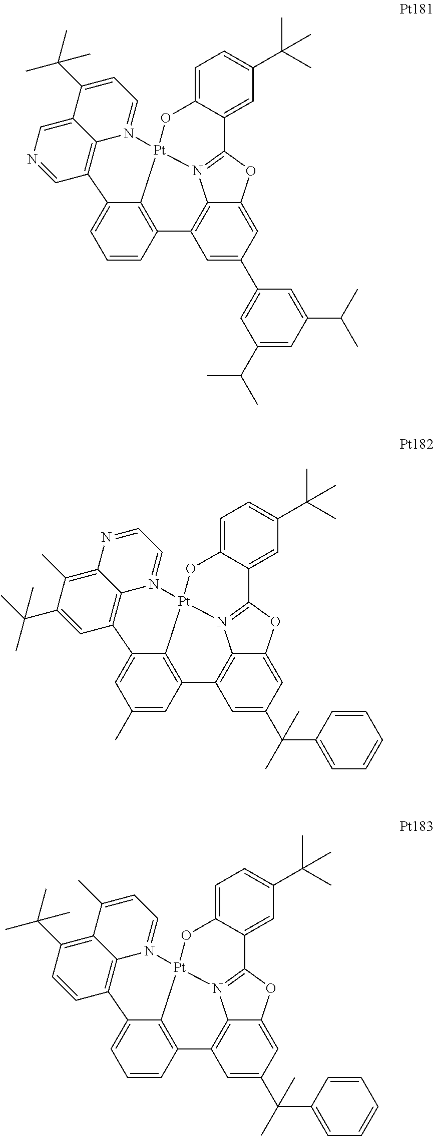

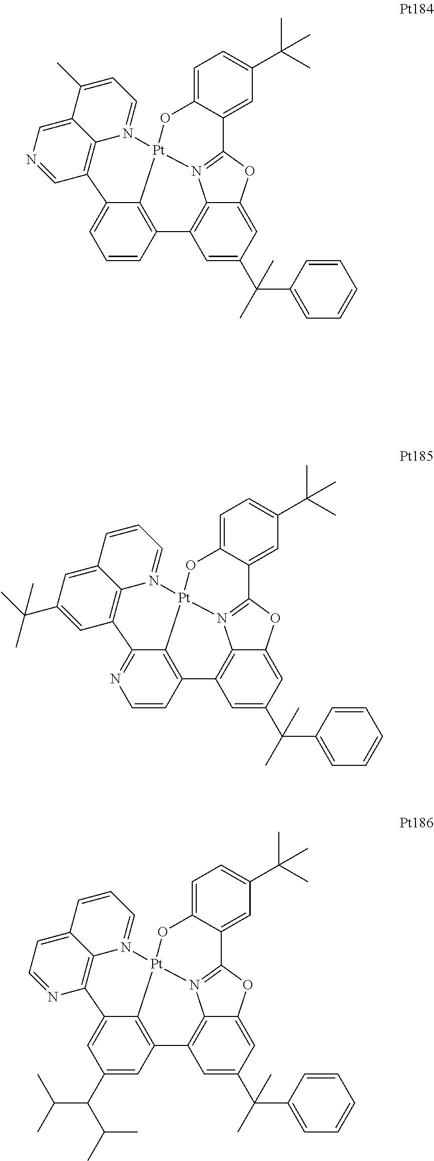

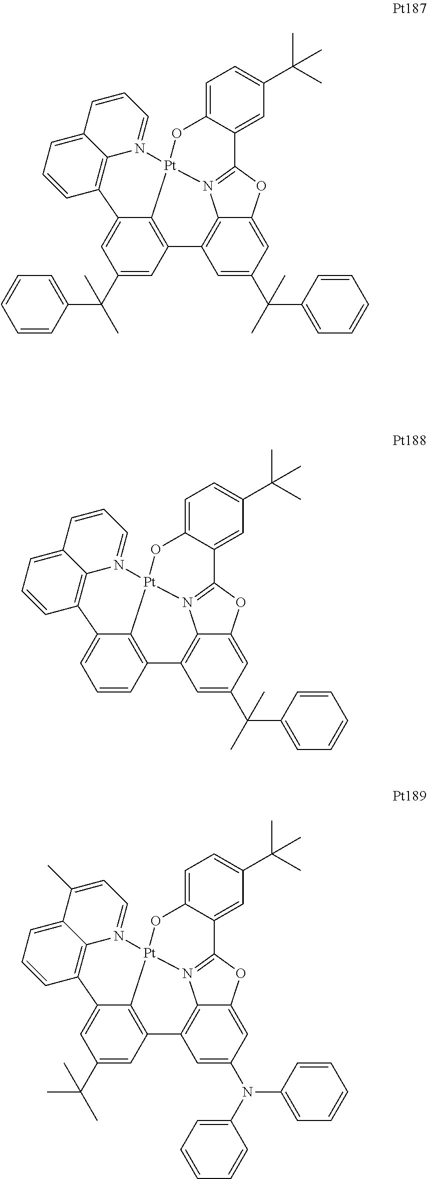

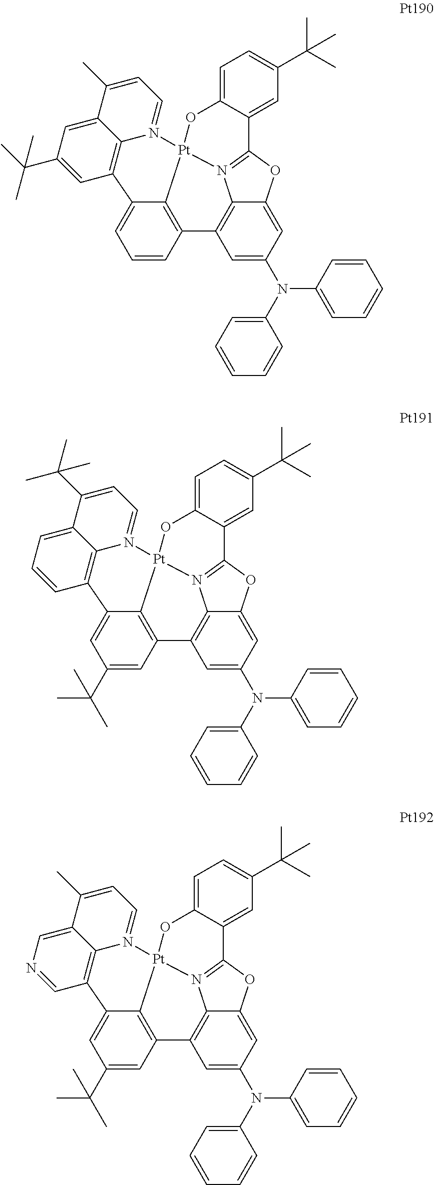

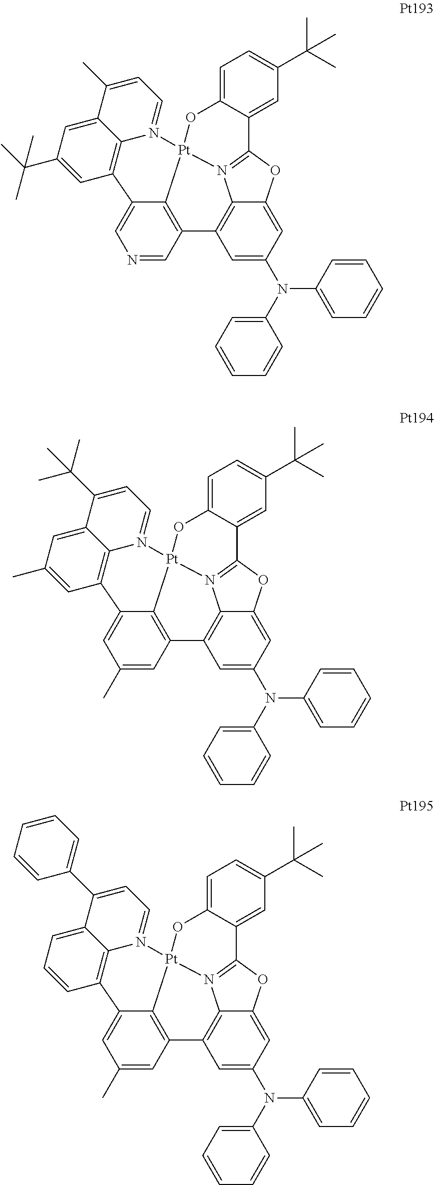

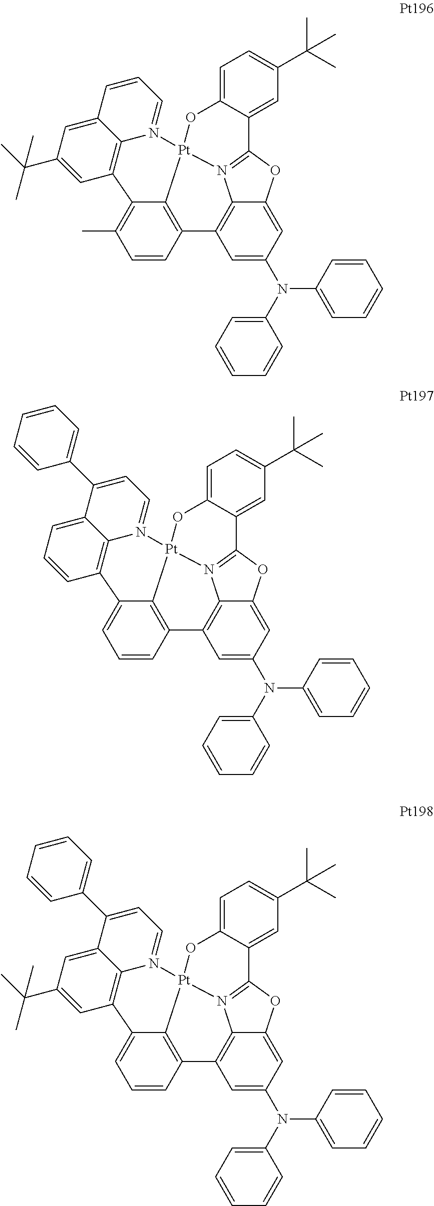

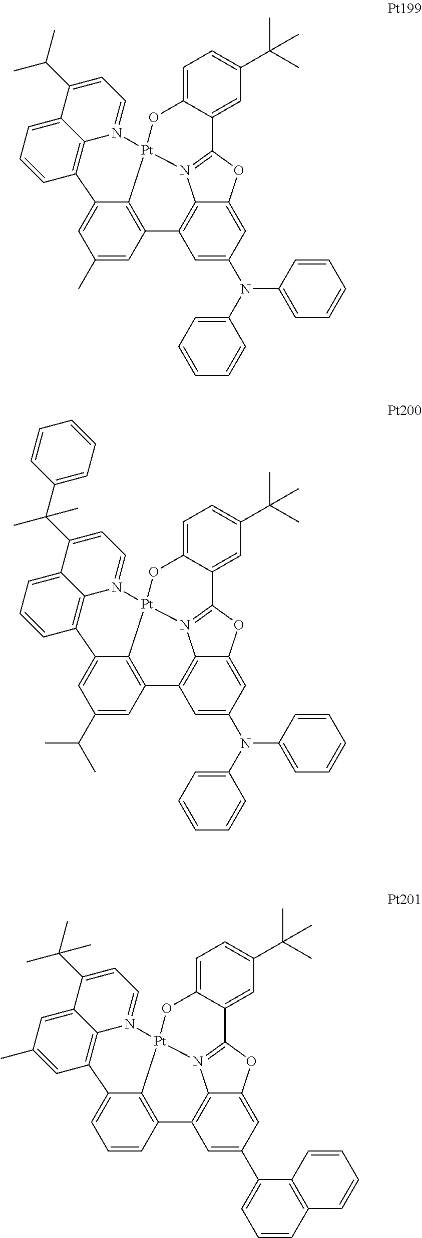

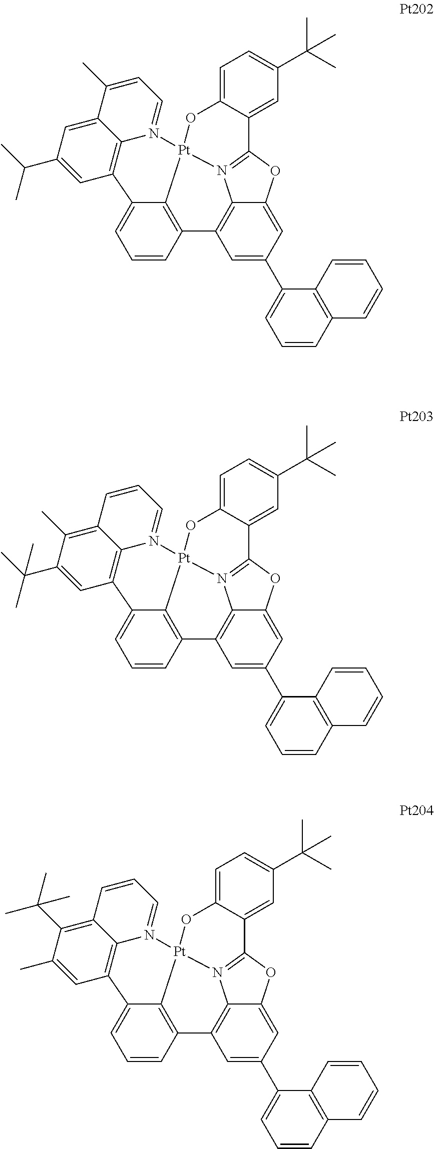

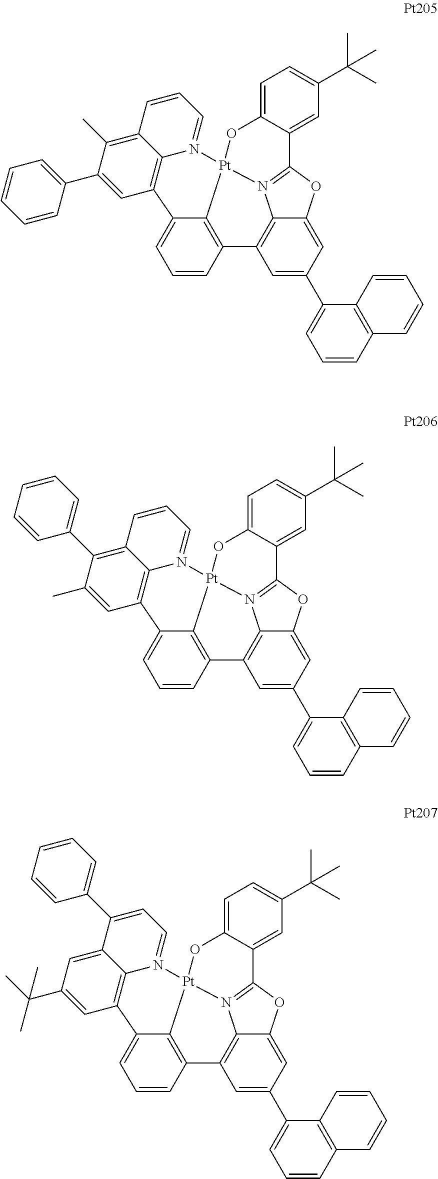

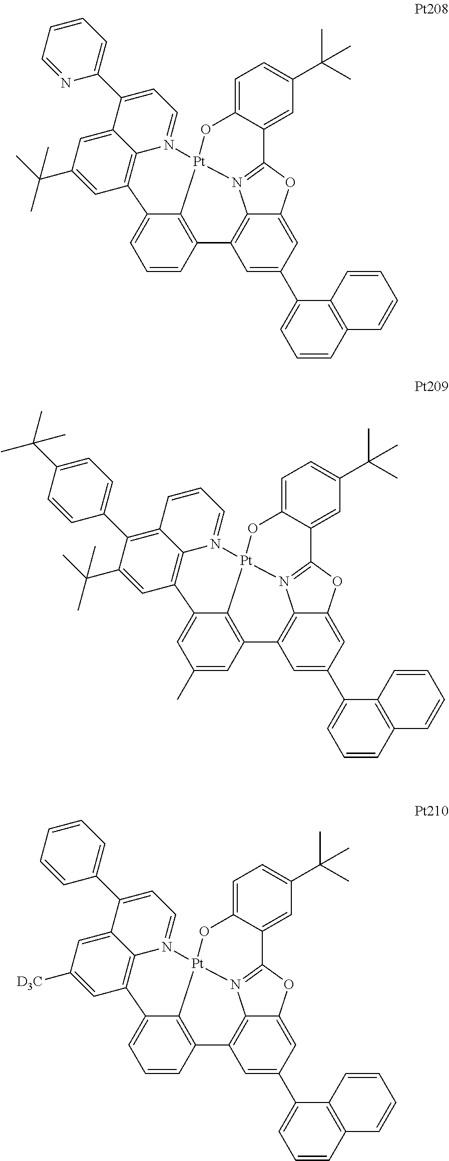

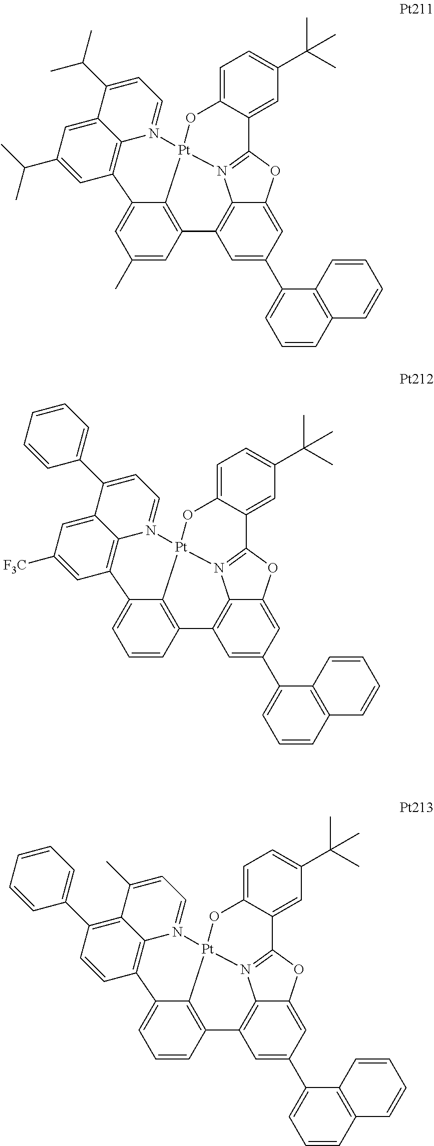

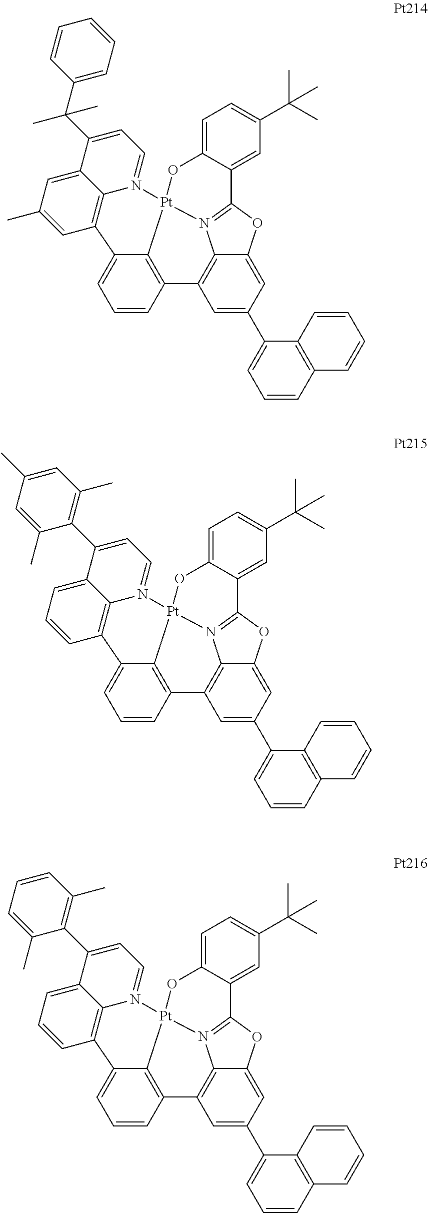

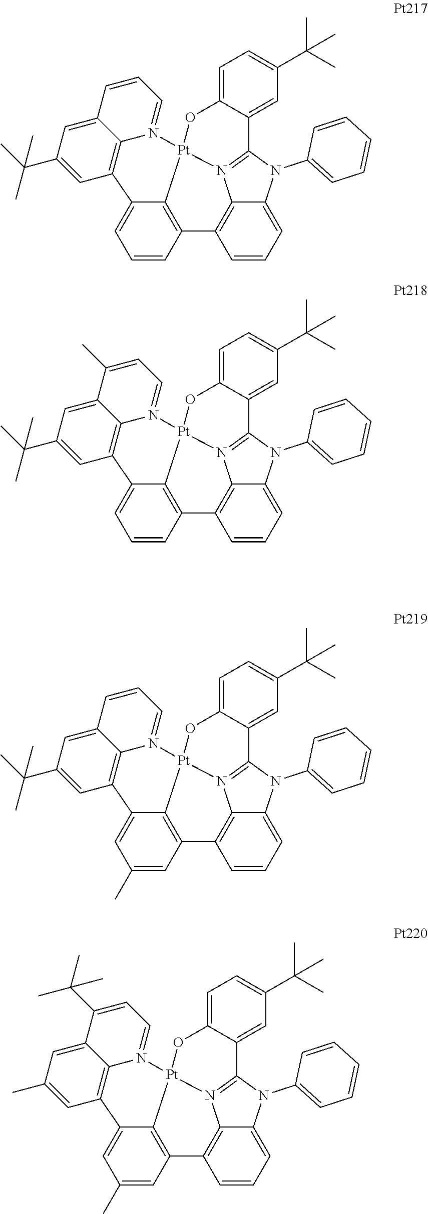

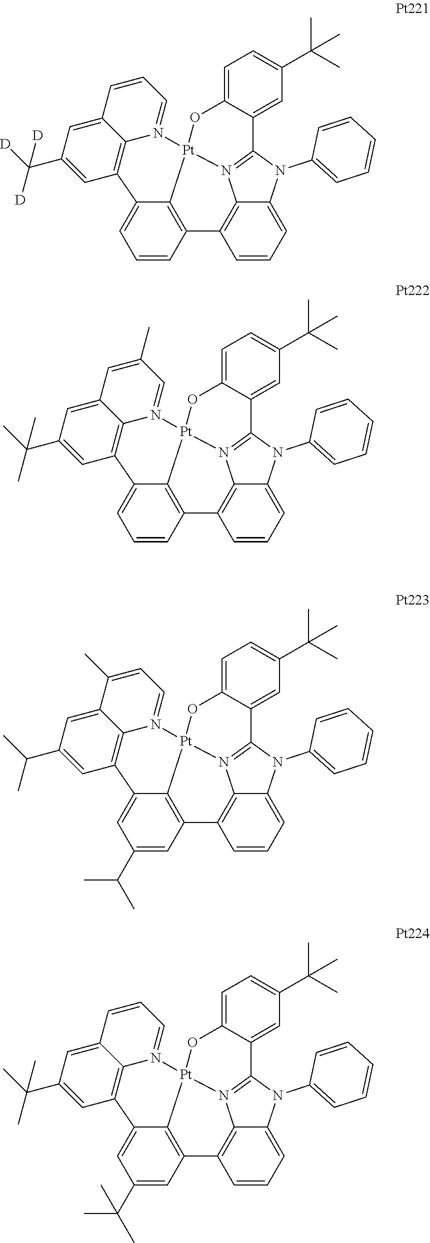

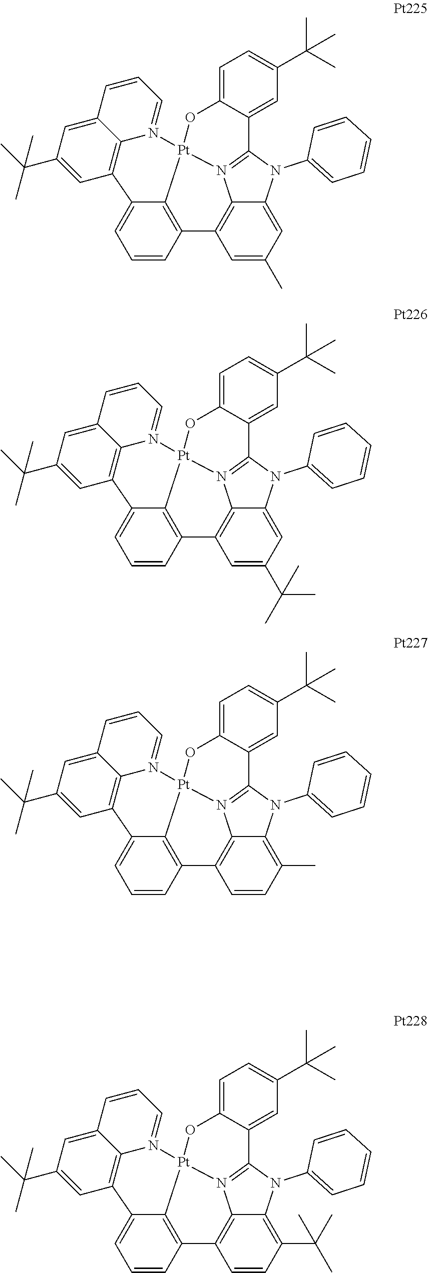

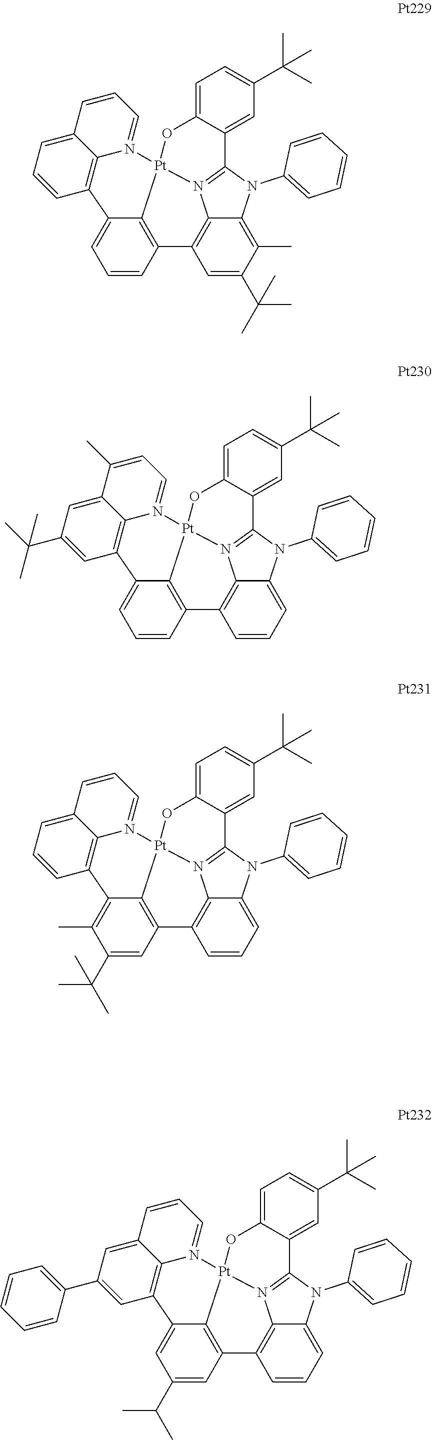

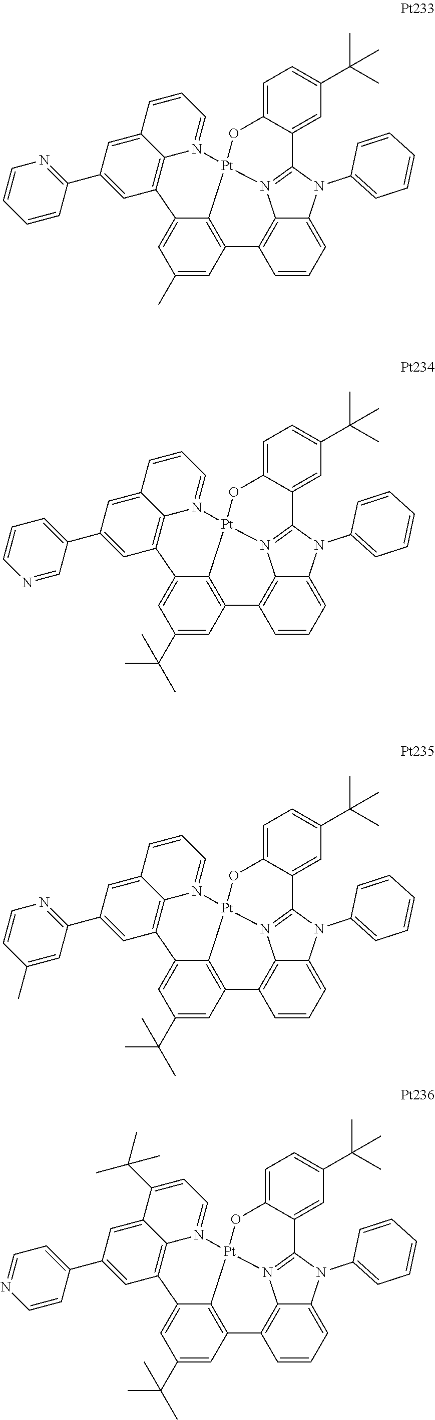

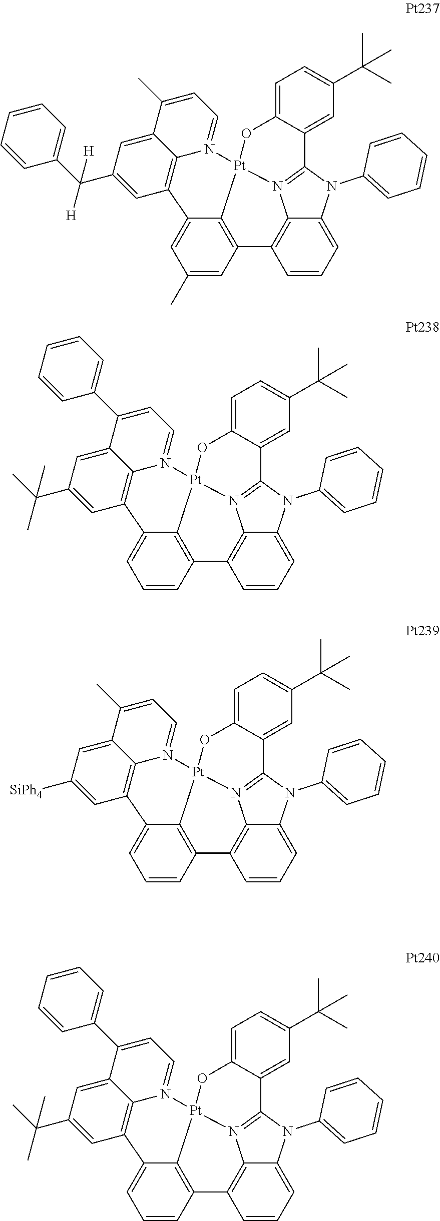

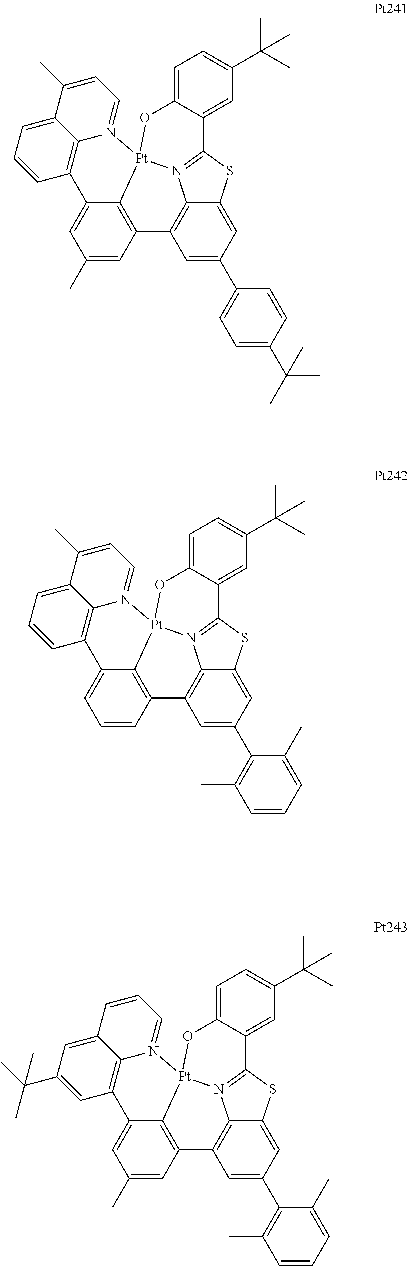

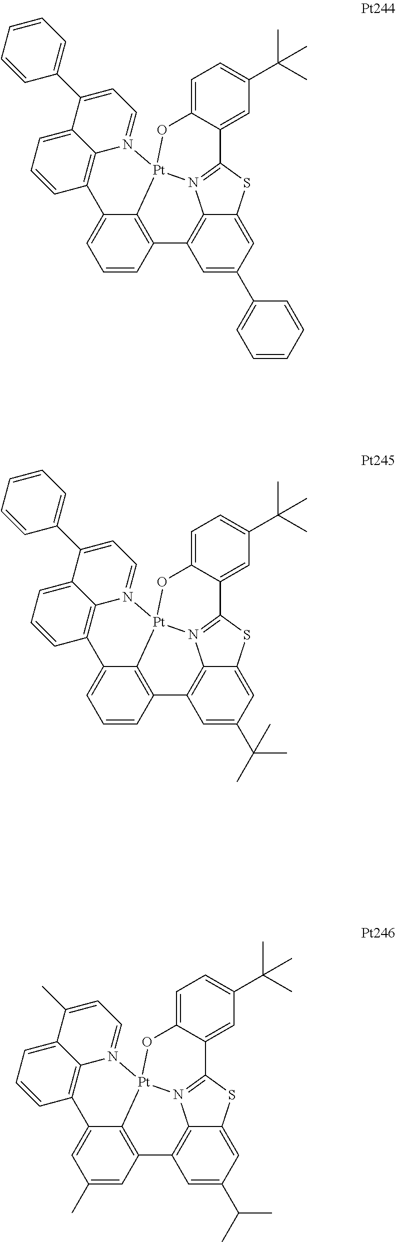

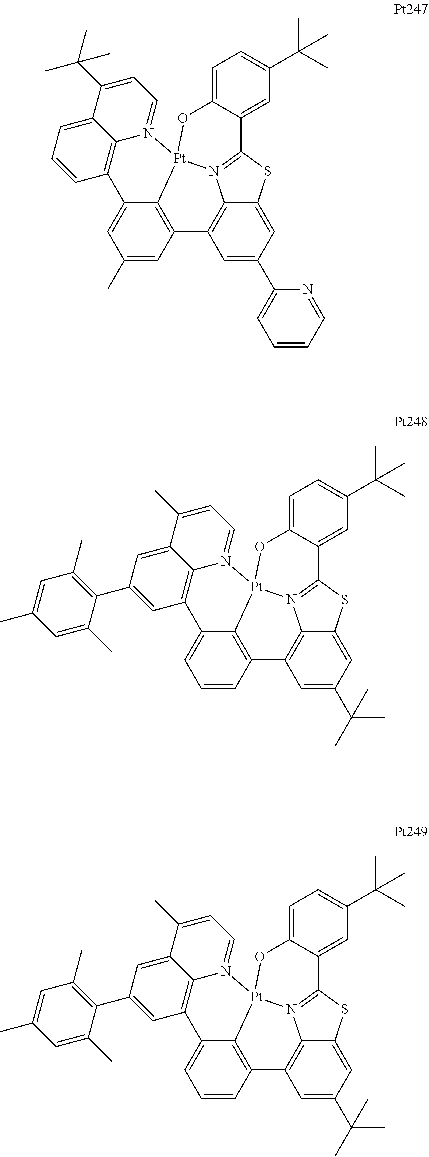

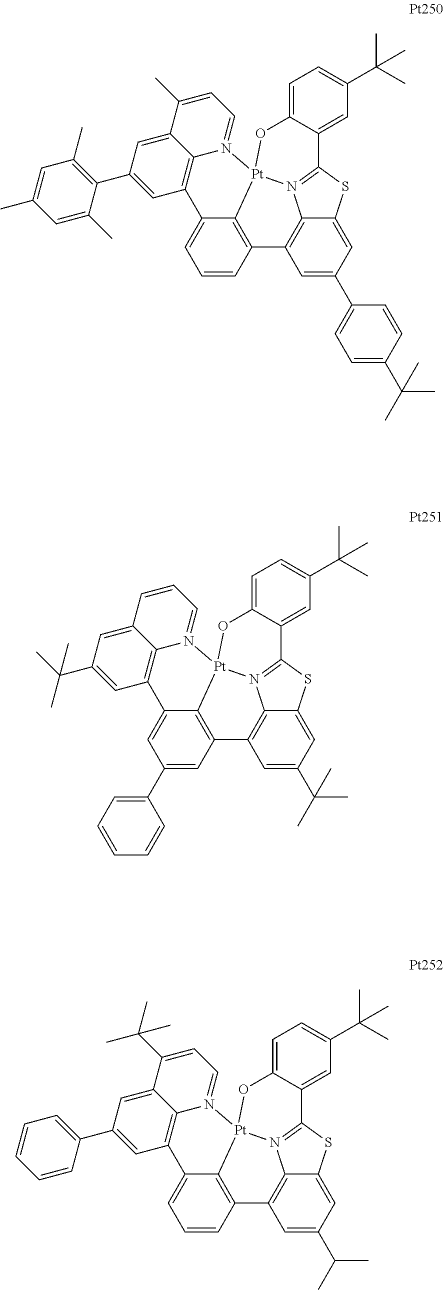

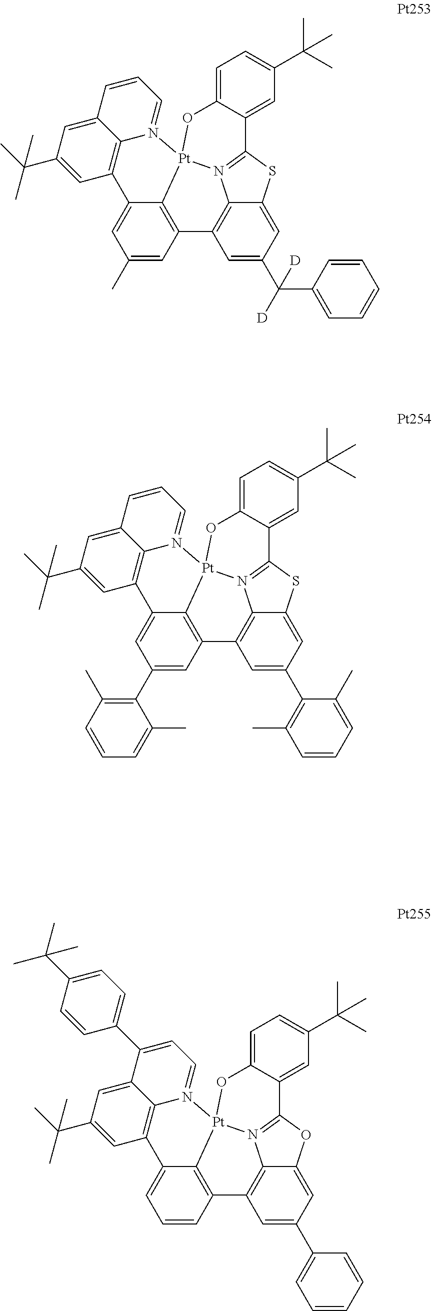

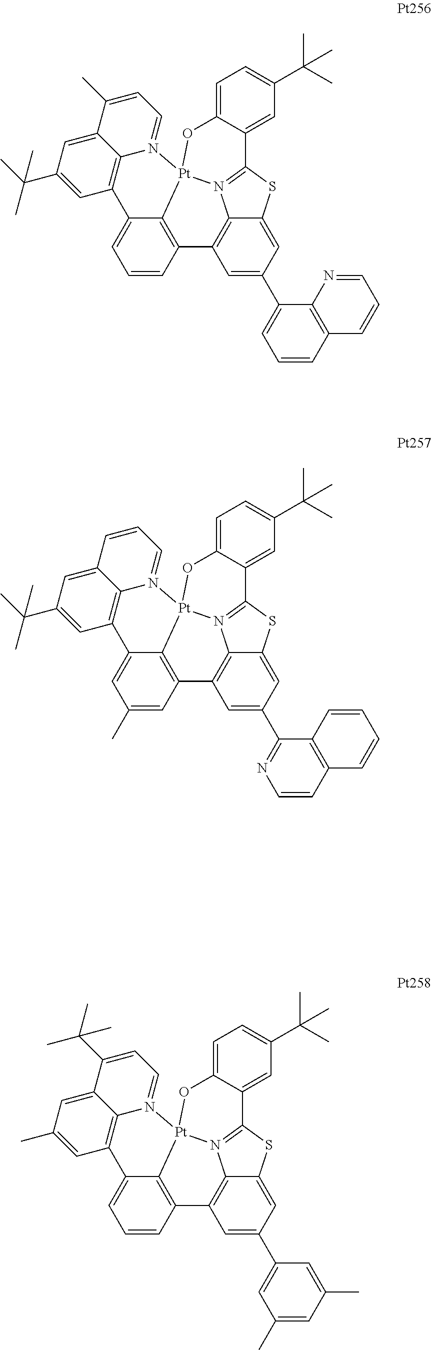

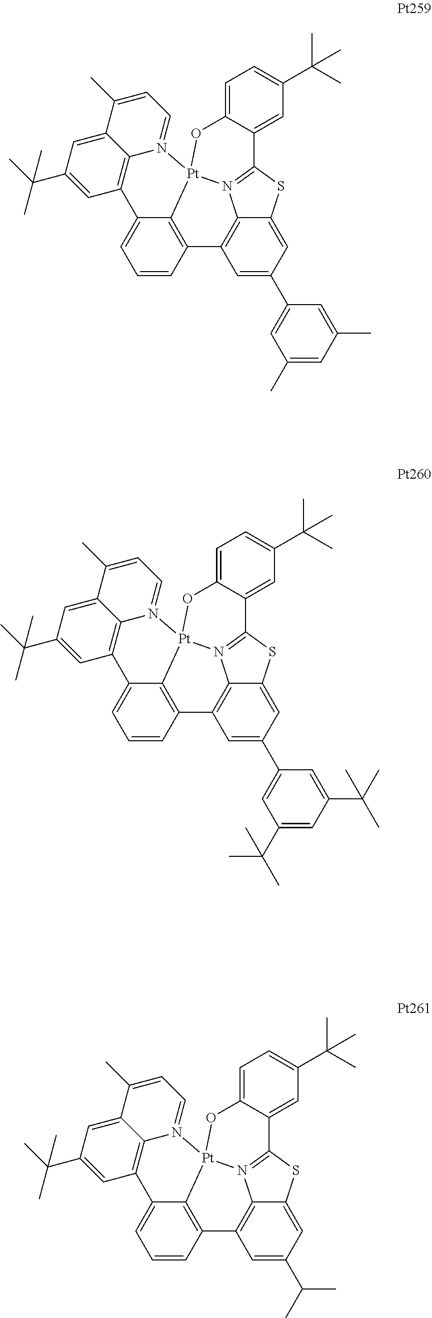

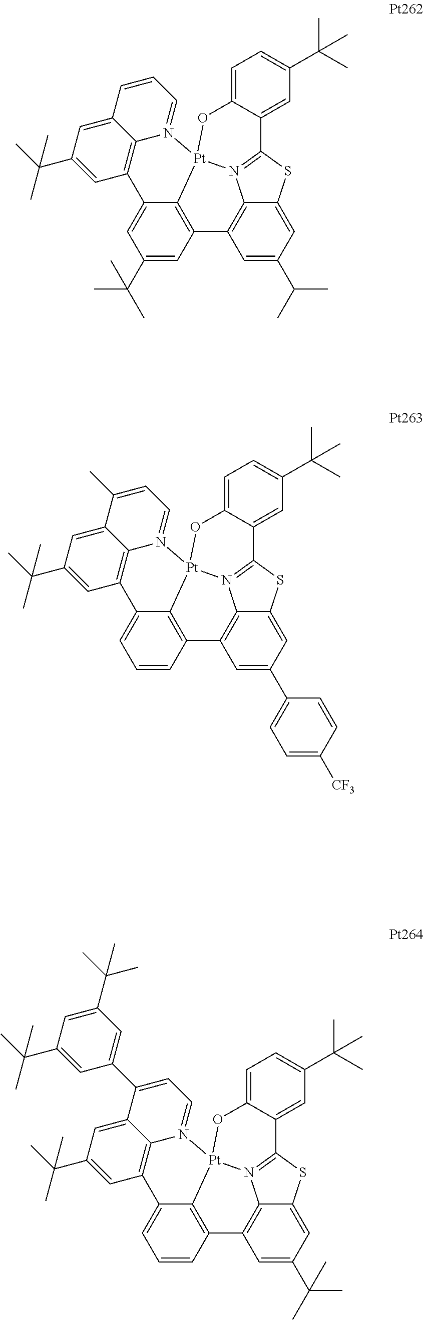

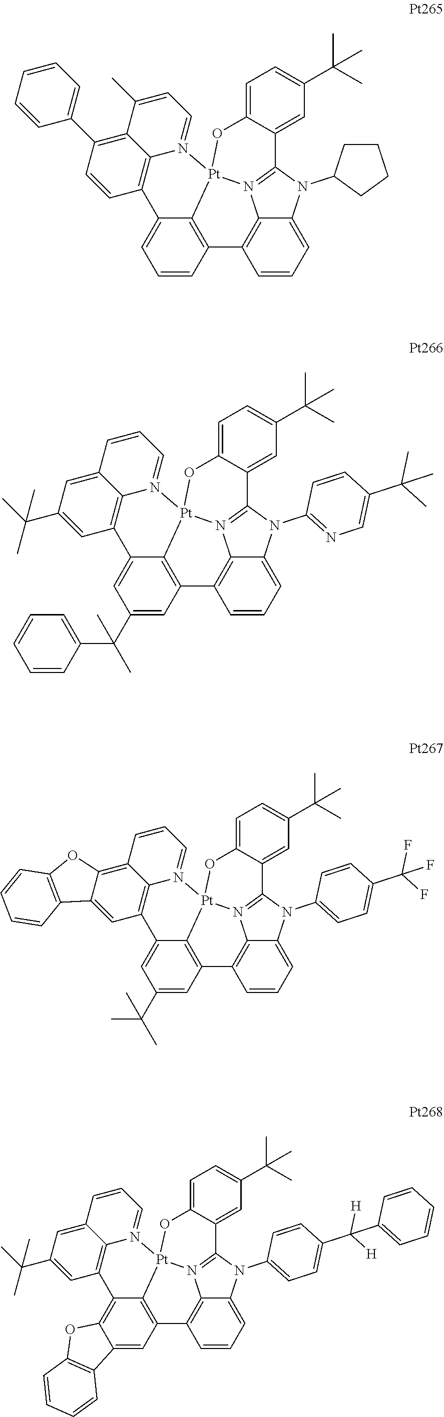

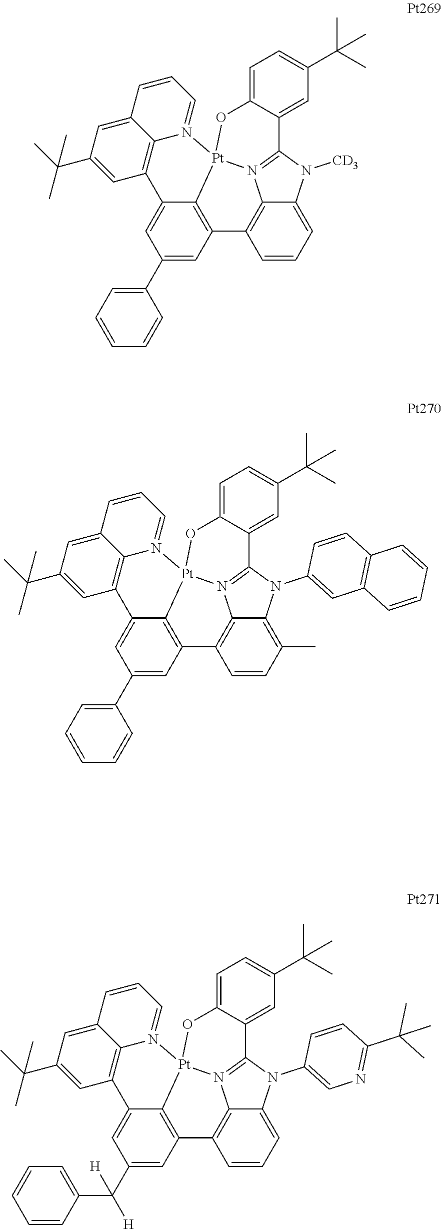

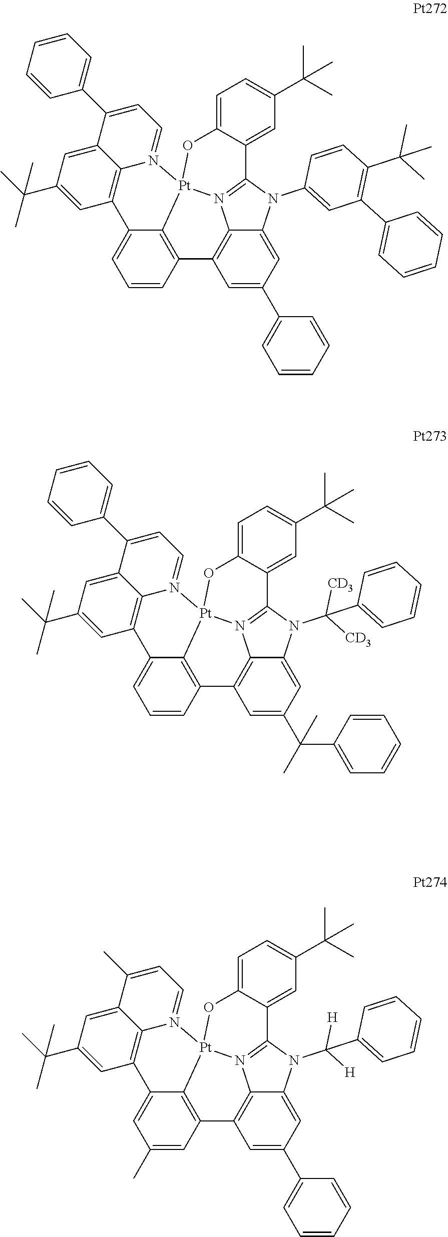

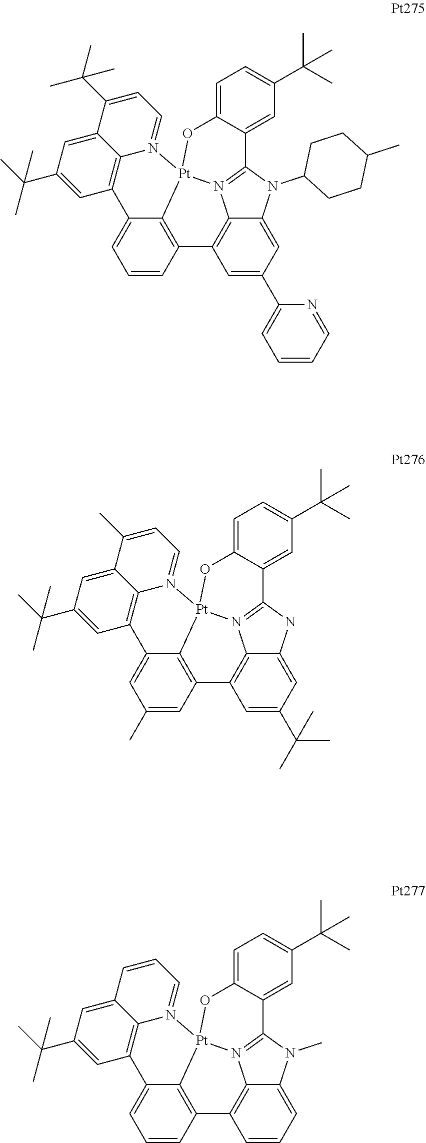

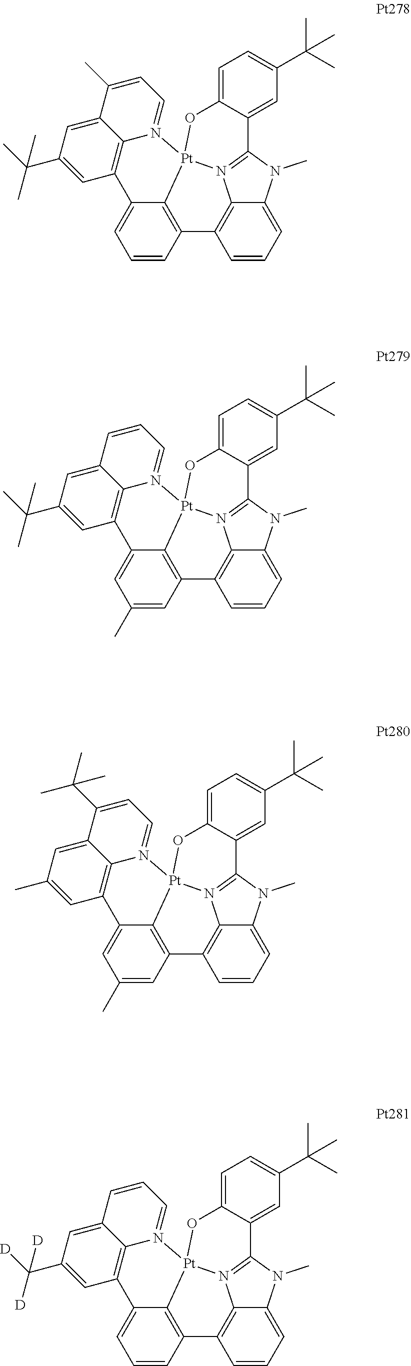

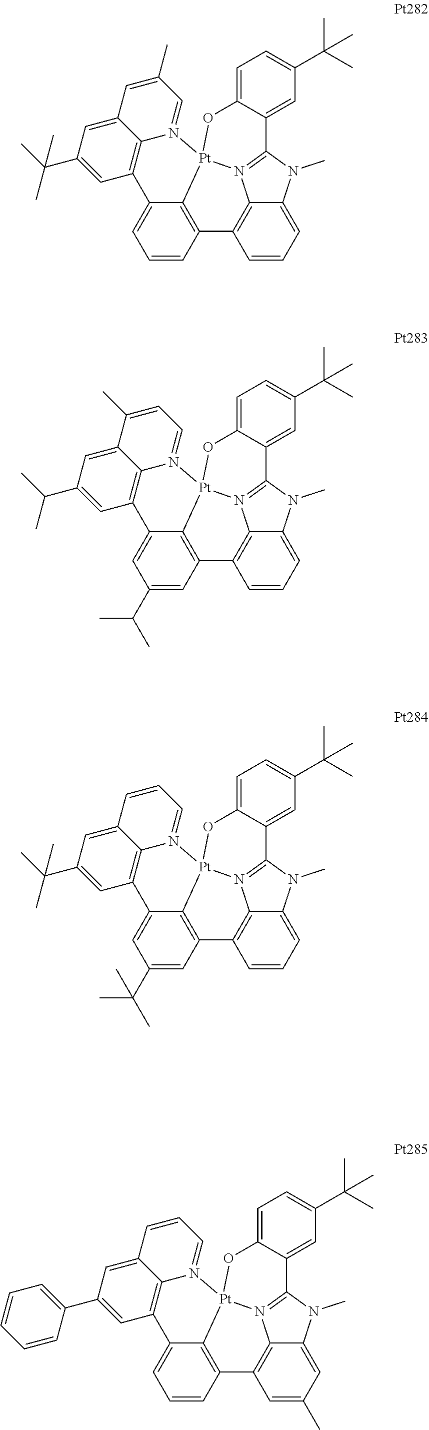

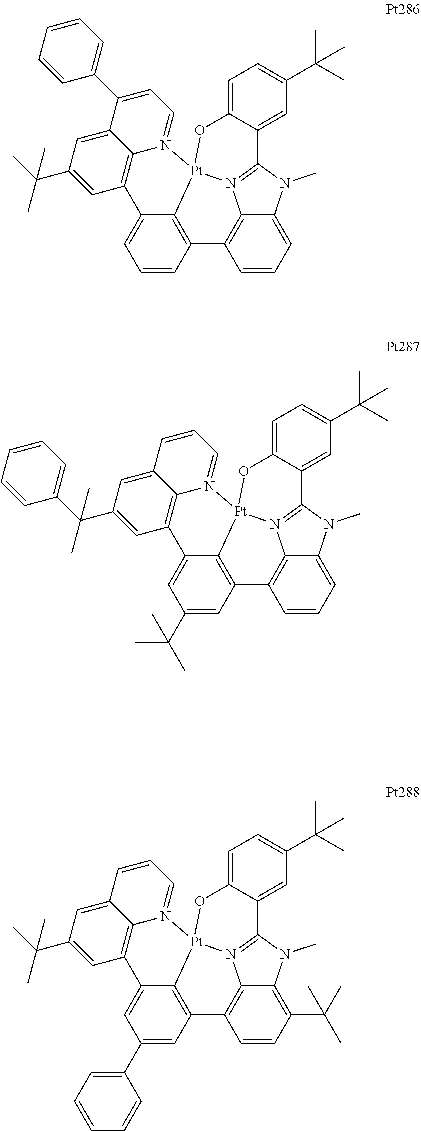

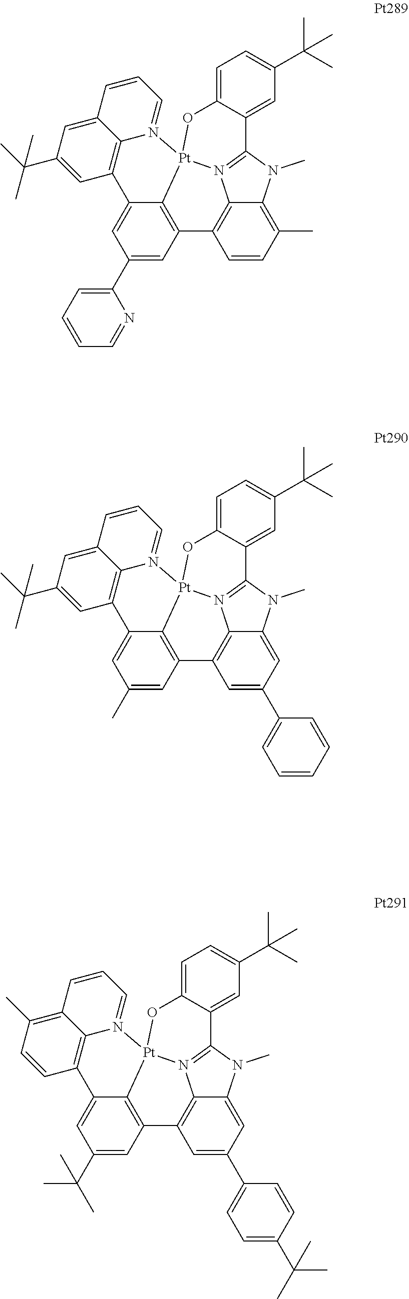

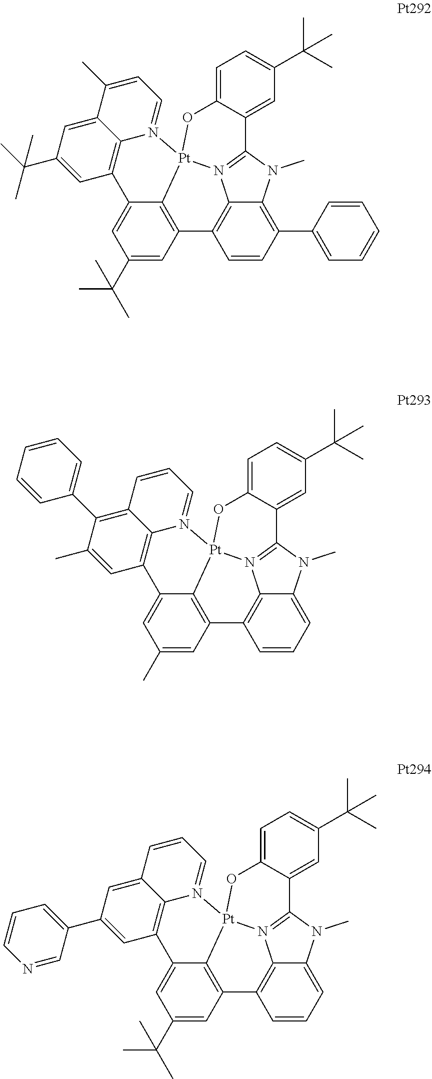

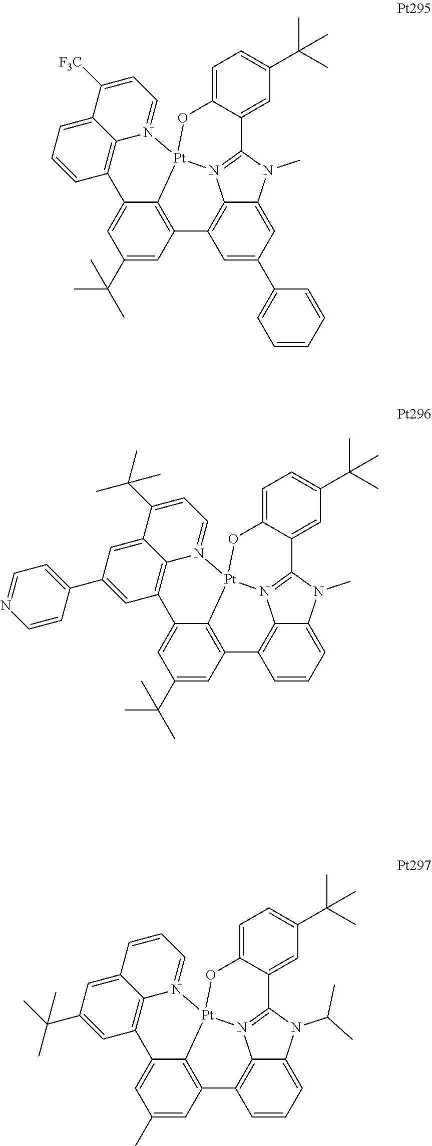

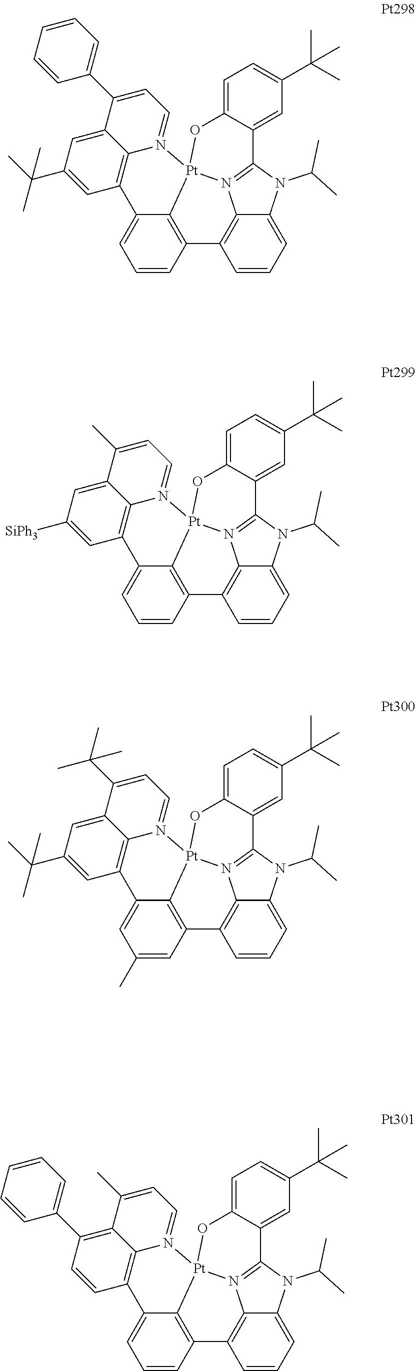

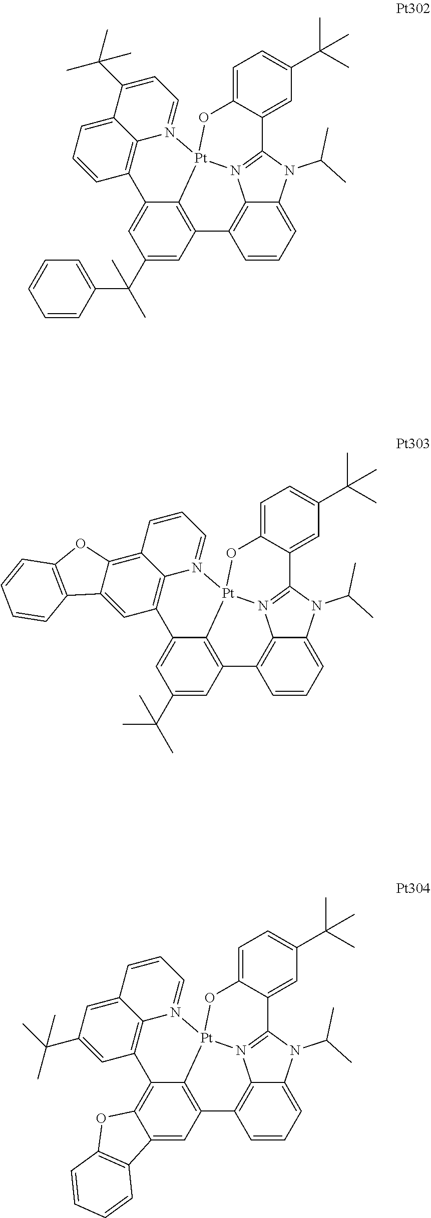

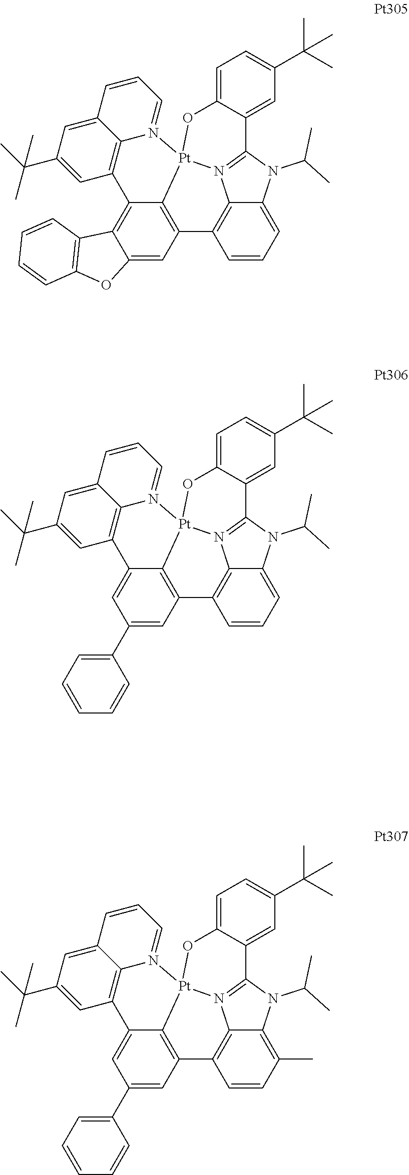

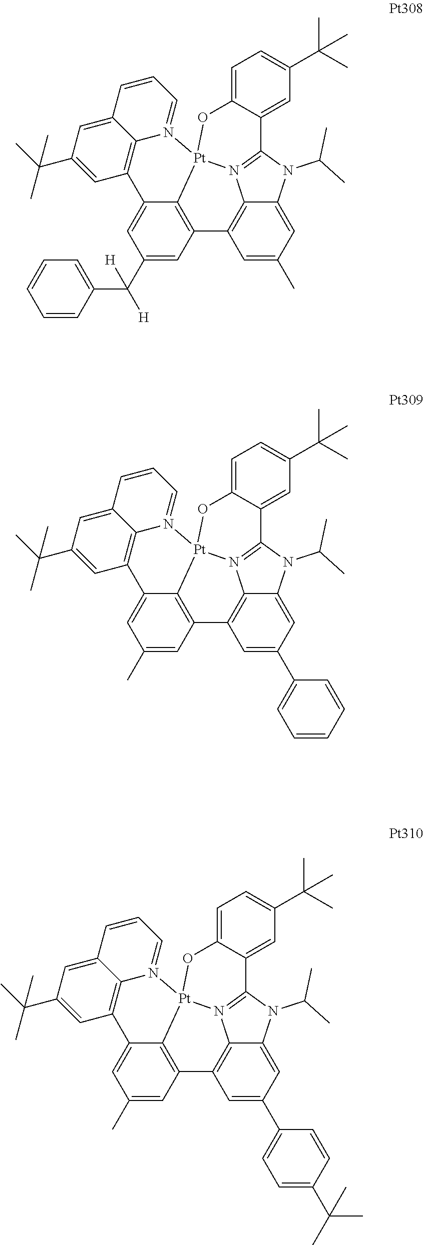

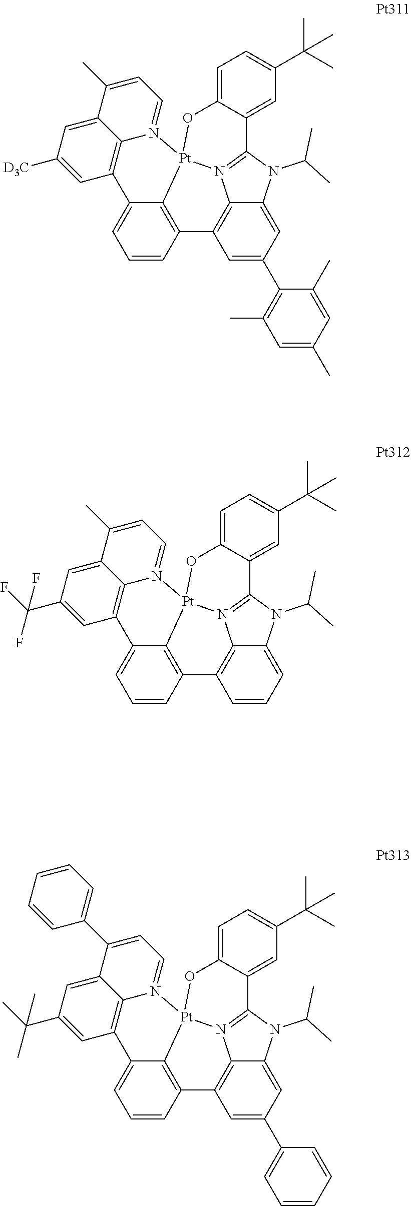

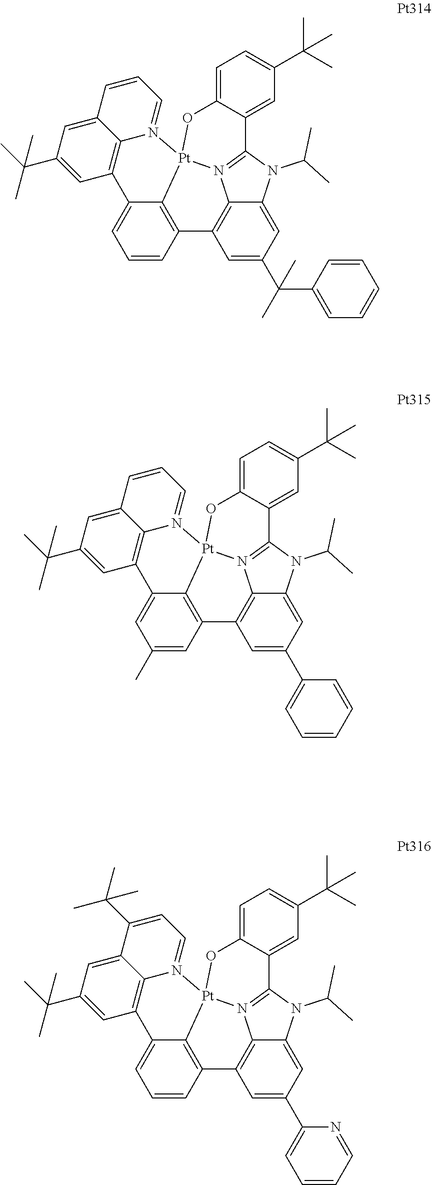

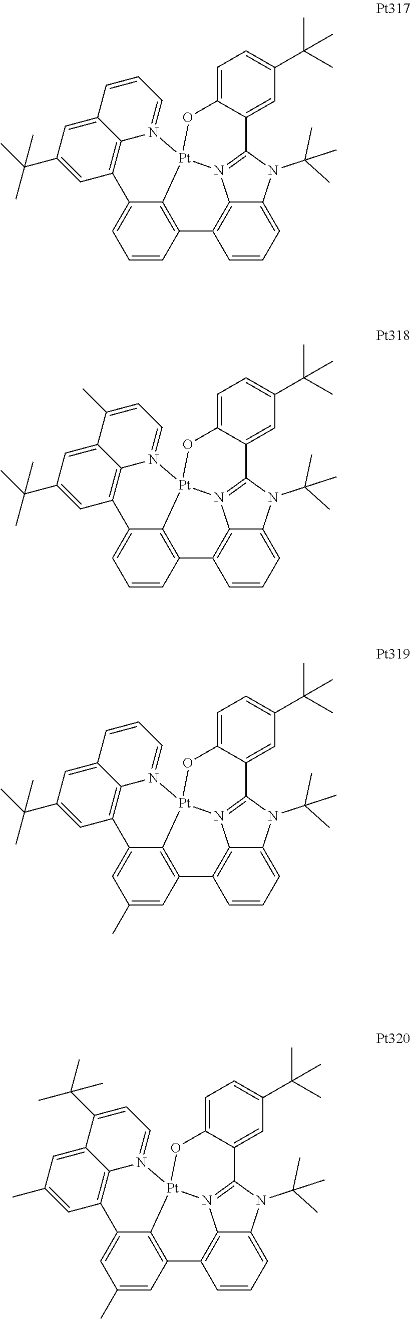

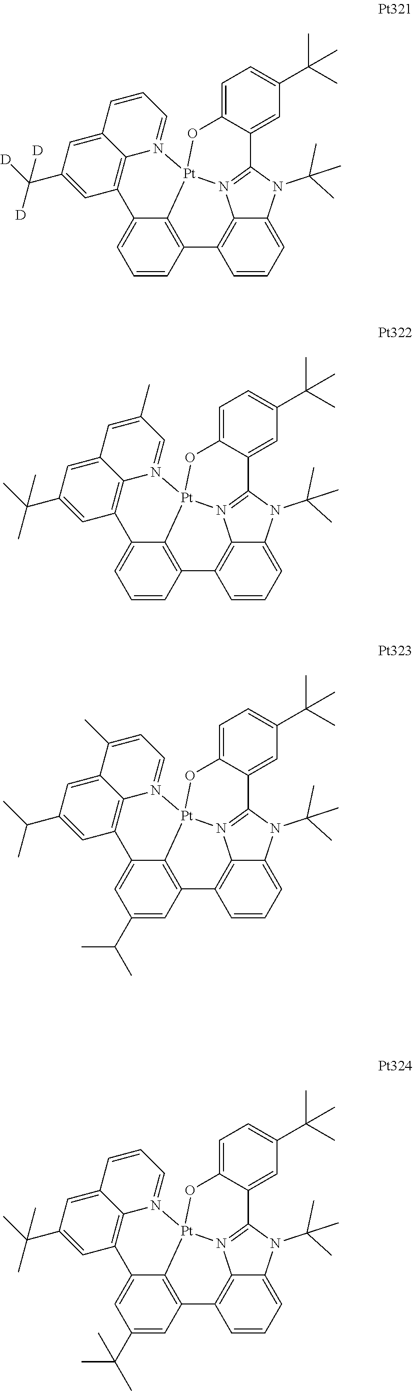

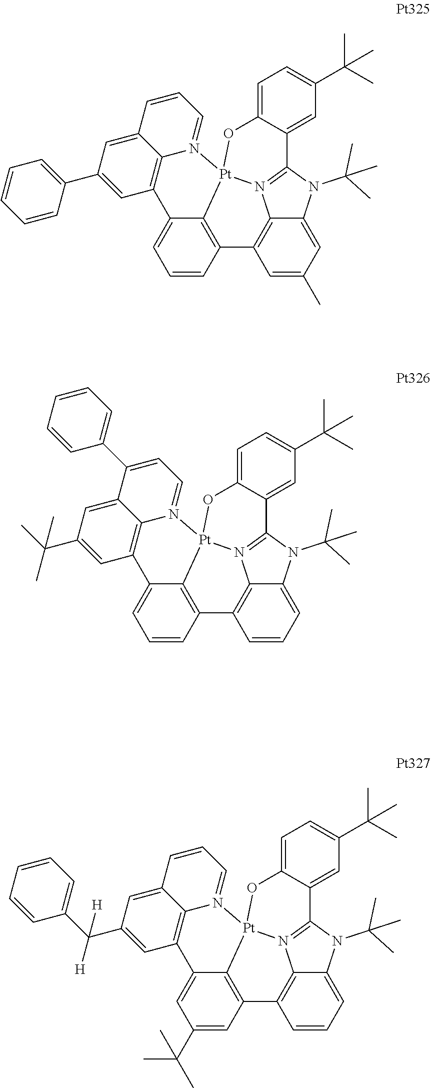

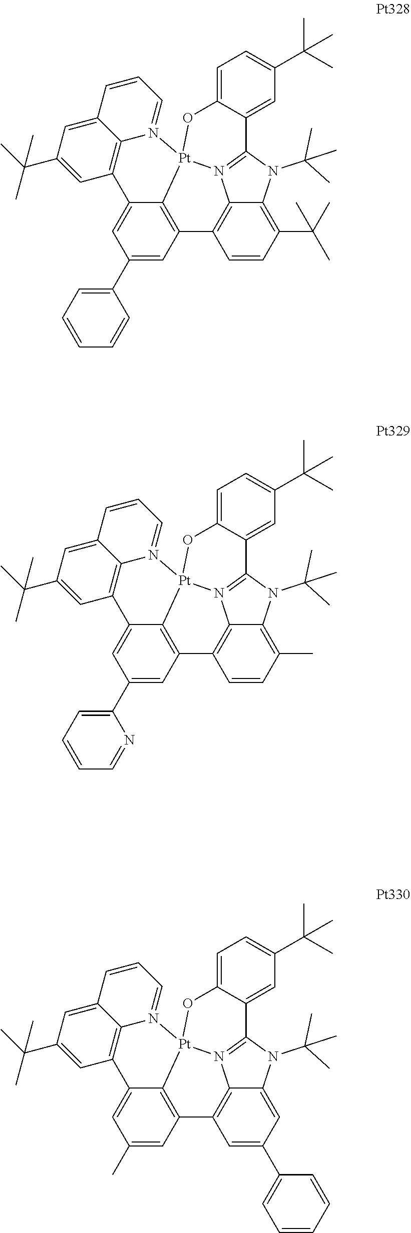

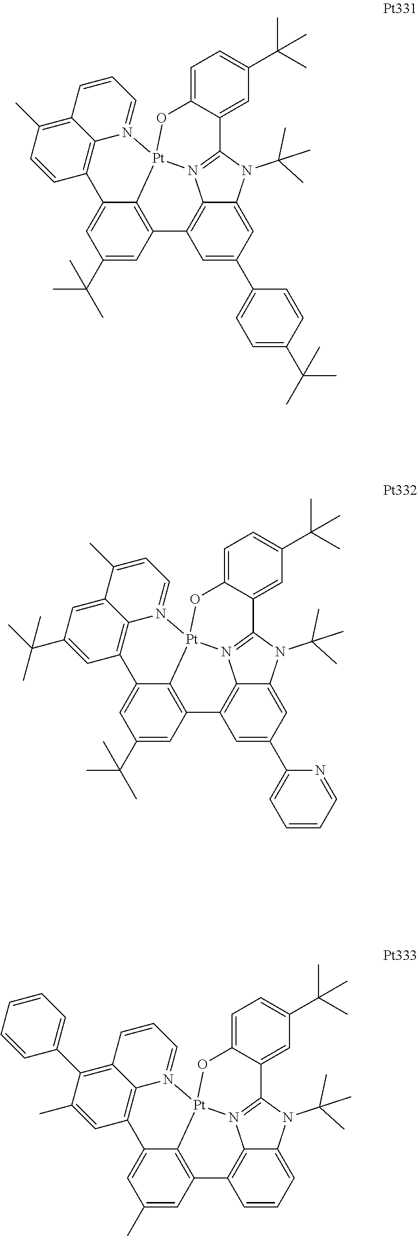

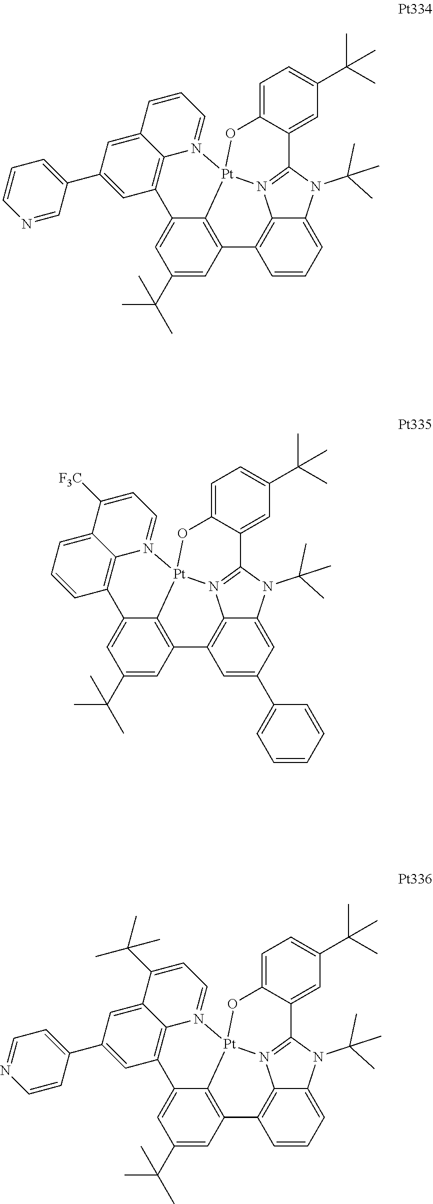

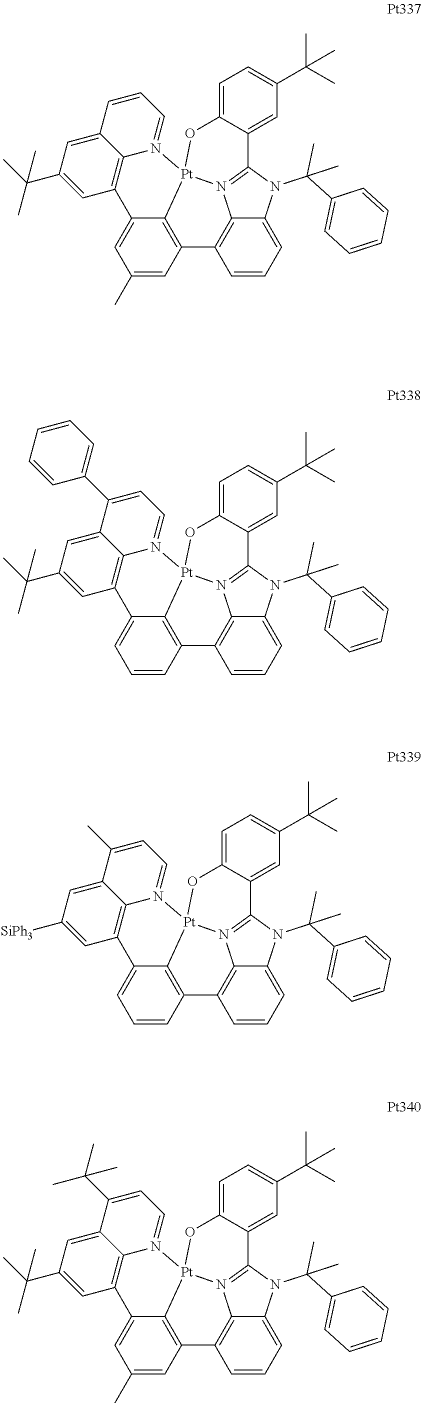

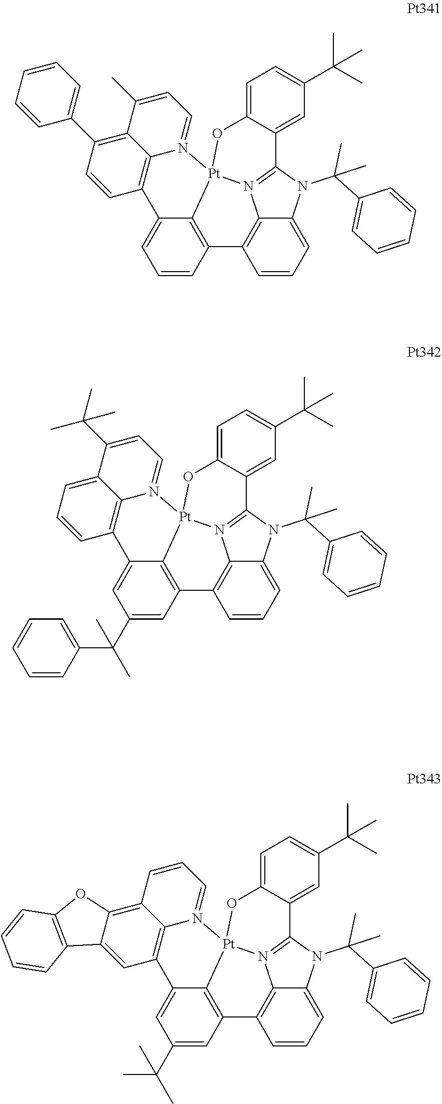

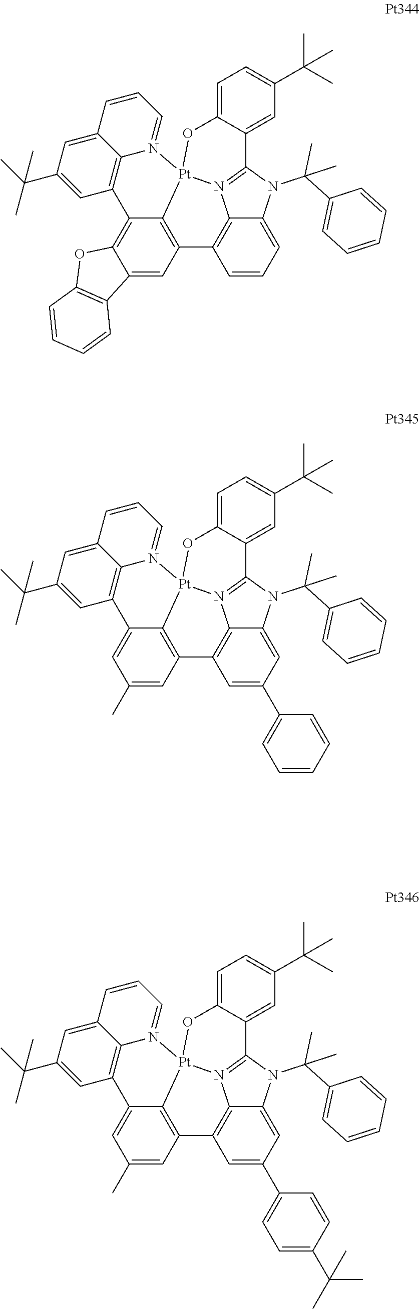

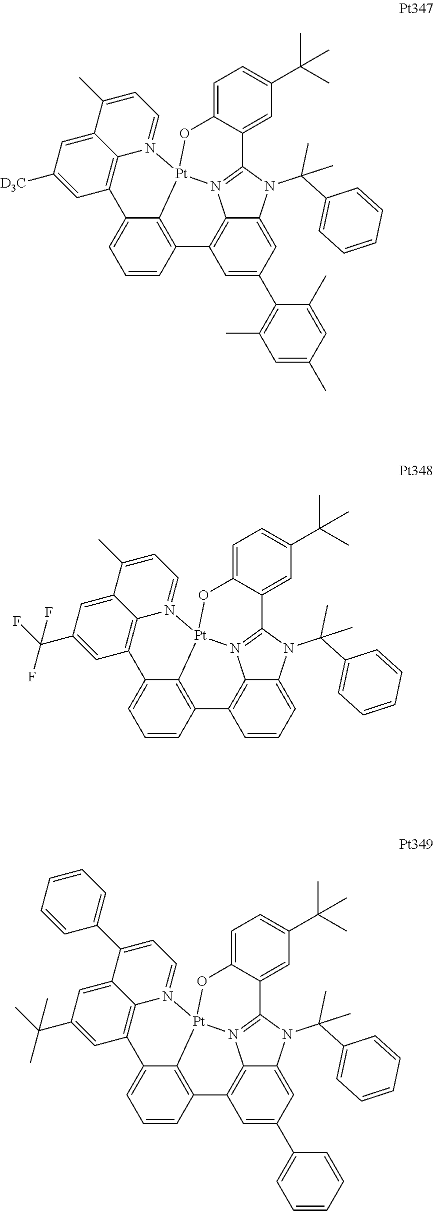

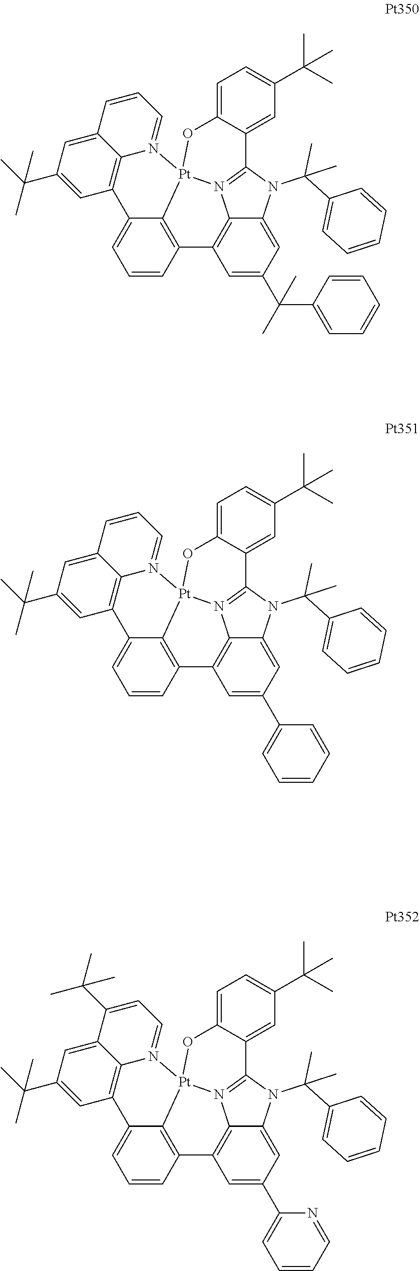

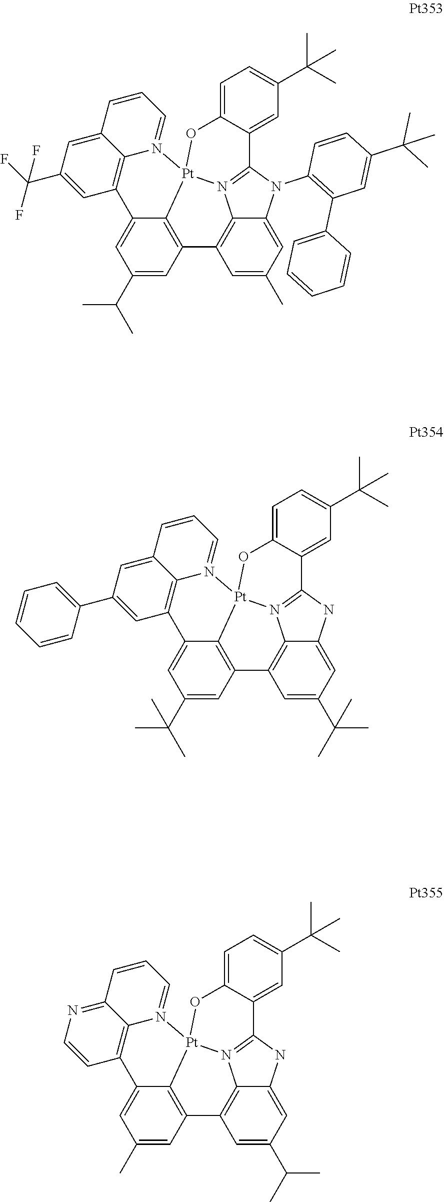

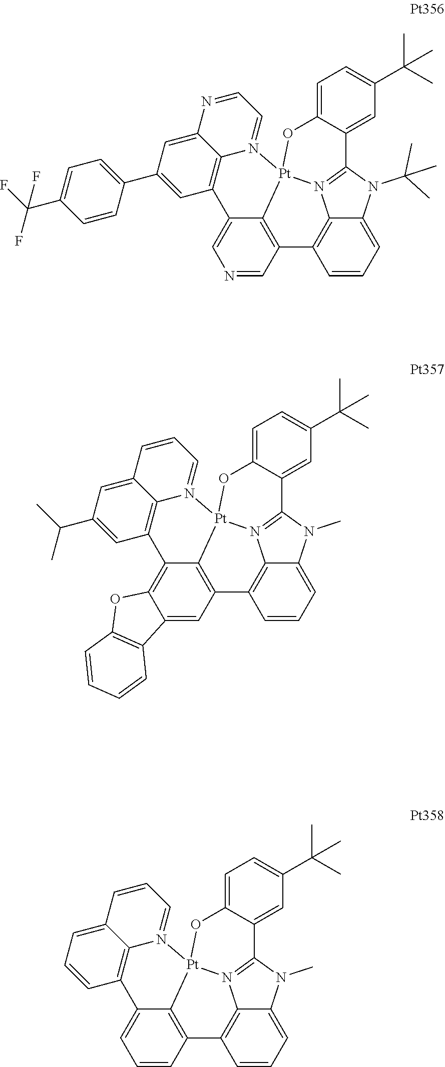

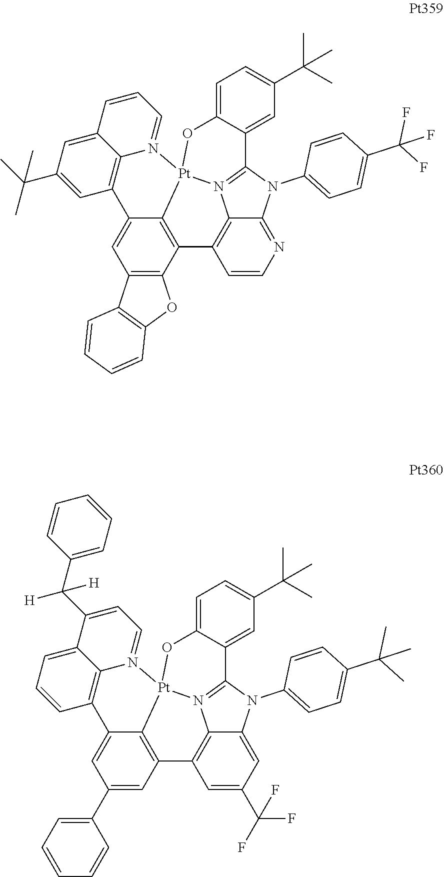

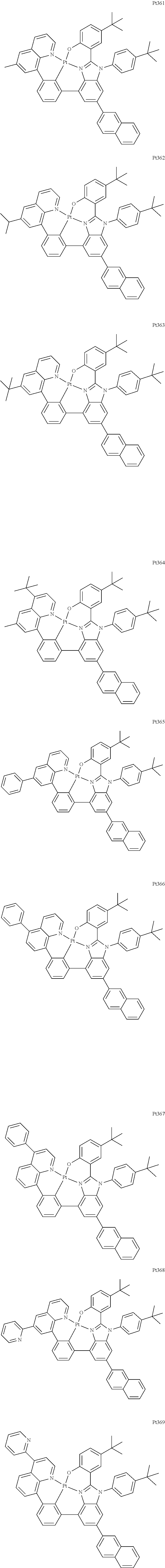

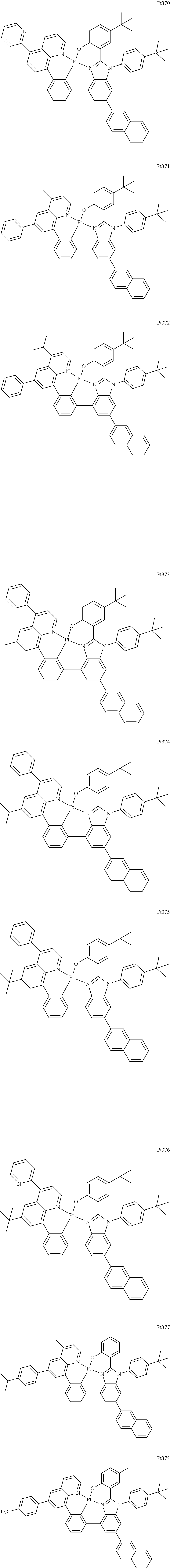

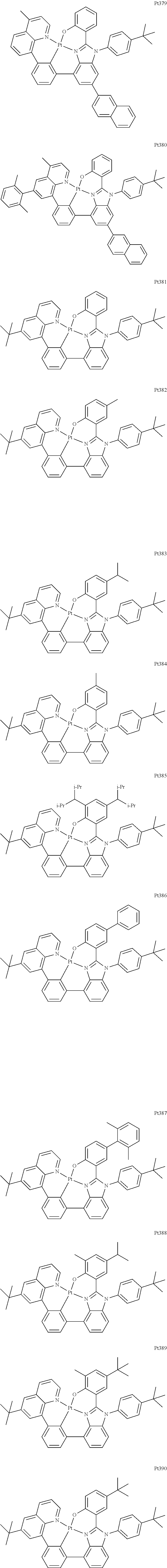

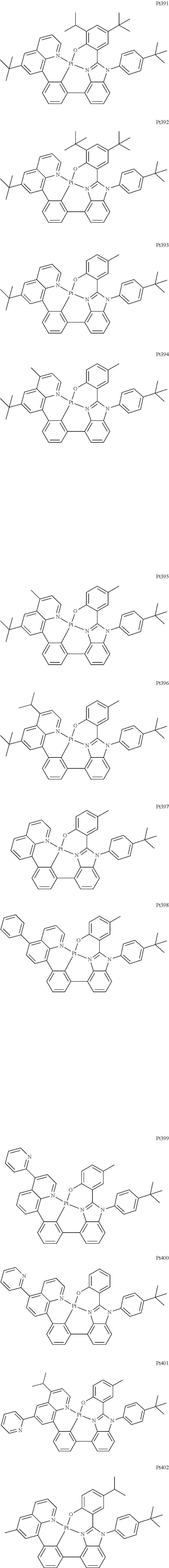

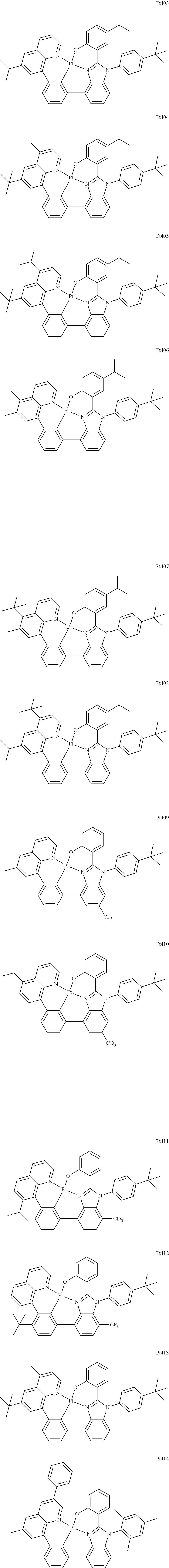

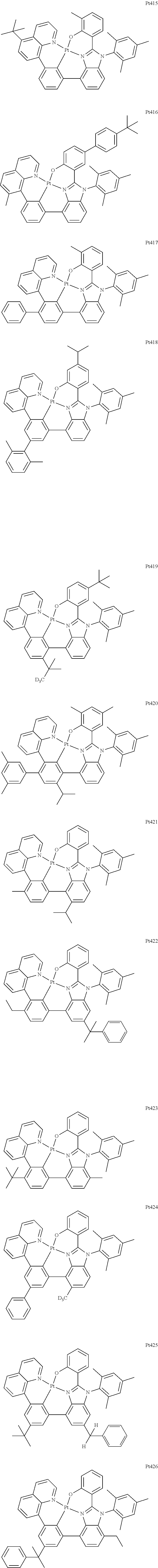

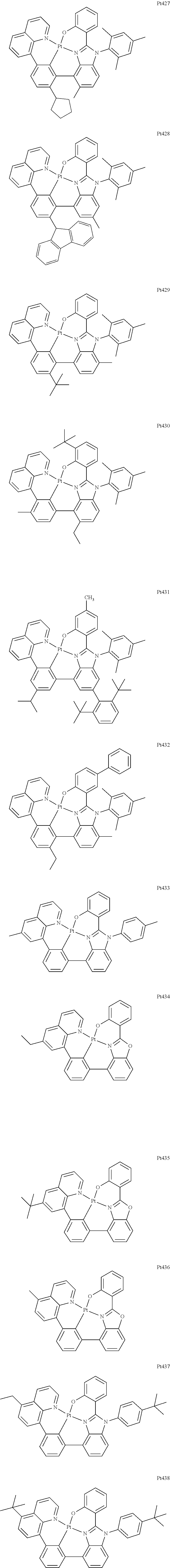

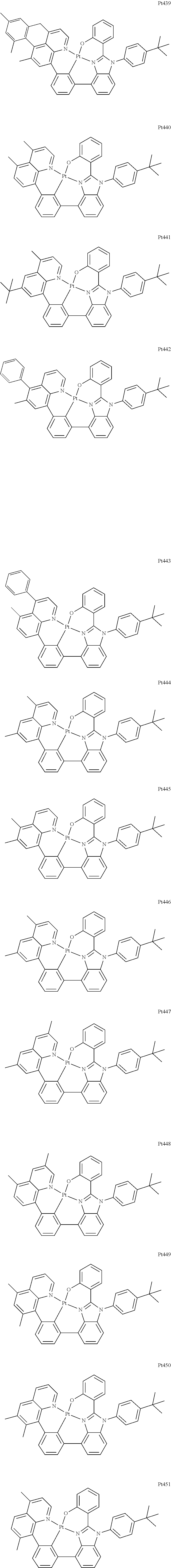

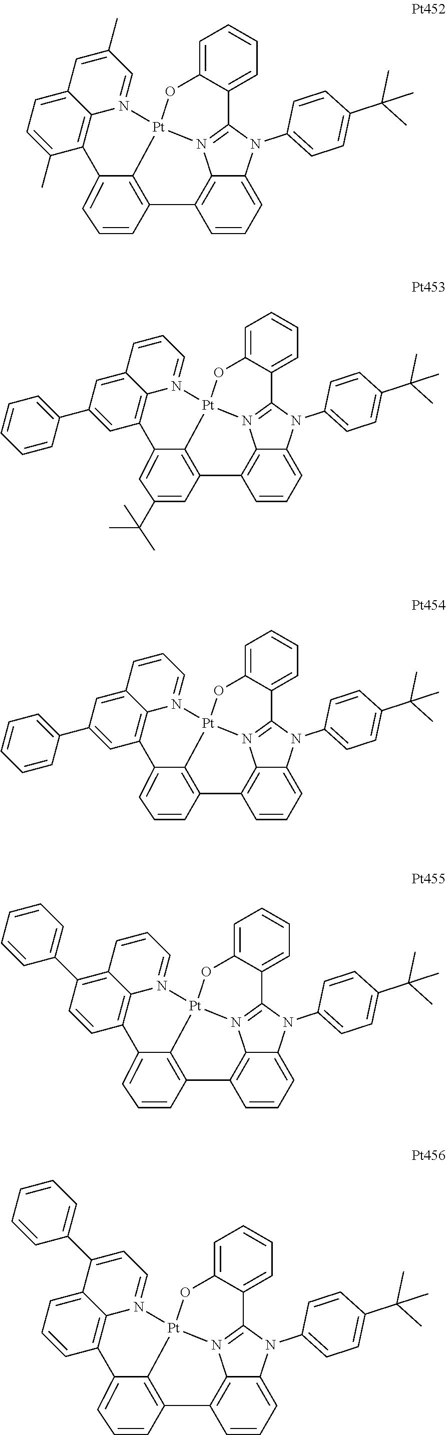

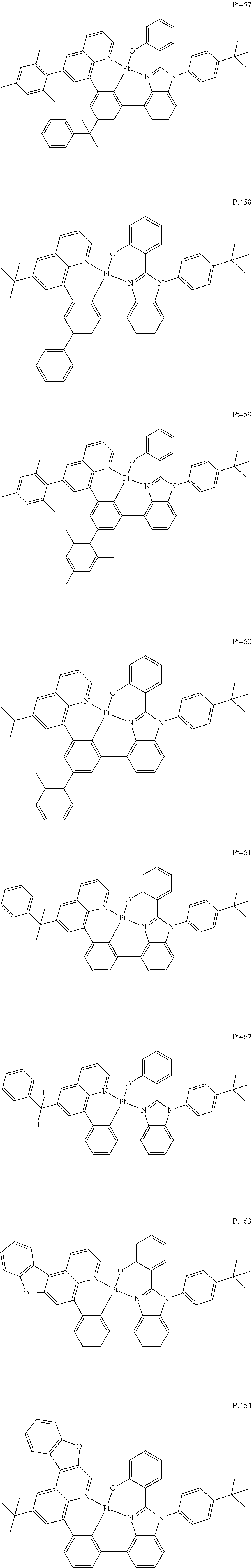

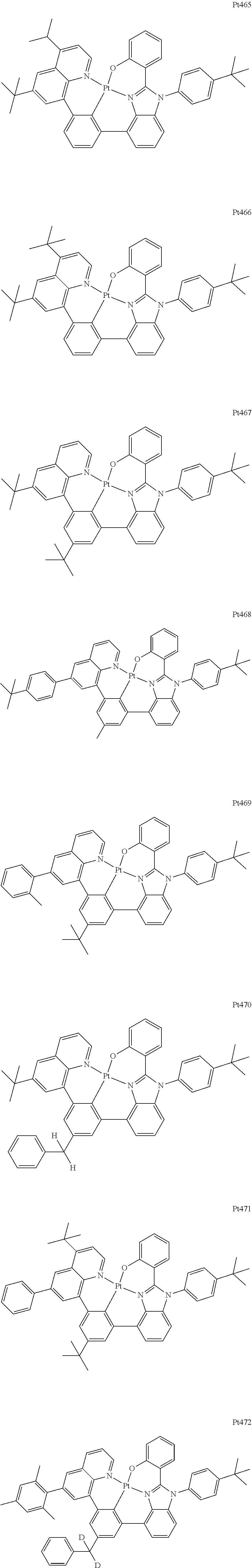

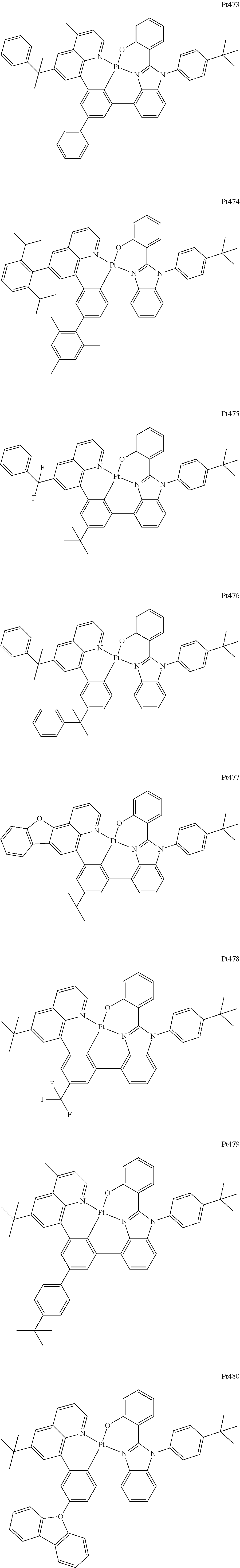

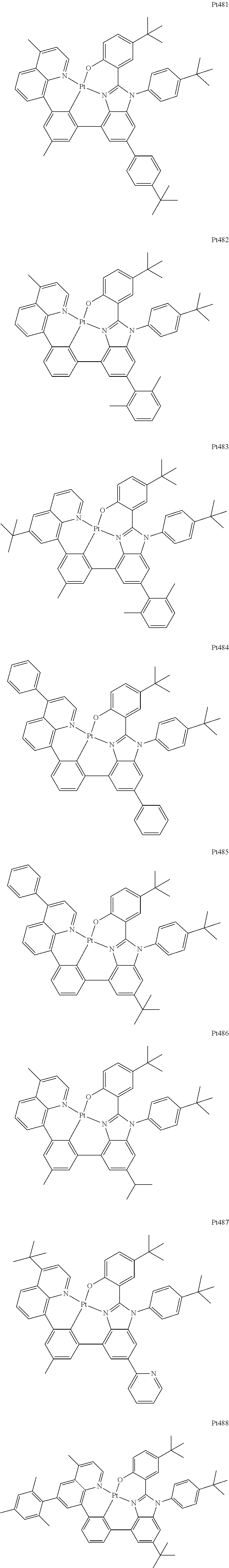

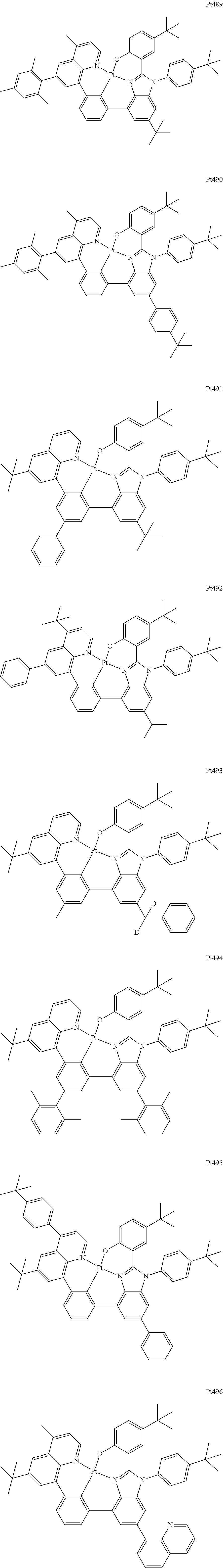

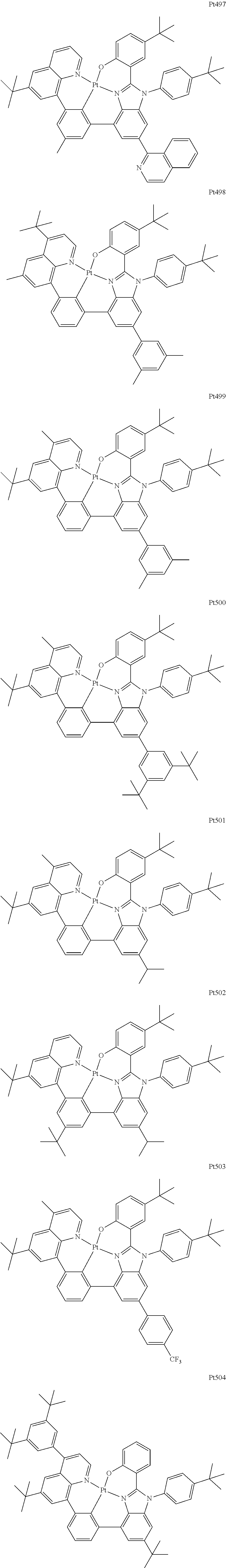

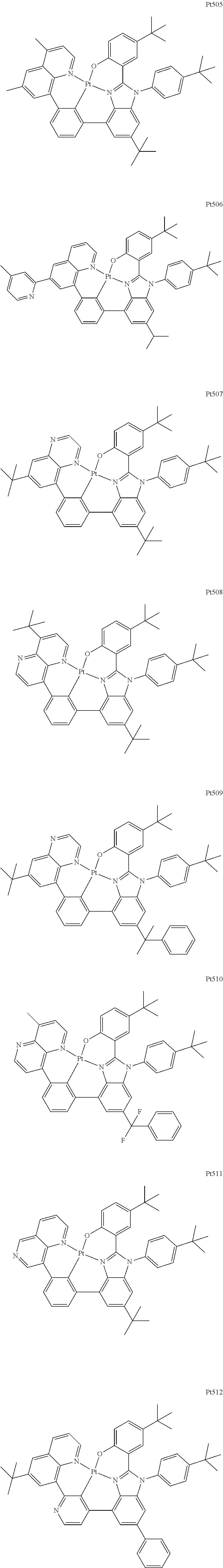

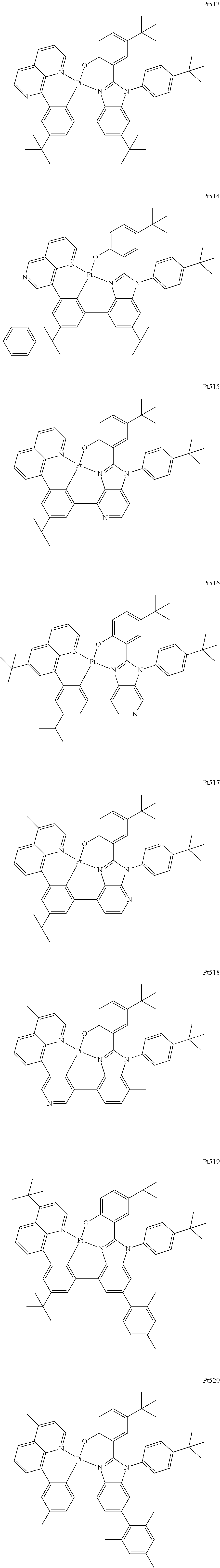

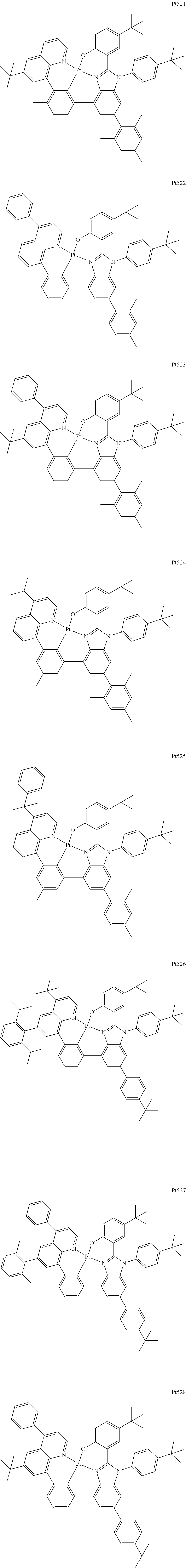

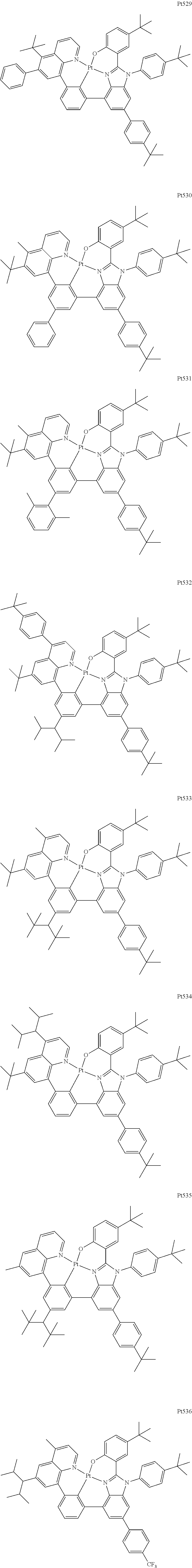

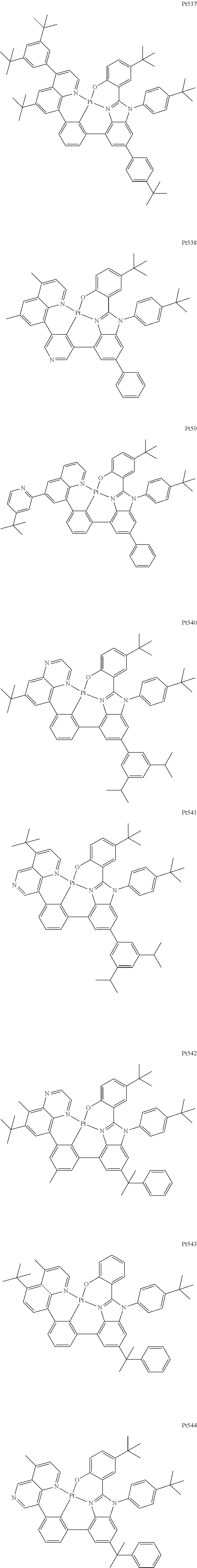

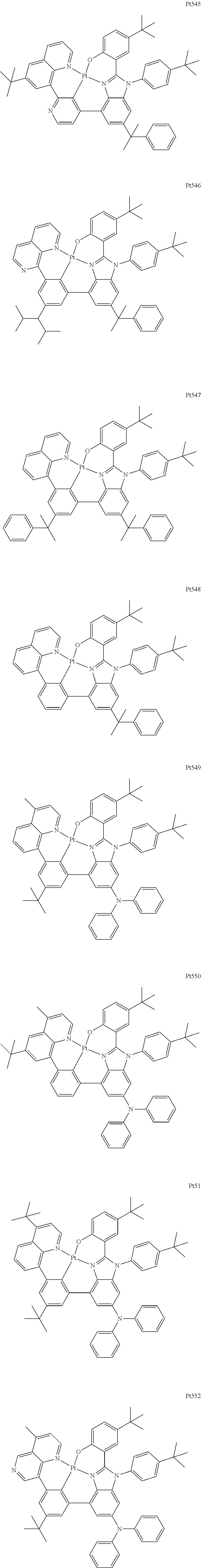

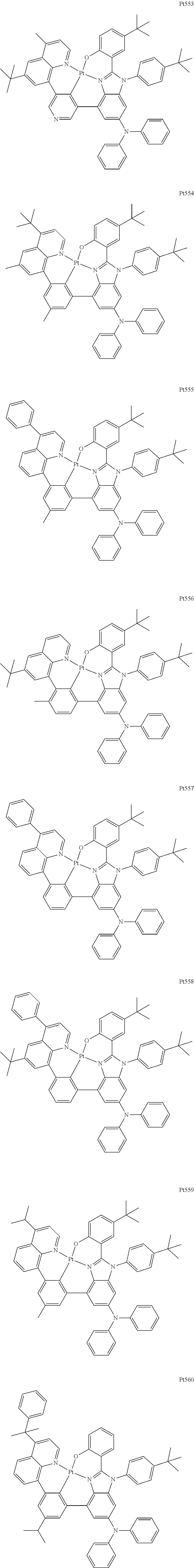

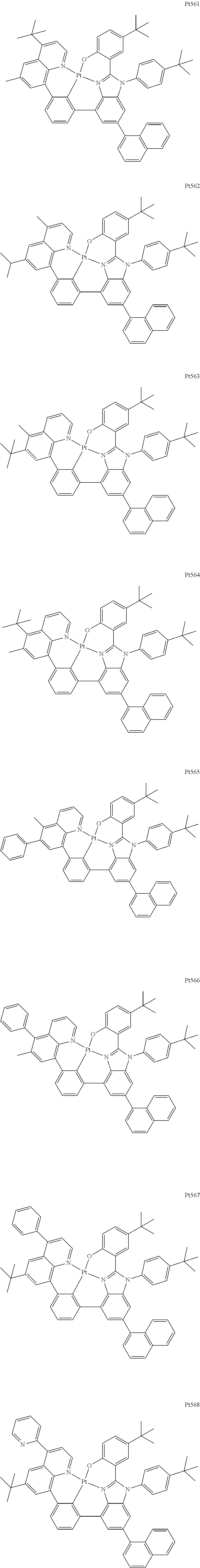

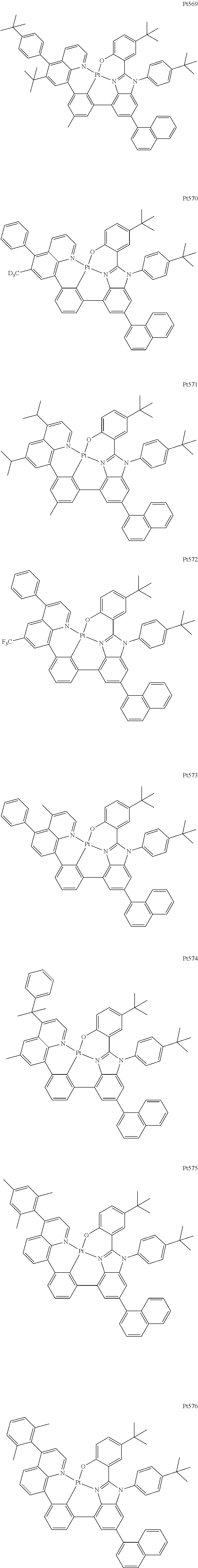

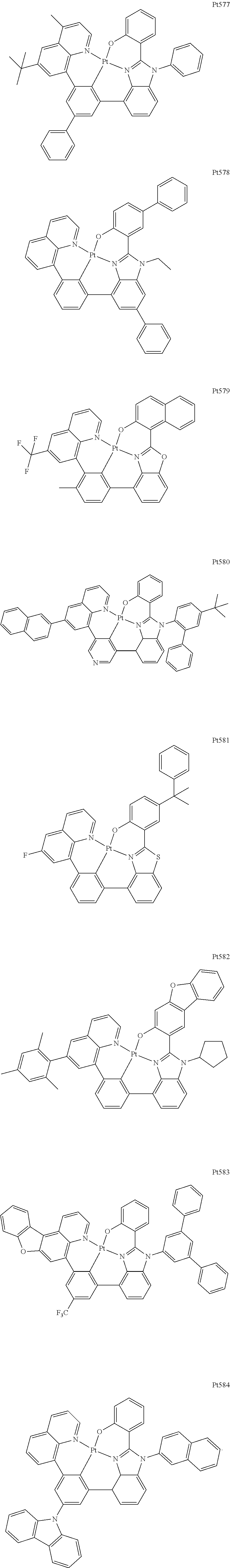

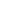

Further, the present invention also provides the use of the cyclic tetradentate metal platinum (II) complex phosphorescent material having the structure shown in formula (I) above in an electronic device.

Further, the electronic device includes an organic electroluminescent device (OLED), an organic integrated circuit (O-IC), an organic field effect transistor (O-FET), an organic thin film transistor (O-TFT), an organic light-emitting transistor (O-LET), an organic solar cell (O-SC), an organic optical detector, an organic photoreceptor, an organic field quenching device (O-FQD), a light-emitting electrochemical cell (LEC), and an organic laser diode (O-laser).

In another aspect, the present invention also provides an organic electroluminescent device including the cyclic tetradentate metal platinum (II) complex phosphorescent material having the structure shown in formula (I) as described above.

Further, the organic electroluminescent device includes a cathode, an anode, and an organic functional layer therebetween; the organic functional layer includes the cyclic tetradentate metal platinum (II) complex phosphorescent material having the structure shown in formula (I) as described above.

Preferably, the organic functional layer includes a light-emitting layer including the cyclic tetradentate metal platinum (II) complex phosphorescent material having the structure shown in formula (I) as described above.

Further, the light-emitting layer also includes a host material, and the mass percentage of the cyclic tetradentate metal platinum (II) complex phosphorescent material is between 1% and 50%. The host material is not limited.

In another aspect, the present invention also provides an organic photovoltaic device including: a substrate layer; a first electrode on the substrate; an organic light-emitting functional layer on the first electrode; a second electrode on the organic light-emitting functional layer; wherein the organic light-emitting functional layer includes the cyclic tetradentate metal platinum (II) complex phosphorescent material having the structure shown in formula (I) as described above. For example, the cyclic tetradentate metal platinum (II) complex phosphorescent material may be included as a light-emitting material in the organic light-emitting functional layer.

Further, the organic light-emitting functional layer includes a host material, and the mass percentage of the cyclic tetradentate metal platinum (II) complex phosphorescent material is between 1% and 50%. The host material is not limited.

In the present invention, the organic optoelectronic device can be prepared by utilizing methods such as sputter coating, electron beam evaporation, vacuum evaporation, etc. to evaporate metal or oxides having electrical conductivity and alloys thereof on a substrate to form an anode; evaporating a hole-injection layer, a hole-transporting layer, a light-emitting layer, an air-blocking layer, and an electron transporting layer on the surface of the anode obtained by the preparation in sequential order, and then evaporating a cathode at a later time. In addition to the above method, an organic electroluminescent device is fabricated on a substrate by evaporation in the order of a cathode, an organic layer, and an anode. The organic layer may also include a multilayer structure such as a hole injection layer, a hole transport layer, a light-emitting layer, a hole blocking layer, and an electron transport layer. In the present invention, the organic layer is prepared by solvent engineering (spin-coating, tape-casting, doctor-blading, screen-printing, ink-jet printing, or thermal-imaging) using a high molecular material instead of the evaporation method, reducing the number of device layers.

The present invention also provides a composition including the cyclic tetradentate metal platinum (II) complex phosphorescent material having the structure shown in formula (I). Preferably, the composition further includes a fluorescent doping material, and the fluorescent doping materials are preferably boron-containing organic molecular light-emitting materials, and preferably phosphorescent sensitizable boron-containing compounds.

The present invention also provides a formulation including the cyclic tetradentate metal platinum (II) complex phosphorescent material having the structure shown in formula (I) or a composition as described above and at least one solvent.

The solvent is not particularly limited, and an unsaturated hydrocarbon solvent such as toluene, xylene, mesitylene, tetrahydronaphthalene, decahydronaphthalene, dicyclohexane, n-butylbenzene, sec-butylbenzene, t-butylbenzene and other unsaturated hydrocarbon solvents, halogenated saturated hydrocarbon solvents such as carbon tetrachloride, chloroform, methylene chloride, ethylene chloride, butyl chloride, butyl bromide, pentyl chloride, pentyl bromide, hexyl chloride, hexyl bromide, cyclohexyl chloride, cyclohexyl bromide, halogenated unsaturated hydrocarbon solvents such as chlorobenzene, dichlorobenzene, trichlorobenzene, ether solvents such as tetrahydrofuran and tetrahydropyran, and other halogenated solvents known to those skilled in the art, can be used.

The present invention also provides a display or lighting device including one or more of the organic photoelectric devices described above.

### Compared with the Prior Art, the Present Invention has the Following Beneficial Effects

The present invention provides a cyclic tetradentate metal platinum (II) complex phosphorescent material based on 8-phenylquinoline, benzoxazole, and phenoxy groups. It is a novel tetradentate platinum (II) complex with a 6/6/6 metal fused ring structure. The phosphorescent materials of the tetradentate fused ring structure system of the present invention have the characteristics of easy modulation of HOMO and LUMO orbital energy levels and strong luminescence. It has good chemical stability and thermal stability and is easy to fabricate evaporation-type OLED devices. The organic electroluminescent device fabricated using the compound of the present invention as a light-emitting layer can reduce the start-up voltage and remarkably improve the external quantum efficiency.

### BRIEF DESCRIPTION OF DRAWINGS

FIG. 1 shows emission spectrums of some metal platinum (II) complex phosphorescent LE materials in the deoxygenated state in dichloromethane solution at room temperature;

FIG. 2 shows the HOMO and LUMO orbital distributions of metal platinum (II) complexes Pt577, Pt578, Pt579, and Pt580; and

FIG. 3 shows the HOMO and LUMO orbital distributions of metal platinum (II) complexes Pt581, Pt582, Pt583, and Pt584.

### DETAILED DESCRIPTION OF THE EMBODIMENTS

Hereinafter, the present invention will be described in detail. The description of the constituent elements recorded below is sometimes based on representative embodiments or specific examples of the present invention, but the present invention is not limited to such embodiments or specific examples.

As used herein, the term “substituted” is intended to encompass all permissible substituents of organic compounds. In broad aspects, permissible substituents include acyclic and cyclic, branched and unbranched, carbocyclic and heterocyclic, and aromatic and non-aromatic substituents of the organic compounds. Illustrative substituents include, for example, those described below. The permissible substituents may be one or more and the same or different for appropriate organic compounds. For purposes of this invention, a heteroatom (e.g. nitrogen) can have a hydrogen substituent and/or any permissible substituent of the organic compound described herein that satisfies the valences of the heteroatom. The present invention is not intended to be limited in any manner by the permissible substituents of organic compounds. Likewise, the term “substituted” or “substituted with” includes the implicit proviso that such substitution is in accordance with a permitted valence of the substituted atom and the substituent and that the substitution results in a stable compound (e.g. a compound that does not spontaneously undergo transformation such as by rearrangement, cyclization, elimination, etc.). It is also contemplated that, in certain aspects, unless expressly stated to the contrary, individual substituents can be further optionally substituted (i.e. further substituted or unsubstituted).

In defining various terms, “R¹-R¹⁶” are used herein as a general symbol to represent various specific substituents. These symbols can be any substituents, not limited to those disclosed herein, and when they are limited in one instance to certain substituents, they can be limited in other instances to some other substituents.

As used herein, “R′, R¹ . . . . R¹⁶” can independently have one or more of the groups listed above. For example, if R¹ is a straight chain alkyl group, one hydrogen atom of the alkyl group may be optionally substituted with hydroxyl, alkoxy, alkyl, halogen, and the like. Depending on the group selected, the first group may be incorporated within the second group, or alternatively, the first group may be pendant, i.e. attached, to the second group. For example, for the phrase “amino-containing alkyl”, the amino group can be incorporated within the backbone of the alkyl group. Optionally, the amino group may be attached to the backbone of the alkyl group. The nature of the selected group will determine whether the first group is embedded in or attached to the second group.

The term “alkyl” as used herein is a branched or unbranched saturated hydrocarbon group of 1 to 60 carbon atoms such as methyl, ethyl, n-propyl, isopropyl, n-butyl, isobutyl, sec-butyl, t-butyl, n-pentyl, isopentyl, sec-pentyl, neopentyl, hexyl, heptyl, hemi-, nonyl, decyl, dodecyl, tetradecyl, hexadecyl, eicosyl, tetracosyl and the like. The alkyl group may be cyclic or acyclic. The alkyl group may be branched or unbranched. The alkyl group is substitutable or unsubstituted. For example, the alkyl group is substitutable with one or more groups including, but not limited to, an optionally substituted alkyl, cycloalkyl, alkoxy, amino, halo, hydroxy, nitro, silyl, sulfo-oxo, or mercapto group as described herein.

The term “aryl” as used herein is a radical of any carbon-based aromatic group containing from 6 to 60 carbon atoms including, but not limited to, phenyl, naphthyl, phenyl, biphenyl, phenoxyphenyl, anthracenyl, phenanthrenyl, and the like. The term “aryl” also includes “heteroaryl”, which is defined as a group containing an aromatic group having at least one heteroatom incorporated within the ring of the aromatic group. Examples of heteroatoms include but are not limited to, nitrogen, oxygen, sulfur, and phosphorus. Likewise, the term “non-heteroaryl” (which is also encompassed by the term “aryl”) defines groups that contain aromatic groups that are free of a heteroatom. The aryl group is substitutable or unsubstituted. The aryl group is substitutable with one or more groups including, but not limited to, alkyl, cycloalkyl, alkoxy, alkenyl, cycloalkenyl, alkynyl, cycloalkynyl, aryl, heteroaryl, aldehyde, amino, carboxyl, ester, halogen, hydroxyl, carbonyl, azido, nitro, silyl, sulfo-oxo, or thiol as described herein.

The compounds of the invention may contain “optionally substituted” moieties. In general, the term “substituted” (whether preceded by the term “optionally” or not) means that one or more hydrogens of the designated moiety are replaced with a suitable substituent. Unless otherwise indicated, an “optionally substituted” group may have a suitable substituent at each substitutable position of the group, and when more than one position in any given structure is substitutable with more than one substituent selected from a specified group, the substituent may be either the same or different at every position. Combinations of substituents envisioned by this invention are preferably those that result in the formation of stable or chemically feasible compounds. In certain aspects, unless expressly stated to the contrary, it is encompassed that individual substituents can be further optionally substituted (i.e. further substituted or unsubstituted).

The compound disclosed herein can exhibit desirable properties and have emission and/or absorption spectra that can be modulated by the selection of appropriate ligands. In another aspect, the invention may exclude any one or more compounds, structures, or portions thereof specifically recited herein.

The compounds of the present invention can be prepared using a variety of methods, including but not limited to those described in the examples provided herein.

It is to be understood that both the foregoing general description and the following detailed description are exemplary and explanatory only and are not restrictive.

The present application can be understood more readily by reference to the following detailed description and examples contained therein.

Before the present compounds, devices, and/or methods are disclosed and described, it is to be understood that they are not limited to specific synthetic methods (as otherwise indicated), or to specific reagents (as otherwise indicated), as such can, of course, vary. It is also to be understood that the terminology used in the invention is for the purpose of describing only the particular aspect and is not intended to be limiting. Although any methods and materials similar or equivalent to those described herein can be used in the practice or testing, exemplary methods and materials are described below. All starting materials and solvents of synthesis examples were purchased commercially unless otherwise specified, and the solvents were used as they are without further treatment.

The substrate of the present invention may be any substrate typically used in organic optoelectronic devices. It may be a glass or transparent plastic substrate, it may be a substrate of an opaque material such as silicon or stainless steel, and it may be a flexible PI film. Different substrates have different mechanical strength, thermal stability, transparency, surface smoothness, and water resistance. The application direction is different according to the properties of the substrates. As the materials for the hole-injecting layer, the hole-transporting layer, and the electron injecting layer, any material can be selected and used from known related materials for OLED devices, and the present invention is not particularly limited thereto.

### SYNTHESIS EXAMPLES

The following examples of compound syntheses, compositions, devices, or methods are provided merely to provide a general approach to the industry and are not intended to limit the scope of the patent. For the data mentioned in the patent (quantities, temperatures, etc.) are guaranteed to be as accurate as possible, but there may be some errors. Unless otherwise noted, the weighing is done separately, the temperature is ° C., or room temperature, and the pressure is near atmospheric.

Methods for the preparation of novel compounds are provided in the following examples, but the preparation of such compounds is not limited to this method. In this technical field, since the claimed compound of the present invention can be easily prepared by modification, the methods listed below or other methods can be used. The following examples are given by way of example only and are not intended to limit the scope of this patent. The temperature, catalyst, concentration, reactants, and course of reaction may be varied to select different conditions for different reactants to produce the compound.

¹H NMR (500 MHz), ¹H NMR (400 MHz), and ¹³C NMR (126 MHz) spectra were measured on an ANANCE III (500M) NMR spectrometer. Unless otherwise specified, DMSO-d₆ or CDCl₃ containing 0.1% TMS was used as the solvent for NMR. TMS (δ=0.00 ppm) was used as an internal standard when CDCl₃ was used as a solvent for ¹H NMR spectrum. TMS (δ=0.00 ppm), residual DMSO peak (δ=2.50 ppm) or residual water peak (δ=3.33 ppm) was used as the internal standard when DMSO-d₆ was used as the solvent. In ¹³C NMR spectra, CDCl₃ (δ=77.00 ppm) or DMSO-d₆ (δ=39.52 ppm) was used as the internal standard. Determination was done on the HPLC-MS Agilent 6210 TOF LC/MS. HRMS spectra were determined on the Agilent 6210 TOF LC/MS type liquid chromatography-time-of-flight mass spectrometer. ¹H NMR spectral data: s=singlet, d=doublet, t=triplet, q=quartet, p=quintet, m=multiplet, br=broad.

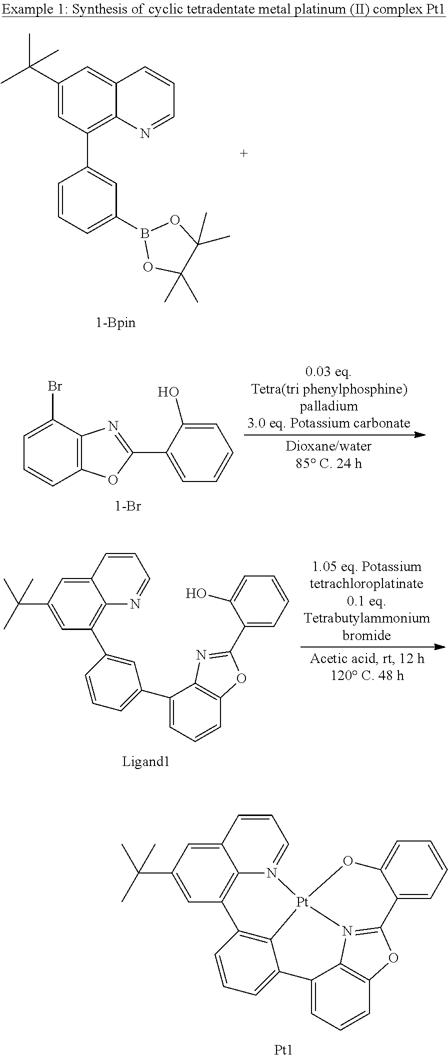

(1) Synthesis of ligand Ligand1: to a schlenk tube with a magnetic stirrer were added 1-Bpin (200 mg, 0.52 mmoL, 1.0 eq.), 1-Br (150 mg, 0.52 mmol, 1.0 eq.), tetra (triphenylphosphine) palladium (18 mg, 0.015 mmoL, 3 mol %), and potassium carbonate (214 mg, 1.55 mmoL, 3.0 eq.) successively. Nitrogen was pumped three times before injecting 1,4-dioxane (4 mL) and water (1 mL). The reaction lasted 12 h at 85° C. under stirring, and the starting material was substantially completely reacted as determined by TLC. The heating was stopped and the solvent was removed under reduced pressure. The mixture was stirred with silica gel and separated by column chromatography. Petroleum ether/ethyl acetate=15/1-12/1 was used as gradient elution to obtain 237 mg of product, a white foam solid, 97% yield. 1H NMR (500 MHz, DMSO-d₆): δ (ppm) 1.46 (s, 9H), 7.07-7.12 (m, 2H), 7.51-7.56 (m, 2H), 7.59 (t, J=8.0 Hz, 1H), 7.68 (t, J=7.5 Hz, 1H), 7.72-7.77 (m, 2H), 7.86 (dd, J=8.0, 1.0 Hz, 1H), 7.93-7.99 (m, 3H), 8.06 (dd, J=8.0, 1.5 Hz, 1H), 8.19 (t, J=1.5 Hz, 1H), 8.43 (dd, J=8.5, 2.0 Hz, 1H), 8.86 (dd, J=4.0, 2.0 Hz, 1H), 11.38 (s, 1H).

(2) Synthesis of Pt1: to a 50 mL three-neck flask equipped with a magnetic stirrer were added Ligand1 (200 mg, 0.43 mmoL, 1.0 eq.), potassium chloroplatinite (185 mg, 0.45 mmoL, 1.05 eq.), and tetra-n-butylammonium bromide (14 mg, 0.043 mmoL, 10 mol %) successively. A condenser tube was connected. Nitrogen was pumped three times before injecting 26 mL of acetic acid with a syringe. The reaction solution was bubbled with nitrogen for 30 minutes. After 12 hours of stirring at room temperature, the temperature was raised to 120° C., and stirring was continued for 48 hours. The reaction solution was cooled, and the solvent was removed under reduced pressure. The mixture was stirred with silica gel and separated by column chromatography. Petroleum ether/dichloromethane=2/1-1/1 was used as gradient elution to obtain 140 mg of product, light yellow solid, 49% yield. ¹H NMR (500 MHz, DMSO-d₆): δ (ppm) 1.49 (s, 9H), 6.76 (ddd, J=8.0, 7.0, 1.0 Hz, 1H), 6.91-6.96 (m, 1H), 7.43 (t, J=7.5 Hz, 1H), 7.47 (ddd, J=8.5, 7.0, 2.0 Hz, 1H), 7.57 (d, J=7.0 Hz, 1H), 7.65 (t, J=8.0 Hz, 1H), 7.79-7.86 (m, 2H), 8.07 (td, J=4.0, 3.5, 2.0 Hz, 2H), 8.21 (d, J=2.0 Hz, 1H), 8.36 (d, J=7.0 Hz, 1H), 8.41 (d, J=8.0 Hz, 1H), 8.83 (dd, J=8.5, 1.5 Hz, 1H), 9.51 (dd, J=5.5, 1.5 Hz, 1H).

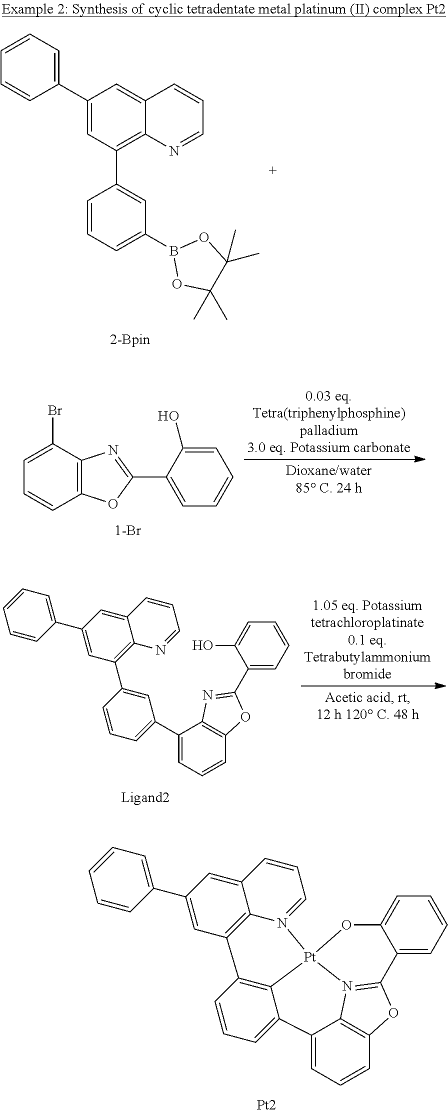

(1) Synthesis of ligand Ligand2: to a schlenk tube with a magnetic stirrer were added 2-Bpin (200 mg, 0.49 mmoL, 1.0 eq.), 1-Br (142 mg, 0.49 mmoL, 1.0 eq.), tetra (triphenylphosphine) palladium (17 mg, 0.015 mmoL, 3 mol %), and potassium carbonate (204 mg, 1.47 mmoL, 3.0 eq.) successively. Nitrogen was pumped three times before injecting 1,4-dioxane (4 mL) and water (1 mL). The reaction lasted 12 h at 85° C. under stirring, and the starting material was substantially completely reacted as determined by TLC. The heating was stopped and the solvent was removed under reduced pressure. The mixture was stirred with silica gel and separated by column chromatography. Petroleum ether/ethyl acetate=15/1-12/1 was used as gradient elution to obtain of 215 mg of product, white foam solid, 90% yield. 1H NMR (500 MHz, DMSO-d₆): δ (ppm) 7.05-7.13 (m, 2H), 7.45 (t, J=7.5 Hz, 1H), 7.51-7.64 (m, 5H), 7.70 (t, J=7.5 Hz, 1H), 7.77 (dd, J=7.5, 0.5 Hz, 1H), 7.86 (td, J=7.5, 7.0, 1.0 Hz, 2H), 7.95-7.98 (m, 2H), 8.00 (dt, J=8.0, 1.0 Hz, 1H), 8.05 (dd, J=8.0, 1.5 Hz, 1H), 8.21 (d, J=2.0 Hz, 1H), 8.29 (t, J=1.5 Hz, 1H), 8.36 (d, J=2.0 Hz, 1H), 8.53 (dd, J=8.5, 1.5 Hz, 1H), 8.94 (dd, J=4.0, 2.0 Hz, 1H), 11.39 (s, 1H).

(2) Synthesis of Pt2: to a 50 mL dried three-neck flask equipped with a magnetic stirrer were added Ligand2 (165 mg, 0.34 mmoL, 1.0 eq.), potassium chloroplatinite (147 mg, 0.35 mmoL, 1.05 eq.), and tetra-n-butylammonium bromide (11 mg, 0.034 mmoL, 10 mol %) successively. A condenser tube was connected. Nitrogen was pumped three times before injecting 20 mL of acetic acid with a syringe. The reaction solution was bubbled with nitrogen for 30 minutes. After 12 hours of stirring at room temperature, the temperature was raised to 120° C., and stirring was continued for 48 hours. The reaction solution was cooled, and the solvent was removed under reduced pressure. The mixture was stirred with silica gel and separated by column chromatography. Petroleum ether/dichloromethane=2/1-1/1 was used as gradient elution to obtain 163 mg of product, light yellow solid, 70% yield. ¹H NMR (500 MHz, DMSO-d₆): δ (ppm) 6.77 (ddd, J=8.0, 7.0, 1.0 Hz, 1H), 6.95-6.99 (m, 1H), 7.42 (t, J=7.5 Hz, 1H), 7.46-7.50 (m, 2H), 7.58 (t, J=7.5 Hz, 2H), 7.66 (t, J=8.0 Hz, 1H), 7.74 (d, J=7.0 Hz, 1H), 7.85 (d, J=8.0 Hz, 1H), 7.88 (dd, J=8.0, 5.5 Hz, 1H), 7.97-8.01 (m, 2H), 8.08 (dd, J=8.0, 1.5 Hz, 1H), 8.37 (d, J=7.5 Hz, 1H), 8.41 (dd, J=5.0, 3.0 Hz, 2H), 8.45 (d, J=2.0 Hz, 1H), 8.90 (dd, J=8.5, 1.5 Hz, 1H), 9.58 (dd, J=5.5, 1.5 Hz, 1H).

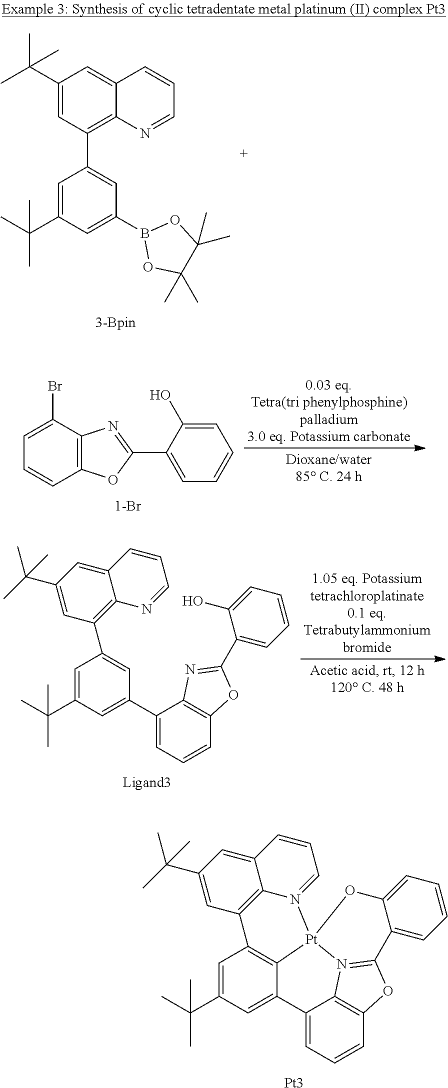

(1) Synthesis of ligand Ligand3: to a schlenk tube with a magnetic stirrer were added 3-Bpin (300 mg, 0.68 mmoL, 1.0 eq.), 1-Br (196 mg, 0.68 mmoL, 1.0 eq.), tetra (triphenylphosphine) palladium (23 mg, 0.020 mmoL, 3 mol %), and potassium carbonate (281 mg, 2.03 mmoL, 3.0 eq.) successively. Nitrogen was pumped three times before injecting 1,4-dioxane (4 mL) and water (1 mL). The reaction lasted 12 h at 85° C. under stirring, and the starting material was substantially completely reacted as determined by TLC. The heating was stopped and the solvent was removed under reduced pressure. The mixture was stirred with silica gel and separated by column chromatography. Petroleum ether/ethyl acetate=15/1-12/1 was used as gradient elution to obtain 297 mg of product, white foam solid, 83% yield. 1H NMR (400 MHz, DMSO-d₆): δ (ppm) 1.44 (s, 9H), 1.46 (s, 9H), 7.07-7.20 (m, 2H), 7.49-7.63 (m, 3H), 7.75 (d, J=6.8 Hz, 2H), 7.85 (d, J=8.0 Hz, 1H), 7.89-7.99 (m, 3H), 8.07 (d, J=6.4 Hz, 2H), 8.35-8.47 (m, 1H), 8.78-8.93 (m, 1H), 11.49 (s, 1H).

(2) Synthesis of Pt3: to a 50 mL three-neck flask equipped with a magnetic stirrer were added Ligand3 (230 mg, 0.44 mmoL, 1.0 eq.), potassium chloroplatinite (190 mg, 0.46 mmoL, 1.05 eq.), and tetra-n-butylammonium bromide (14 mg, 0.044 mmoL, 10 mol %) successively. A condenser tube was connected. Nitrogen was pumped three times before injecting 26 mL of acetic acid with a syringe. The reaction solution was bubbled with nitrogen for 30 minutes. After 12 hours of stirring at room temperature, the temperature was raised to 120° C. and stirring was continued for 48 hours. The reaction solution was cooled, and the solvent was removed under reduced pressure. The mixture was stirred with silica gel and separated by column chromatography. Petroleum ether/dichloromethane=2/1-1/1 was used as gradient elution to obtain 200 mg of product, light yellow solid, 63% yield. ¹H NMR (500 MHz, DMSO-d₆): δ (ppm) 1.45 (s, 9H), 1.50 (s, 9H), 6.76 (ddd, J=8.0, 7.0, 1.0 Hz, 1H), 6.94 (d, J=8.0 Hz, 1H), 7.47 (ddd, J=8.5, 7.0, 2.0 Hz, 1H), 7.51 (d, J=2.0 Hz, 1H), 7.66 (t, J=8.0 Hz, 1H), 7.77-7.86 (m, 2H), 8.07 (dd, J=6.5, 2.0 Hz, 2H), 8.19 (d, J=2.0 Hz, 1H), 8.33 (d, J=2.0 Hz, 1H), 8.46 (d, J=8.5 Hz, 1H), 8.83 (dd, J=8.5, 1.5 Hz, 1H), 9.53 (dd, J=5.5, 1.5 Hz, 1H).

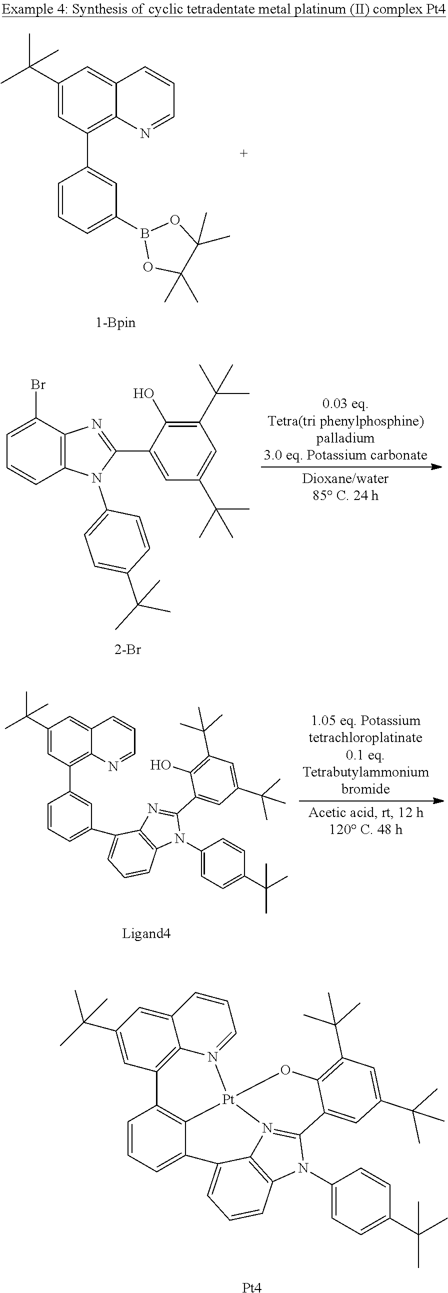

(1) Synthesis of ligand Ligand4: to a schlenk tube with a magnetic stirrer were added 1-Bpin (145 mg, 0.37 mmoL, 1.0 eq.), 2-Br (200 mg, 0.37 mmoL, 1.0 eq.), tetra (triphenylphosphine) palladium (13 mg, 0.011 mmoL, 3 mol %), and potassium carbonate (155 mg, 1.10 mmoL, 3.0 eq.) successively. Nitrogen was pumped three times before injecting 1,4-dioxane (4 mL) and water (1 mL). The reaction lasted 12 h at 85° C. under stirring, and the starting material was substantially completely reacted as determined by TLC. The heating was stopped and the solvent was removed under reduced pressure. The mixture was stirred with silica gel and separated by column chromatography. Petroleum ether/ethyl acetate=15/1-12/1 was used as gradient elution to obtain 233 mg of product, white foam solid, 87% yield. 1H NMR (400 MHz, CDCl₃): δ (ppm) 0.93 (s, 9H), 1.41 (s, 9H), 1.42 (s, 9H), 1.47 (s, 9H), 6.89 (d, J=2.4 Hz, 1H), 7.10 (dd, J=8.0, 0.8 Hz, 1H), 7.32 (t, J=7.6 Hz, 1H), 7.35-7.43 (m, 3H), 7.56 (dd, J=7.6, 0.8 Hz, 1H), 7.59-7.66 (m, 2H), 7.68-7.79 (m, 3H), 7.93 (d, J=2.0 Hz, 1H), 8.15 (t, J=1.6 Hz, 1H), 8.16-8.24 (m, 2H), 8.92 (dd, J=4.2, 1.6 Hz, 1H), 13.59 (s, 1H).

(2) Synthesis of Pt4: to a 50 mL dried three-neck flask equipped with a magnetic stirrer were added Ligand4 (200 mg, 0.28 mmoL, 1.0 eq.), potassium chloroplatinite (122 mg, 0.29 mmoL, 1.05 eq.), and tetra-n-butylammonium bromide (9 mg, 0.028 mmoL, 10 mol %) successively. A condenser tube was connected. Nitrogen was pumped three times before injecting 17 mL of acetic acid with a syringe. The reaction solution was bubbled with nitrogen for 30 minutes. After 12 hours of stirring at room temperature, the temperature was raised to 120° C., and stirring was continued for 48 hours. The reaction solution was cooled, and the solvent was removed under reduced pressure. The mixture was stirred with silica gel and separated by column chromatography. Petroleum ether/dichloromethane=2/1-1/1 was used as gradient elution to obtain 211 mg of product, light yellow solid, 83% yield. ¹H NMR (400 MHz, DMSO-d₆): δ (ppm) 0.82 (s, 9H), 1.20 (s, 9H), 1.36 (s, 9H), 1.49 (s, 9H), 6.74 (d, J=2.4 Hz, 1H), 7.11 (d, J=2.4 Hz, 1H), 7.18 (d, J=8.0 Hz, 1H), 7.37 (t, J=7.6 Hz, 1H), 7.43-7.61 (m, 4H), 7.69 (d, J=8.8 Hz, 2H), 7.75 (dd, J=8.0, 5.2 Hz, 1H), 8.03 (d, J=2.0 Hz, 1H), 8.20 (d, J=7.6 Hz, 1H), 8.27 (d, J=8.0 Hz, 1H), 8.34 (d, J=2.0 Hz, 1H), 8.79 (dd, J=8.4, 1.2 Hz, 1H), 9.56 (dd, J=5.2, 1.2 Hz, 1H).

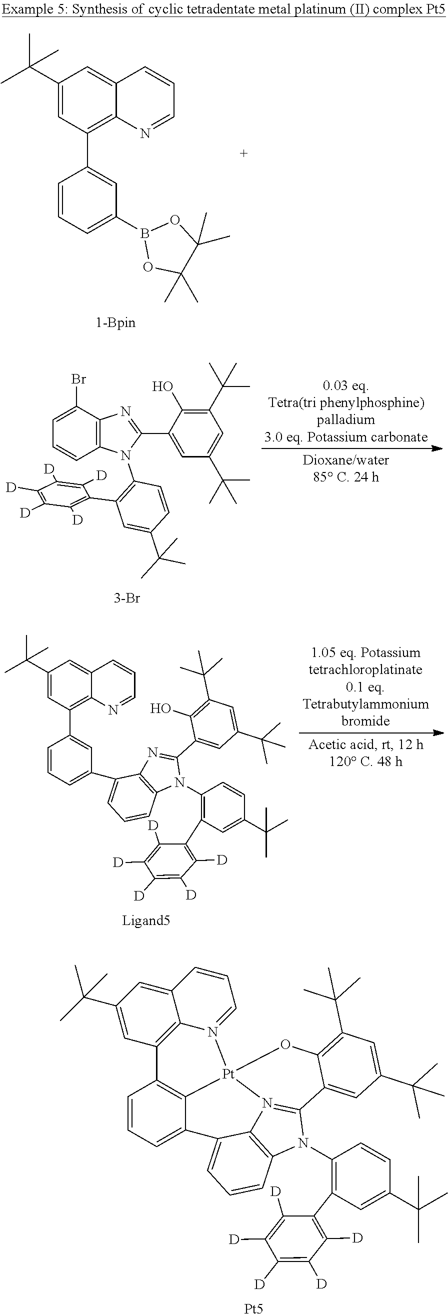

(1) Synthesis of ligand Ligand5: to a schlenk tube with a magnetic stirrer were added 1-Bpin (76 mg, 0.20 mmoL, 1.0 eq.), 3-Br (120 mg, 0.20 mmol, 1.0 eq.), tetra (triphenylphosphine) palladium (7 mg, 0.0059 mmoL, 3 mol %), and potassium carbonate (81 mg, 0.59 mmoL, 3.0 eq.) successively. Nitrogen was pumped three times before injecting 1,4-dioxane (4 mL) and water (1 mL). The reaction lasted 12 h at 85° C. under stirring, and the starting material was substantially completely reacted as determined by TLC. The heating was stopped and the solvent was removed under reduced pressure. The mixture was stirred with silica gel and separated by column chromatography. Petroleum ether/ethyl acetate=15/1-12/1 was used as gradient elution to obtain 147 mg of product, white foam solid, 92% yield. 1H NMR (500 MHz, DMSO-d₆): δ (ppm) 0.92 (s, 9H), 1.21 (s, 9H), 1.40 (s, 9H), 1.43 (s, 9H), 6.88 (d, J=2.5 Hz, 1H), 7.12-7.17 (m, 2H), 7.39 (t, J=8.0 Hz, 1H), 7.50 (dd, J=8.5, 4.0 Hz, 1H), 7.58 (dd, J=7.0, 1.5 Hz, 2H), 7.67 (td, J=4.5, 1.5 Hz, 2H), 7.71 (d, J=8.5 Hz, 1H), 7.77 (dd, J=8.5, 2.5 Hz, 1H), 7.92 (q, J=2.0 Hz, 2H), 7.93-7.97 (m, 1H), 8.16 (s, 1H), 8.39 (dd, J=8.5, 1.5 Hz, 1H), 8.81 (dd, J=4.0, 2.0 Hz, 1H), 12.97 (s, 1H).

(2) Synthesis of Pt5: to a 50 mL dried three-neck flask equipped with a magnetic stirrer were added Ligand5 (127 mg, 0.16 mmoL, 1.0 eq.), potassium chloroplatinite (67 mg, 0.17 mmoL, 1.05 eq.), and tetra-n-butylammonium bromide (5 mg, 0.016 mmoL, 10 mol %) successively. A condenser tube was connected. Nitrogen was pumped three times before injecting 10 mL of acetic acid with a syringe. The reaction solution was bubbled with nitrogen for 30 minutes. After 12 hours of stirring at room temperature, the temperature was raised to 120° C., and stirring was continued for 48 hours. The reaction solution was cooled, and the solvent was removed under reduced pressure. The mixture was stirred with silica gel and separated by column chromatography. Petroleum ether/dichloromethane=2/1-1/1 was used as gradient elution to obtain 125 mg of product, light yellow solid, 79% yield. ¹H NMR (500 MHz, CDCl₃): δ (ppm) 0.88 (s, 9H), 1.20 (s, 9H), 1.42 (s, 9H), 1.49 (s, 9H), 6.89 (d, J=2.5 Hz, 1H), 7.02 (d, J=8.0 Hz, 1H), 7.13 (d, J=2.5 Hz, 1H), 7.29 (t, J=8.0 Hz, 1H), 7.34 (t, J=7.5 Hz, 1H), 7.45 (dd, J=8.0, 5.0 Hz, 1H), 7.51-7.60 (m, 4H), 7.68 (d, J=2.0 Hz, 1H), 8.06 (d, J=8.0 Hz, 1H), 8.09-8.13 (m, 1H), 8.25 (d, J=2.0 Hz, 1H), 8.35 (dd, J=8.5, 1.5 Hz, 1H), 9.55 (dd, J=5.0, 1.5 Hz, 1H).

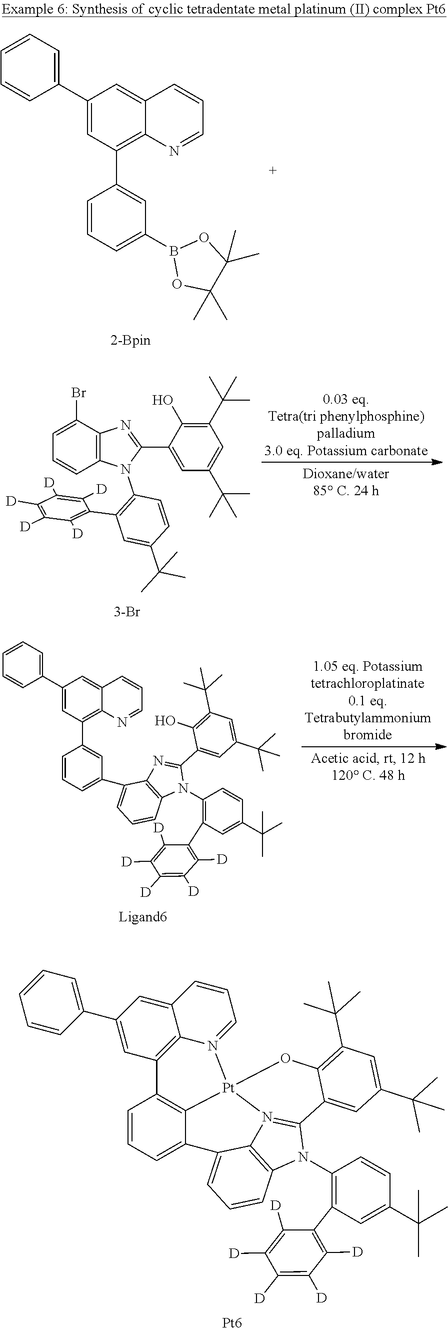

(1) Synthesis of ligand Ligand6: to a schlenk tube with a magnetic stirrer were added 2-Bpin (81 mg, 0.20 mmoL, 1.0 eq.), 3-Br (120 mg, 0.20 mmoL, 1.0 eq.), tetra (triphenylphosphine) palladium (7 mg, 0.0059 mmoL, 3 mol %), and potassium carbonate (81 mg, 0.59 mmoL, 3.0 eq.) successively. Nitrogen was pumped three times before injecting 1,4-dioxane (4 mL) and water (1 mL). The reaction lasted 12 h at 85° C. under stirring, and the starting material was substantially completely reacted as determined by TLC. The heating was stopped and the solvent was removed under reduced pressure. The mixture was stirred with silica gel and separated by column chromatography. Petroleum ether/ethyl acetate=15/1-12/1 was used as gradient elution to obtain 137 mg of product, white foam solid, 84% yield. 1H NMR (500 MHz, DMSO-d₆): δ (ppm) 0.94 (s, 9H), 1.20 (s, 9H), 1.41 (s, 9H), 6.91 (d, J=2.5 Hz, 1H), 7.15 (dd, J=8.0, 1.0 Hz, 1H), 7.16 (d, J=2.5 Hz, 1H), 7.36-7.40 (m, 1H), 7.40-7.44 (m, 1H), 7.50 (t, J=7.5 Hz, 2H), 7.57-7.64 (m, 3H), 7.69 (t, J=7.5 Hz, 1H), 7.73 (d, J=8.5 Hz, 1H), 7.76-7.82 (m, 2H), 7.88-7.93 (m, 2H), 8.01 (dt, J=8.0, 1.0 Hz, 1H), 8.18 (d, J=2.0 Hz, 1H), 8.27 (t, J=1.5 Hz, 1H), 8.33 (d, J=2.0 Hz, 1H), 8.51 (dd, J=8.5, 2.0 Hz, 1H), 8.91 (dd, J=4.0, 2.0 Hz, 1H), 13.08 (s, 1H).

(2) Synthesis of Pt6: to a 50 mL dried three-neck flask equipped with a magnetic stirrer were added Ligand6 (117 mg, 0.14 mmoL, 1.0 eq.), potassium chloroplatinite (63 mg, 0.15 mmoL, 1.05 eq.), and tetra-n-butylammonium bromide (5 mg, 0.014 mmoL, 10 mol %) successively. A condenser tube was connected. Nitrogen was pumped three times before injecting 9 mL of acetic acid with a syringe. The reaction solution was bubbled with nitrogen for 30 minutes. After 12 hours of stirring at room temperature, the temperature was raised to 120° C., and stirring was continued for 48 hours. The reaction solution was cooled, and the solvent was removed under reduced pressure. The mixture was stirred with silica gel and separated by column chromatography. Petroleum ether/dichloromethane=2/1-1/1 was used as gradient elution to obtain 111 mg of product, light yellow solid, 79% yield. ¹H NMR (500 MHz, CDCl₃): δ (ppm) 0.89 (s, 9H), 1.21 (s, 9H), 1.43 (s, 9H), 6.91 (d, J=2.5 Hz, 1H), 7.03 (d, J=8.0 Hz, 1H), 7.15 (d, J=2.5 Hz, 1H), 7.30 (t, J=8.0 Hz, 1H), 7.34 (t, J=7.5 Hz, 1H), 7.43-7.46 (m, 1H), 7.49-7.63 (m, 8H), 7.77-7.80 (m, 2H), 7.96 (d, J=2.0 Hz, 1H), 8.07 (d, J=8.0 Hz, 1H), 8.12 (d, J=8.0 Hz, 1H), 8.42 (d, J=2.0 Hz, 1H), 8.45 (dd, J=8.0, 1.5 Hz, 1H), 9.61 (dd, J=5.0, 1.5 Hz, 1H).

### Example 7: Synthesis of Pt7

Pt7 was synthesized by referring to the synthesis procedure and reaction condition of compound Pt1. The desired product was obtained as 122 mg of yellow solid with a yield of 63%. Molecular weight [M+H]⁺: 738.73.

### Example 8: Synthesis of Pt33

Pt33 was synthesized by referring to the synthesis procedure and reaction condition of compound Pt1. The desired product was obtained as 201 mg of yellow solid with a yield of 79%. Molecular weight [M+H]⁺: 707.72.

### Example 9: Synthesis of Pt48

Pt48 was synthesized by referring to the synthesis procedure and reaction condition of compound Pt1. The desired product was obtained as 159 mg of yellow solid with a yield of 68%. Molecular weight [M+H]⁺: 831.83.

### Example 10: Synthesis of Pt67

Pt67 was synthesized by referring to the synthesis procedure and reaction condition of compound Pt1. The desired product was obtained as 186 mg of yellow solid with a yield of 69%. Molecular weight [M+H]⁺: 754.73.

### Example 11: Synthesis of Pt77

Pt77 was synthesized by referring to the synthesis procedure and reaction condition of compound Pt1. The desired product was obtained as 175 mg of yellow solid with a yield of 65%. Molecular weight [M+H]⁺: 859.87.

### Example 12: Synthesis of Pt79

Pt79 was synthesized by referring to the synthesis procedure and reaction condition of compound Pt1. The desired product was obtained as 210 mg of yellow solid with a yield of 80%. Molecular weight [M+H]⁺: 928.03.

### Example 13: Synthesis of Pt96

Pt96 was synthesized by referring to the synthesis procedure and reaction condition of compound Pt1. The desired product was obtained as 169 mg of yellow solid with a yield of 63%. Molecular weight [M+H]⁺: 755.76.

### Example 14: Synthesis of Pt107

Pt107 was synthesized by referring to the synthesis procedure and reaction condition of compound Pt1. The desired product was obtained as 163 mg of yellow solid with a yield of 58%. Molecular weight [M+H]⁺: 774.84.

### Example 15: Synthesis of Pt137

Pt137 was synthesized by referring to the synthesis procedure and reaction condition of compound Pt1. The desired product was obtained as 210 mg of yellow solid with a yield of 76%. Molecular weight [M+H]⁺: 861.93.

### Example 16: Synthesis of Pt150

Pt150 was synthesized by referring to the synthesis procedure and reaction condition of compound Pt1. The desired product was obtained as 182 mg of yellow solid with a yield of 68%. Molecular weight [M+H]⁺: 805.77.

### Example 17: Synthesis of Pt156

Pt156 was synthesized by referring to the synthesis procedure and reaction condition of compound Pt1. The desired product was obtained as 188 mg of yellow solid with a yield of 77%. Molecular weight [M+H]⁺: 763.82.

### Example 18: Synthesis of Pt178

Pt178 was synthesized by referring to the synthesis procedure and reaction condition of compound Pt1. The desired product was obtained as 178 mg of yellow solid with a yield of 78%. Molecular weight [M+H]⁺: 769.79.

### Example 19: Synthesis of Pt184

Pt184 was synthesized by referring to the synthesis procedure and reaction condition of compound Pt1. The desired product was obtained as 153 mg of yellow solid with a yield of 49%. Molecular weight [M+H]⁺: 797.84.

### Example 20: Synthesis of Pt192

Pt192 was synthesized by referring to the synthesis procedure and reaction condition of compound Pt1. The desired product was obtained as 190 mg of yellow solid with a yield of 76%. Molecular weight [M+H]⁺: 902.98.

### Example 21: Synthesis of Pt208

Pt208 was synthesized by referring to the synthesis procedure and reaction condition of compound Pt1. The desired product was obtained as 152 mg of yellow solid with a yield of 62%. Molecular weight [M+H]⁺: 924.00.

### Example 22: Synthesis of Pt239

Pt239 was synthesized by referring to the synthesis procedure and reaction condition of compound Pt1. The desired product was obtained as 167 mg of yellow solid with a yield of 68%. Molecular weight [M+H]⁺: 1012.18.

### Example 23: Synthesis of Pt246

Pt246 was synthesized by referring to the synthesis procedure and reaction condition of compound Pt1. The desired product was obtained as 182 mg of yellow solid with a yield of 73%. Molecular weight [M+H]⁺: 750.84.

### Example 24: Synthesis of Pt254

Pt254 was synthesized by referring to the synthesis procedure and reaction condition of compound Pt1. The desired product was obtained as 166 mg of yellow solid with a yield of 56%. Molecular weight [M+H]⁺: 945.12.

### Example 25: Synthesis of Pt269

Pt269 was synthesized by referring to the synthesis procedure and reaction condition of compound Pt1. The desired product was obtained as 190 mg of yellow solid with a yield of 74%. Molecular weight [M+H]⁺: 812.91.

### Example 26: Synthesis of Pt281

Pt281 was synthesized by referring to the synthesis procedure and reaction condition of compound Pt1. The desired product was obtained as 192 mg of yellow solid with a yield of 79%. Molecular weight [M+H]⁺: 694.74.

### Example 27: Synthesis of Pt305

Pt305 was synthesized by referring to the synthesis procedure and reaction condition of compound Pt1. The desired product was obtained as 173 mg of yellow solid with a yield of 68%. Molecular weight [M+H]⁺: 851.93.

### Example 28: Synthesis of Pt325

Pt325 was synthesized by referring to the synthesis procedure and reaction condition of compound Pt1. The desired product was obtained as 188 mg of yellow solid with a yield of 73%. Molecular weight [M+H]⁺: 809.90.

### Example 29: Synthesis of Pt349

Pt349 was synthesized by referring to the synthesis procedure and reaction condition of compound Pt1. The desired product was obtained as 180 mg of yellow solid with a yield of 68%. Molecular weight [M+H]⁺: 990.15.

### Example 30: Synthesis of Pt368

Pt368 was synthesized by referring to the synthesis procedure and reaction condition of compound Pt1. The desired product was obtained as 191 mg of yellow solid with a yield of 75%. Molecular weight [M+H]⁺: 999.11.

### Example 31: Synthesis of Pt382

Pt382 was synthesized by referring to the synthesis procedure and reaction condition of compound Pt1. The desired product was obtained as 143 mg of yellow solid with a yield of 65%. Molecular weight [M+H]⁺: 809.90.

### Example 32: Synthesis of Pt392

Pt392 was synthesized by referring to the synthesis procedure and reaction condition of compound Pt1. The desired product was obtained as 167 mg of yellow solid with a yield of 66%. Molecular weight [M+H]⁺: 908.09.

### Example 33: Synthesis of Pt409

Pt409 was synthesized by referring to the synthesis procedure and reaction condition of compound Pt1. The desired product was obtained as 178 mg of yellow solid with a yield of 73%. Molecular weight [M+H]⁺: 821.79.

### Example 34: Synthesis of Pt462

Pt462 was synthesized by referring to the synthesis procedure and reaction condition of compound Pt1. The desired product was obtained as 156 mg of yellow solid with a yield of 59%. Molecular weight [M+H]⁺: 829.89.

### Example 35: Synthesis of Pt476

Pt476 was synthesized by referring to the synthesis procedure and reaction condition of compound Pt1. The desired product was obtained as 170 mg of yellow solid with a yield of 68%. Molecular weight [M+H]⁺: 976.12.

### Example 36: Synthesis of Pt484

Pt484 was synthesized by referring to the synthesis procedure and reaction condition of compound Pt1. The desired product was obtained as 192 mg of yellow solid with a yield of 79%. Molecular weight [M+H]⁺: 948.07.

### Example 37: Synthesis of Pt516

Pt516 was synthesized by referring to the synthesis procedure and reaction condition of compound Pt1. The desired product was obtained as 167 mg of yellow solid with a yield of 68%. Molecular weight [M+H]⁺: 895.05.

### Example 38: Synthesis of Pt560

Pt560 was synthesized by referring to the synthesis procedure and reaction condition of compound Pt1. The desired product was obtained as 158 mg of yellow solid with a yield of 58%. Molecular weight [M+H]⁺: 1067.23.

### Example 39: Synthesis of Pt577

Pt577 was synthesized by referring to the synthesis procedure and reaction condition of compound Pt1. The desired product was obtained as 166 mg of yellow solid with a yield of 65%. Molecular weight [M+H]⁺: 829.89.

### Example 40: Synthesis of Pt578

Pt578 was synthesized by referring to the synthesis procedure and reaction condition of compound Pt1. The desired product was obtained as 178 mg of yellow solid with a yield of 72%. Molecular weight [M+H]⁺: 787.81.

### Example 41: Synthesis of Pt579

Pt579 was synthesized by referring to the synthesis procedure and reaction condition of compound Pt1. The desired product was obtained as 189 mg of yellow solid with a yield of 78%. Molecular weight [M+H]⁺: 740.62.

### Example 42: Synthesis of Pt580

Pt580 was synthesized by referring to the synthesis procedure and reaction condition of compound Pt1. The desired product was obtained as 177 mg of yellow solid with a yield of 71%. Molecular weight [M+H]⁺: 945.02.

### Example 43: Synthesis of Pt581

Pt581 was synthesized by referring to the synthesis procedure and reaction condition of compound Pt1. The desired product was obtained as 159 mg of yellow solid with a yield of 63%. Molecular weight [M+H]⁺: 760.77.

### Example 44: Synthesis of Pt582

Pt582 was synthesized by referring to the synthesis procedure and reaction condition of compound Pt1. The desired product was obtained as 183 mg of yellow solid with a yield of 74%. Molecular weight [M+H]⁺: 883.93.

### Example 45: Synthesis of Pt583

Pt583 was synthesized by referring to the synthesis procedure and reaction condition of compound Pt1. The desired product was obtained as 202 mg of yellow solid with a yield of 80%. Molecular weight [M+H]⁺: 993.93.

### Example 46: Synthesis of Pt584

Pt584 was synthesized by referring to the synthesis procedure and reaction condition of compound Pt1. The desired product was obtained as 182 mg of yellow solid with a yield of 79%. Molecular weight [M+H]⁺: 900.92.

### Photophysical Testing and Theoretical Calculation Description:

Steady state emission experiments and lifetime measurements were performed on a Horiba Jobin Yvon FluoroLog-3 spectrometer. Pt (II) complexes were theoretically calculated using the Titan software package, and the geometry of the ground state (So) molecule was optimized using density-functional theory (DFT). DFT calculations were performed using B3LYP functional where the 6-31G (d) basis set was used for C, H, O and S atoms and the LANL2DZ basis set was used for Pt atoms.

### Experimental Data and Analysis

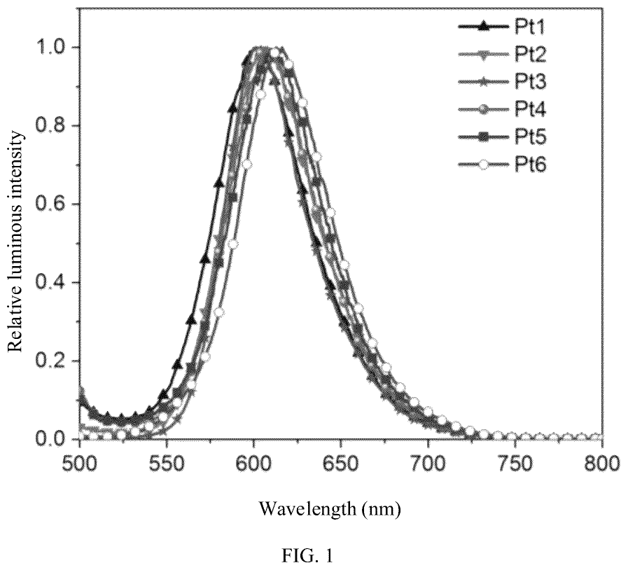

FIG. 1 shows emission spectrums of some metal platinum (II) complex phosphorescent LE material in the deoxygenated state in dichloromethane solution at room temperature. It can be seen from FIG. 1 that Pt1, Pt2, Pt3, Pt4, Pt5, and Pt6 can emit intense orange-red light and can be applied to the OLED light-emitting layer material.

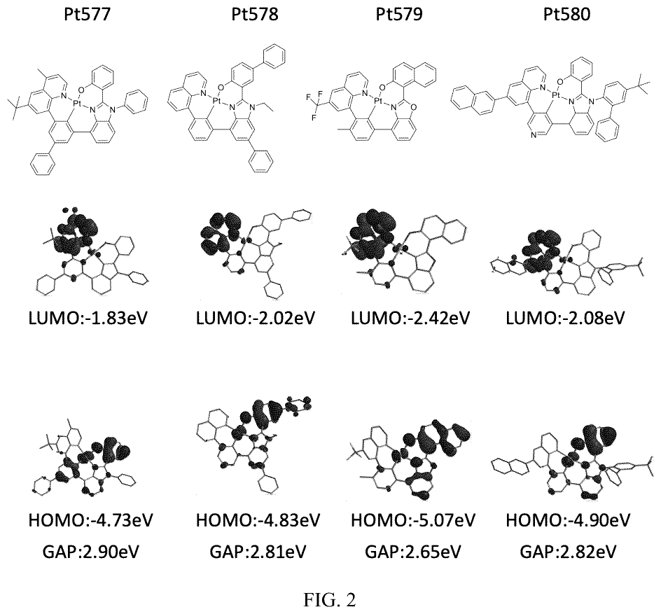

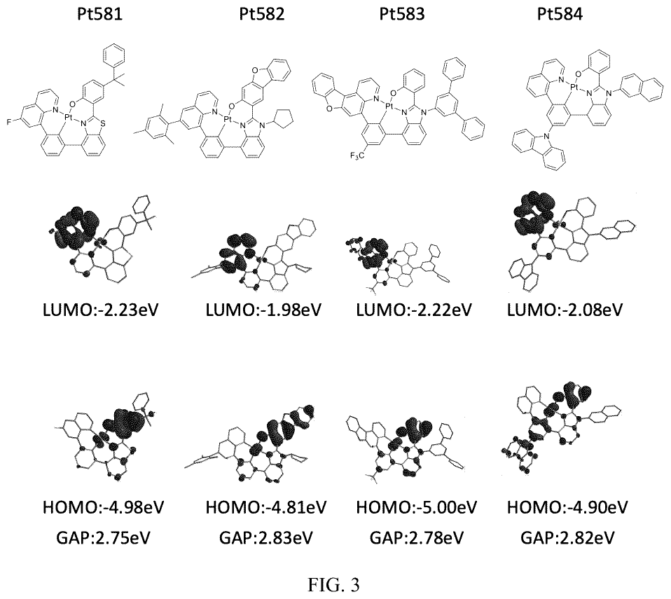

The following structures were calculated using density functional theory (DFT). Table 1 shows DFT theoretical calculation data, FIG. 2 shows the HOMO and LUMO orbital distributions of metal platinum (II) complexes Pt577, Pt578, Pt579, and Pt580; and FIG. 3 shows the HOMO and LUMO orbital distributions of metal platinum (II) complexes Pt581, Pt582, Pt583, and Pt584.

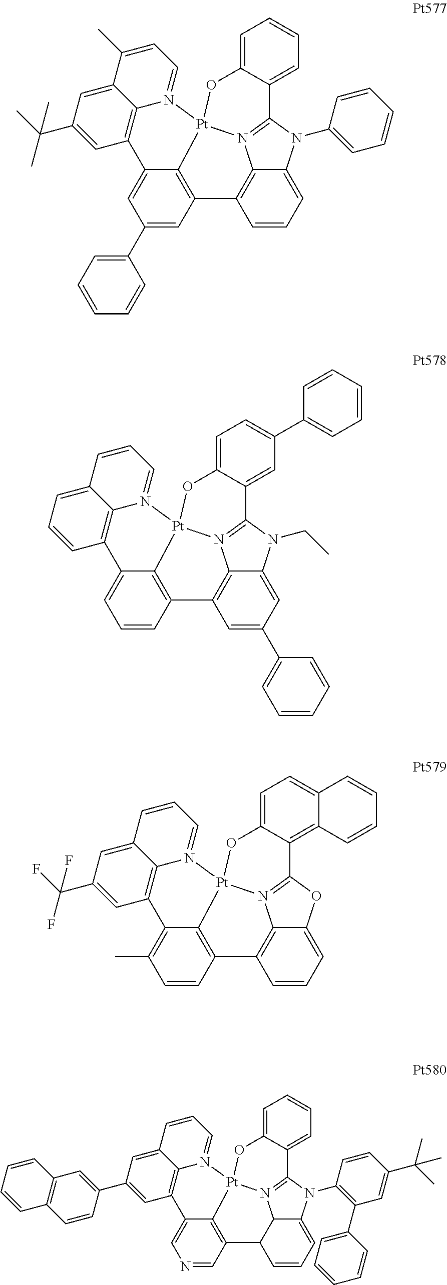

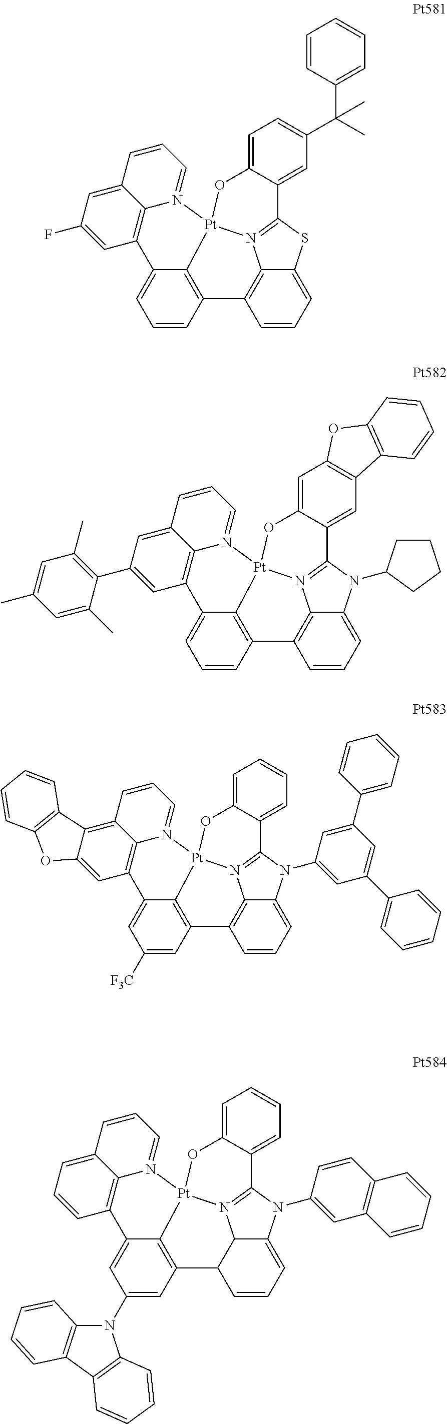

TABLE 1
DFT theoretical calculation data

| | LUMO/ | HOMO/ | Band | | LUMO/ | HOMO/ | Band |
|---|---|---|---|---|---|---|---|
| Name | eV | eV | gap/eV | Name | eV | eV | gap/eV |
| Pt577 | −1.83 | −4.73 | 2.90 | Pt578 | −2.02 | −4.83 | 2.81 |
| Pt579 | −2.42 | −5.07 | 2.65 | Pt580 | −2.08 | −4.90 | 2.82 |
| Pt581 | −2.23 | −4.98 | 2.75 | Pt582 | −1.98 | −4.81 | 2.83 |
| Pt583 | −2.22 | −5.00 | 2.78 | Pt584 | −2.08 | −4.90 | 2.82 |

It can be seen from FIGS. 2 and 3, and Table 1 that Pt577, Pt578, Pt579, and Pt580 have similar LUMO orbital distributions that are mainly concentrated in the quinoline moieties. In addition, alkyl substitutions, aryl substitutions, and the fused-ring structure all have a large impact on their LUMO orbital distributions. It is also found that the magnitude of the LUMO energy level also changes with the electron-donating ability. The HOMO orbital distributions of Pt581, Pt582, Pt583, Pt584, etc. are mainly concentrated on the phenoxy-coordinated phenyl moieties, and the introduction of alkyl, aryl, heteroatom, and the fused-ring structure on the phenoxy phenyl are able to effectively modulate the HOMO energy level, thus realizing the photophysical property modulation for luminescent materials. The above experimental data and theoretical calculation results fully show that the cyclic tetradentate metal platinum (II) complex phosphorescent material based on 8-phenylquinoline, benzoxazole, and phenoxy groups disclosed in the present invention has the characteristics of easy modulation of HOMO and LUMO orbital energy levels and high efficiency of phosphorescence quantum, indicating its great application prospect in the field of OLED.

### Fabrication of OLED Devices

In a preferred embodiment of the present invention, the OLED device of the present invention includes a hole transport layer. The hole transport material may be selected from known or unknown materials and is particularly preferred from the following structures, but this does not mean that the present invention is limited to the following structures:

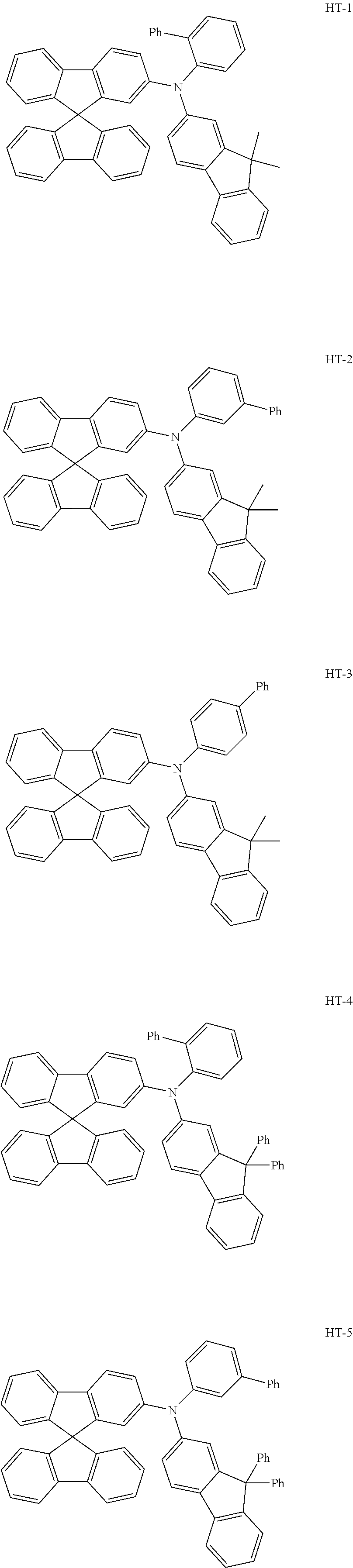 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3cccc(-c4ccccc4)c3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccccc2N(c2ccc3c(c2)C(c2ccccc2)(c2ccccc2)c2ccccc2-3)c2ccc3c(c2)C2(c4ccccc4-c4ccccc42)c2ccccc2-3)cc1 ; c1ccc(-c2cccc(N(c3ccc4c(c3)C(c3ccccc3)(c3ccccc3)c3ccccc3-4)c3ccc4c(c3)C3(c5ccccc5-c5ccccc53)c3ccccc3-4)c2)cc1]

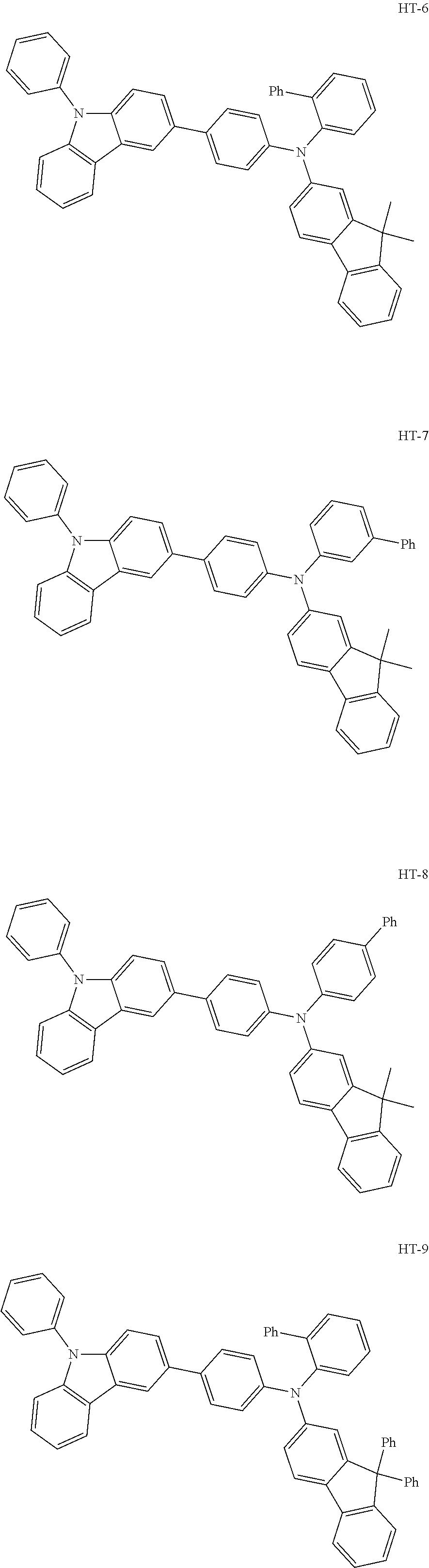 [SMILES: CC1(C)c2ccccc2-c2ccc(N(c3ccc(-c4ccc5c(c4)c4ccccc4n5-c4ccccc4)cc3)c3ccccc3-c3ccccc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccccc2N(c2ccc(-c3ccc4c(c3)c3ccccc3n4-c3ccccc3)cc2)c2ccc3c(c2)C(c2ccccc2)(c2ccccc2)c2ccccc2-3)cc1]

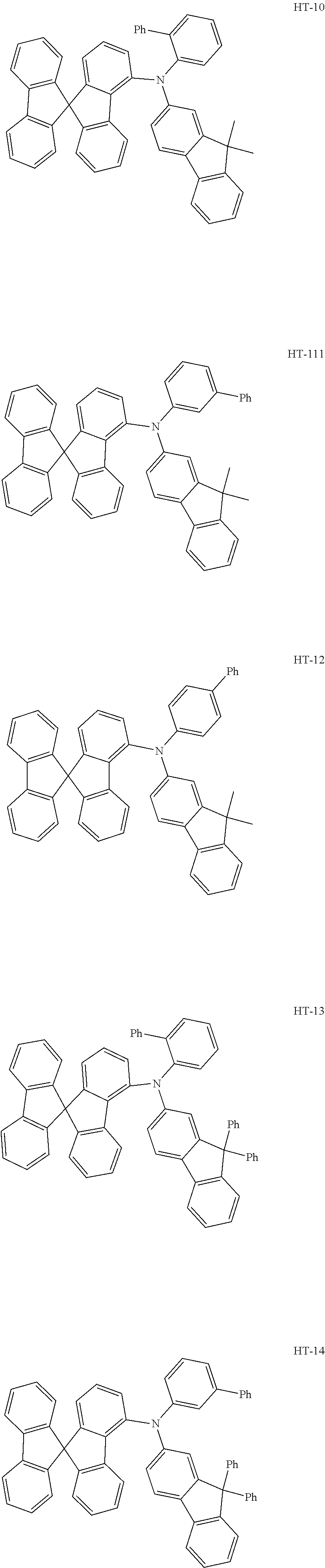 [SMILES: CC1(C)c2ccccc2-c2ccc(N(c3ccccc3-c3ccccc3)c3cccc4c3-c3ccccc3C43c4ccccc4-c4ccccc43)cc21 ; CC1(C)c2ccccc2-c2ccc(N(c3cccc(-c4ccccc4)c3)c3cccc4c3-c3ccccc3C43c4ccccc4-c4ccccc43)cc21 ; CC1(C)c2ccccc2-c2ccc(N(c3ccc(-c4ccccc4)cc3)c3cccc4c3-c3ccccc3C43c4ccccc4-c4ccccc43)cc21 ; c1ccc(-c2ccccc2N(c2ccc3c(c2)C(c2ccccc2)(c2ccccc2)c2ccccc2-3)c2cccc3c2-c2ccccc2C32c3ccccc3-c3ccccc32)cc1 ; c1ccc(-c2cccc(N(c3ccc4c(c3)C(c3ccccc3)(c3ccccc3)c3ccccc3-4)c3cccc4c3-c3ccccc3C43c4ccccc4-c4ccccc43)c2)cc1]

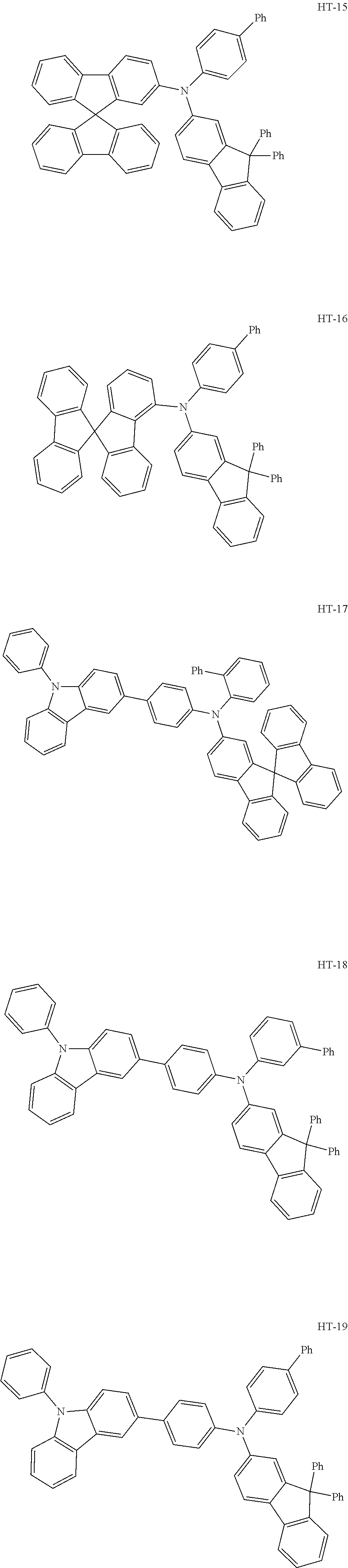

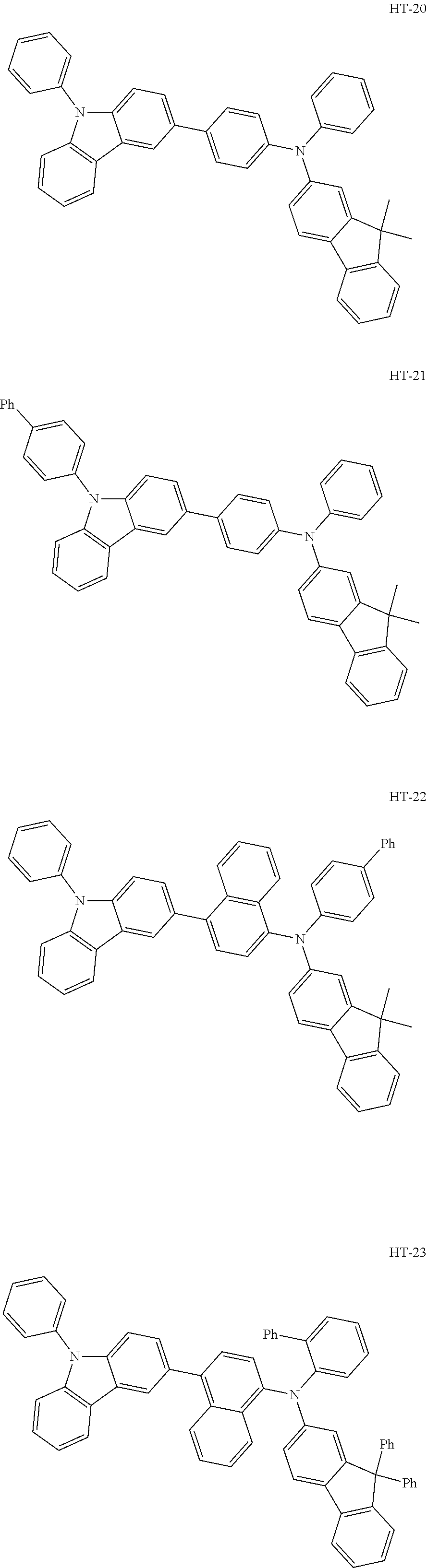 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21 ; CC1(C)c2ccccc2-c2ccc(N(c3ccc(-c4ccccc4)cc3)c3ccc(-c4ccc5c(c4)c4ccccc4n5-c4ccccc4)c4ccccc34)cc21 ; c1ccc(-c2ccccc2N(c2ccc3c(c2)C(c2ccccc2)(c2ccccc2)c2ccccc2-3)c2ccc(-c3ccc4c(c3)c3ccccc3n4-c3ccccc3)c3ccccc23)cc1]

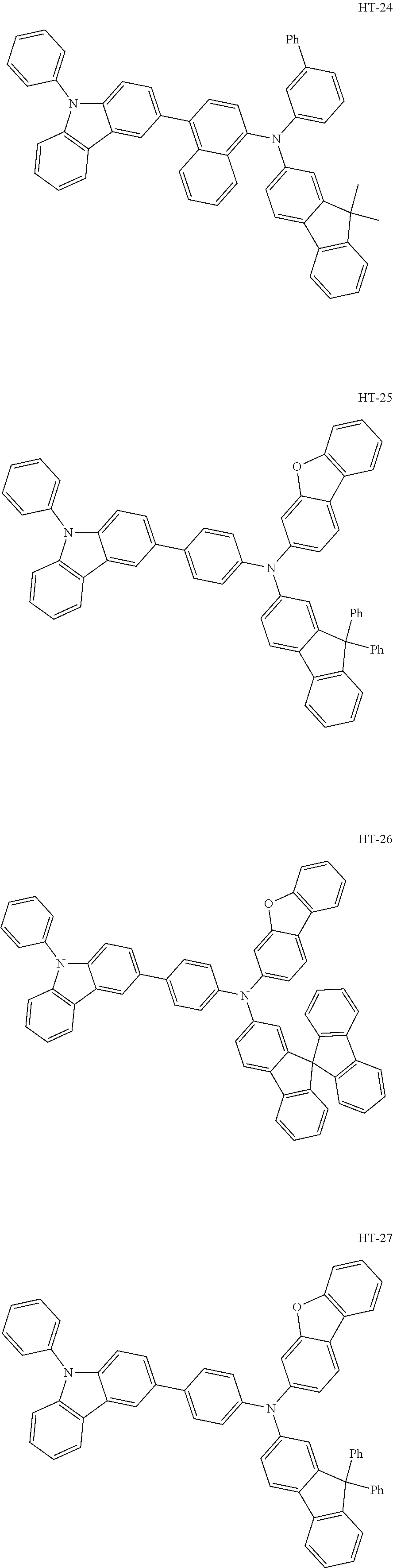 [SMILES: CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-n2c3ccccc3c3cc(-c4ccc(N(c5ccc6c(c5)C5(c7ccccc7-c7ccccc75)c5ccccc5-6)c5ccc6c(c5)oc5ccccc56)cc4)ccc32)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1]

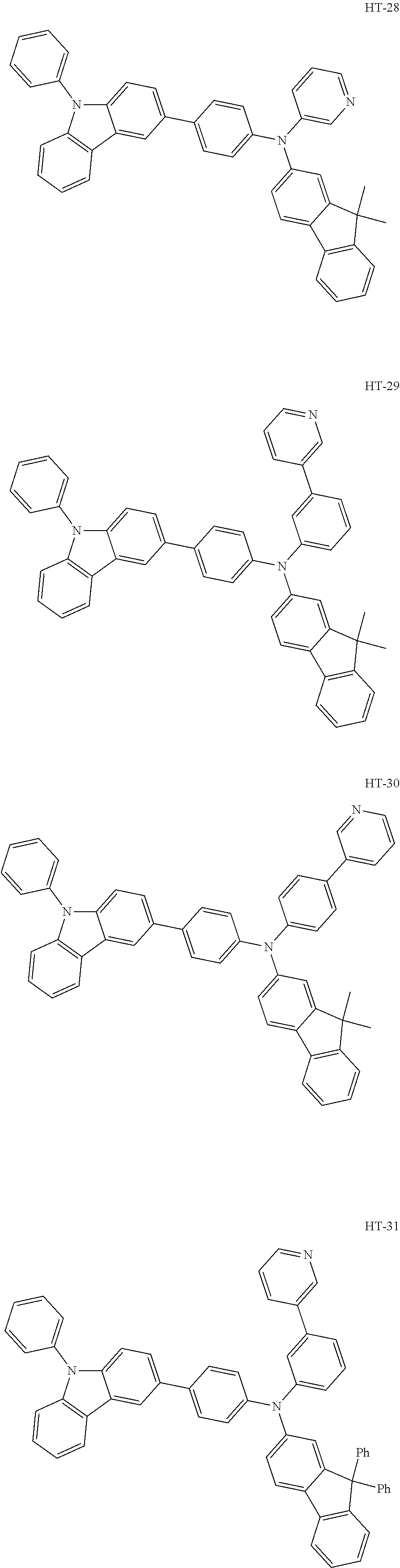 [SMILES: CC1(C)c2ccccc2-c2ccc(N(c3ccc(-c4ccc5c(c4)c4ccccc4n5-c4ccccc4)cc3)c3cccnc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; c1ccc(-n2c3ccccc3c3cc(-c4ccc(N(c5cccc(-c6cccnc6)c5)c5ccc6c(c5)C(c5ccccc5)(c5ccccc5)c5ccccc5-6)cc4)ccc32)cc1]

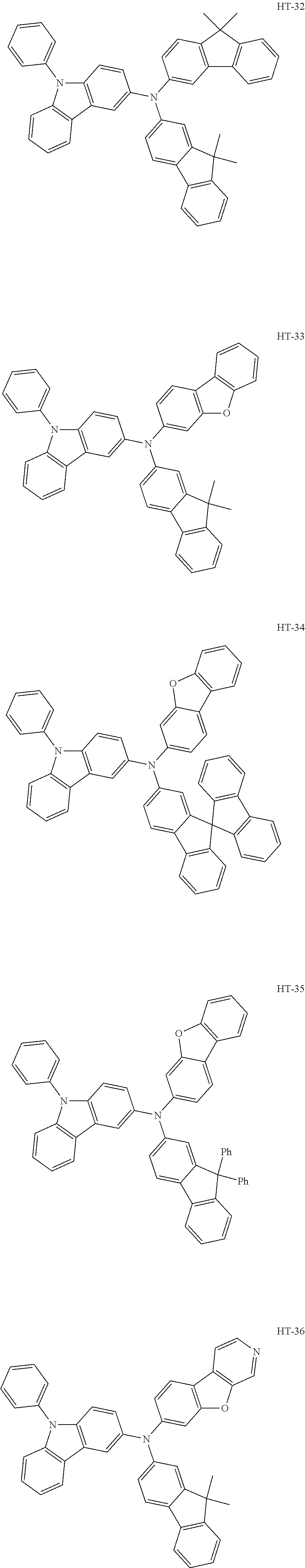 [SMILES: CC1(C)c2ccccc2-c2cc(N(c3ccc4c(c3)C(C)(C)c3ccccc3-4)c3ccc4c(c3)c3ccccc3n4-c3ccccc3)ccc21 ; CC1(C)c2ccccc2-c2ccc(N(c3ccc4c(c3)oc3ccccc34)c3ccc4c(c3)c3ccccc3n4-c3ccccc3)cc21 ; c1ccc(-n2c3ccccc3c3cc(N(c4ccc5c(c4)C4(c6ccccc6-c6ccccc64)c4ccccc4-5)c4ccc5c(c4)oc4ccccc45)ccc32)cc1 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1 ; CC1(C)c2ccccc2-c2ccc(N(c3ccc4c(c3)oc3cnccc34)c3ccc4c(c3)c3ccccc3n4-c3ccccc3)cc21]

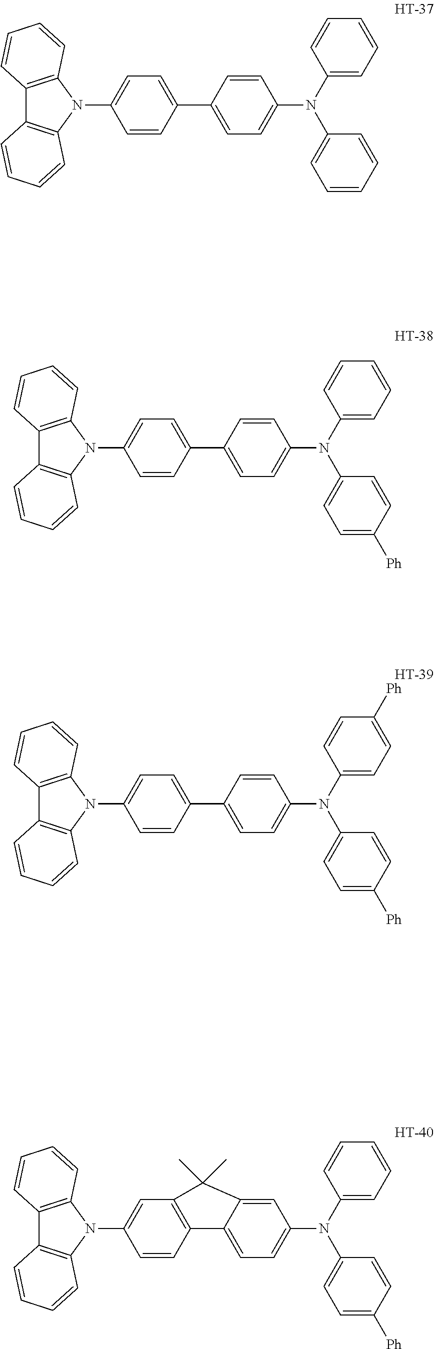 [SMILES: c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21]

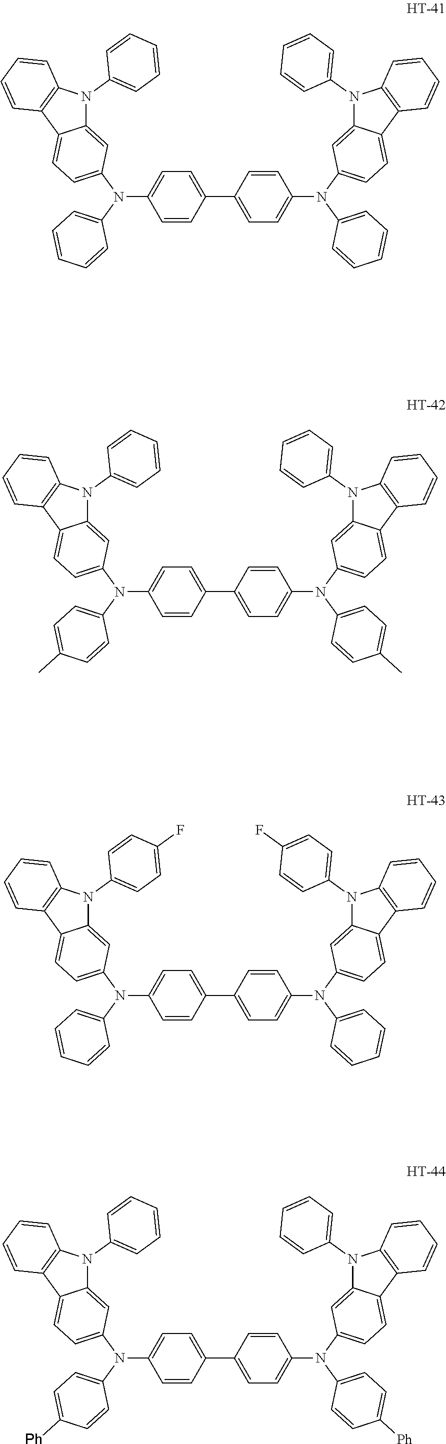 [SMILES: c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1 ; Cc1ccc(N(c2ccc(-c3ccc(N(c4ccc(C)cc4)c4ccc5c6ccccc6n(-c6ccccc6)c5c4)cc3)cc2)c2ccc3c4ccccc4n(-c4ccccc4)c3c2)cc1 ; Fc1ccc(-n2c3ccccc3c3ccc(N(c4ccccc4)c4ccc(-c5ccc(N(c6ccccc6)c6ccc7c8ccccc8n(-c8ccc(F)cc8)c7c6)cc5)cc4)cc32)cc1 ; c1ccc(-c2ccc(N(c3ccc(-c4ccc(N(c5ccc(-c6ccccc6)cc5)c5ccc6c7ccccc7n(-c7ccccc7)c6c5)cc4)cc3)c3ccc4c5ccccc5n(-c5ccccc5)c4c3)cc2)cc1]

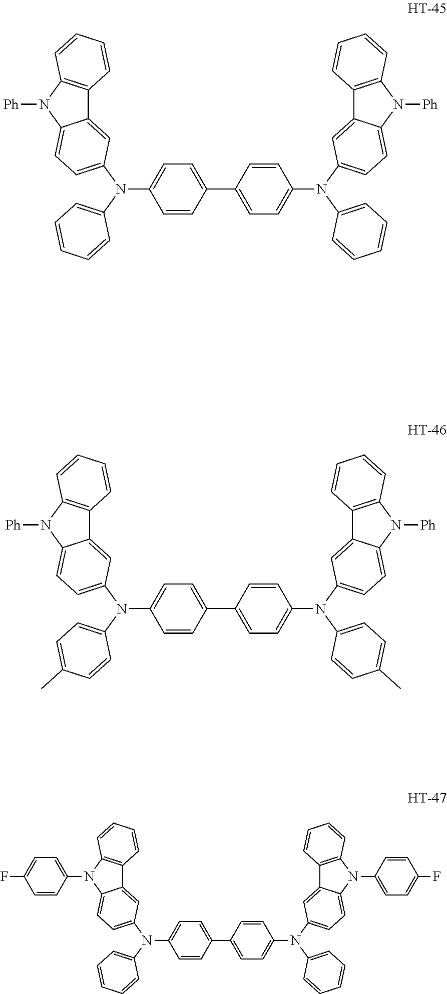 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

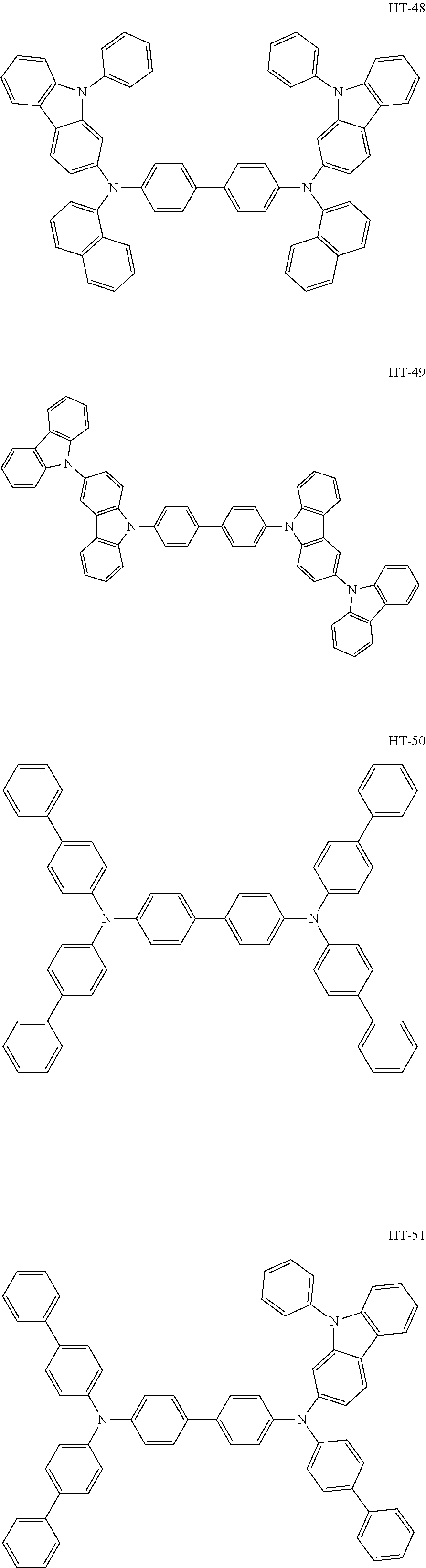 [SMILES: c1ccc(-n2c3ccccc3c3ccc(N(c4ccc(-c5ccc(N(c6ccc7c8ccccc8n(-c8ccccc8)c7c6)c6cccc7ccccc67)cc5)cc4)c4cccc5ccccc45)cc32)cc1 ; c1ccc2c(c1)c1ccccc1n2-c1ccc2c(c1)c1ccccc1n2-c1ccc(-c2ccc(-n3c4ccccc4c4cc(-n5c6ccccc6c6ccccc65)ccc43)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1]

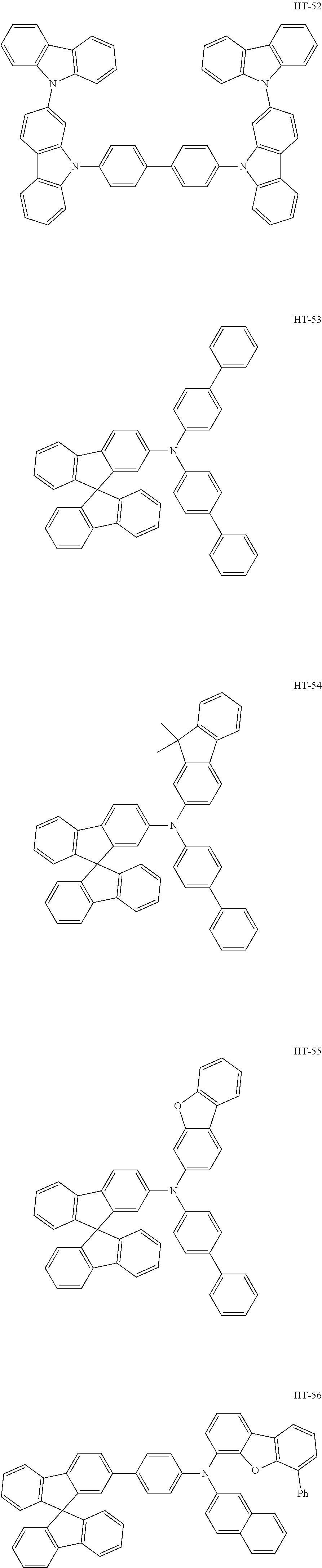 [SMILES: c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1 ; c1ccc(-c2ccc(N(c3ccc(-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccc(N(c3ccc4c(c3)C3(c5ccccc5-c5ccccc53)c3ccccc3-4)c3ccc4c(c3)oc3ccccc34)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

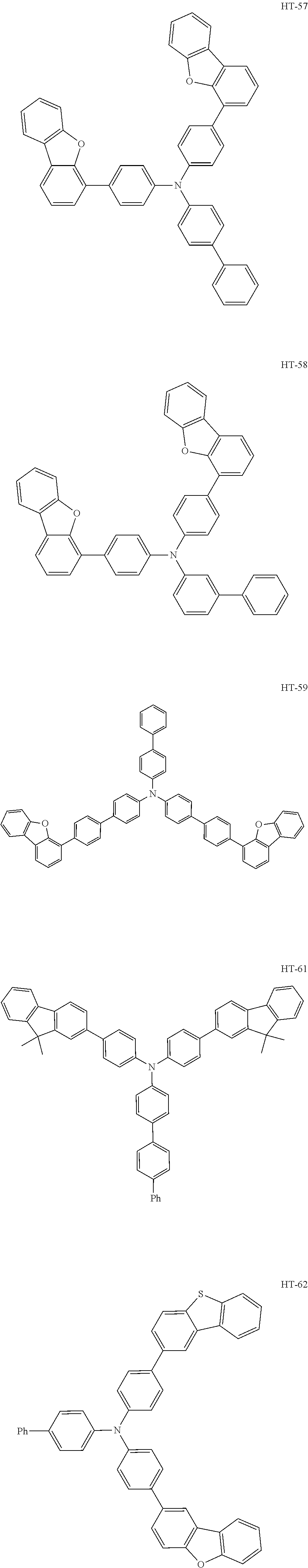 [SMILES: c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1]

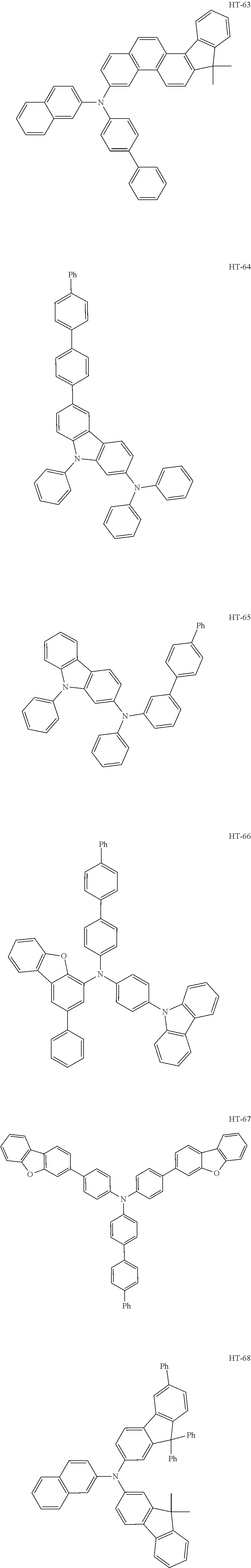

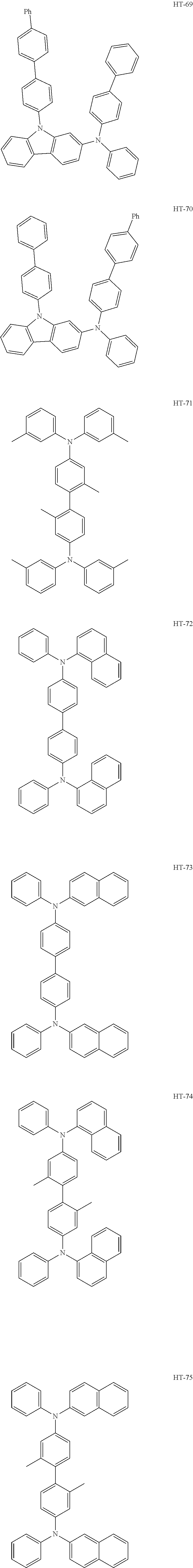

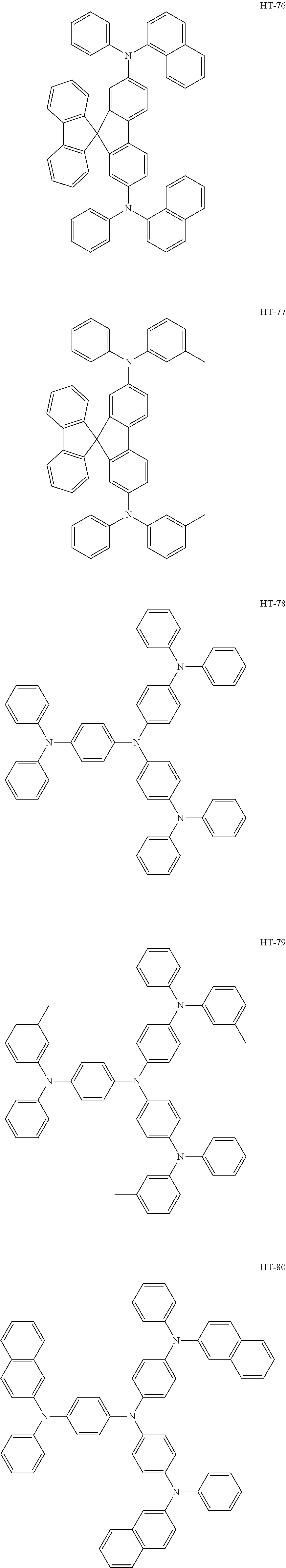 [SMILES: c1ccc(N(c2ccc3c(c2)C2(c4ccccc4-c4ccccc42)c2cc(N(c4ccccc4)c4cccc5ccccc45)ccc2-3)c2cccc3ccccc23)cc1 ; Cc1cccc(N(c2ccccc2)c2ccc3c(c2)C2(c4ccccc4-c4ccccc42)c2cc(N(c4ccccc4)c4cccc(C)c4)ccc2-3)c1 ; c1ccc(N(c2ccccc2)c2ccc(N(c3ccc(N(c4ccccc4)c4ccccc4)cc3)c3ccc(N(c4ccccc4)c4ccccc4)cc3)cc2)cc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

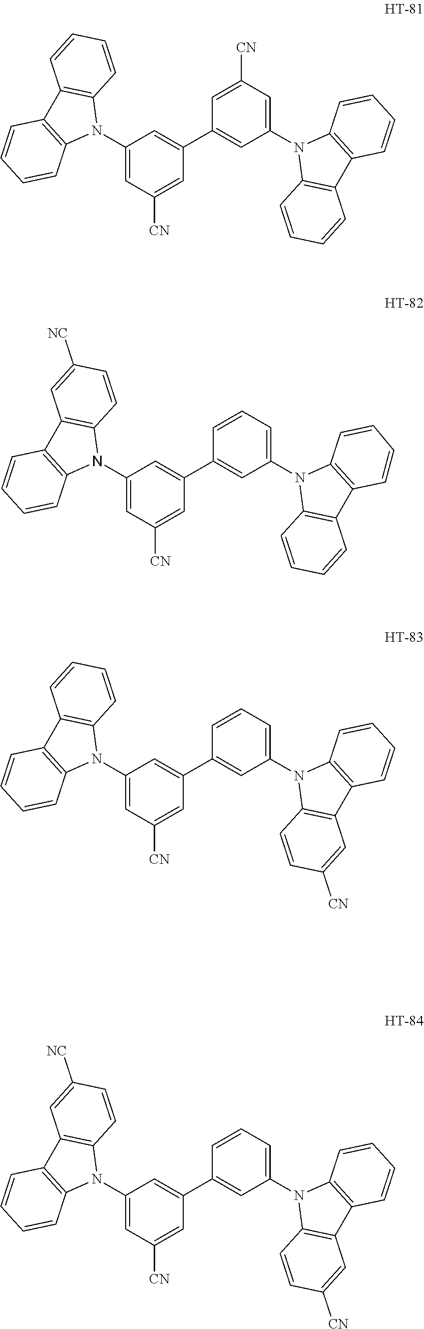 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

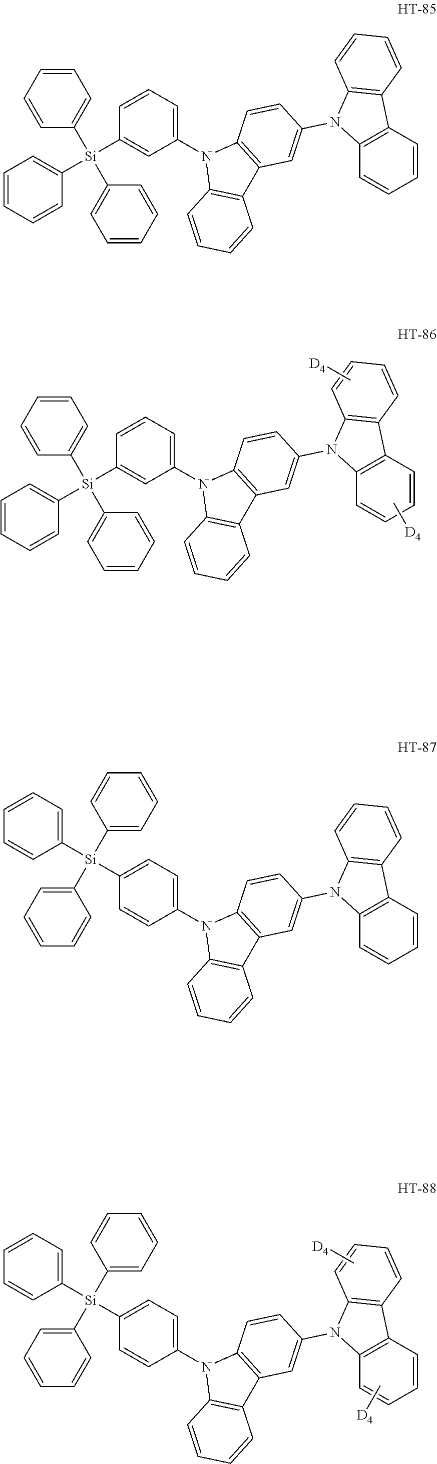

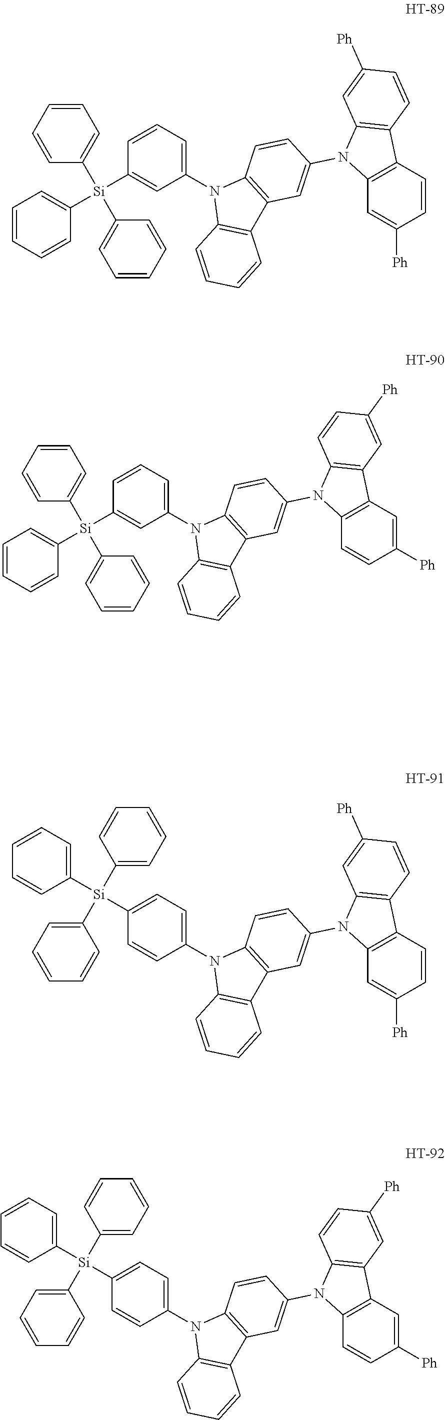 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

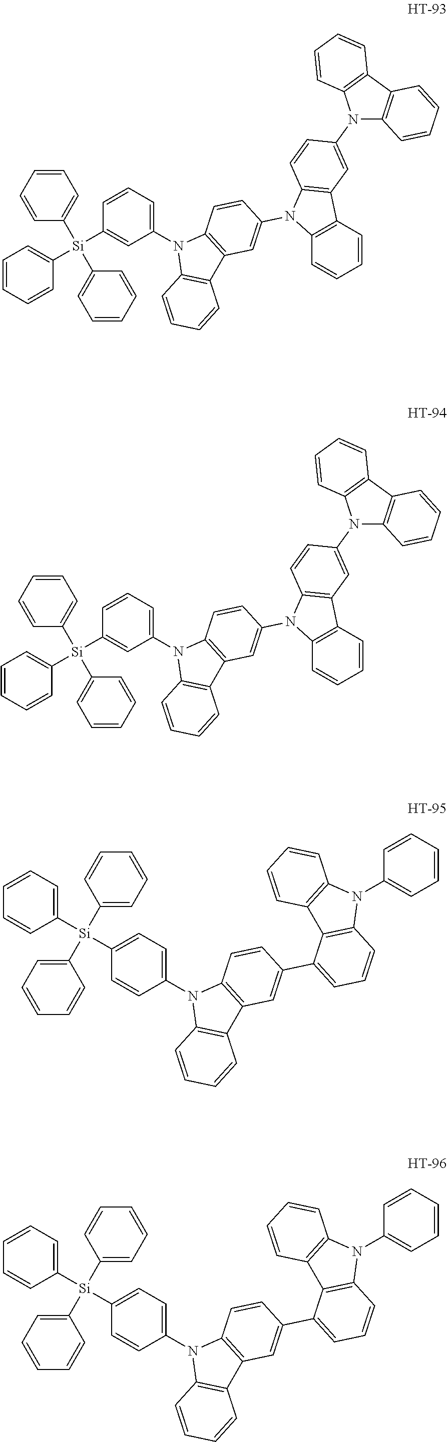 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

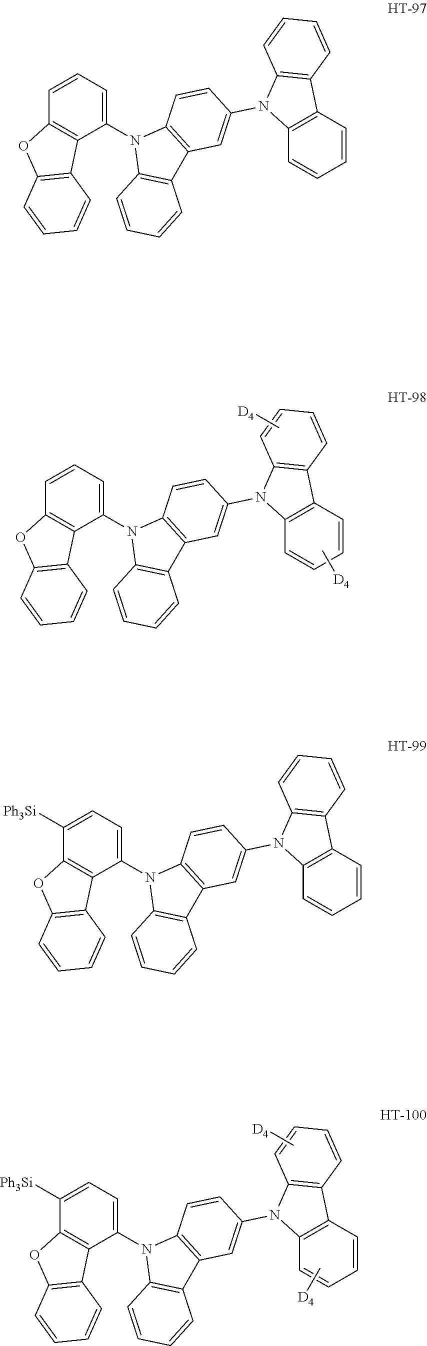

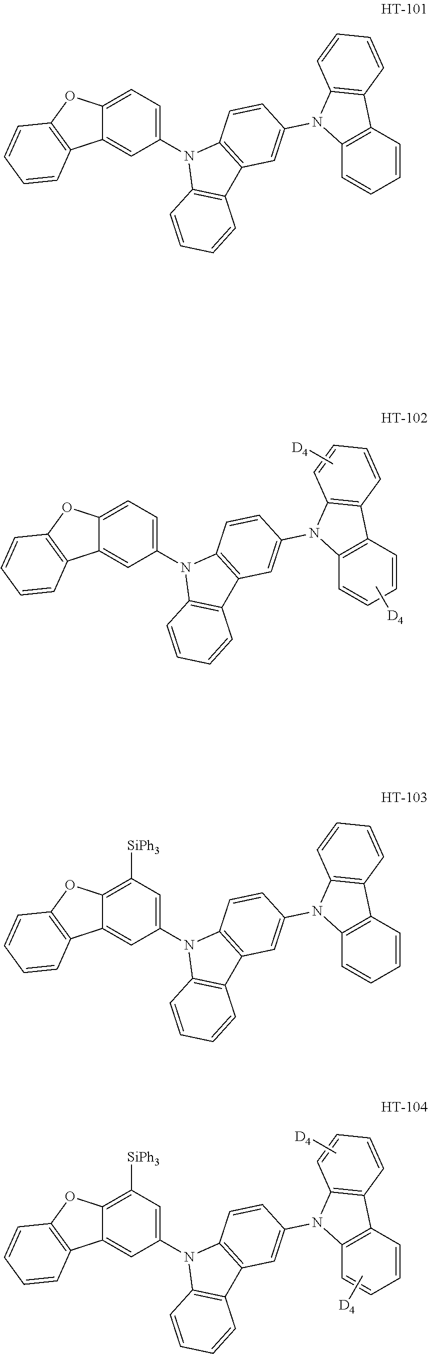

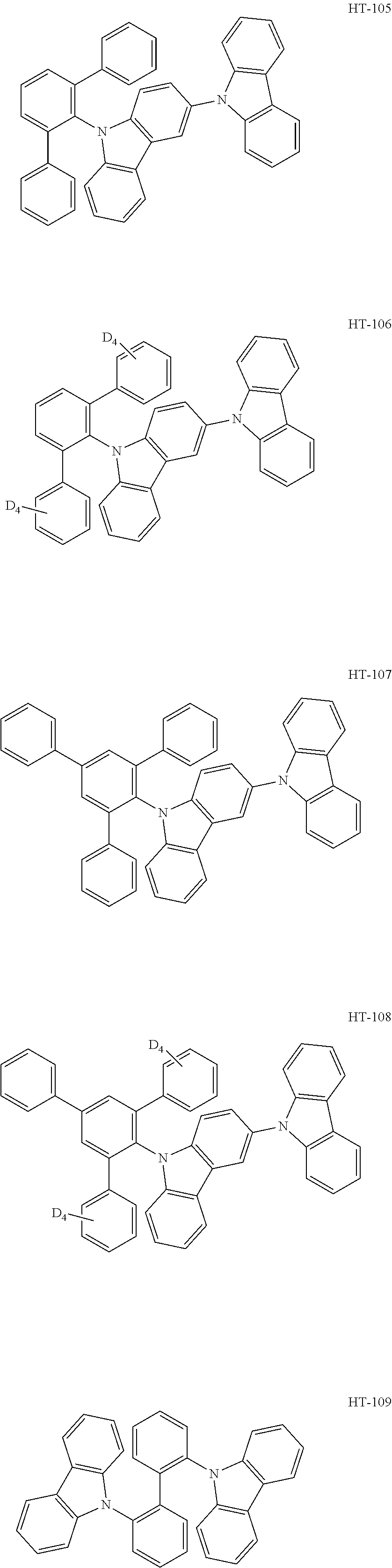

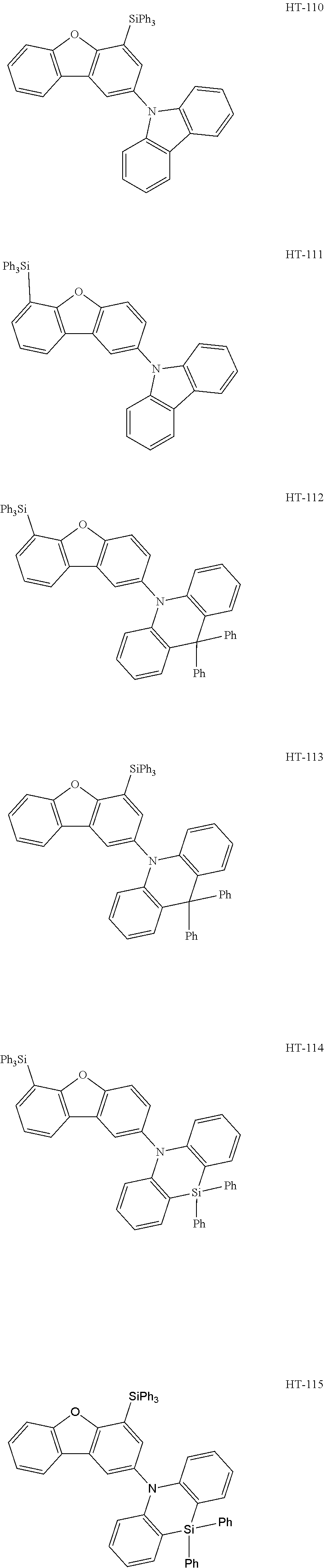

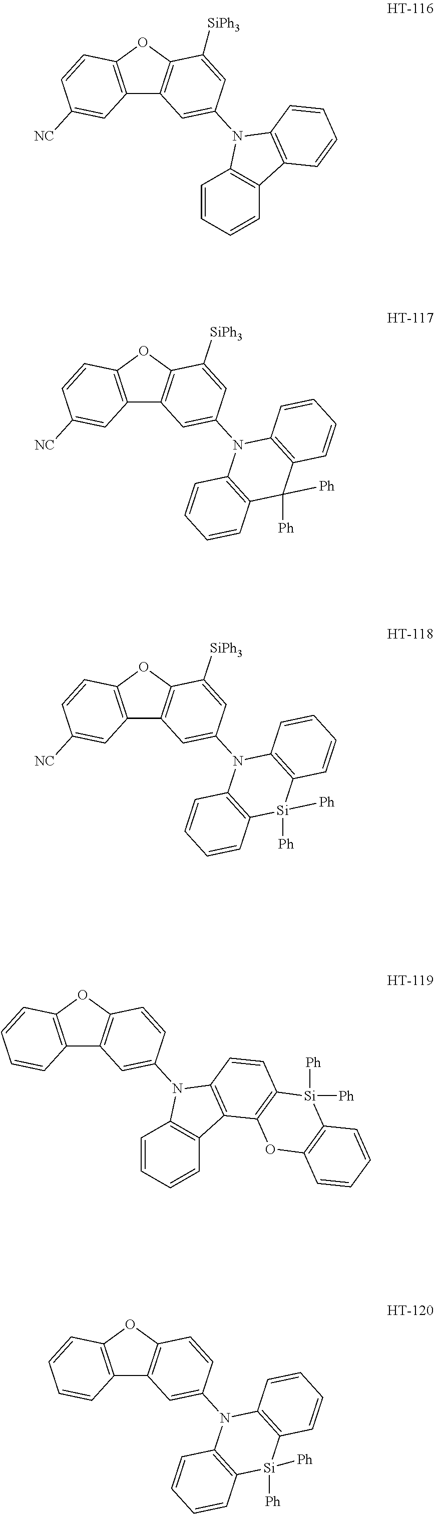

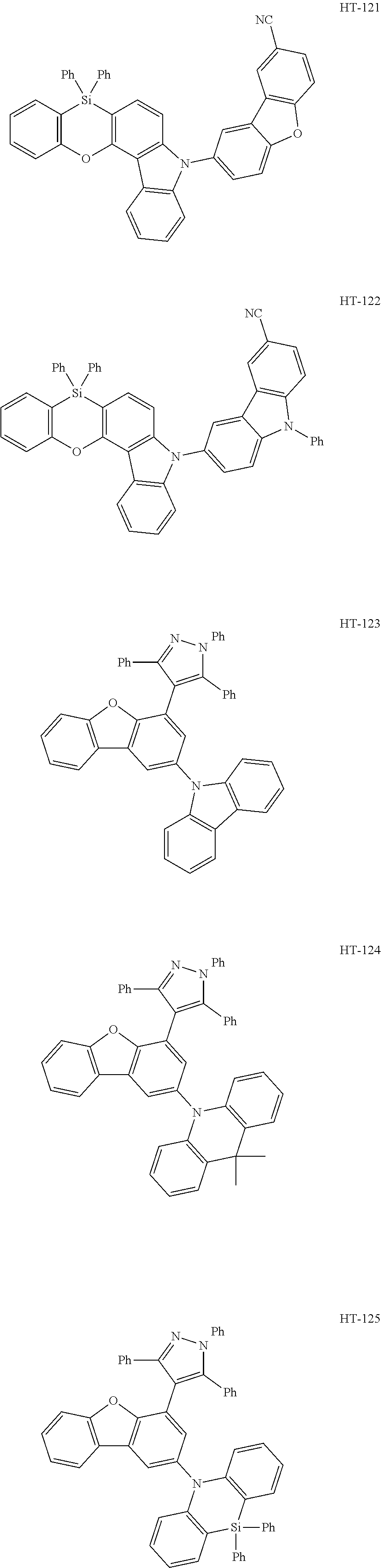

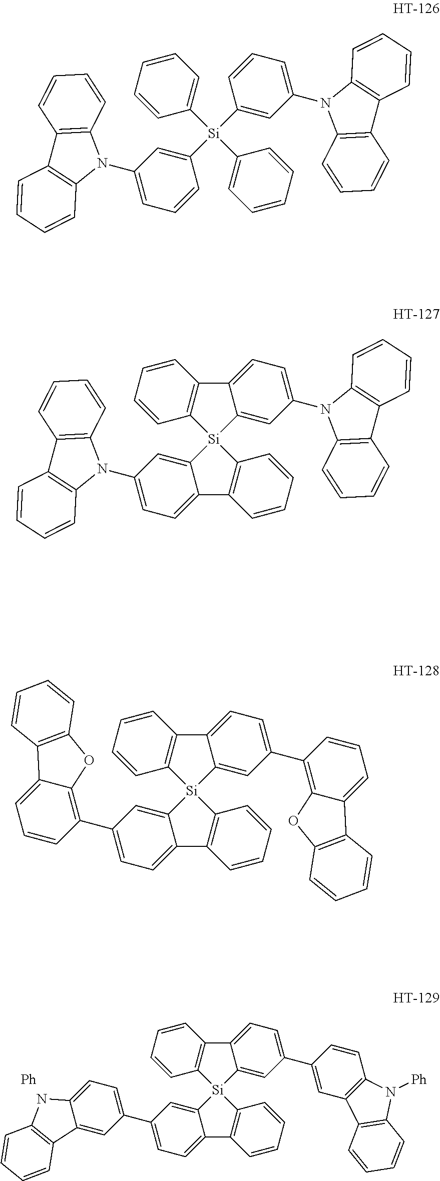 [SMILES: c1ccc([Si](c2ccccc2)(c2cccc(-n3c4ccccc4c4ccccc43)c2)c2cccc(-n3c4ccccc4c4ccccc43)c2)cc1 ; c1ccc2c(c1)-c1ccc(-n3c4ccccc4c4ccccc43)cc1[Si]21c2ccccc2-c2ccc(-n3c4ccccc4c4ccccc43)cc21 ; c1ccc2c(c1)-c1ccc(-c3cccc4c3oc3ccccc34)cc1[Si]21c2ccccc2-c2ccc(-c3cccc4c3oc3ccccc34)cc21 ; "Ph" ; c1ccc(-n2c3ccccc3c3cc(-c4ccc5c(c4)[Si]4(c6ccccc6-c6ccc(-c7ccc8[nH]c9ccccc9c8c7)cc64)c4ccccc4-5)ccc32)cc1]

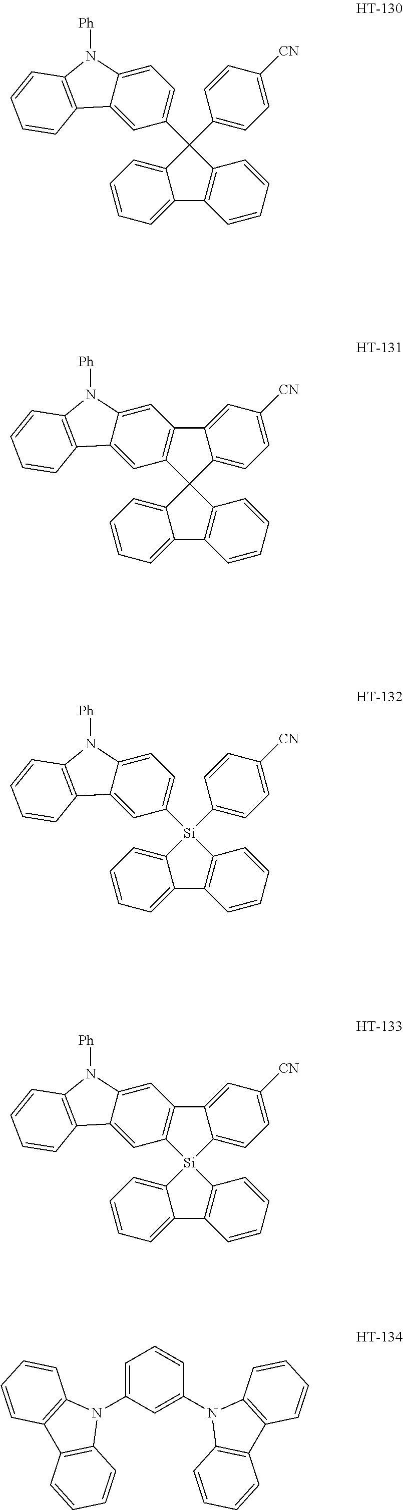 [SMILES: N#Cc1ccc(C2(c3ccc4c(c3)c3ccccc3n4-c3ccccc3)c3ccccc3-c3ccccc32)cc1 ; N#Cc1ccc2c(c1)-c1cc3c(cc1C21c2ccccc2-c2ccccc21)c1ccccc1n3-c1ccccc1 ; N#Cc1ccc([Si]2(c3ccc4c(c3)c3ccccc3n4-c3ccccc3)c3ccccc3-c3ccccc32)cc1 ; N#Cc1ccc2c(c1)-c1cc3c(cc1[Si]21c2ccccc2-c2ccccc21)c1ccccc1n3-c1ccccc1 ; c1cc(-n2c3ccccc3c3ccccc32)cc(-n2c3ccccc3c3ccccc32)c1]

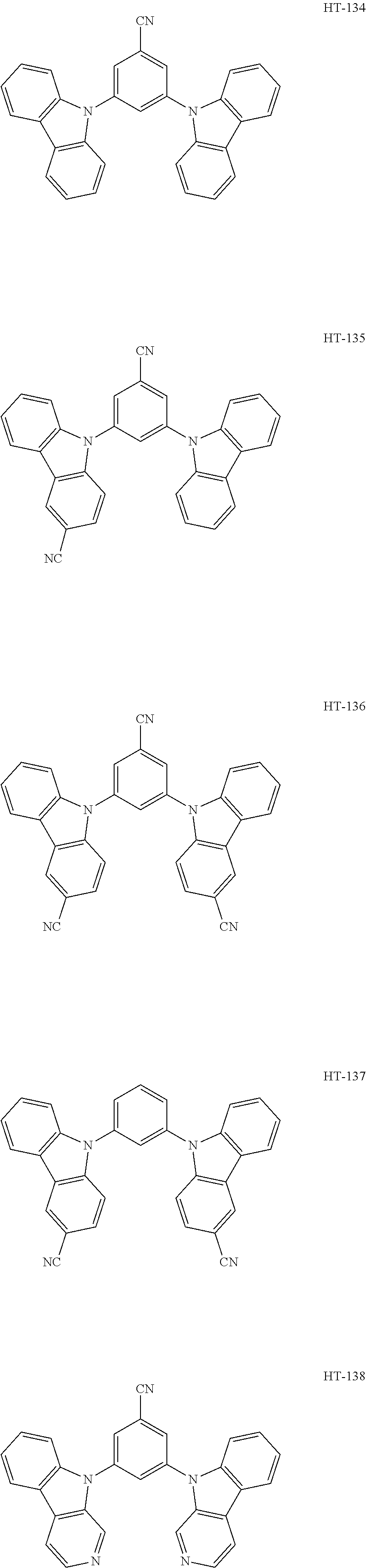 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)c1 ; N#Cc1cc(-n2c3ccccc3c3ccncc32)cc(-n2c3ccccc3c3ccncc32)c1]

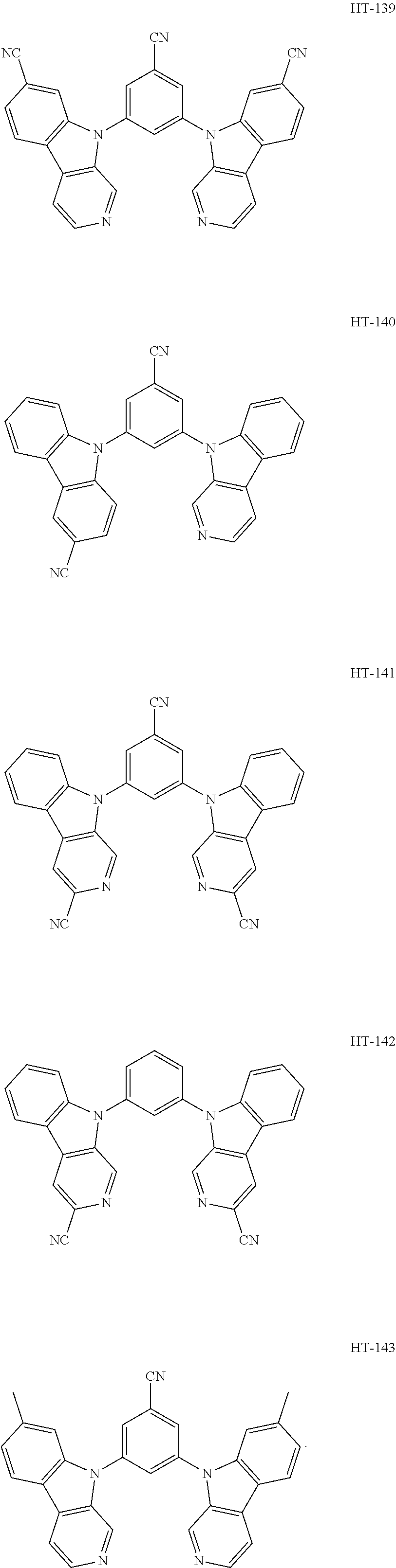 [SMILES: N#Cc1cc(-n2c3cnccc3c3ccc(C#N)cc32)cc(-n2c3cnccc3c3ccc(C#N)cc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)c3)c2cn1 ; Cc1ccc2c3ccncc3n(-c3cc(C#N)cc(-n4c5cnccc5c5ccc(C)cc54)c3)c2c1]

In a preferred embodiment of the invention, the hole transport layer contained in the OLED device of the invention includes one or more p-type dopants. Preferred p-type dopants of the present invention may be selected from the following structures, but this does not mean that the present invention is limited to the following structures:

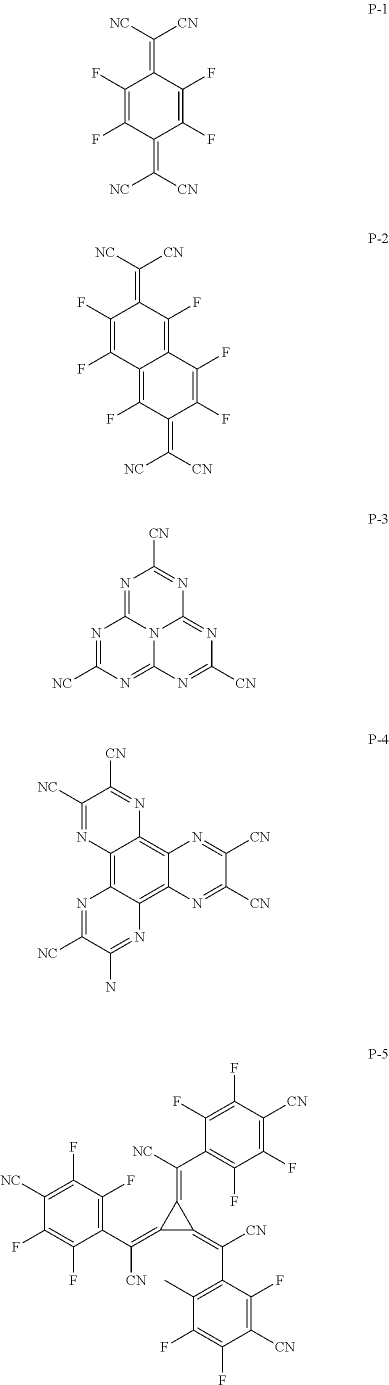 [SMILES: N#CC(C#N)=c1c(F)c(F)c(=C(C#N)C#N)c(F)c1F ; N#CC(C#N)=c1c(F)c(F)c2c(F)c(=C(C#N)C#N)c(F)c(F)c2c1F ; N#CC1=NC2=NC(C#N)=NC3=NC(C#N)=NC(=N1)N23 ; N#Cc1nc2c(nc1N)c1nc(C#N)c(C#N)nc1c1nc(C#N)c(C#N)nc21 ; Cc1c(F)c(F)c(C#N)c(F)c1/C(C#N)=C1/C(=C(/C#N)c2c(F)c(F)c(C#N)c(F)c2F)/C1=C(/C#N)c1c(F)c(F)c(C#N)c(F)c1F]

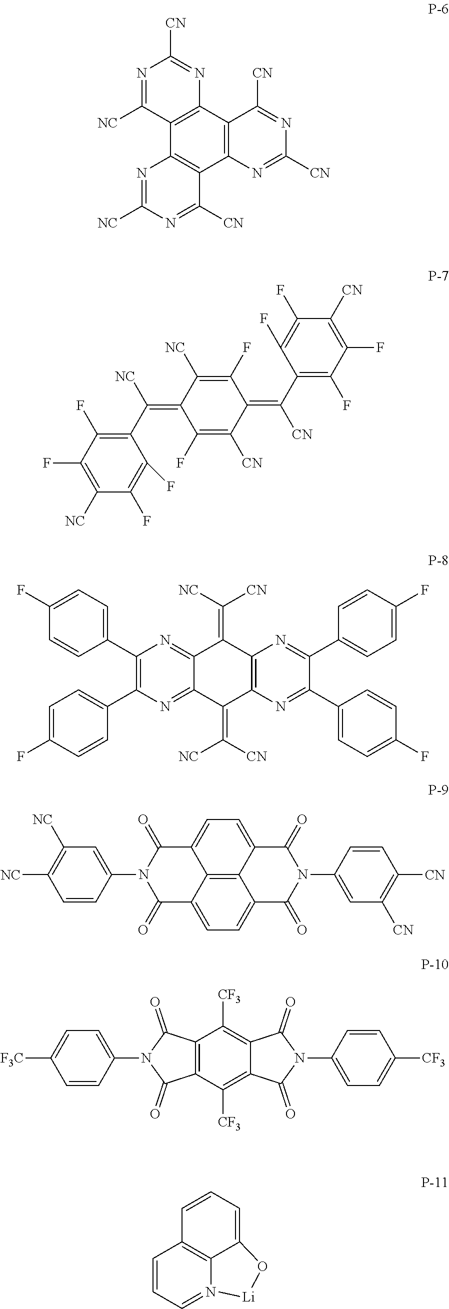

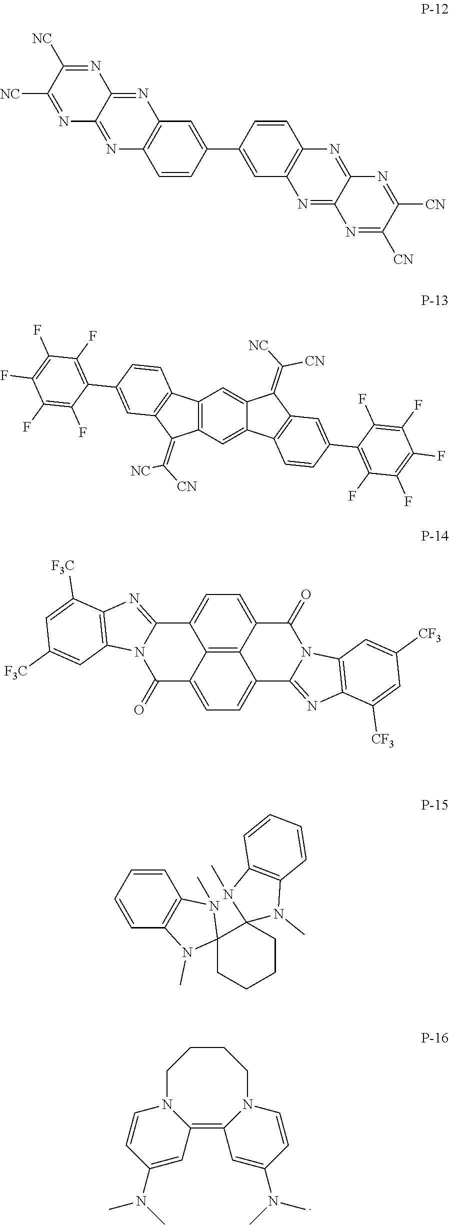

In a preferred embodiment of the invention, the electron transport layer may be selected from at least one of the compounds ET-1 to ET-77, but this does not mean that the present invention is limited to the following structures:

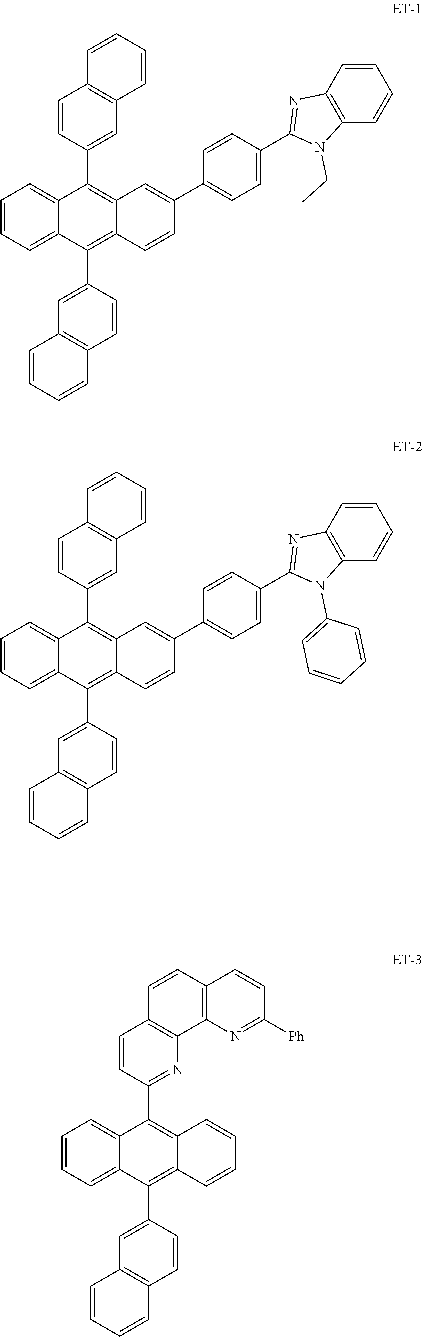 [SMILES: CCn1c(-c2ccc(-c3ccc4c(-c5ccc6ccccc6c5)c5ccccc5c(-c5ccc6ccccc6c5)c4c3)cc2)nc2ccccc21 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3ccc4ccc(-c5c6ccccc6c(-c6ccc7ccccc7c6)c6ccccc56)nc4c3n2)cc1]

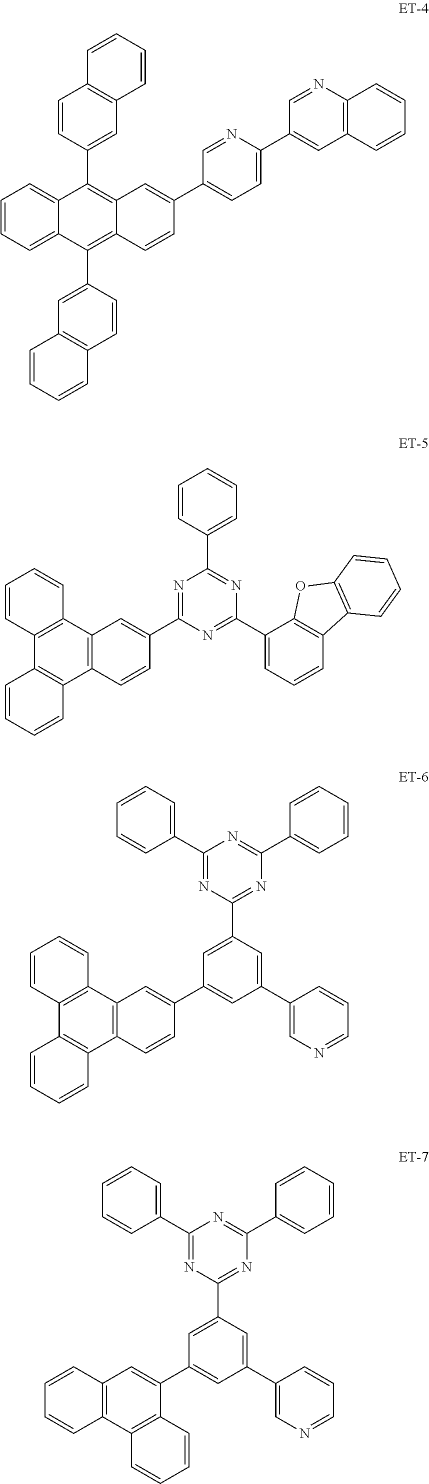 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-c2nc(-c3ccc4c5ccccc5c5ccccc5c4c3)nc(-c3cccc4c3oc3ccccc34)n2)cc1 ; c1ccc(-c2nc(-c3ccccc3)nc(-c3cc(-c4cccnc4)cc(-c4ccc5c6ccccc6c6ccccc6c5c4)c3)n2)cc1 ; c1ccc(-c2nc(-c3ccccc3)nc(-c3cc(-c4cccnc4)cc(-c4cc5ccccc5c5ccccc45)c3)n2)cc1]

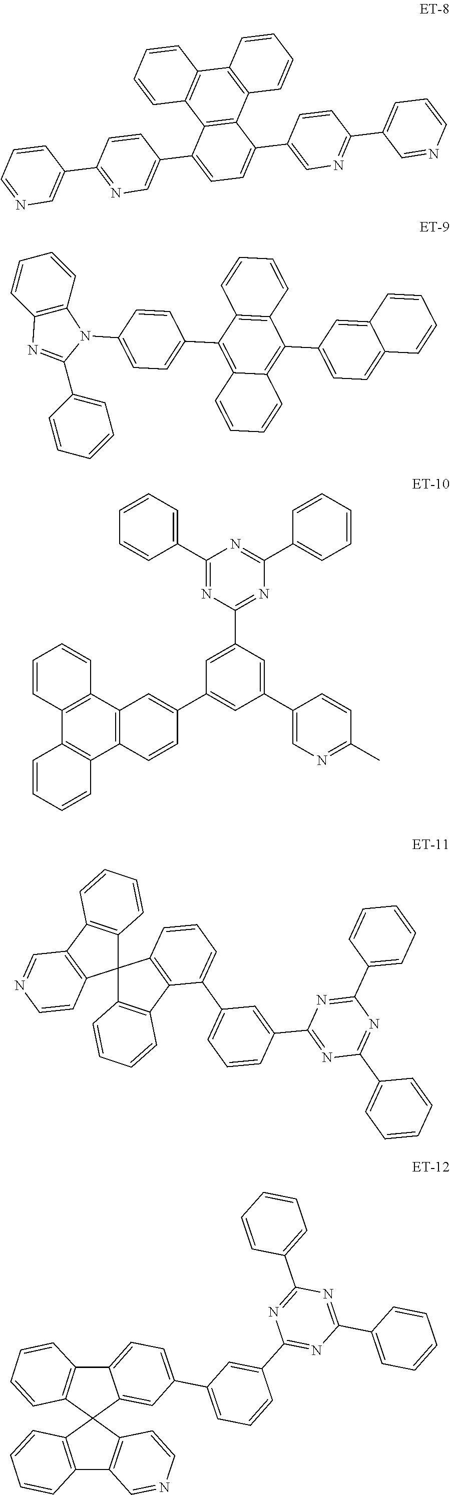 [SMILES: c1cncc(-c2ccc(-c3ccc(-c4ccc(-c5cccnc5)nc4)c4c5ccccc5c5ccccc5c34)cn2)c1 ; c1ccc(-c2nc3ccccc3n2-c2ccc(-c3c4ccccc4c(-c4ccc5ccccc5c4)c4ccccc34)cc2)cc1 ; Cc1ccc(-c2cc(-c3ccc4c5ccccc5c5ccccc5c4c3)cc(-c3nc(-c4ccccc4)nc(-c4ccccc4)n3)c2)cn1 ; c1ccc(-c2nc(-c3ccccc3)nc(-c3cccc(-c4cccc5c4-c4ccccc4C54c5ccccc5-c5cnccc54)c3)n2)cc1 ; c1ccc(-c2nc(-c3ccccc3)nc(-c3cccc(-c4ccc5c(c4)C4(c6ccccc6-c6cnccc64)c4ccccc4-5)c3)n2)cc1]

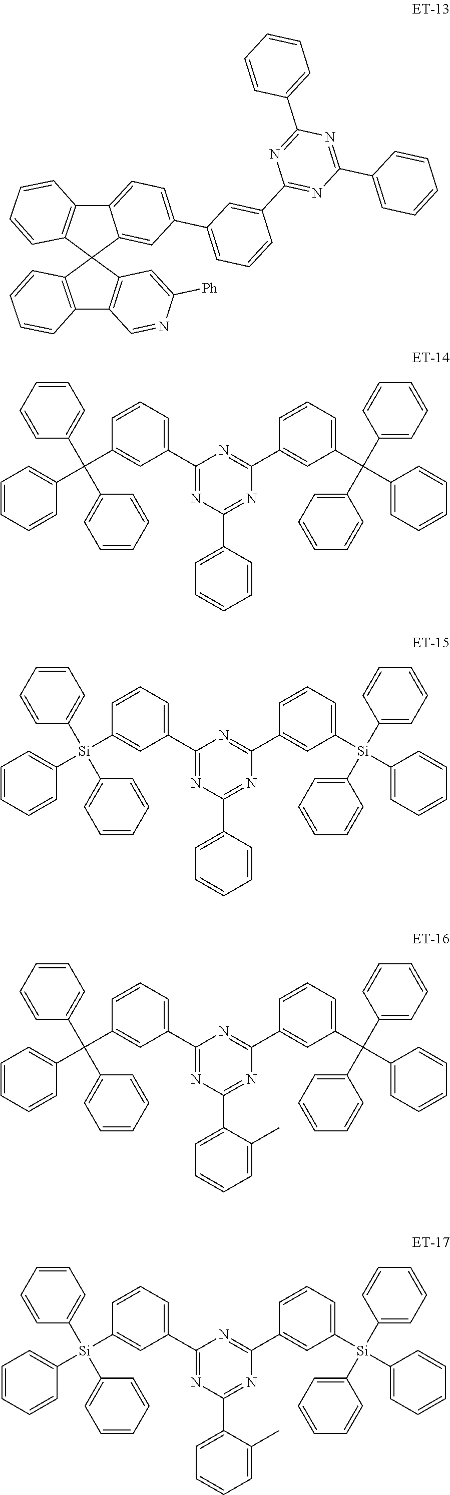

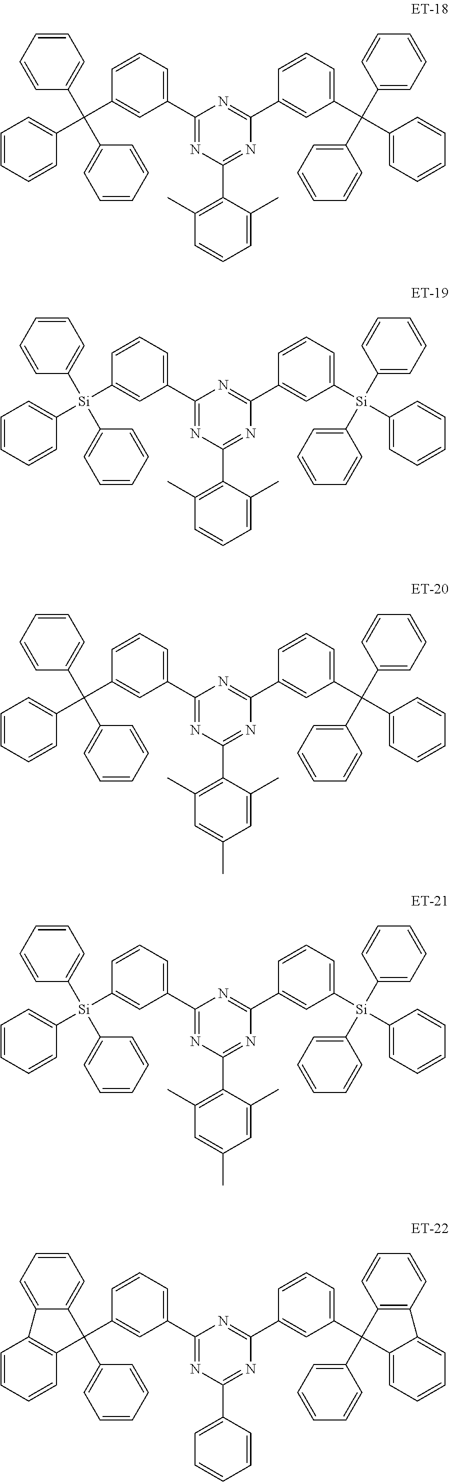

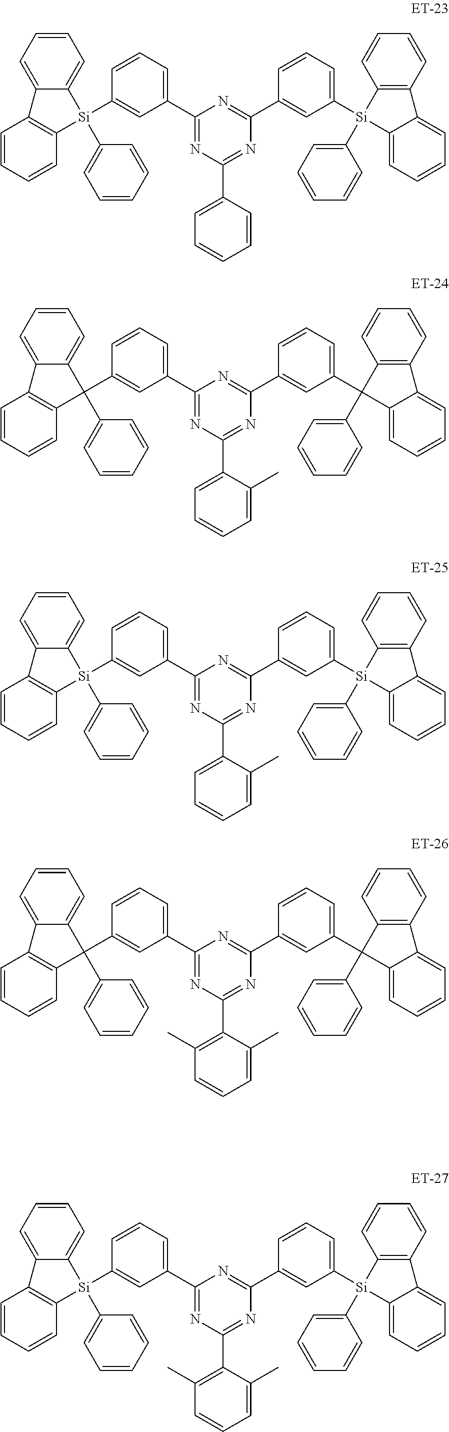

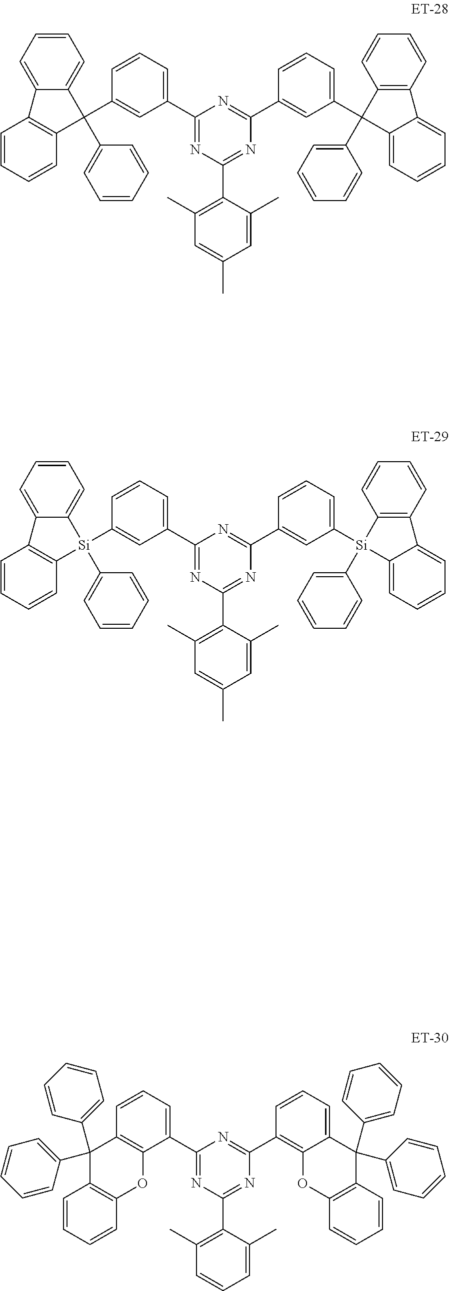 [SMILES: Cc1cc(C)c(-c2nc(-c3cccc(C4(c5ccccc5)c5ccccc5-c5ccccc54)c3)nc(-c3cccc(C4(c5ccccc5)c5ccccc5-c5ccccc54)c3)n2)c(C)c1 ; Cc1cc(C)c(-c2nc(-c3cccc([Si]4(c5ccccc5)c5ccccc5-c5ccccc54)c3)nc(-c3cccc([Si]4(c5ccccc5)c5ccccc5-c5ccccc54)c3)n2)c(C)c1 ; Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1]

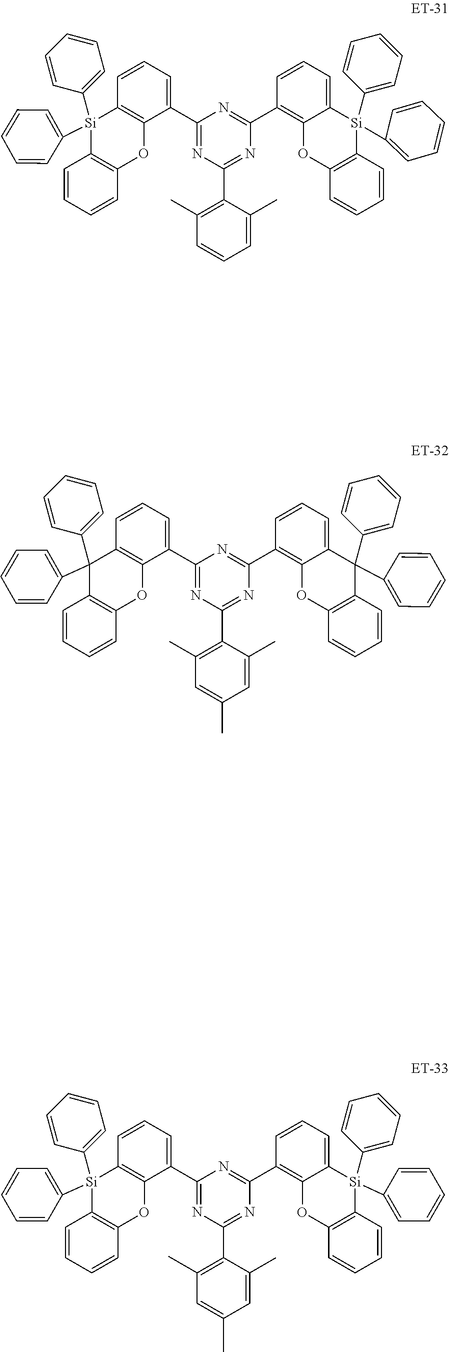 [SMILES: Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

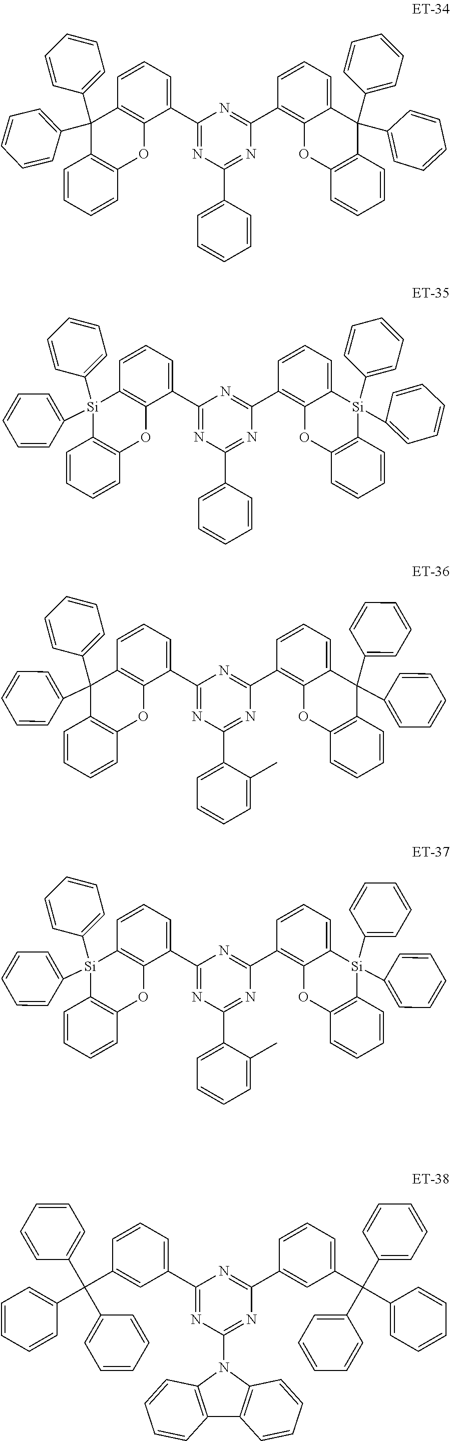

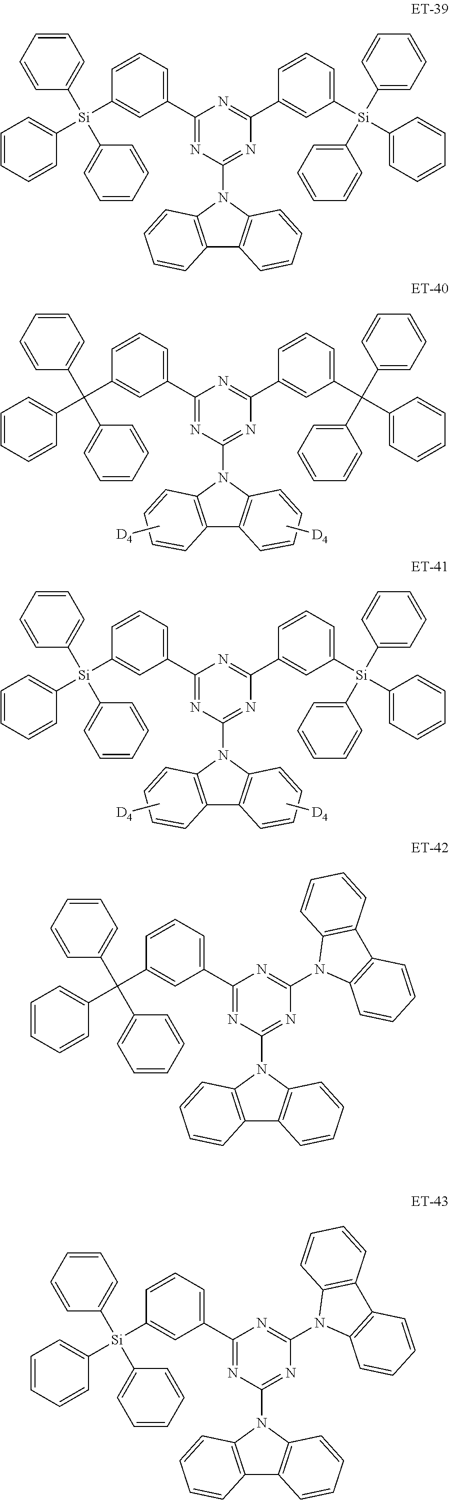

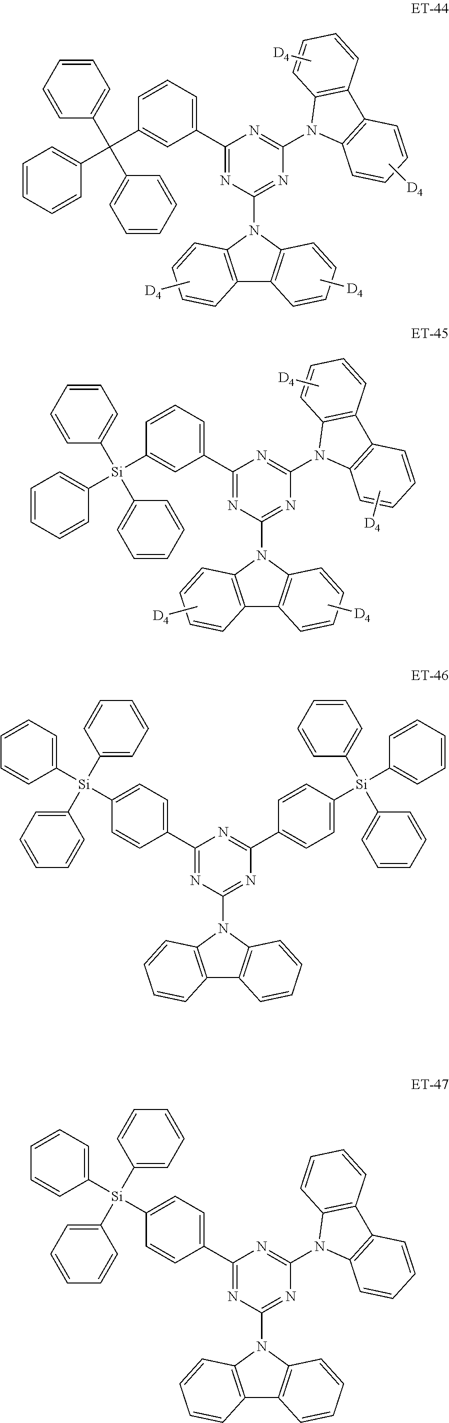

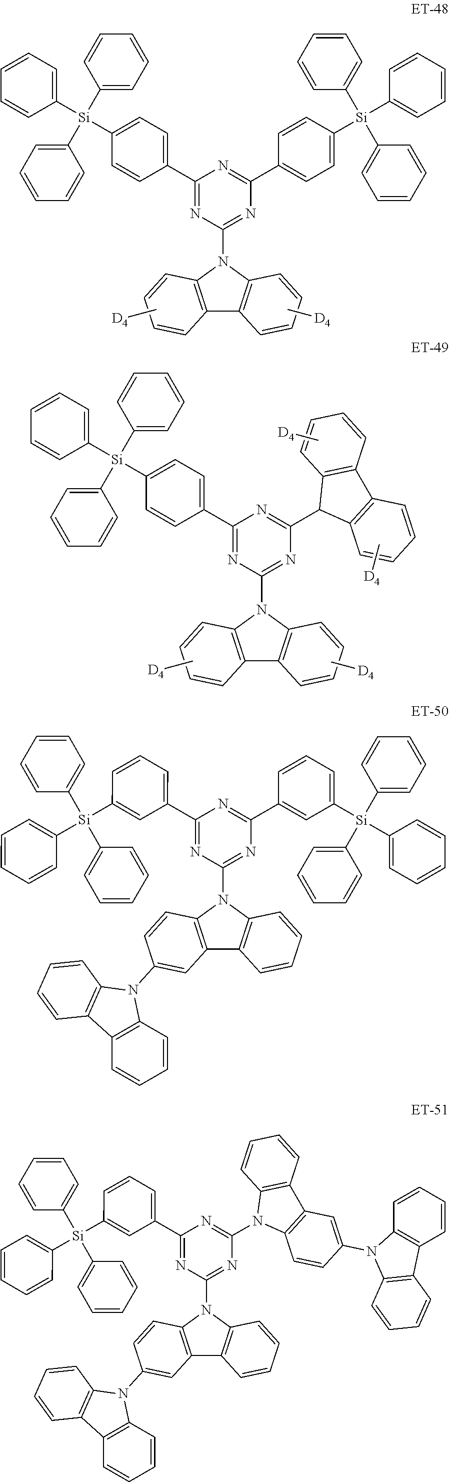

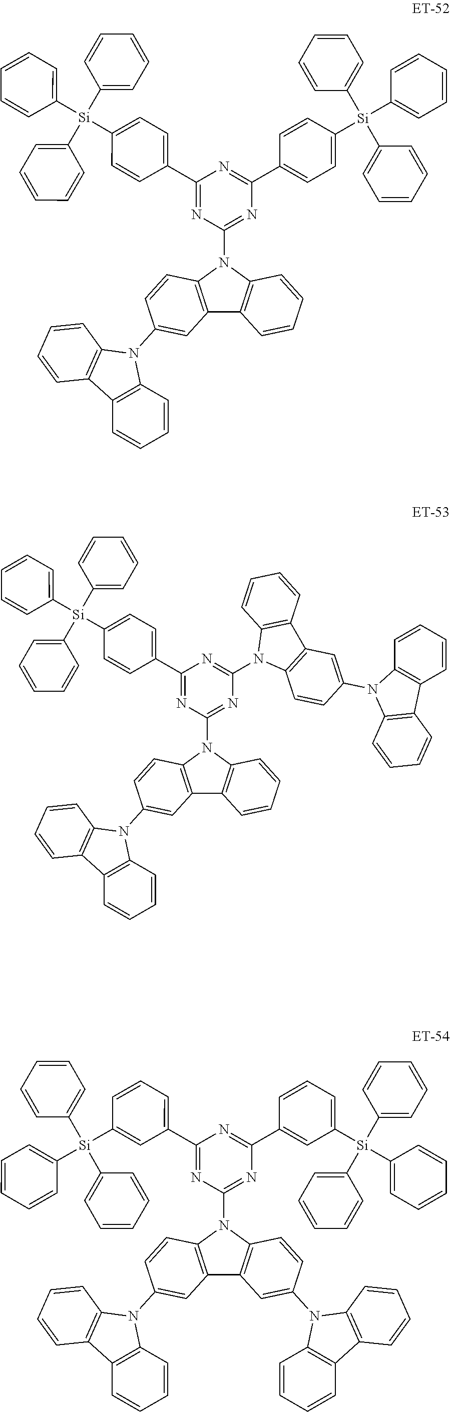 [SMILES: c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccc(-n6c7ccccc7c7ccccc76)cc5c5cc(-n6c7ccccc7c7ccccc76)ccc54)n3)c2)cc1]

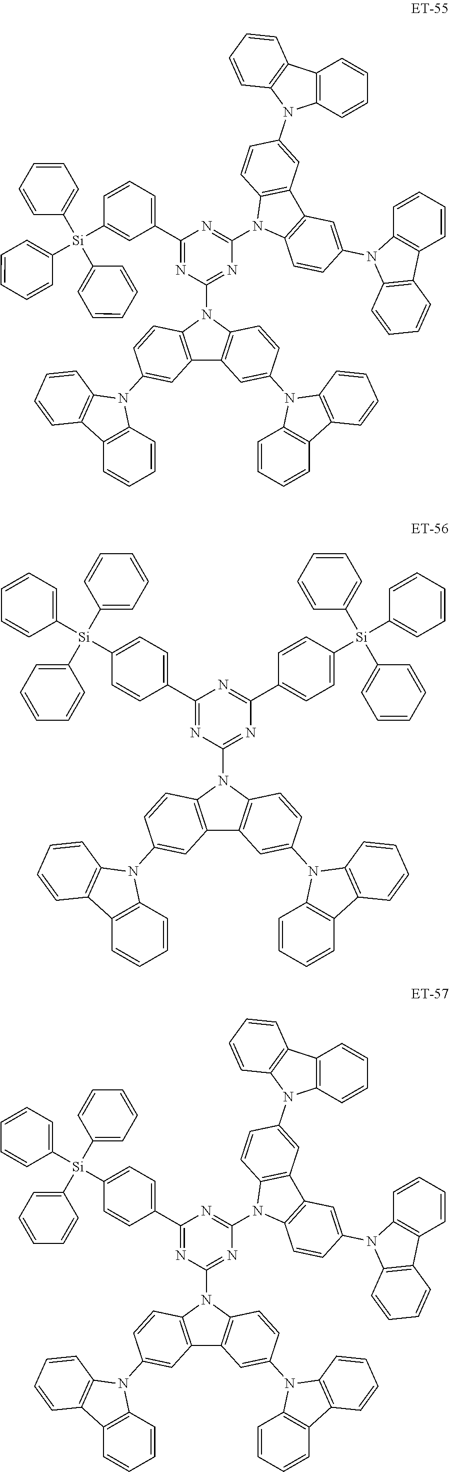

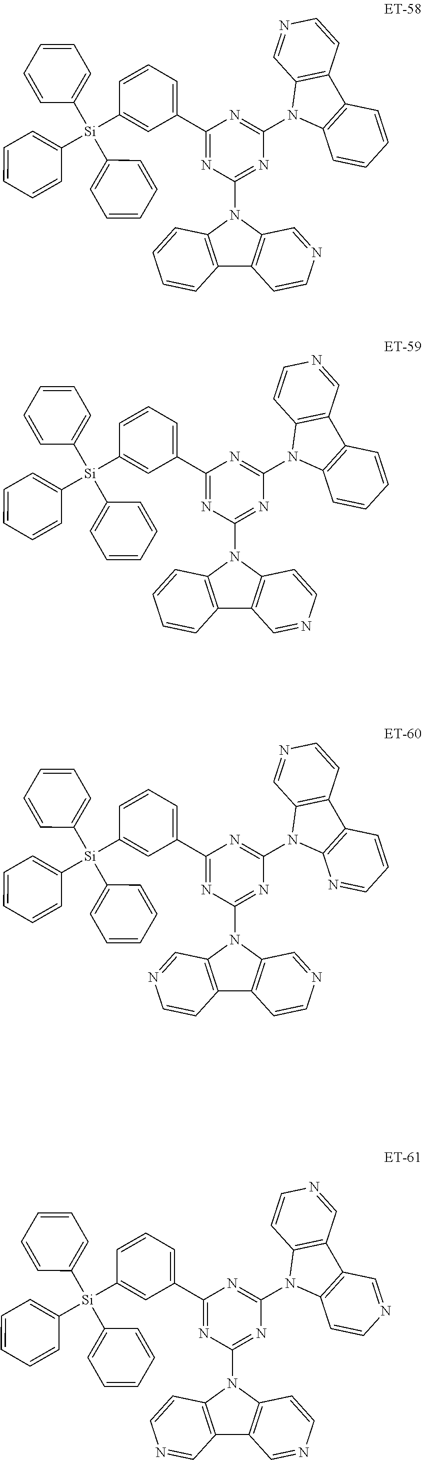 [SMILES: c1ccc([Si](c2ccccc2)(c2ccccc2)c2cccc(-c3nc(-n4c5ccccc5c5ccncc54)nc(-n4c5ccccc5c5ccncc54)n3)c2)cc1 ; c1ccc([Si](c2ccccc2)(c2ccccc2)c2cccc(-c3nc(-n4c5ccccc5c5cnccc54)nc(-n4c5ccccc5c5cnccc54)n3)c2)cc1 ; c1ccc([Si](c2ccccc2)(c2ccccc2)c2cccc(-c3nc(-n4c5cnccc5c5ccncc54)nc(-n4c5cnccc5c5cccnc54)n3)c2)cc1 ; c1ccc([Si](c2ccccc2)(c2ccccc2)c2cccc(-c3nc(-n4c5ccncc5c5cnccc54)nc(-n4c5ccncc5c5cnccc54)n3)c2)cc1]

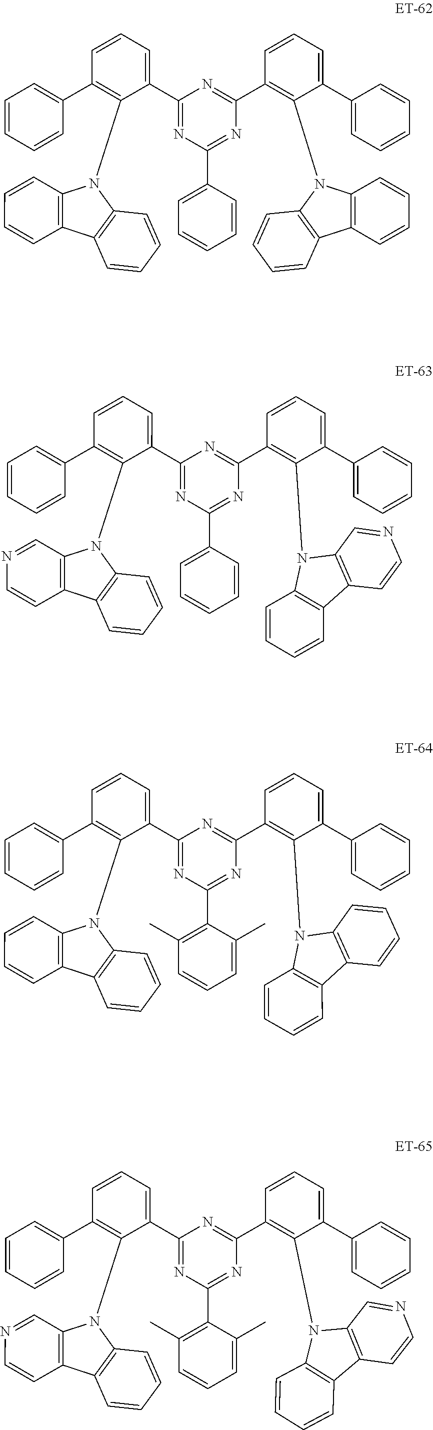 [SMILES: c1ccc(-c2nc(-c3cccc(-c4ccccc4)c3-n3c4ccccc4c4ccccc43)nc(-c3cccc(-c4ccccc4)c3-n3c4ccccc4c4ccccc43)n2)cc1 ; c1ccc(-c2nc(-c3cccc(-c4ccccc4)c3-n3c4ccccc4c4ccncc43)nc(-c3cccc(-c4ccccc4)c3-n3c4ccccc4c4ccncc43)n2)cc1 ; Cc1cccc(C)c1-c1nc(-c2cccc(-c3ccccc3)c2-n2c3ccccc3c3ccccc32)nc(-c2cccc(-c3ccccc3)c2-n2c3ccccc3c3ccccc32)n1 ; Cc1cccc(C)c1-c1nc(-c2cccc(-c3ccccc3)c2-n2c3ccccc3c3ccncc32)nc(-c2cccc(-c3ccccc3)c2-n2c3ccccc3c3ccncc32)n1]

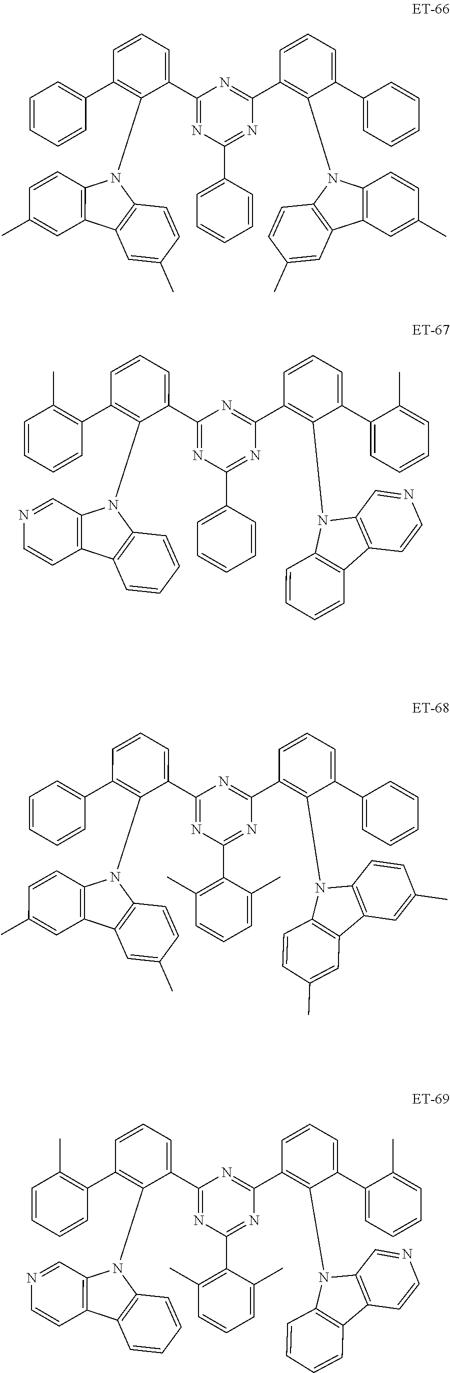

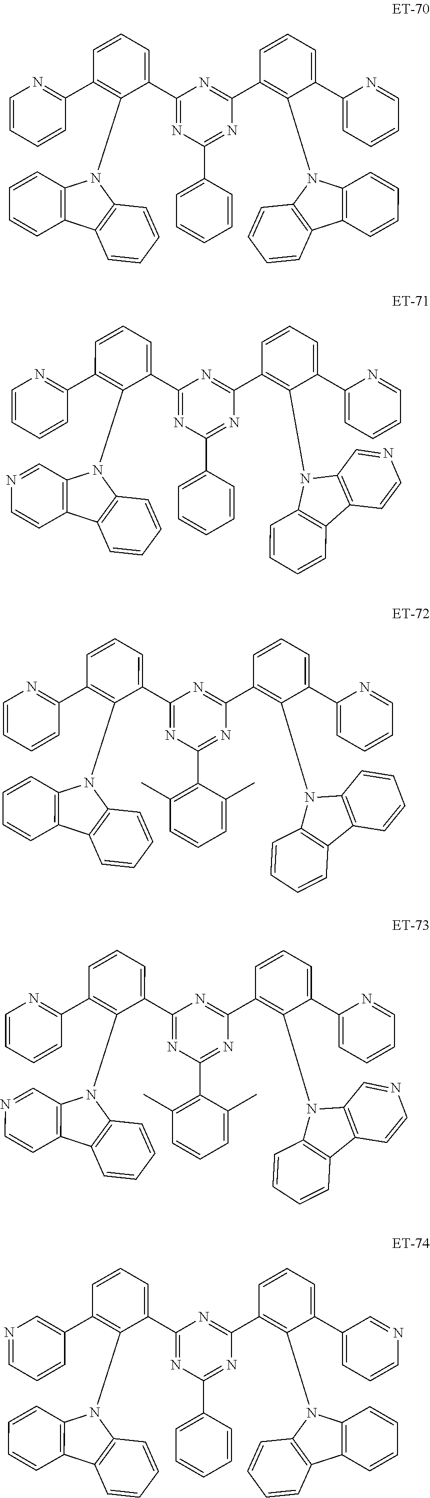

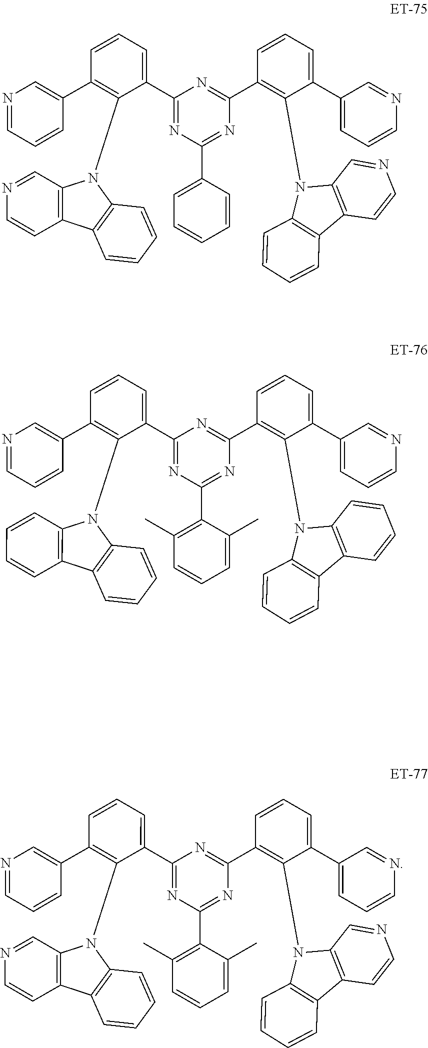 [SMILES: c1ccc(-c2nc(-c3cccc(-c4cccnc4)c3-n3c4ccccc4c4ccncc43)nc(-c3cccc(-c4cccnc4)c3-n3c4ccccc4c4ccncc43)n2)cc1 ; Cc1cccc(C)c1-c1nc(-c2cccc(-c3cccnc3)c2-n2c3ccccc3c3ccccc32)nc(-c2cccc(-c3cccnc3)c2-n2c3ccccc3c3ccccc32)n1 ; Cc1cccc(C)c1-c1nc(-c2cccc(-c3cccnc3)c2-n2c3ccccc3c3ccncc32)nc(-c2cccc(-c3cccnc3)c2-n2c3ccccc3c3ccncc32)n1]

The electron transport layer may be formed from an organic material together with one or more n-type dopants (e.g. LiQ, LiTHPh, etc.).

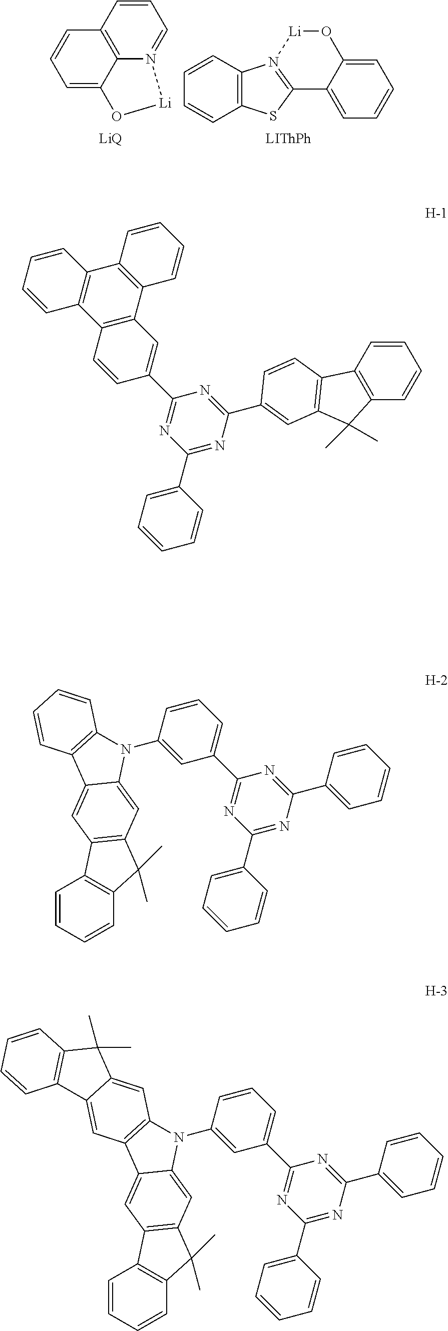

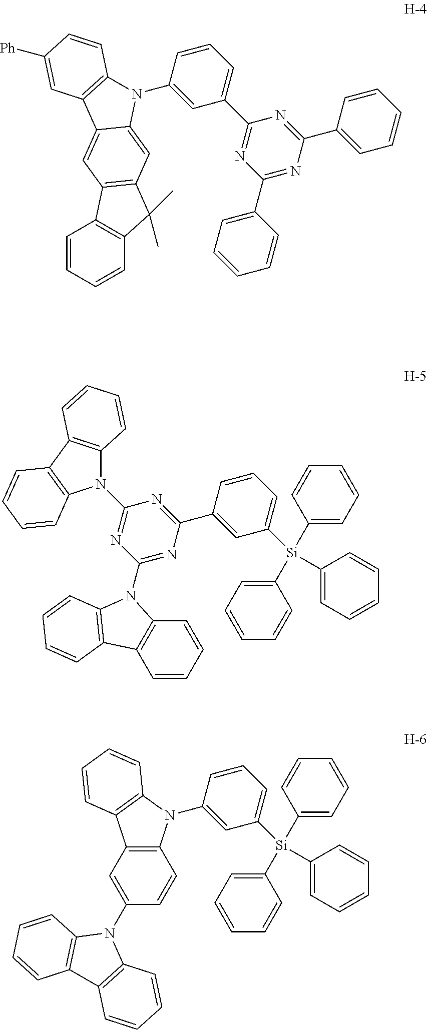 [SMILES: CC1(C)c2ccccc2-c2cc3c4cc(-c5ccccc5)ccc4n(-c4cccc(-c5nc(-c6ccccc6)nc(-c6ccccc6)n5)c4)c3cc21 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2cccc(-n3c4ccccc4c4cc(-n5c6ccccc6c6ccccc65)ccc43)c2)cc1]

As a reference fabrication method for a device example, the method of the present invention includes: evaporating a p-doped material on the surface or an anode of an ITO glass with a light-emitting area of 2 mm×2 mm or co-evaporating the p-doped material with a hole injection material at a concentration of 1%-50% to form a hole injection layer (HIL) of 5-100 nm, a hole transport layer (HTL) of 5-200 nm, then forming a light-emitting layer (EML) of 10-100 nm (which may contain the compound described in the present invention) on the hole transport layer, and forming an electron transport layer (ETL) of 20-200 nm and a cathode of 50-200 nm. If necessary, an electron blocking layer (EBL) is added between the HTL and EML layers, and an electron injecting layer (EIL) is added between the ETL and the cathode to fabricate an OLED device. The OLED was tested by standard methods. The device materials referred to in the present invention may be obtained by known synthetic methods unless otherwise specified.

In a preferred embodiment, the structure of Device Example 1 provided by the present invention is ITO/P-4 (10 nm)/NPD (60 nm)/HT-85 (5 nm)/platinum (II) complex: H-1 (25 nm) (mass ration of Pt1:H-1 is 10:90)/ET-8 (5 nm)/ET-14 or BPyTP (40 nm)/LiQ (1 nm)/A1 (100 nm).

Device Examples 2 to 47 and Comparative Example 1 were prepared using a structure similar to Device Example 1, except that Pt1 in Device Example 1 was replaced with Pt2, Pt3, Pt4, Pt5, Pt6, Pt7, Pt33, Pt48, Pt67, Pt77, Pt79, Pt96, Pt107, Pt137, Pt150, Pt156, Pt178, Pt184, Pt192, Pt208, Pt239, Pt246, Pt254, Pt269, Pt281, Pt305, Pt325, Pt349, Pt368, Pt382, Pt392, Pt409, Pt462, Pt476, Pt484, Pt516, Pt560, Pt577, Pt578, Pt579, Pt580, Pt581, Pt582, Pt583, Pt584 and PtON11Me, respectively. The comparative example and each device example prepared above were tested for luminescent characteristics by standard methods, and the data are shown in Table 2. The structural formulas of the devices involved are as follows:

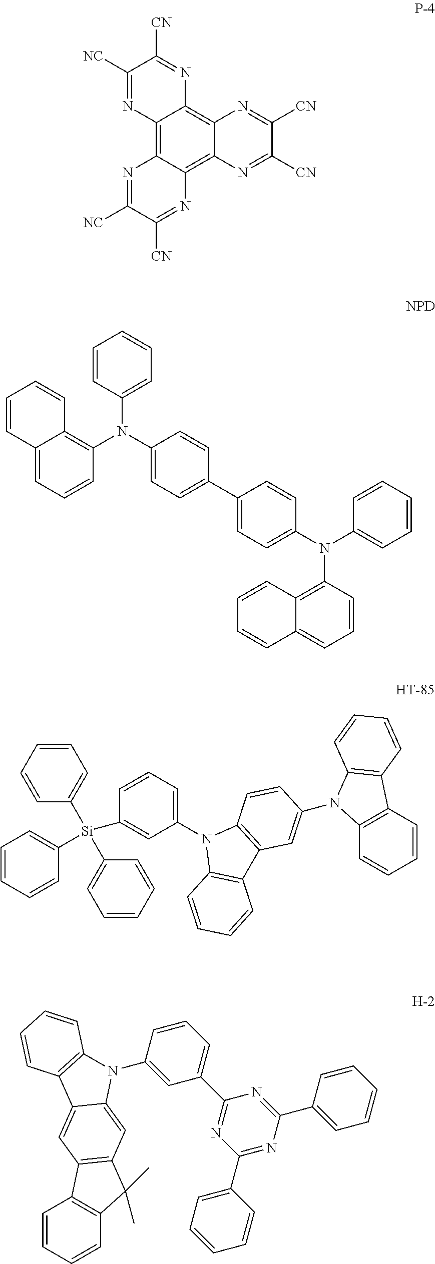 [SMILES: N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1 ; c1ccc([Si](c2ccccc2)(c2ccccc2)c2cccc(-n3c4ccccc4c4cc(-n5c6ccccc6c6ccccc65)ccc43)c2)cc1 ; CC1(C)c2ccccc2-c2cc3c4ccccc4n(-c4cccc(-c5nc(-c6ccccc6)nc(-c6ccccc6)n5)c4)c3cc21]

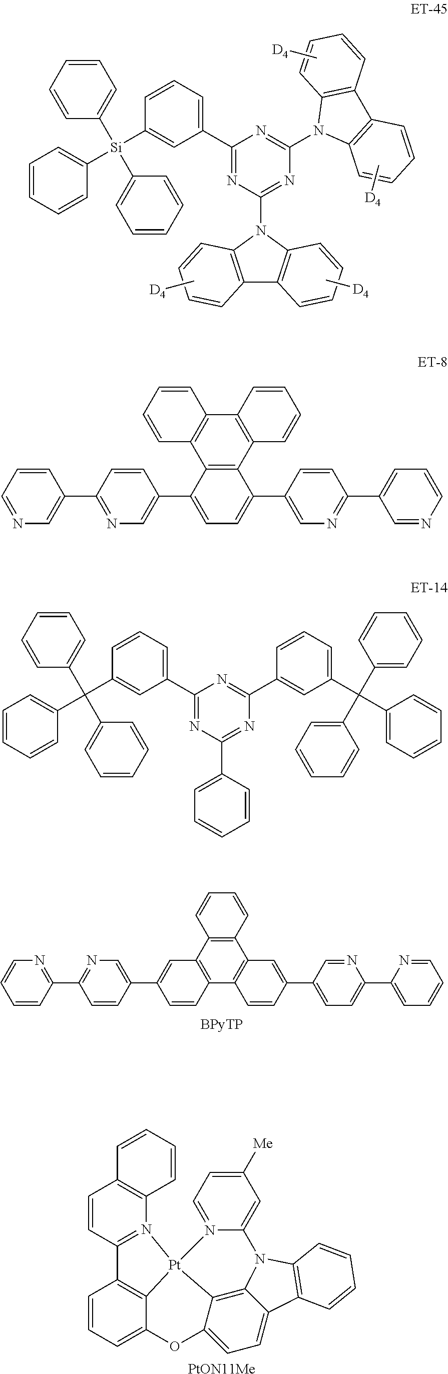

TABLE 2
Device Properties of Some Phosphorescent Materials

| | Metal | Start-up | External quantum |
|---|---|---|---|
| | complex | Voltage (V) | efficiency EQE (%) |
| Device Example 1 | Pt1 | 3.2 | 21 |
| Device Example 2 | Pt2 | 3.3 | 23 |
| Device Example 3 | Pt3 | 3.4 | 21 |
| Device Example 4 | Pt4 | 3.3 | 22 |
| Device Example 5 | Pt5 | 3.2 | 24 |
| Device Example 6 | Pt6 | 3.3 | 25 |
| Device Example 7 | Pt7 | 3.2 | 21 |
| Device Example 8 | Pt33 | 3.2 | 23 |
| Device Example 9 | Pt48 | 3.2 | 24 |
| Device Example 10 | Pt67 | 3.2 | 23 |
| Device Example 11 | Pt77 | 3.2 | 26 |
| Device Example 12 | Pt79 | 3.3 | 24 |
| Device Example 13 | Pt96 | 3.2 | 24 |
| Device Example 14 | Pt107 | 3.3 | 27 |
| Device Example 15 | Pt137 | 3.3 | 22 |
| Device Example 16 | Pt150 | 3.3 | 23 |
| Device Example 17 | Pt156 | 3.2 | 23 |
| Device Example 18 | Pt178 | 3.2 | 23 |
| Device Example 19 | Pt184 | 3.2 | 24 |
| Device Example 20 | Pt192 | 3.3 | 25 |
| Device Example 21 | Pt208 | 3.3 | 25 |
| Device Example 22 | Pt239 | 3.3 | 26 |
| Device Example 23 | Pt246 | 3.3 | 25 |
| Device Example 24 | Pt254 | 3.3 | 23 |
| Device Example 25 | Pt269 | 3.2 | 26 |
| Device Example 26 | Pt281 | 3.2 | 26 |
| Device Example 27 | Pt305 | 3.2 | 25 |
| Device Example 28 | Pt325 | 3.3 | 24 |
| Device Example 29 | Pt349 | 3.3 | 25 |
| Device Example 30 | Pt368 | 3.3 | 25 |
| Device Example 31 | Pt382 | 3.2 | 26 |
| Device Example 32 | Pt392 | 3.4 | 27 |
| Device Example 33 | Pt409 | 3.2 | 24 |
| Device Example 34 | Pt462 | 3.1 | 25 |
| Device Example 35 | Pt476 | 3.2 | 25 |
| Device Example 36 | Pt484 | 3.2 | 24 |
| Device Example 37 | Pt516 | 3.2 | 23 |
| Device Example 38 | Pt560 | 3.4 | 23 |
| Device Example 39 | Pt577 | 3.2 | 27 |
| Device Example 40 | Pt578 | 3.2 | 26 |
| Device Example 41 | Pt579 | 3.3 | 26 |
| Device Example 42 | Pt580 | 3.3 | 26 |
| Device Example 43 | Pt581 | 3.2 | 25 |
| Device Example 44 | Pt582 | 3.2 | 25 |
| Device Example 45 | Pt583 | 3.2 | 27 |
| Device Example 46 | Pt584 | 3.2 | 26 |
| Comparative | PtON11Me | 3.5 | 12.5 |
| Example | | | |

As can be seen from Table 2, Device Examples 1 to 46 prepared in the present application all have a lower start-up voltage and a higher external quantum efficiency compared with the comparative example 1, indicating that the phosphorescent material cyclic tetradentate metal platinum (II) complex provided in the present invention has a certain commercial application value.

It will be understood by those skilled in the art that the embodiments described above are specific examples for practicing the invention, and that various changes in form and details may be made therein without departing from the spirit and scope of the invention. For example, many of the substituent structures described herein can be replaced with other structures without departing from the spirit of the invention.

What is claimed is:

1. A cyclic tetradentate metal platinum (II) complex phosphorescent material having the general structure shown in formula (1): 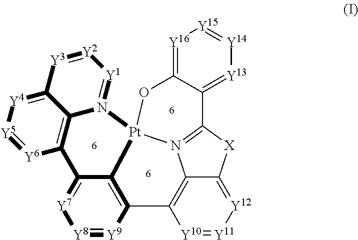
where X is selected from NR′, S or O; where R′ is selected from hydrogen, halogen, substituted or unsubstituted C1-C30 alkyl, substituted or unsubstituted C1-C30 cycloalkyl, substituted or unsubstituted C6-C30 aryl, and combination thereof;
Y¹-Y¹⁶ are each independently selected from CR¹-CR¹⁶ or N, and the Y¹-Y¹⁶ are not N at the same time; where R¹-R¹⁶ are each independently selected from hydrogen, halogen, substituted or unsubstituted C1-C60 alkyl, substituted or unsubstituted C1-C60 cycloalkyl, substituted or unsubstituted C1-C60 heterocycloalkyl, substituted or unsubstituted C6-C60 aryl, substituted or unsubstituted C6-C18 arylamine, substituted or unsubstituted C18-C60 arylsilyl, and combination thereof; and the heteroatom is selected from O and N.

2. The cyclic tetradentate metal platinum (II) complex phosphorescent material according to claim 1, wherein R′ is selected from hydrogen, F, substituted or unsubstituted C1-C10 alkyl, substituted or unsubstituted C1-C10 cycloalkyl, substituted or unsubstituted C6-C30 aryl, substituted or unsubstituted C6-C30 azaaryl, and combination thereof.

3. The cyclic tetradentate metal platinum (II) complex phosphorescent material according to claim 1, wherein R′ is selected from hydrogen, F, methyl, ethyl, propyl, isopropyl, t-butyl, cyclopropyl, cyclobutyl, cyclopentyl, cyclohexyl, phenyl, biphenyl, triaryl, naphthyl, pyridyl, and combination thereof.

4. The cyclic tetradentate metal platinum (II) complex phosphorescent material according to claim 1, wherein R¹-R¹⁶ are each independently selected from hydrogen, F, substituted or unsubstituted C1-C30 alkyl, substituted or unsubstituted C1-C30 cycloalkyl, substituted or unsubstituted C1-C30 N heterocycloalkyl, substituted or unsubstituted C6-C30 aryl, substituted or unsubstituted C12-C18 arylamine, substituted or unsubstituted C18 arylsilyl, and combination thereof.

5. The cyclic tetradentate metal platinum (II) complex phosphorescent material according to claim 1, wherein R¹-R¹⁶ are each independently selected from hydrogen, F, methyl, ethyl, propyl, isopropyl, t-butyl, heptyl, cyclopropyl, cyclobutyl, cyclopentyl, cyclohexyl, phenyl, biphenyl, triaryl, naphthyl, pyridyl, quinolinyl, benzofuranyl, dibenzofuranyl, triarylsilane, diphenylamine, diphenylamine oxide, and combination thereof.

6. The cyclic tetradentate metal platinum (II) complex phosphorescent material according to claim 1, wherein two or more adjacent R′ and R¹-R¹⁶ are each independently or selectively linked to form a condensed ring.

7. The cyclic tetradentate metal platinum (II) complex phosphorescent material according to claim 1, wherein at least one of the hydrogens of R′ and R¹-R¹⁶ is substitutable with deuterium.

8. The cyclic tetradentate metal platinum (II) complex phosphorescent material according to claim 1, wherein the phosphorescent material is any one of the following structural formulas:

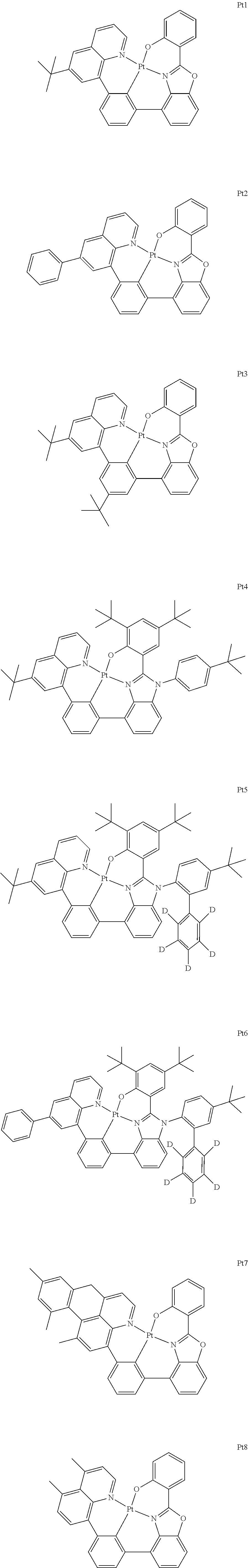

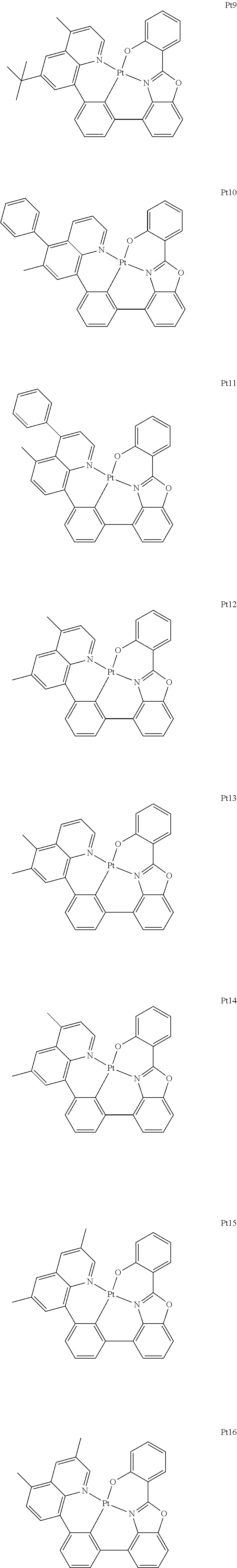

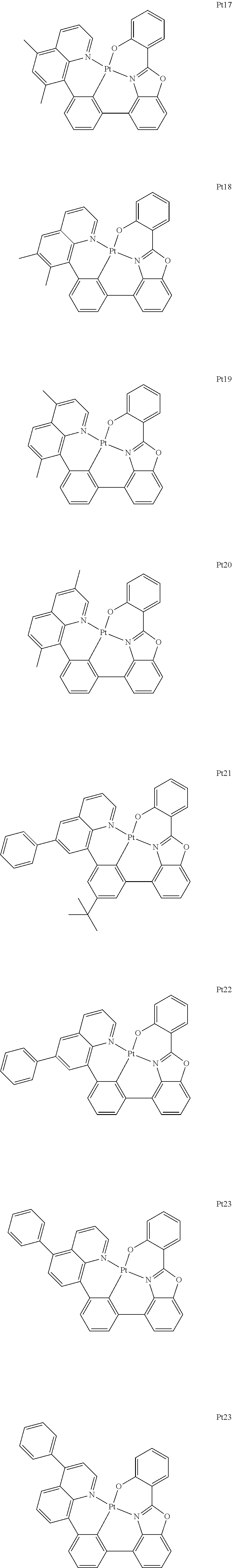

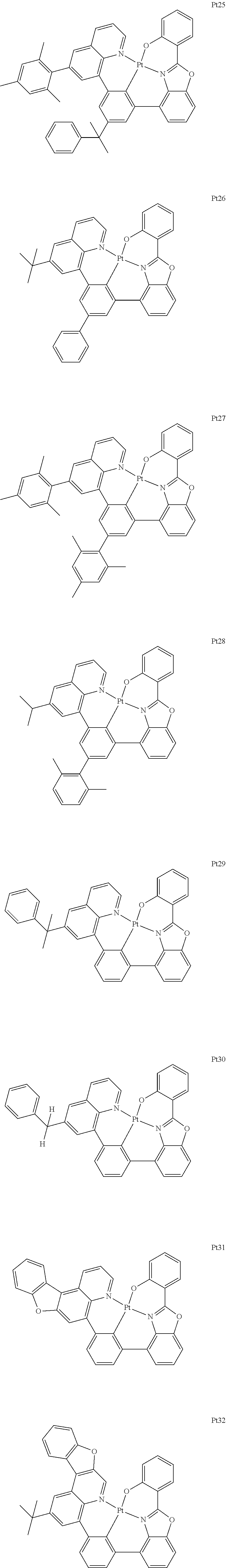

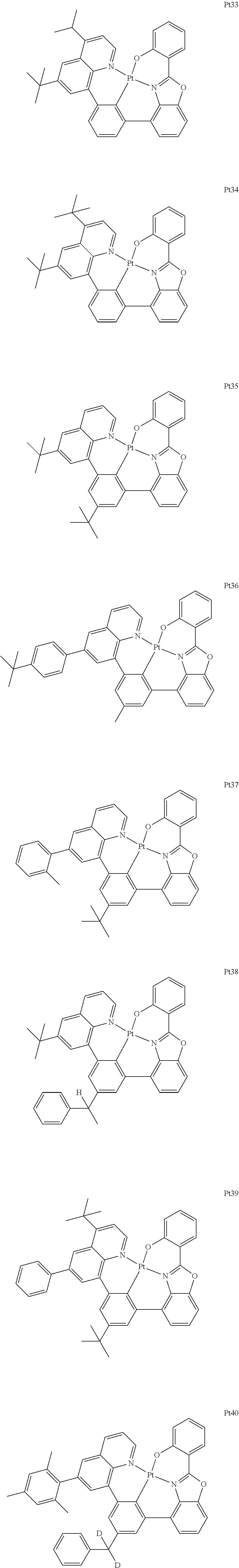

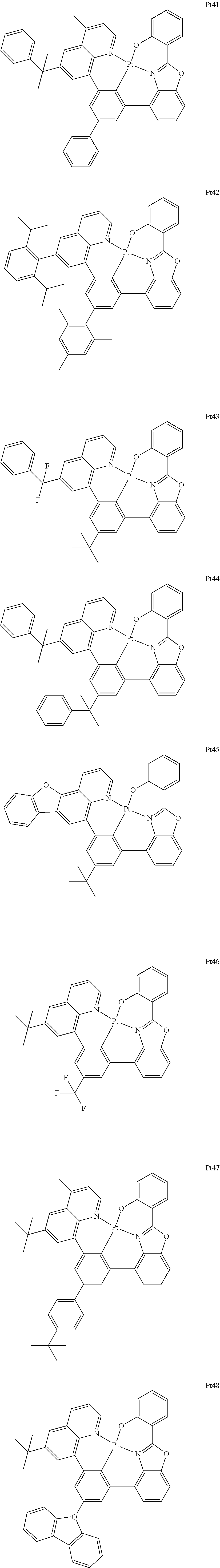

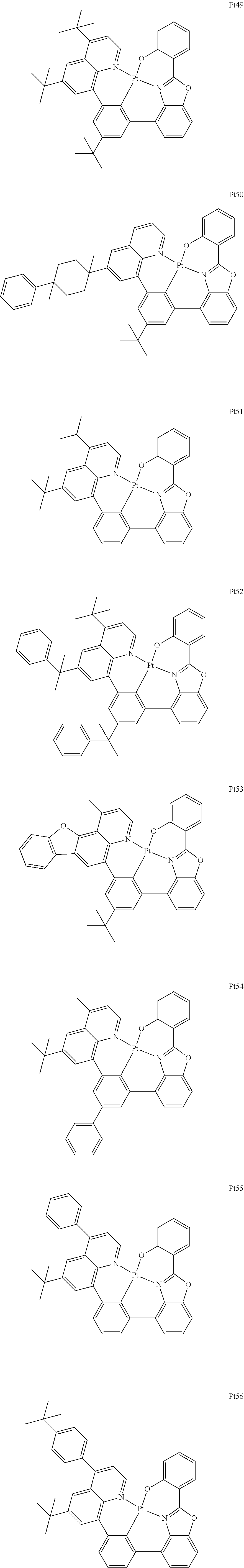

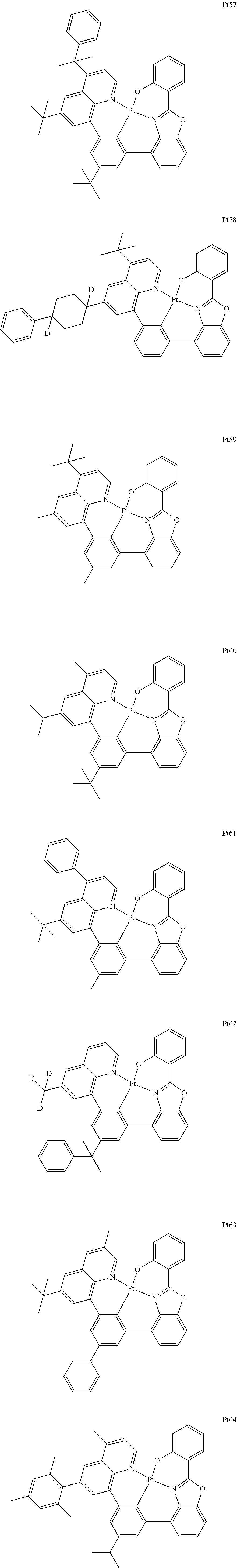

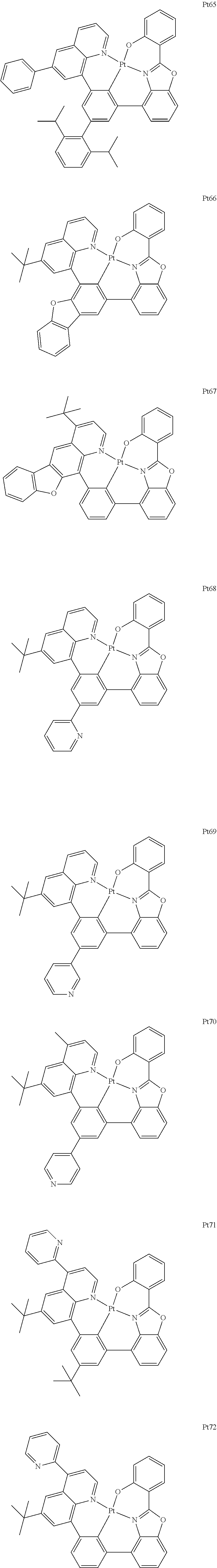

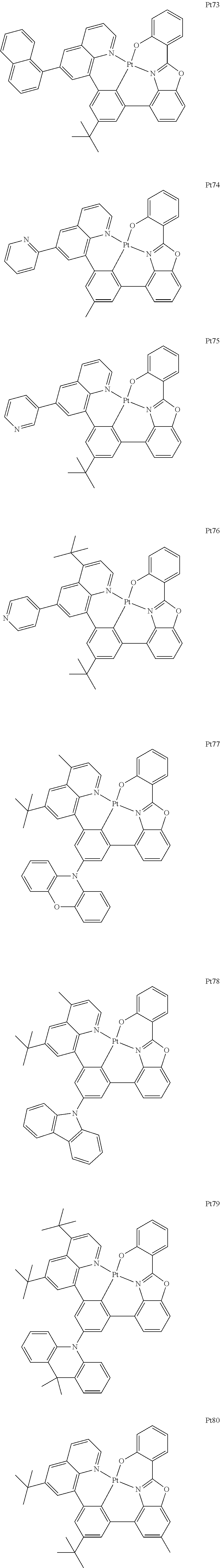

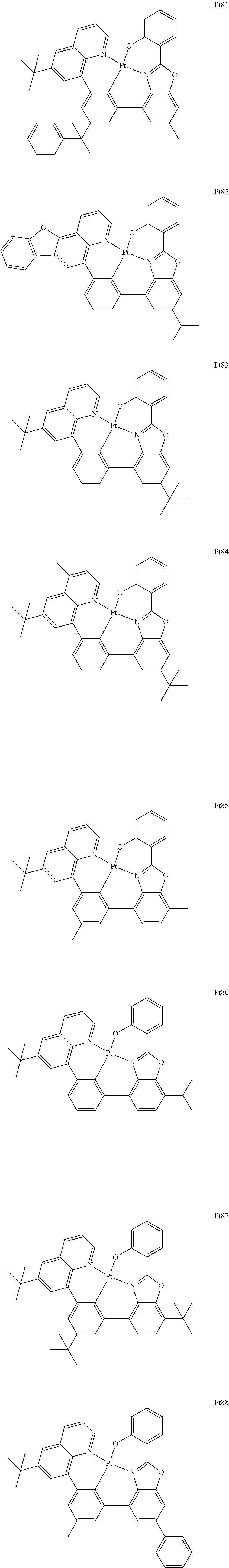

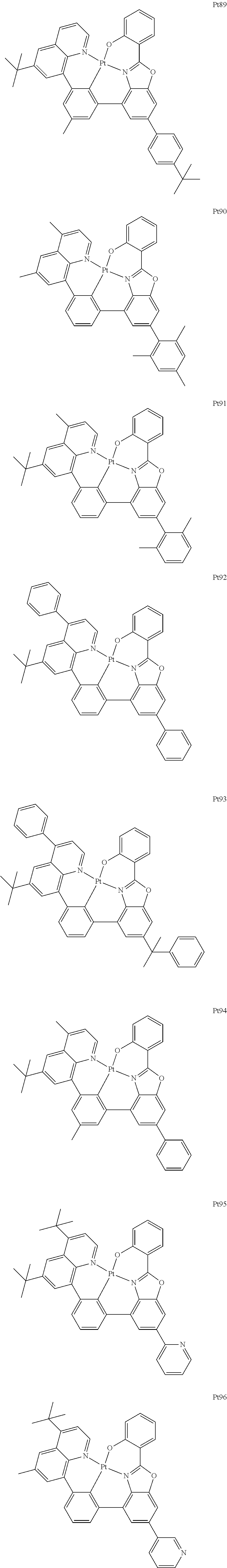

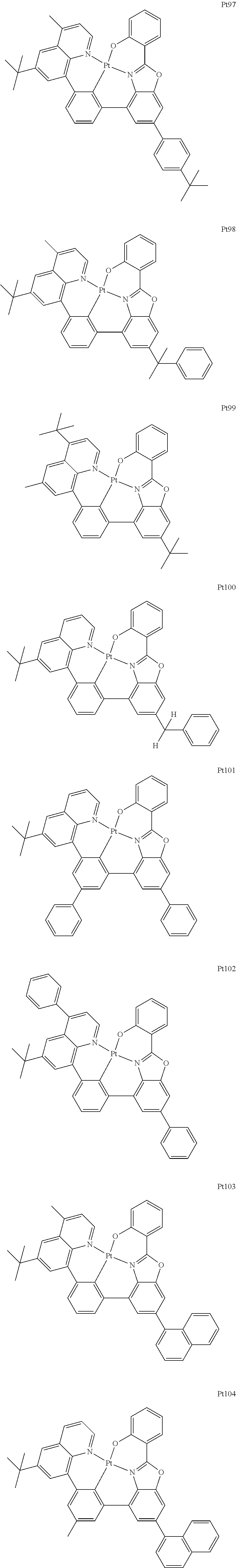

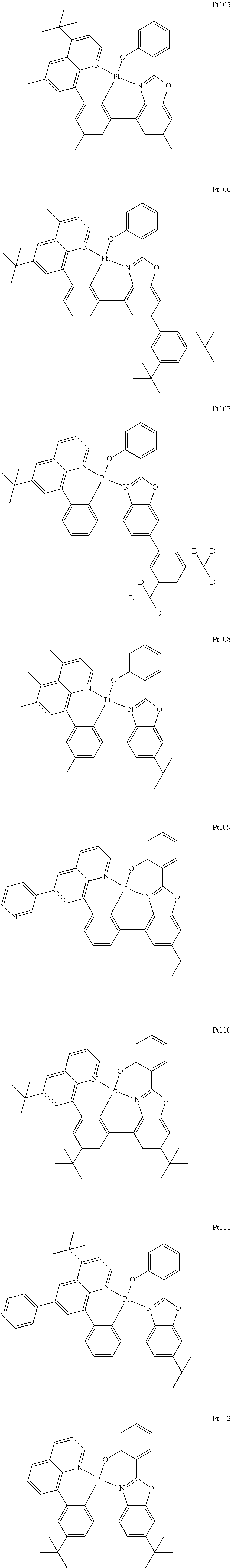

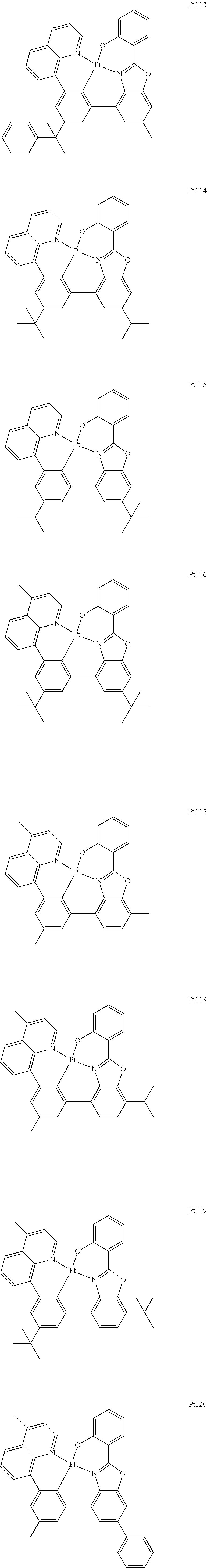

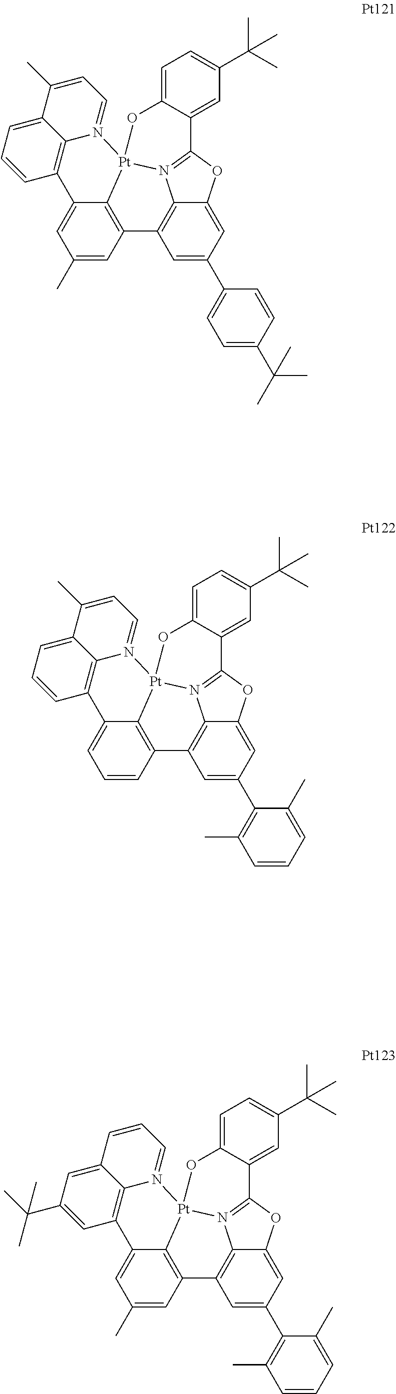

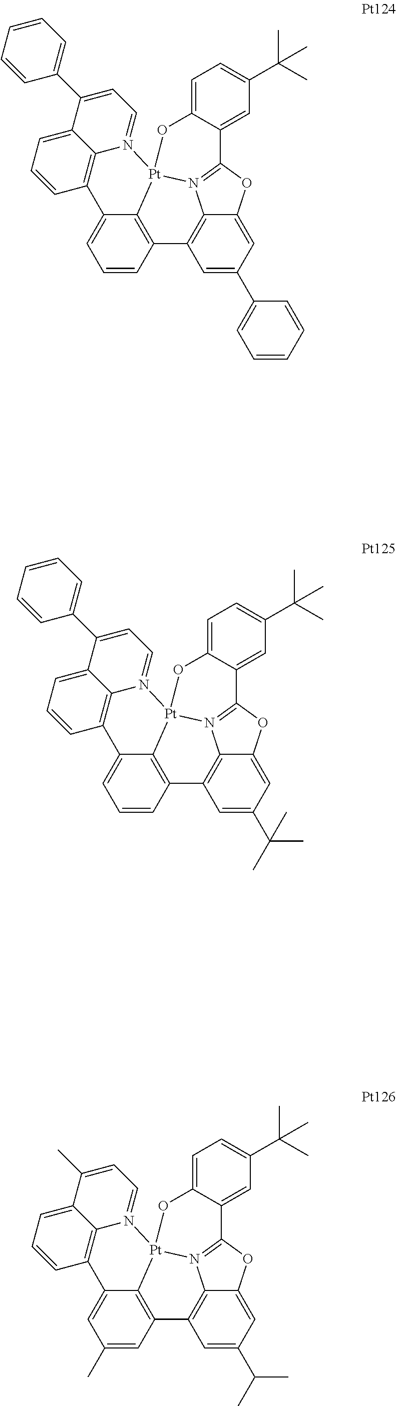

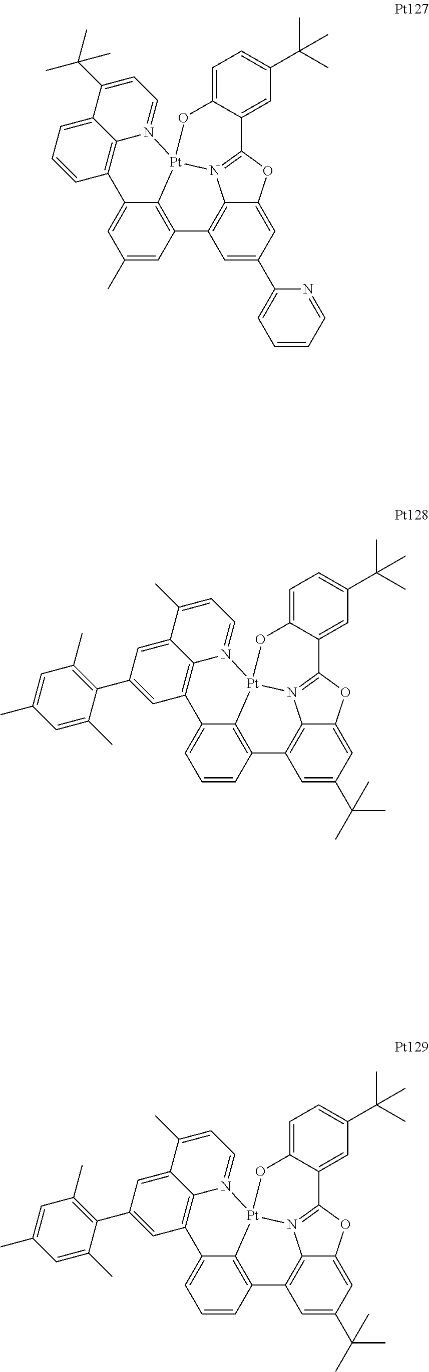

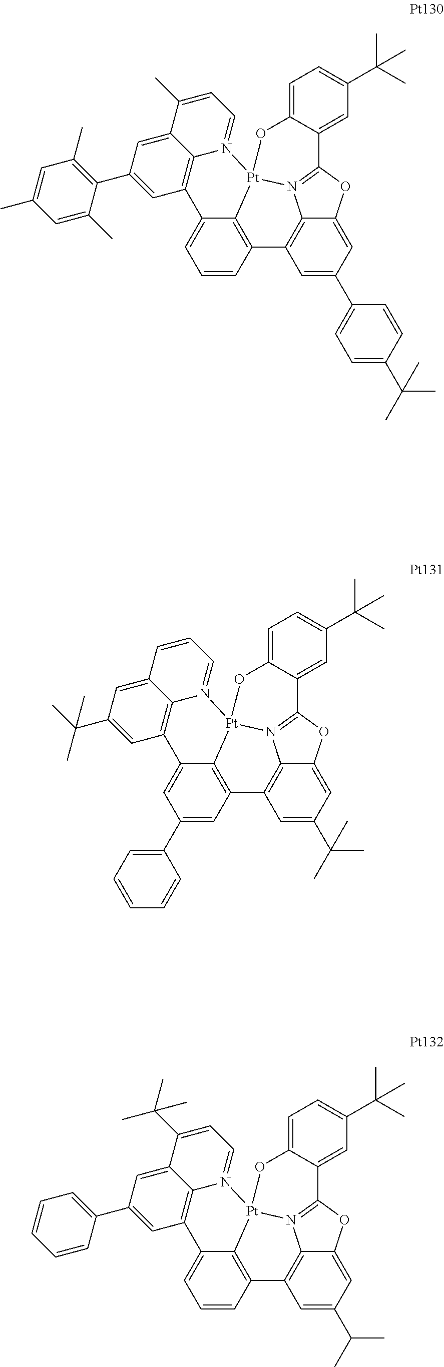

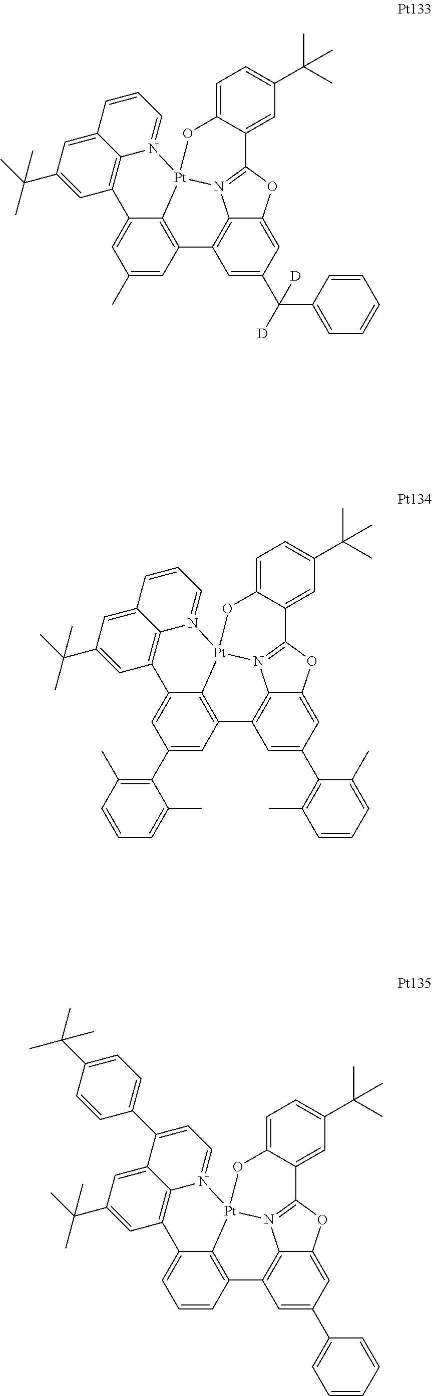

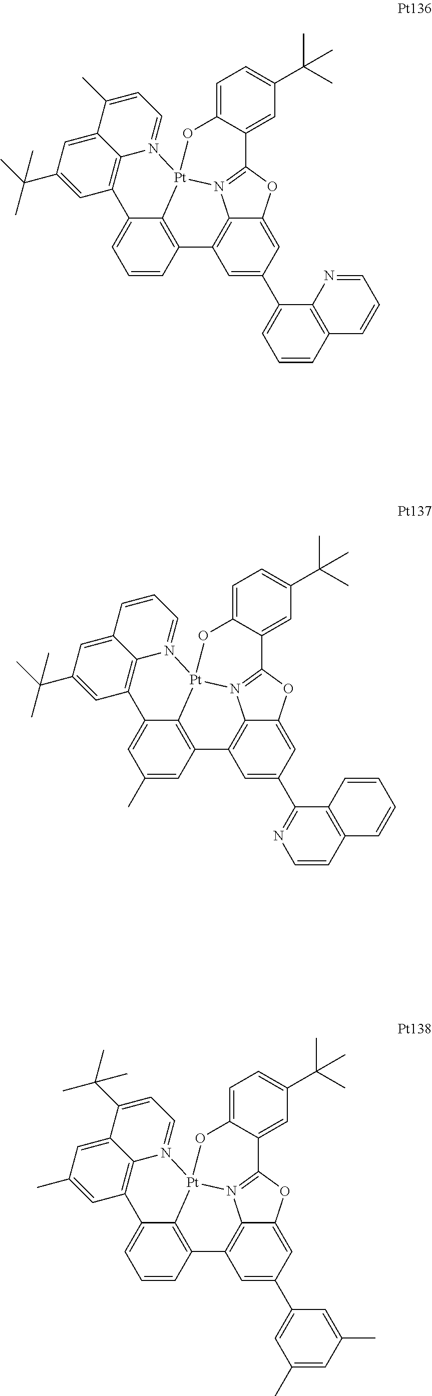

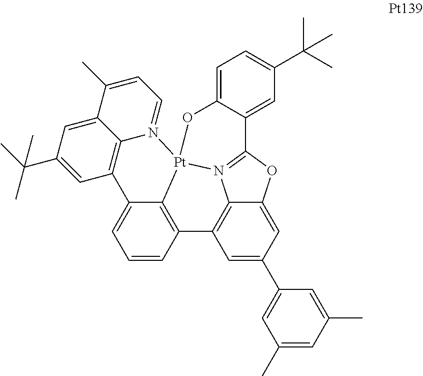

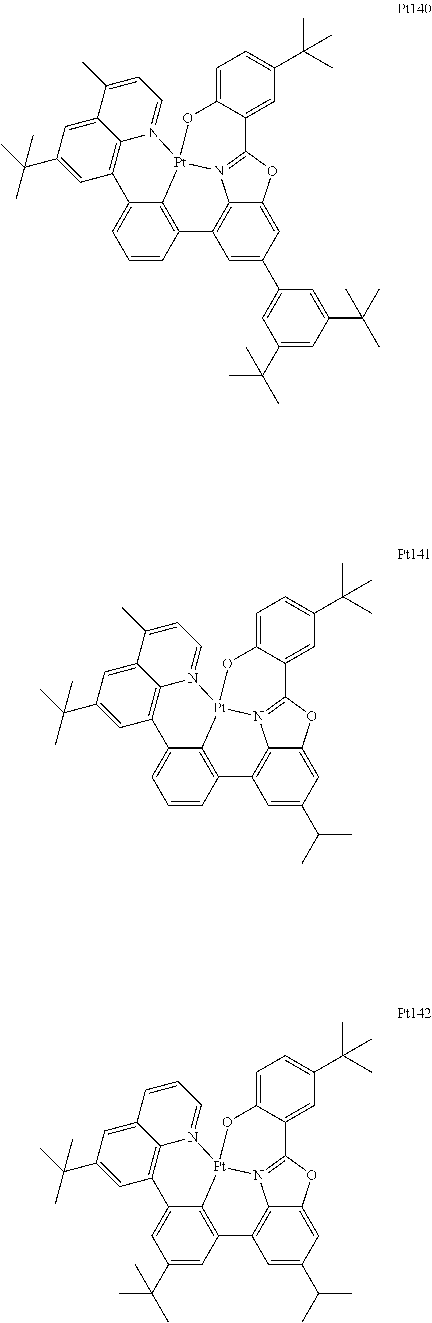

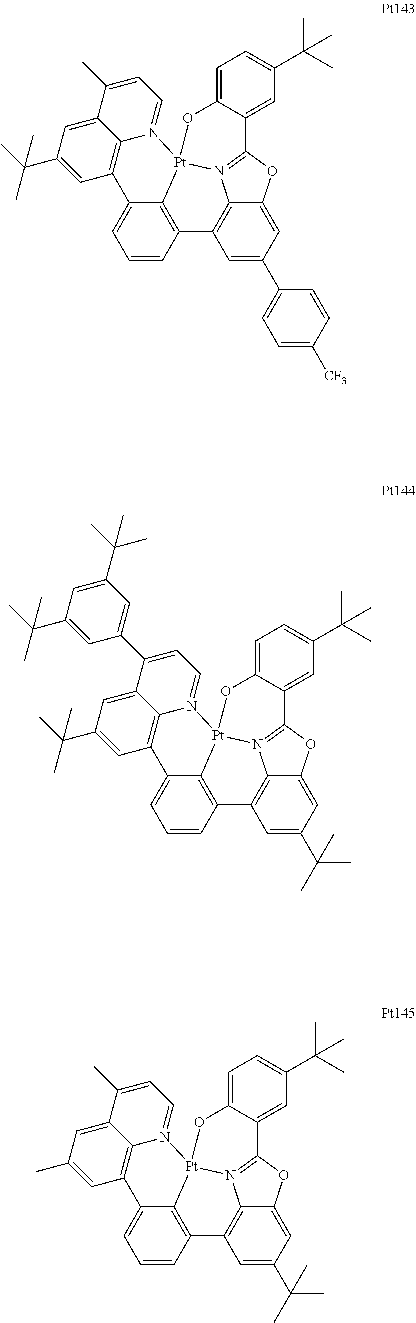

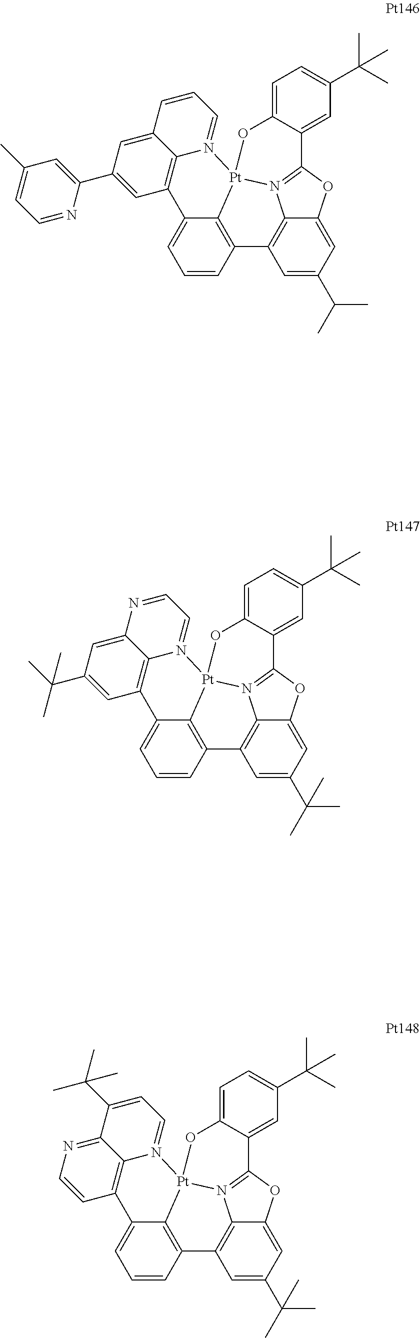

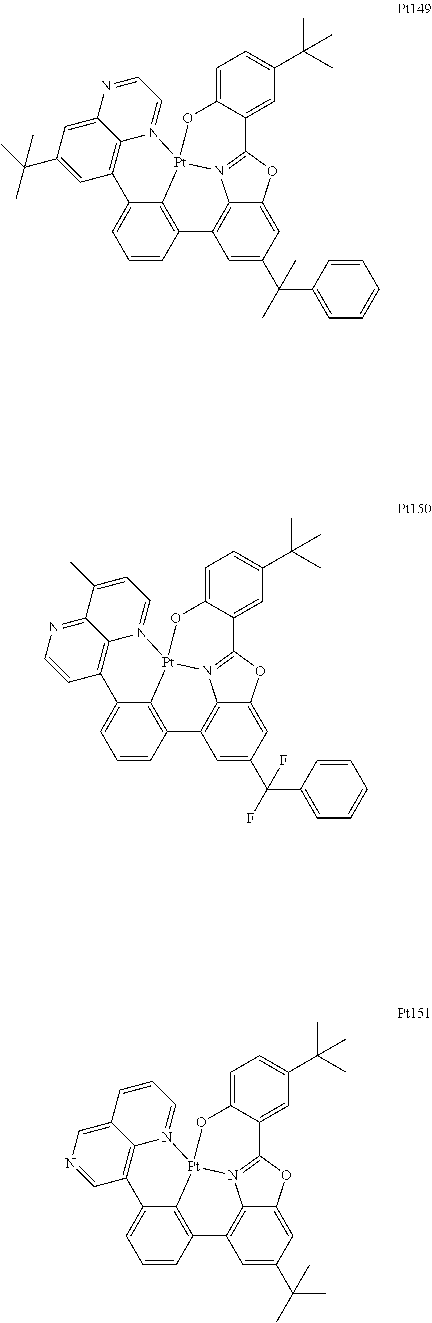

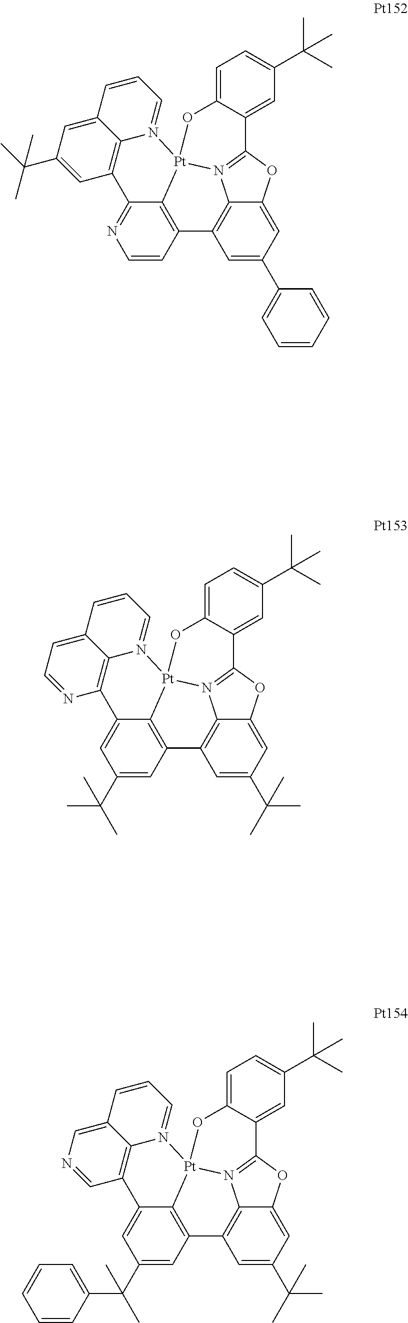

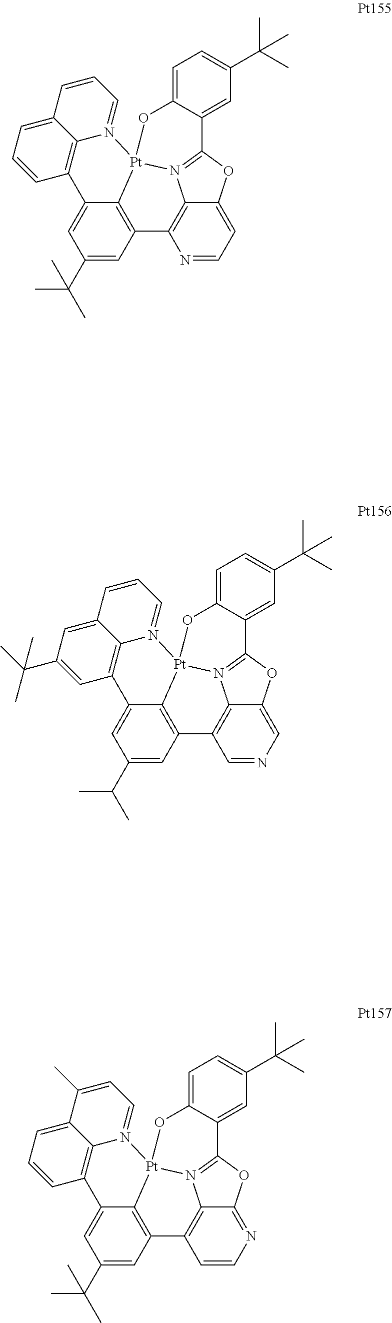

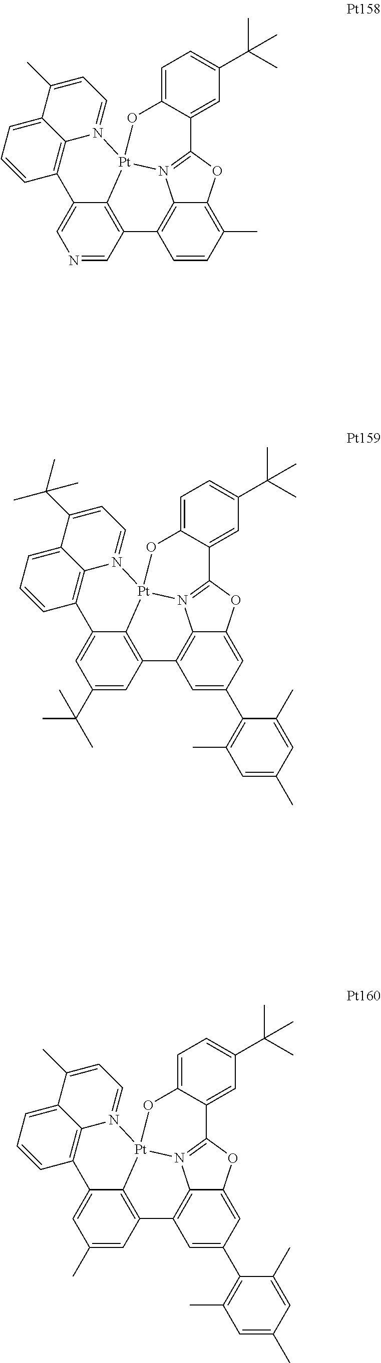

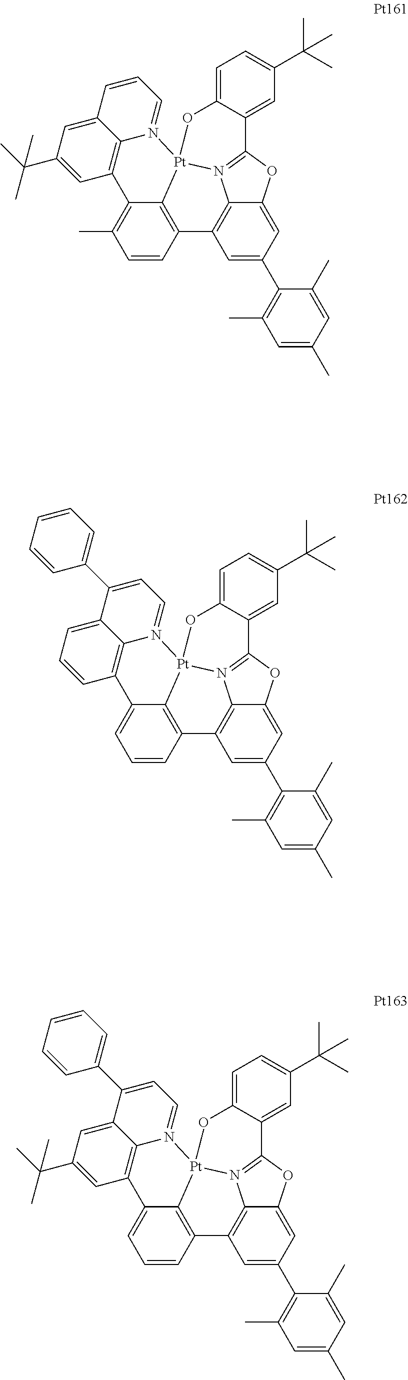

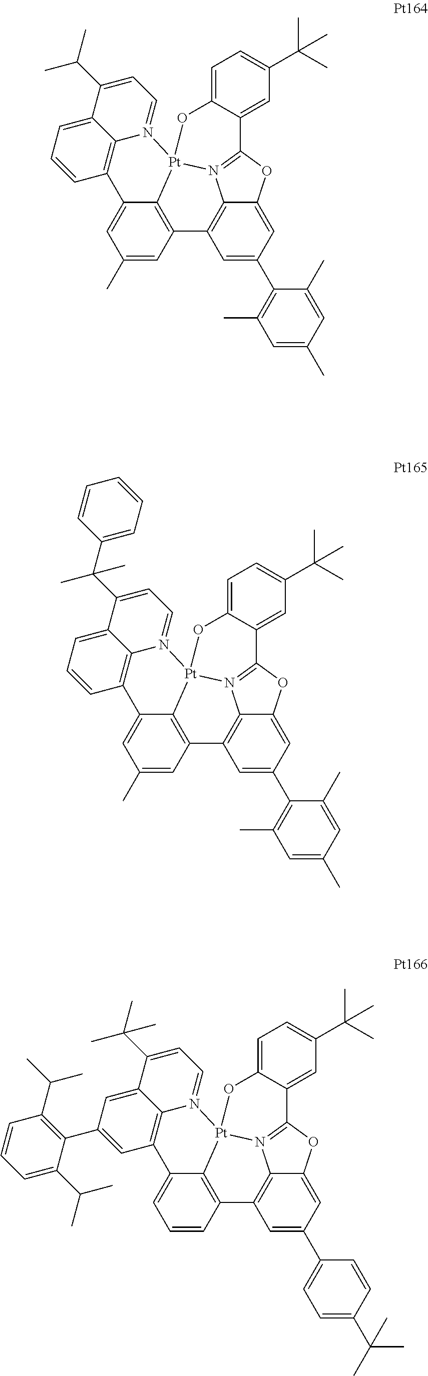

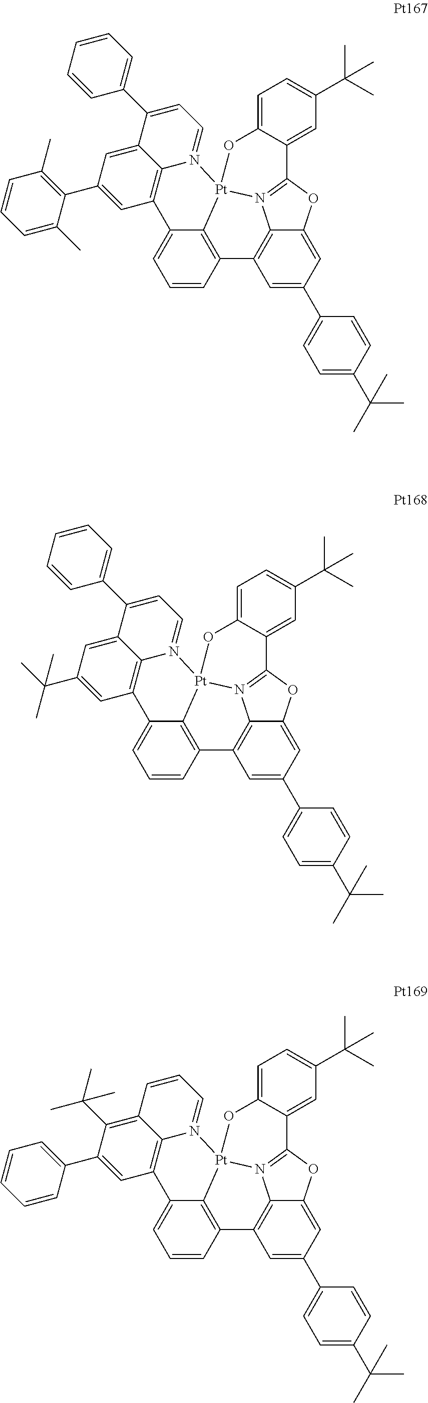

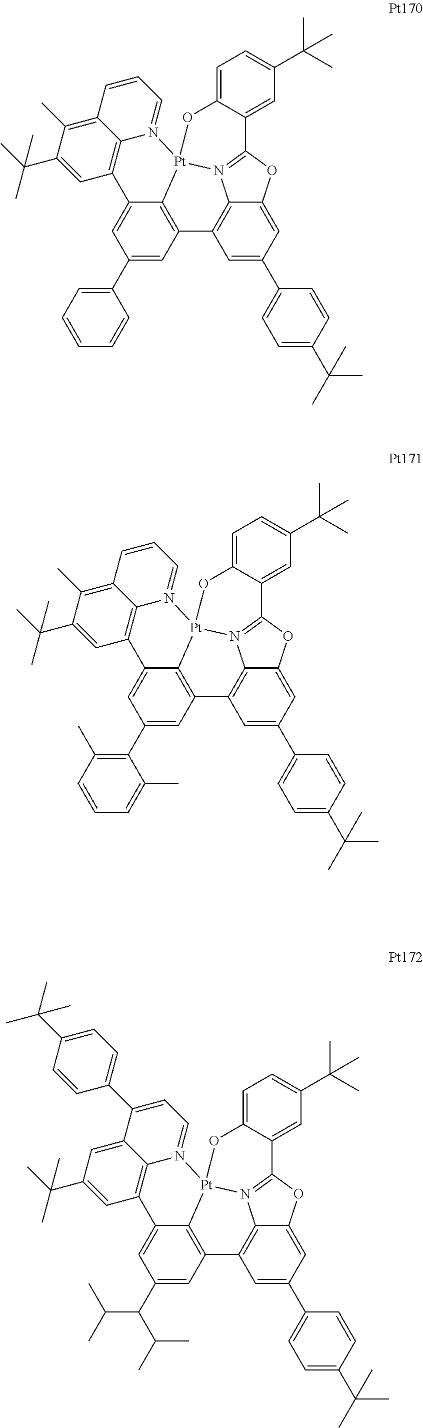

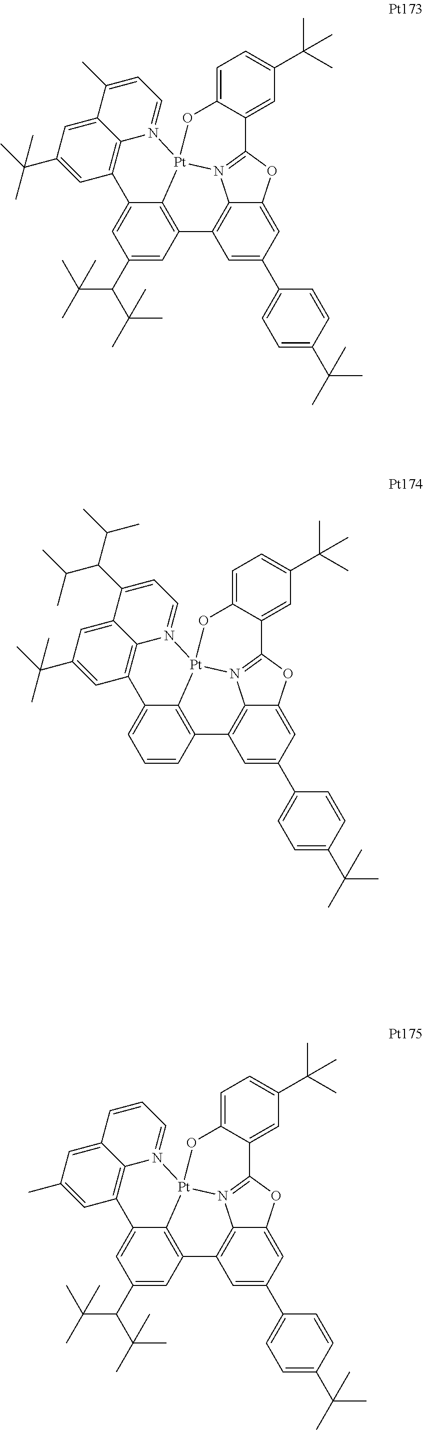

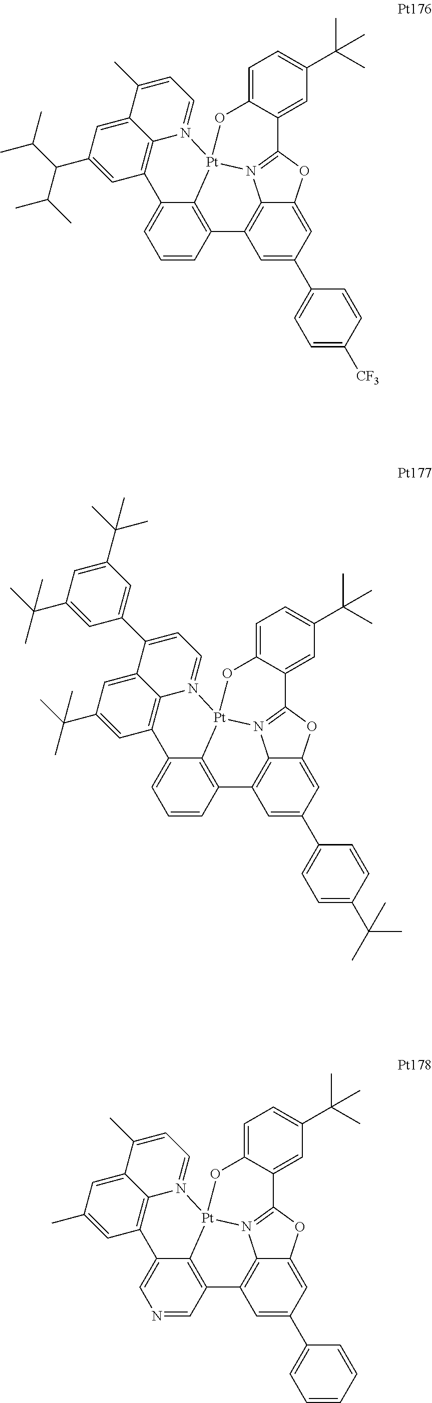

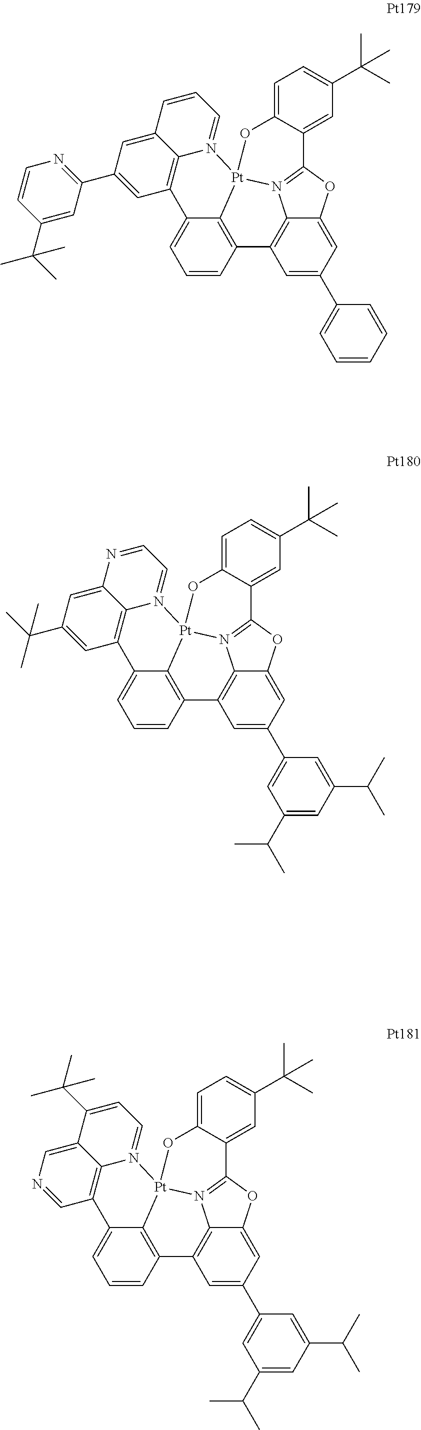

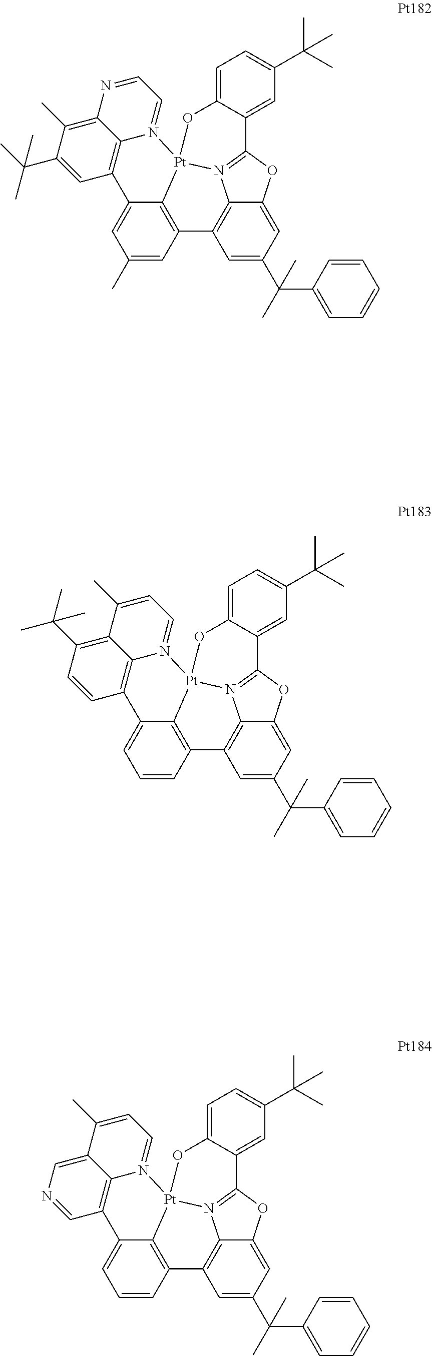

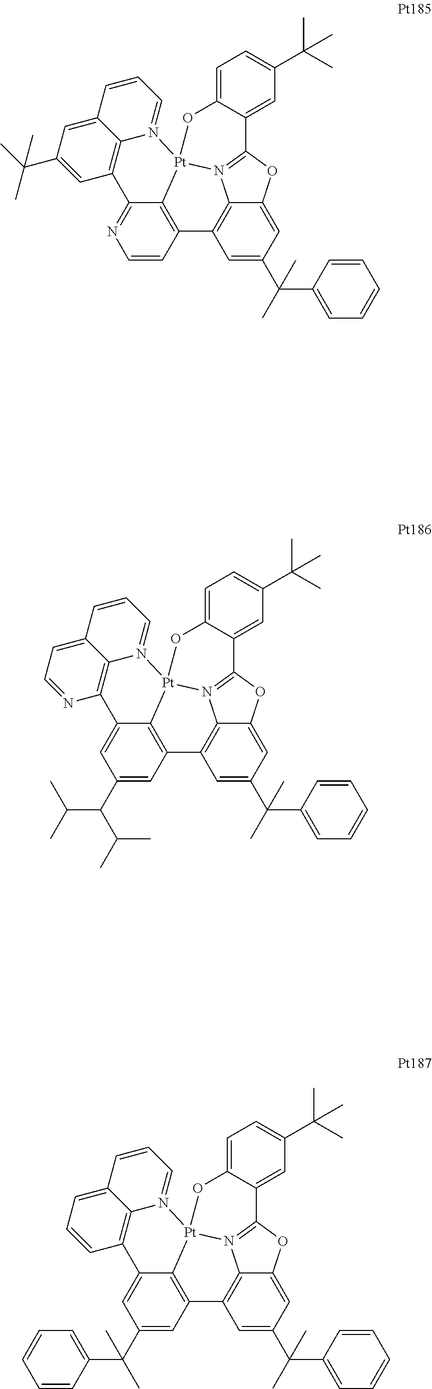

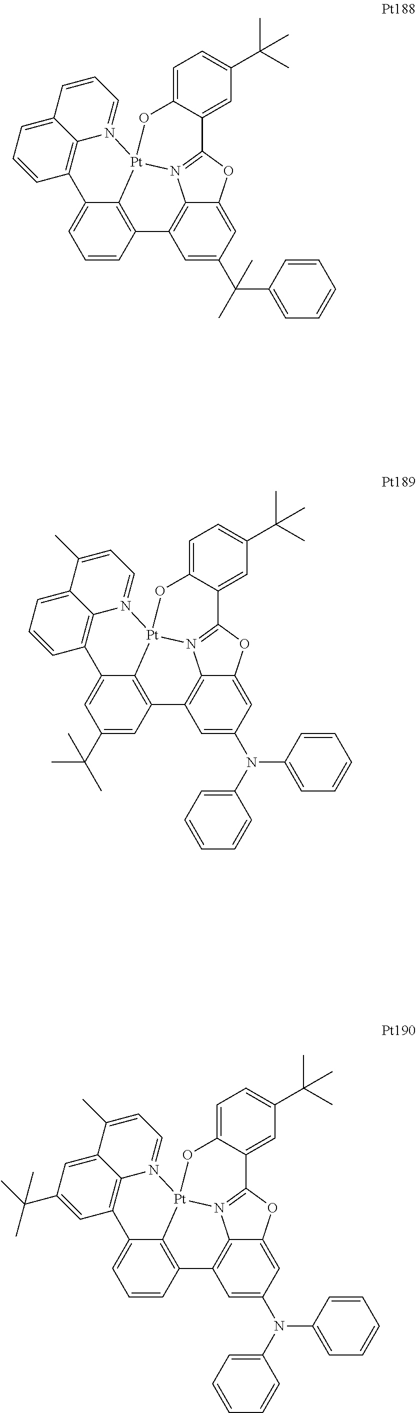

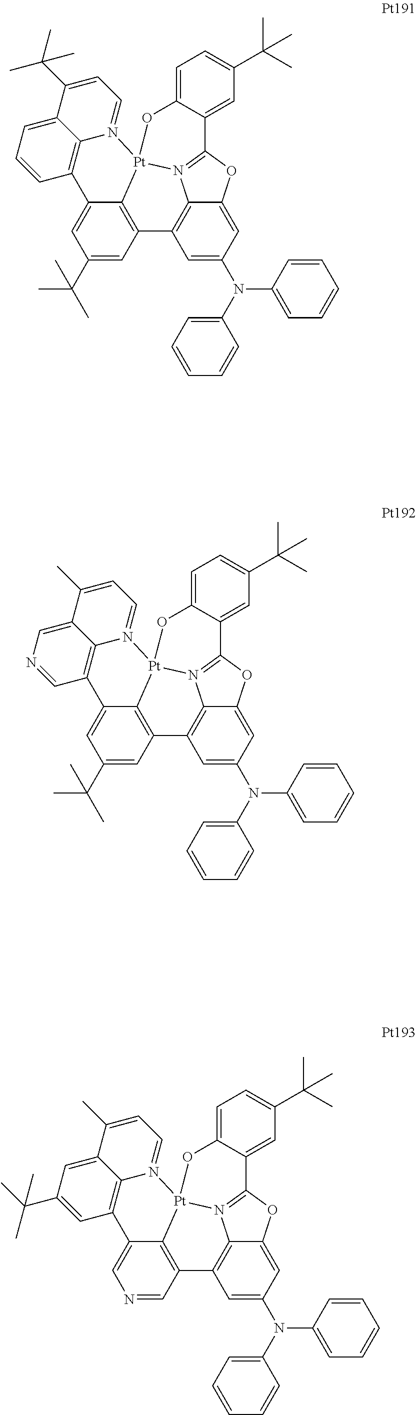

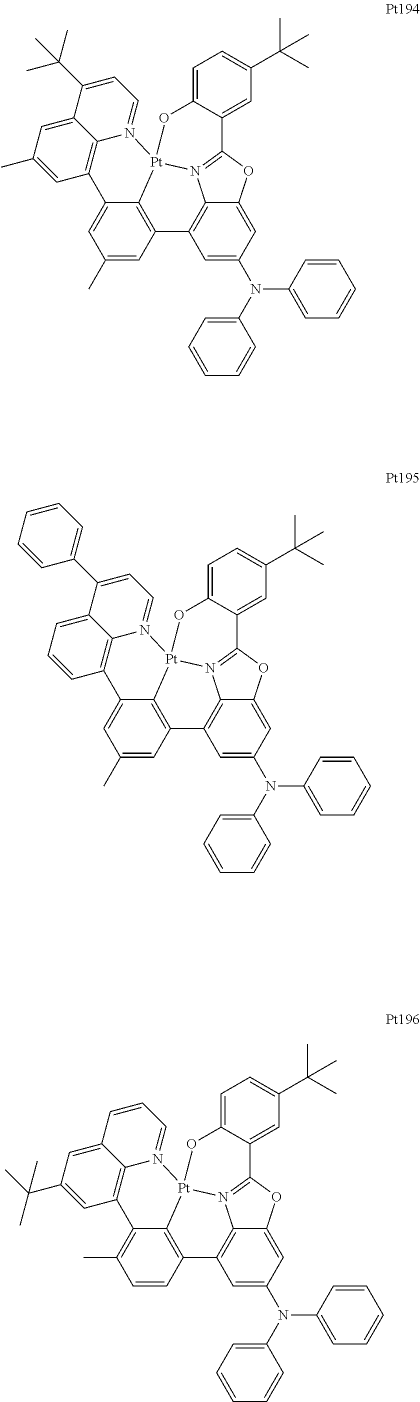

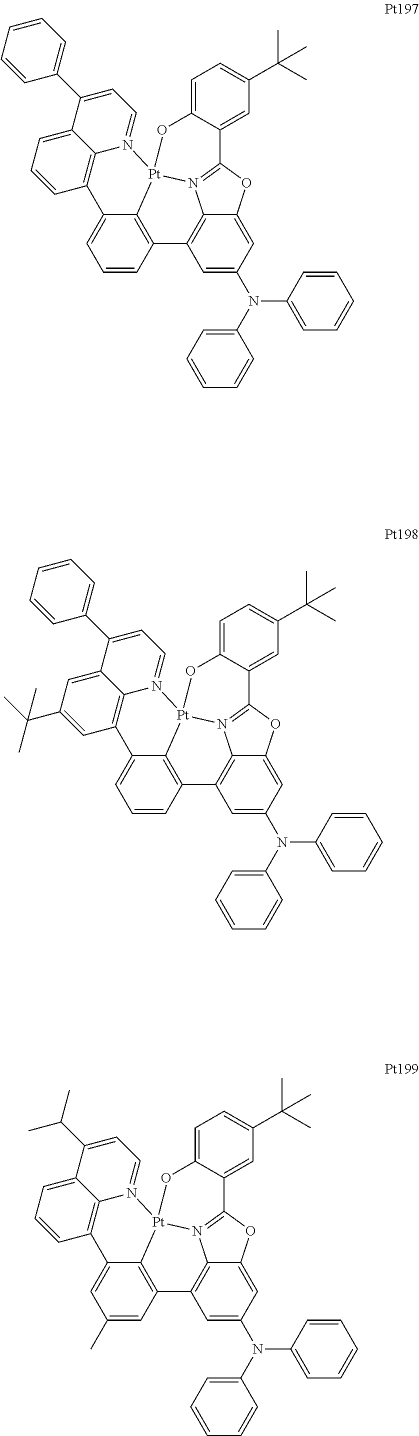

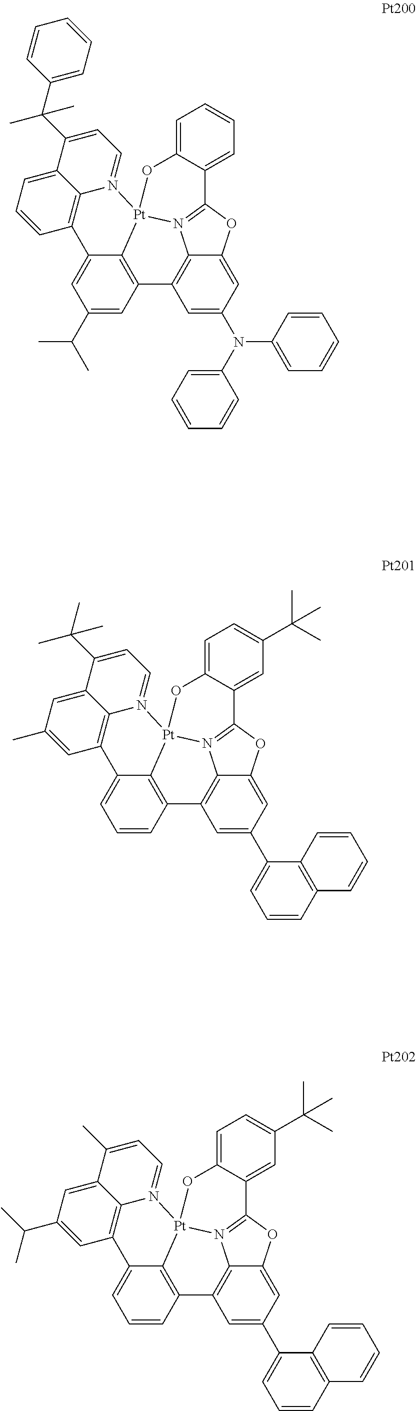

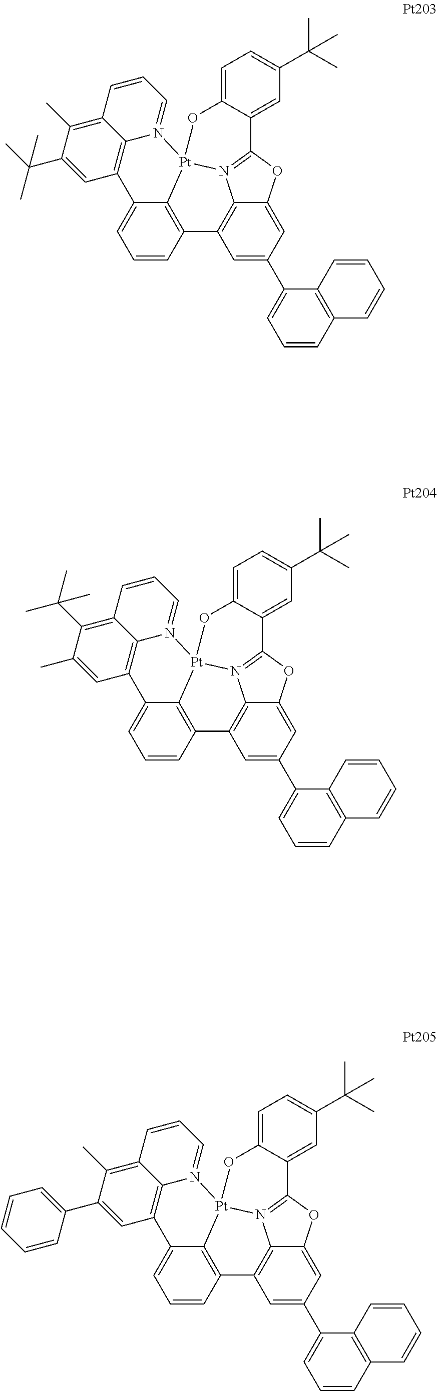

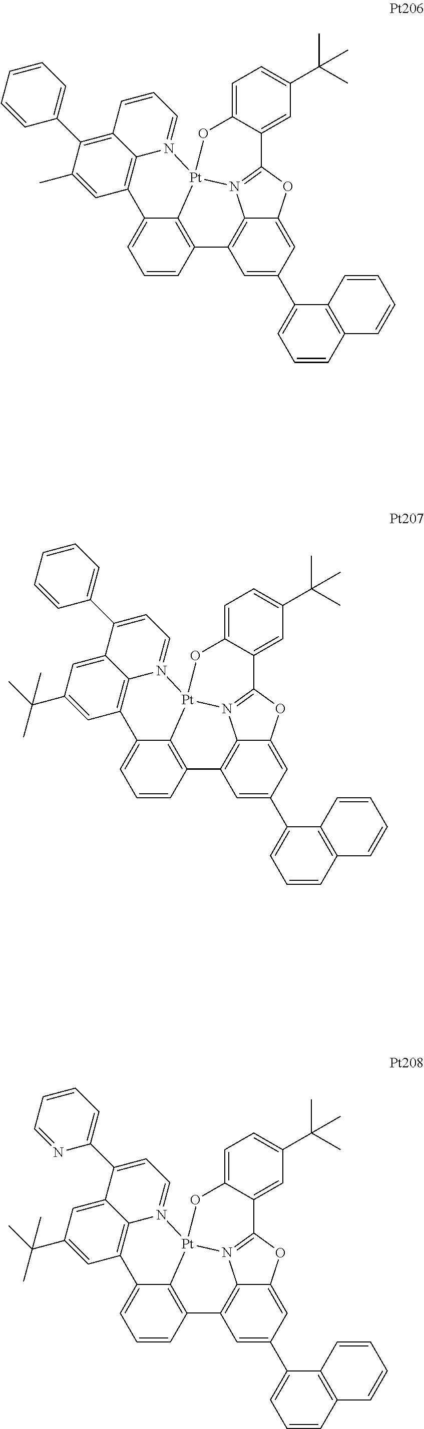

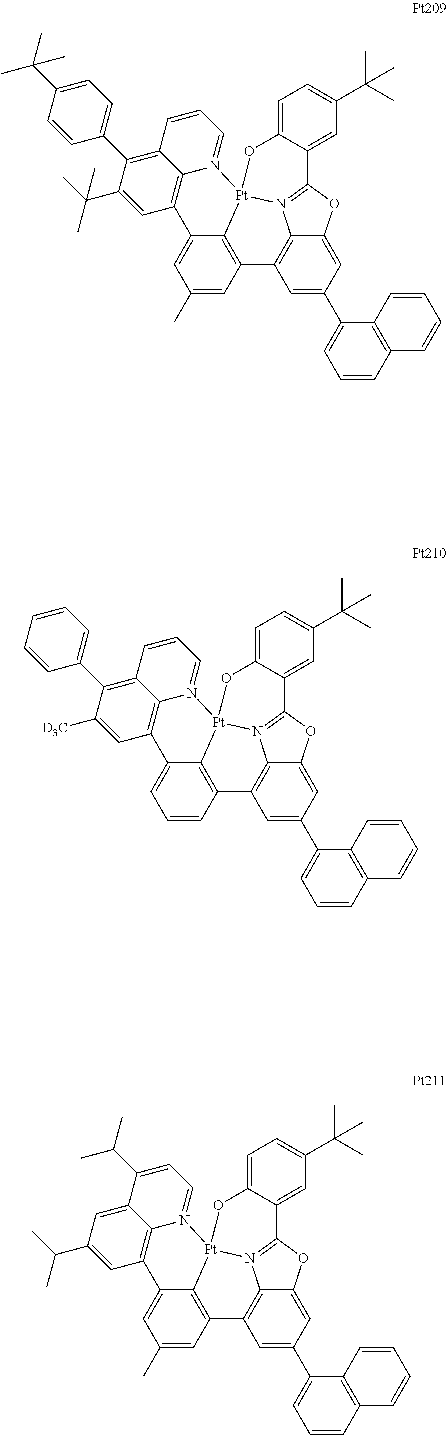

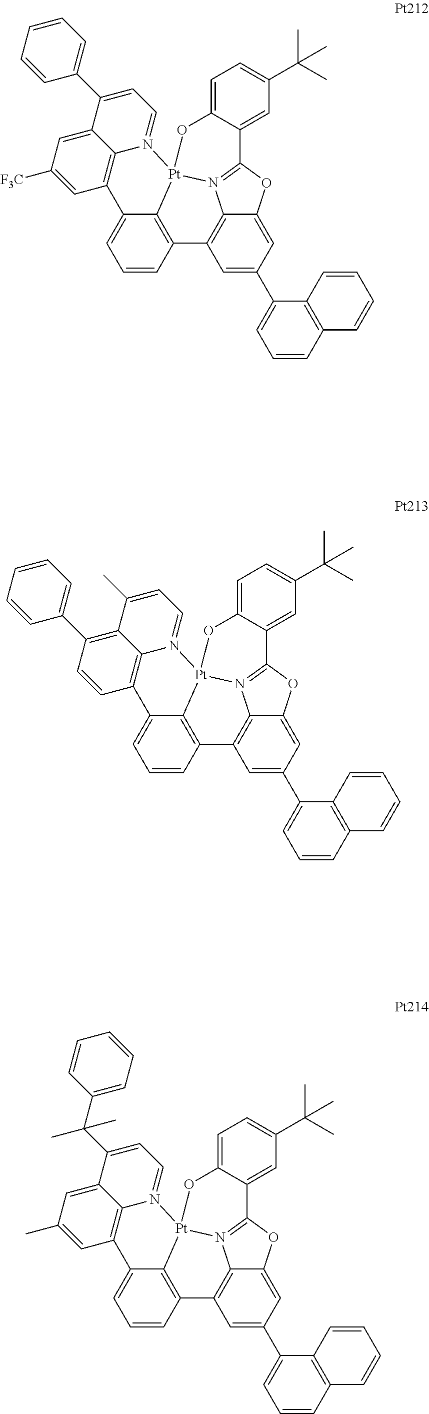

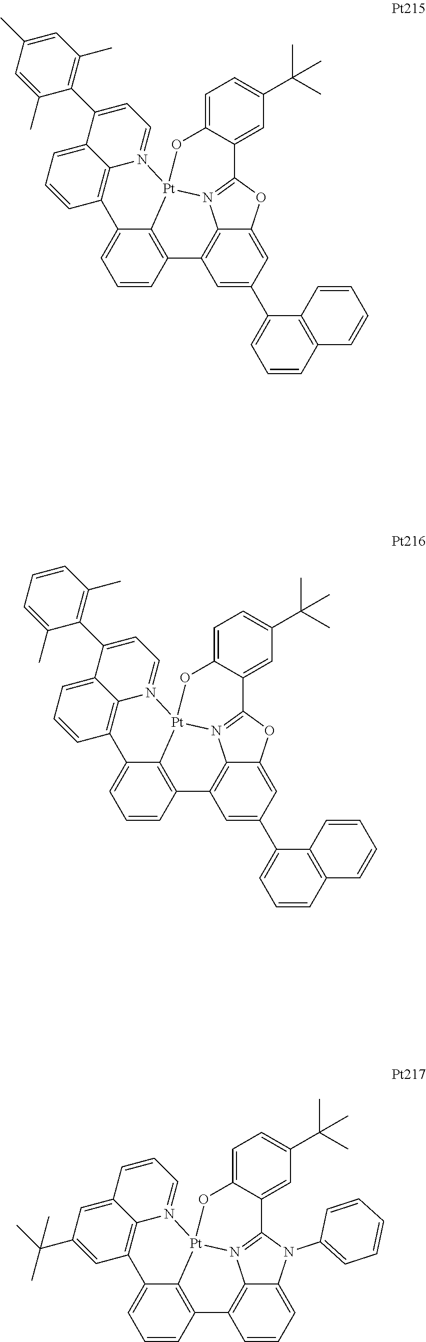

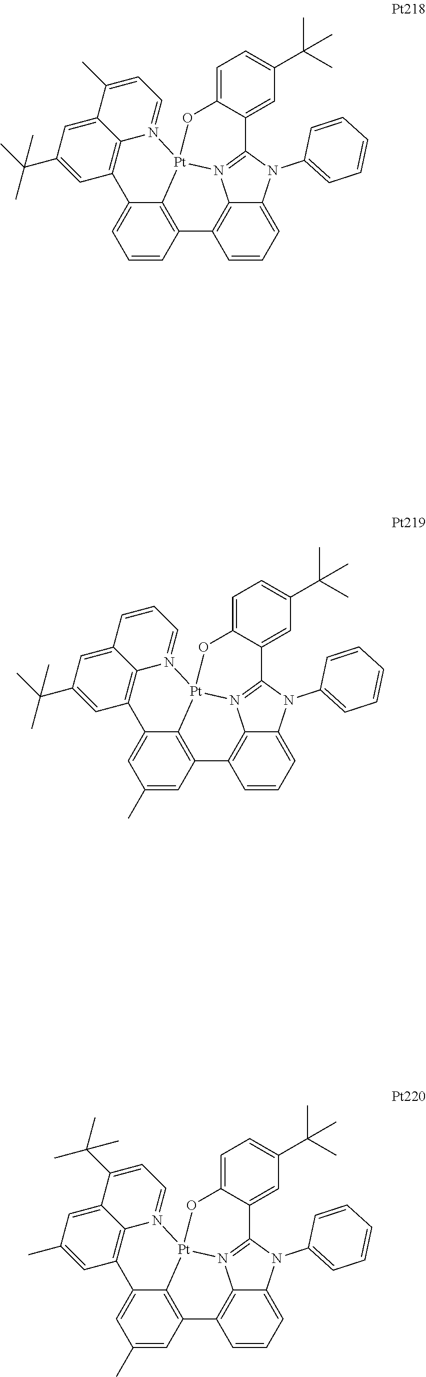

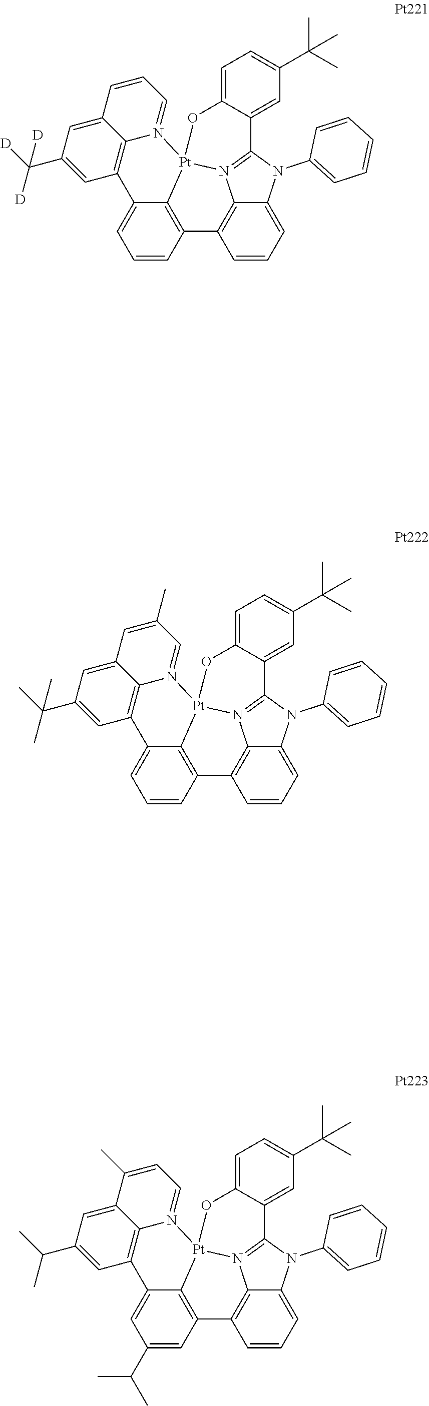

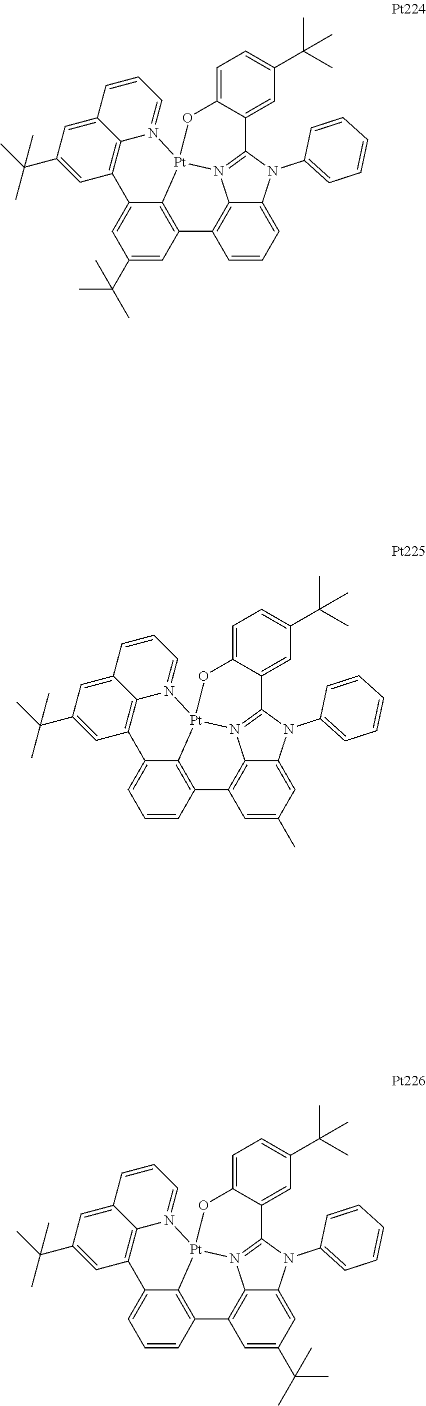

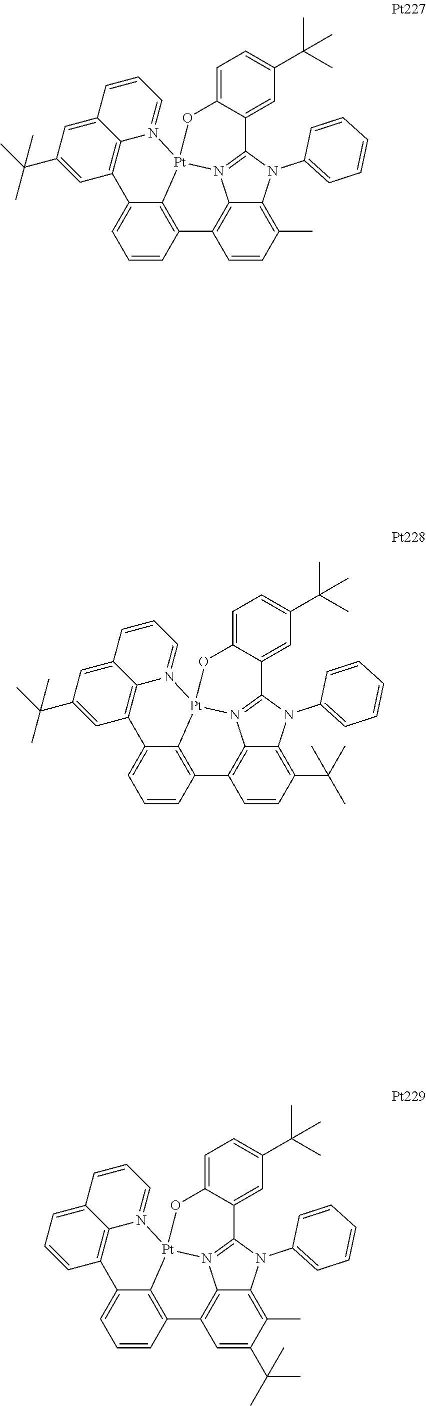

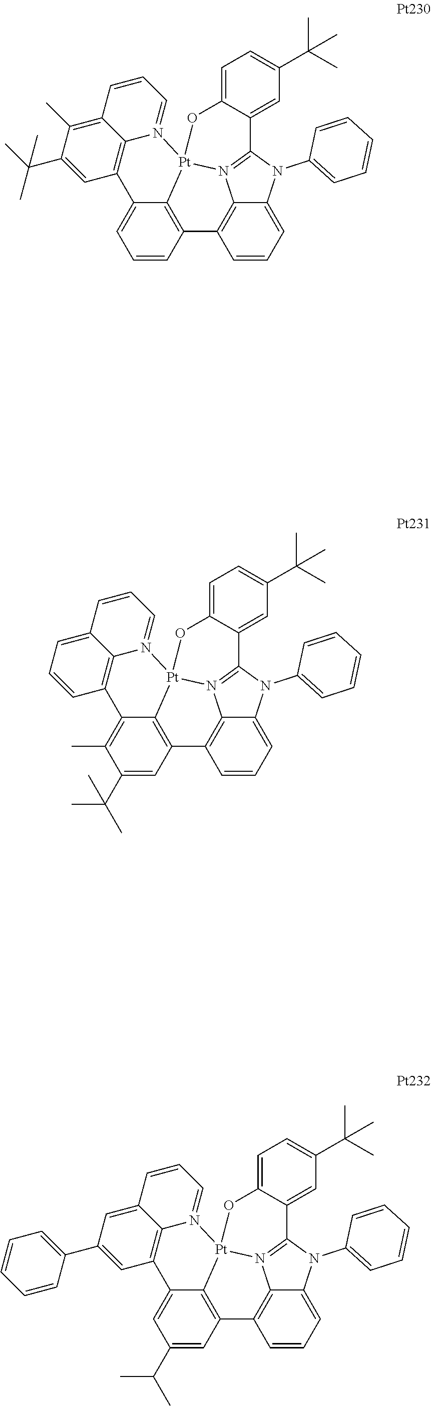

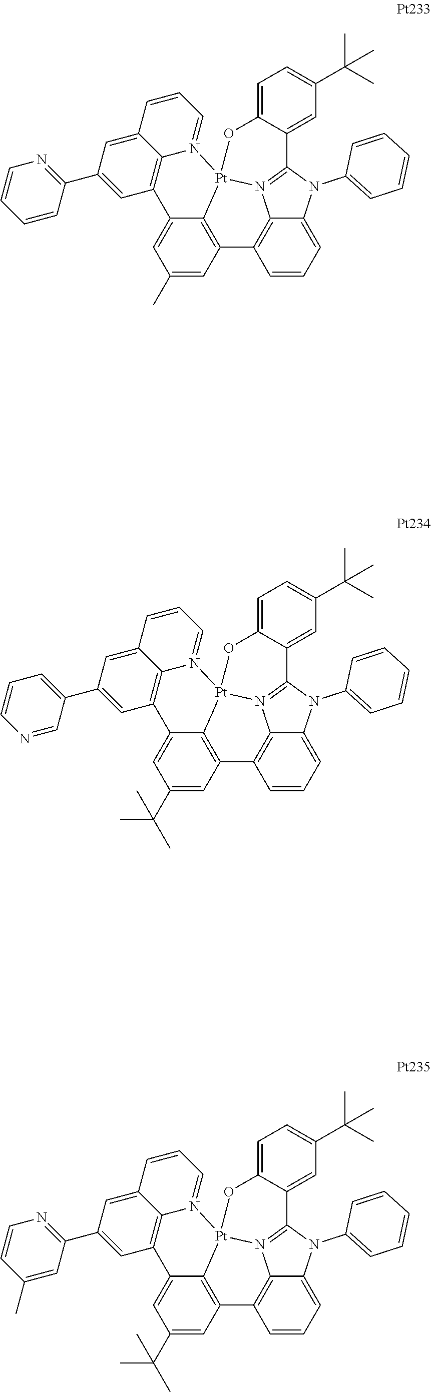

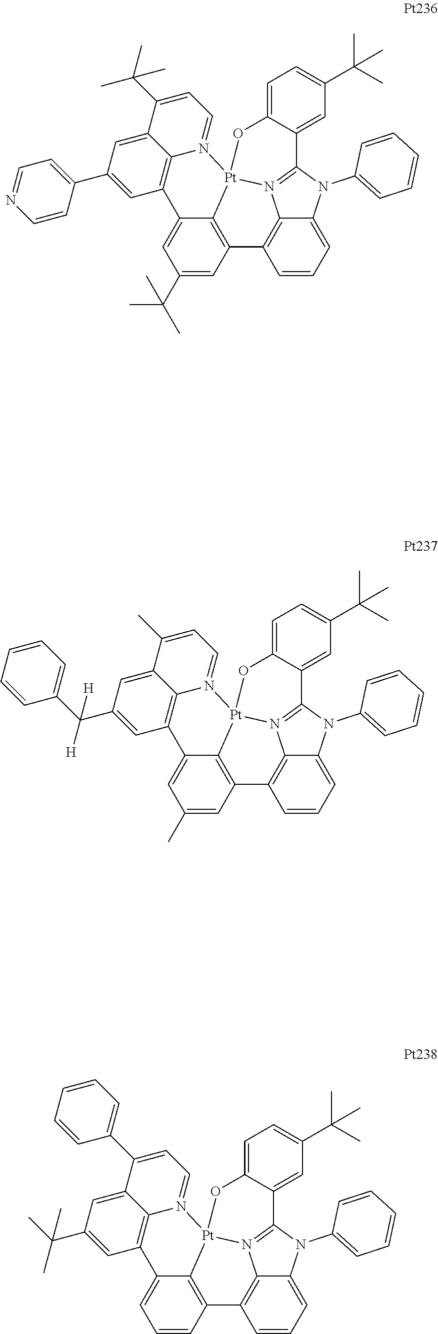

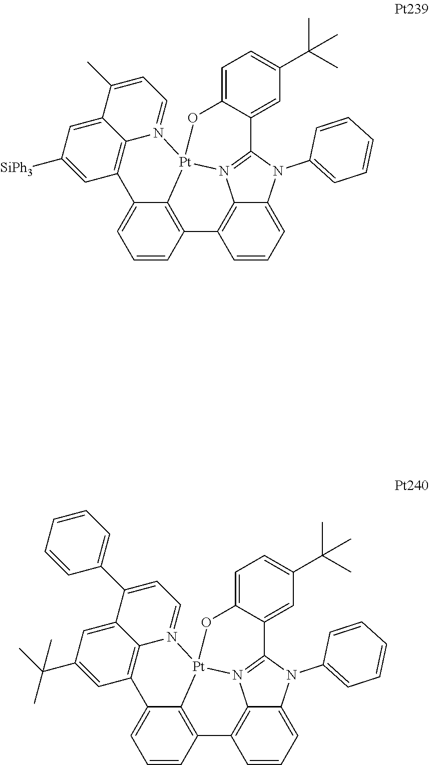

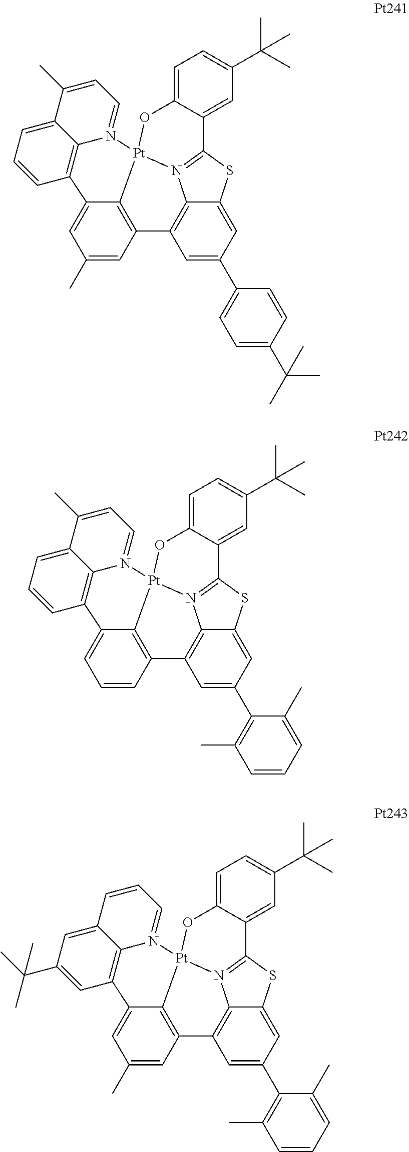

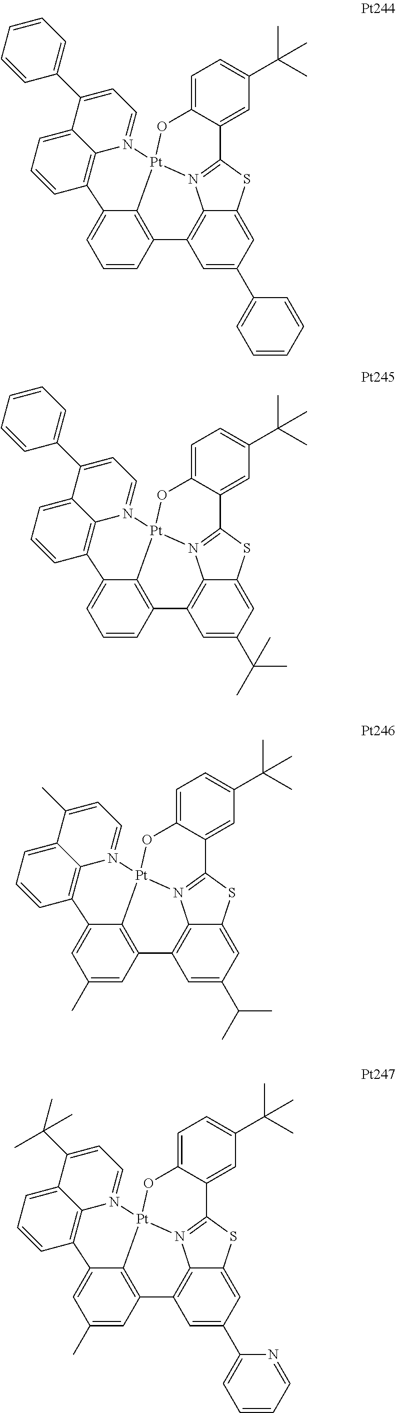

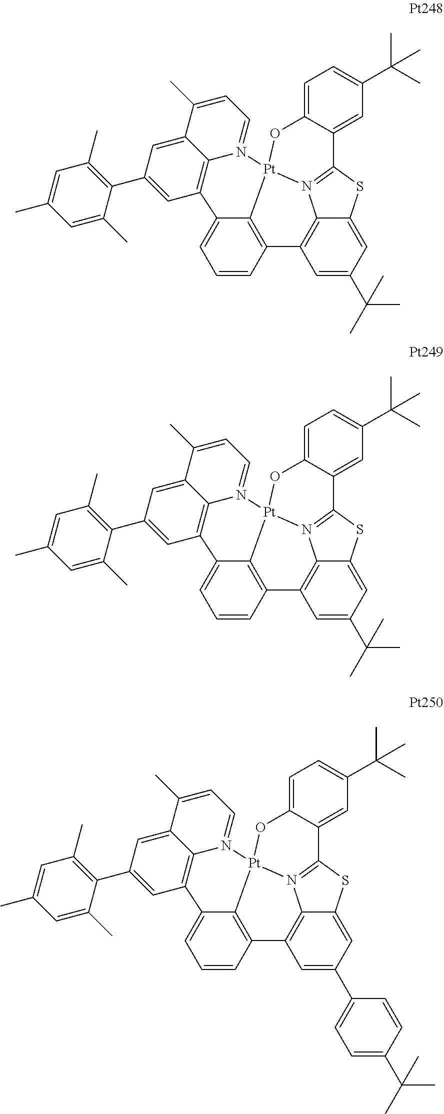

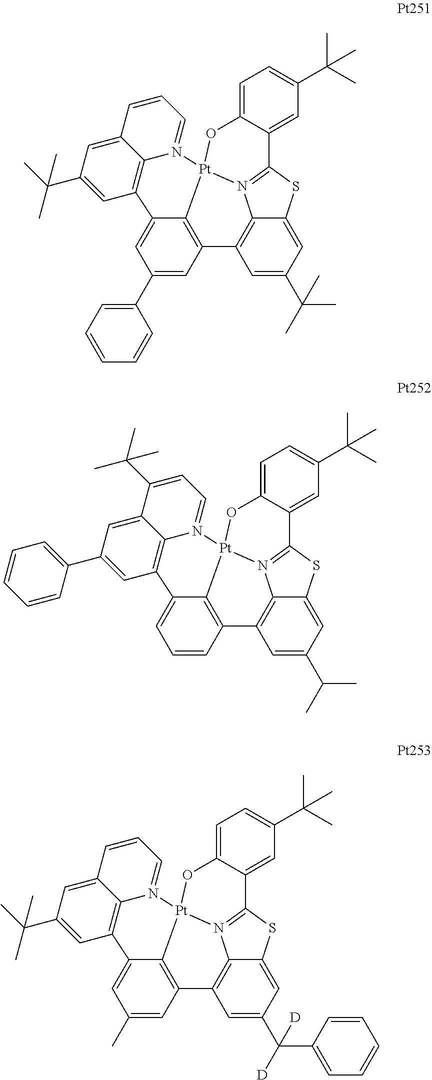

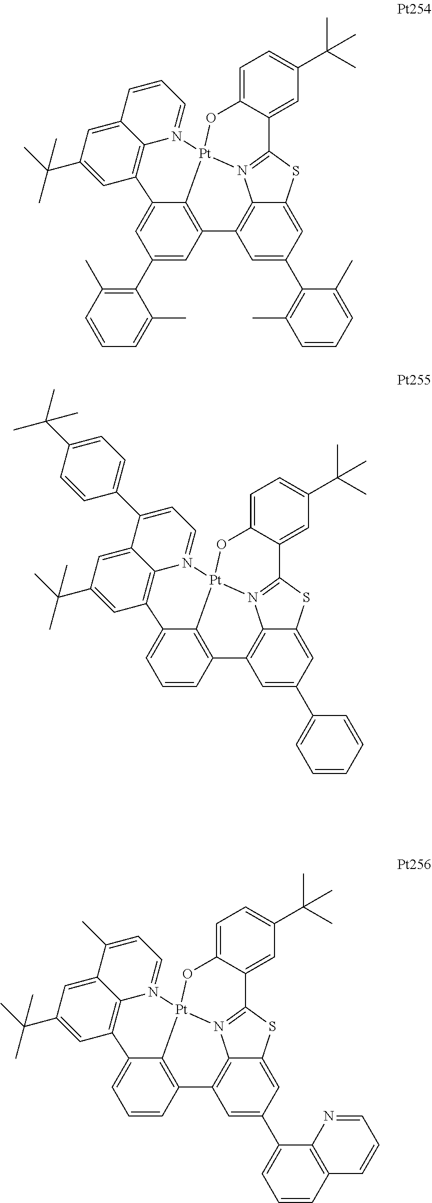

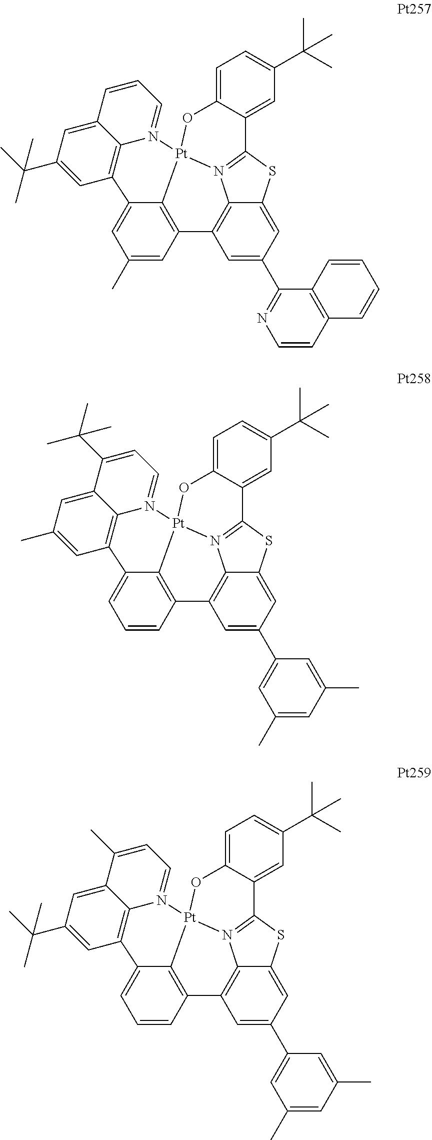

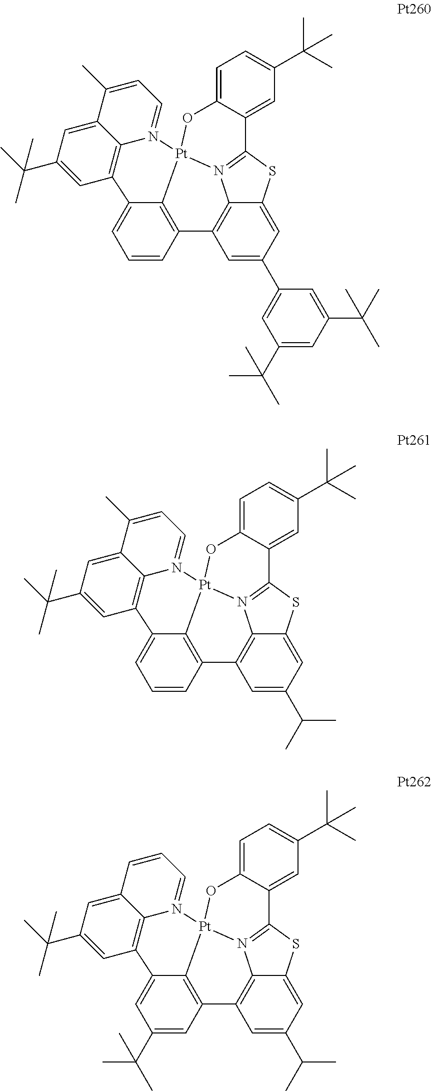

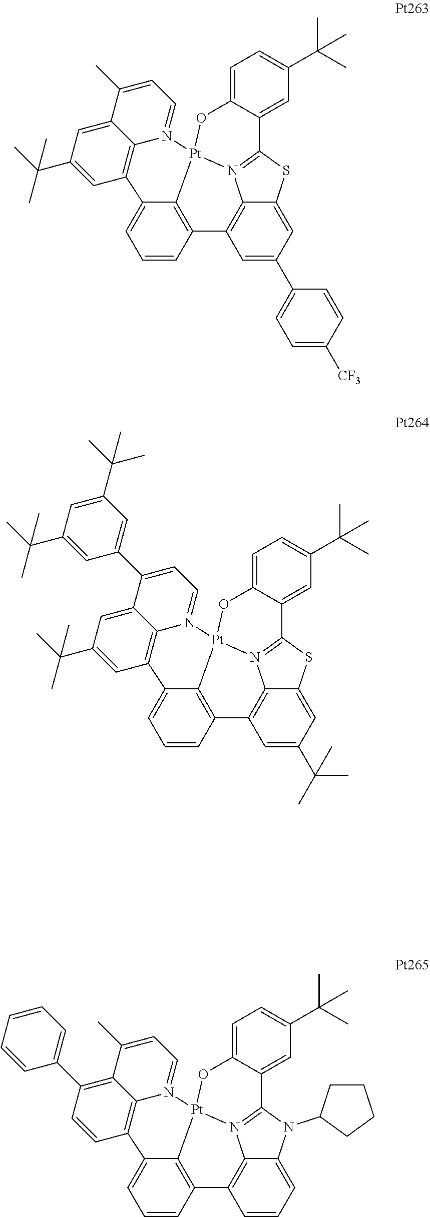

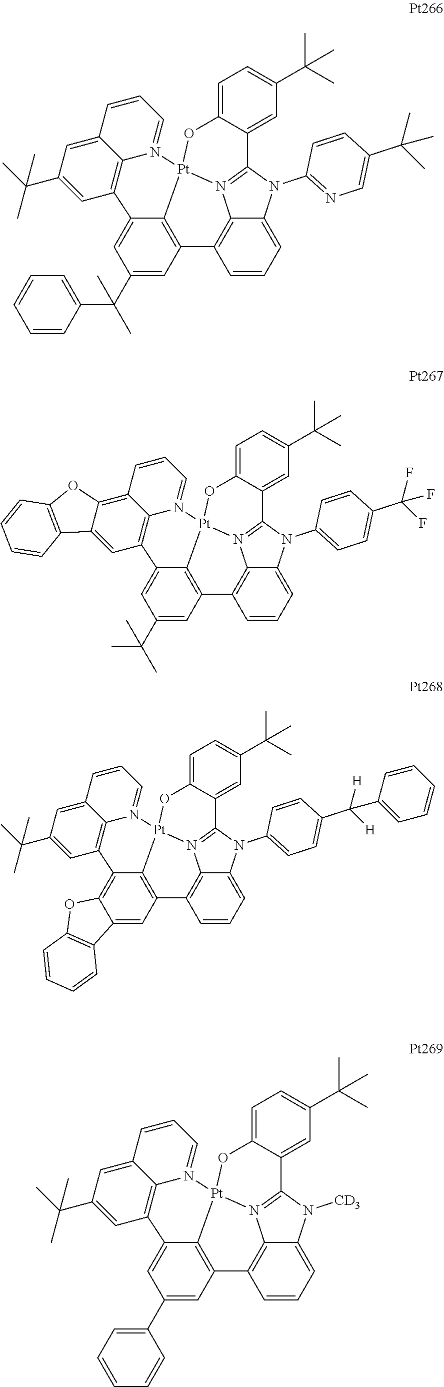

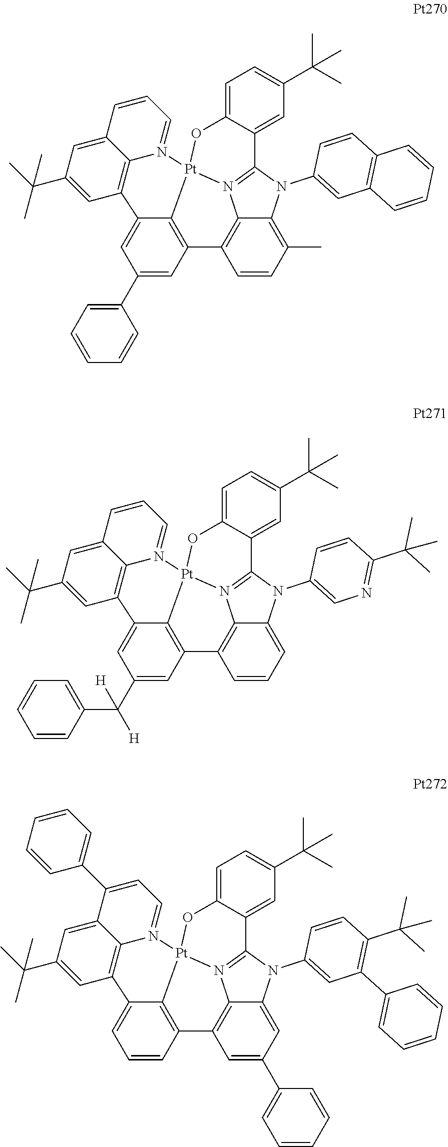

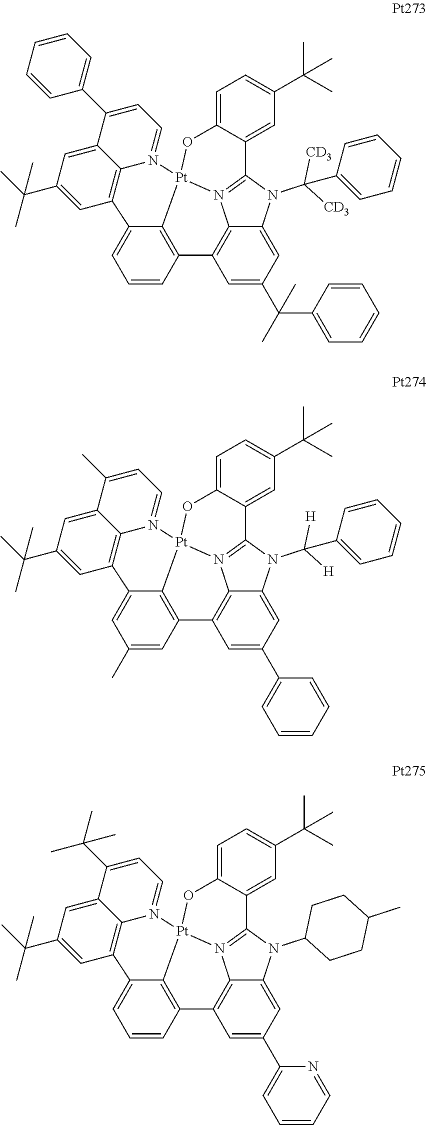

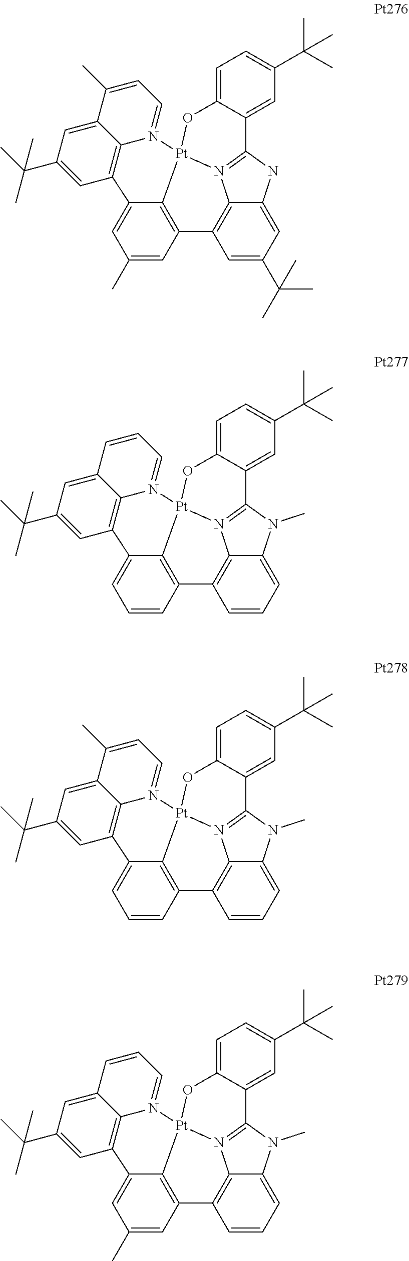

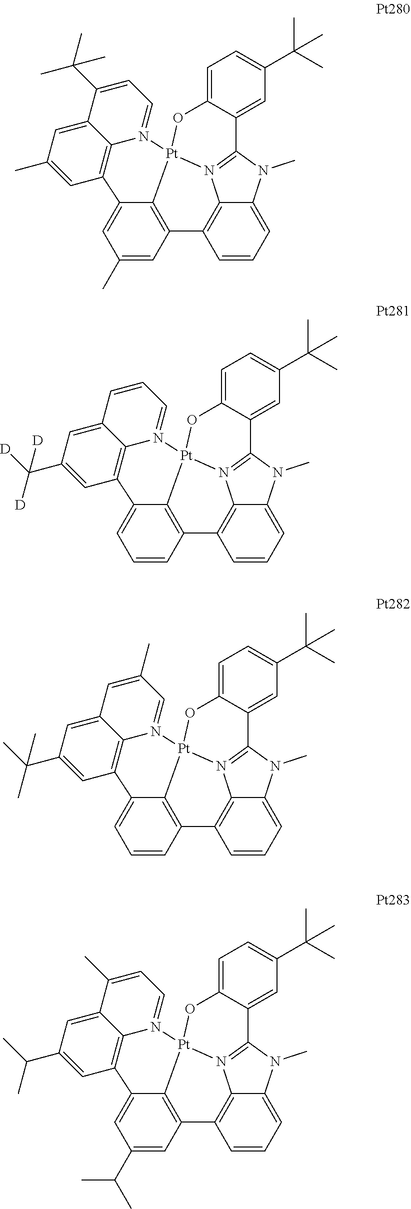

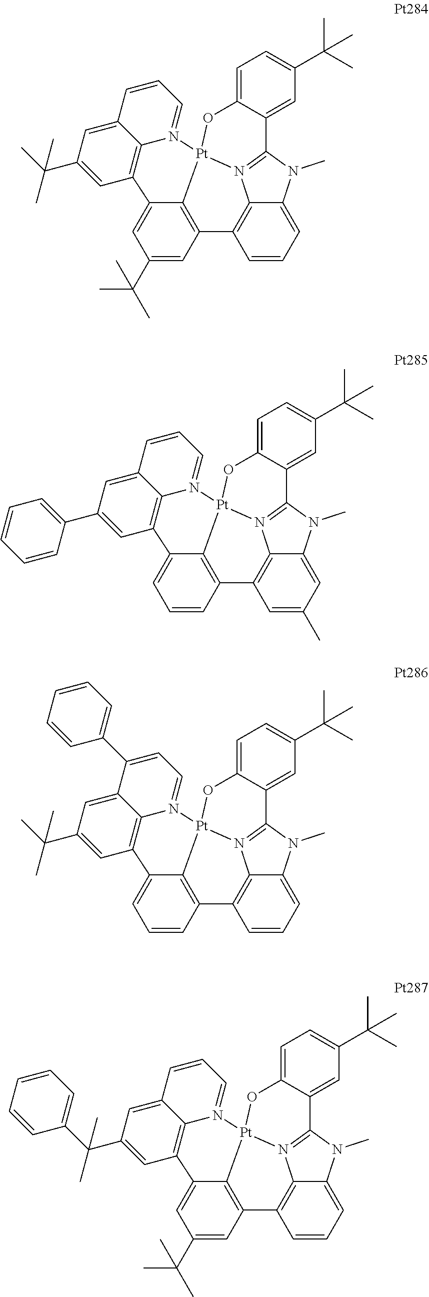

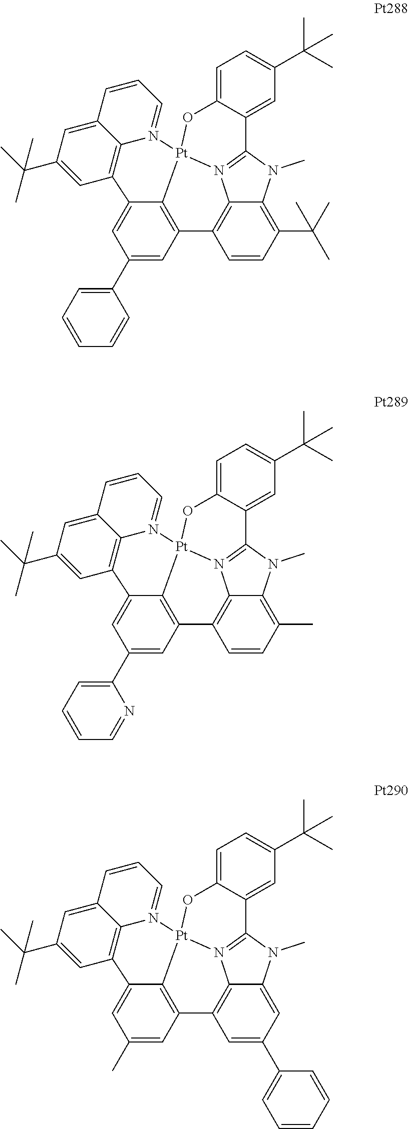

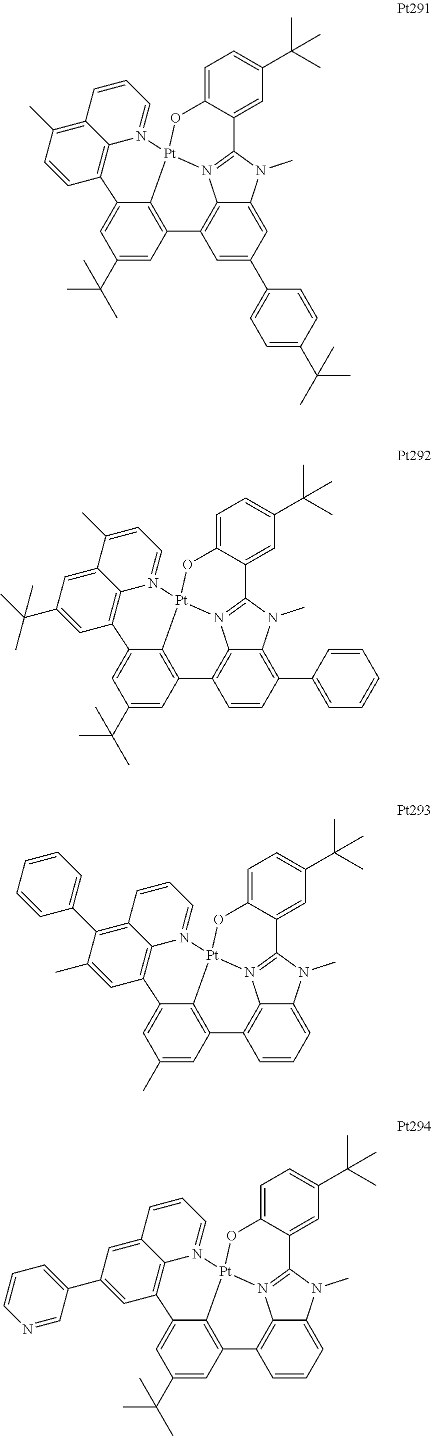

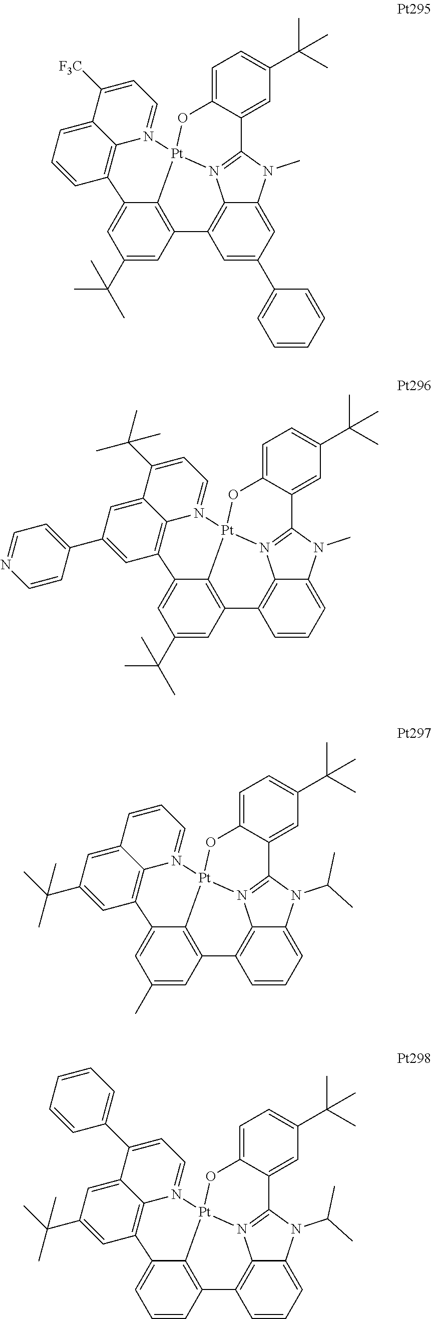

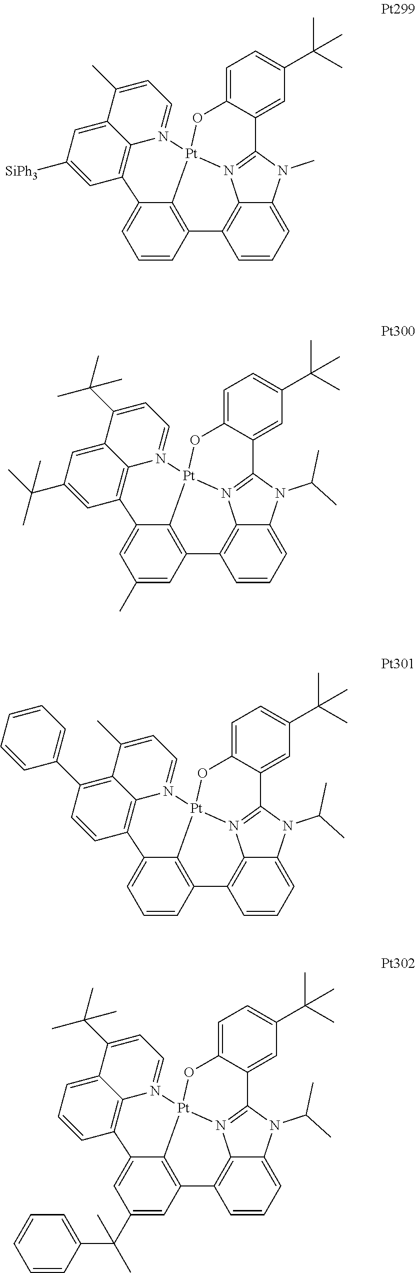

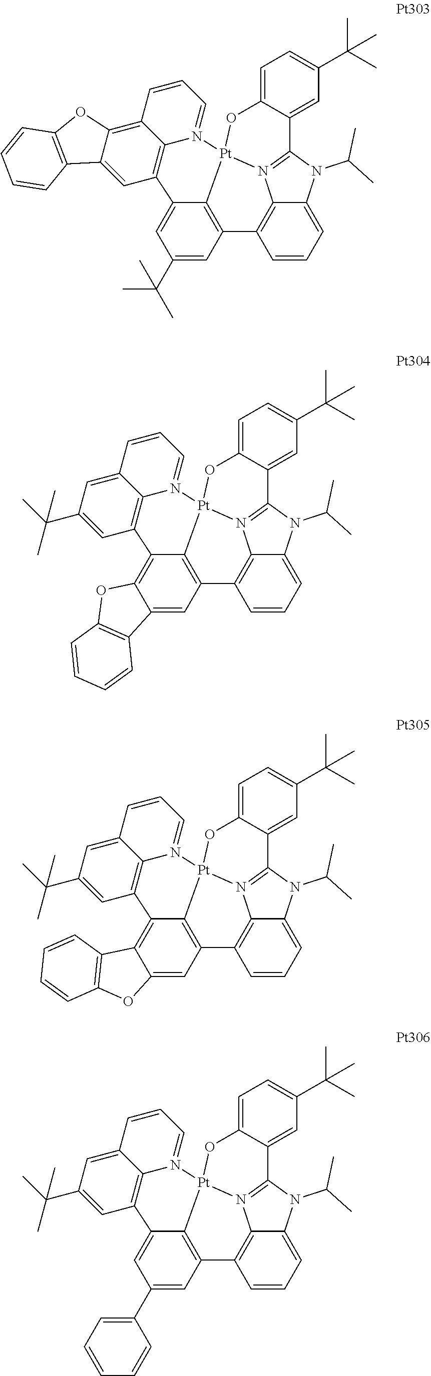

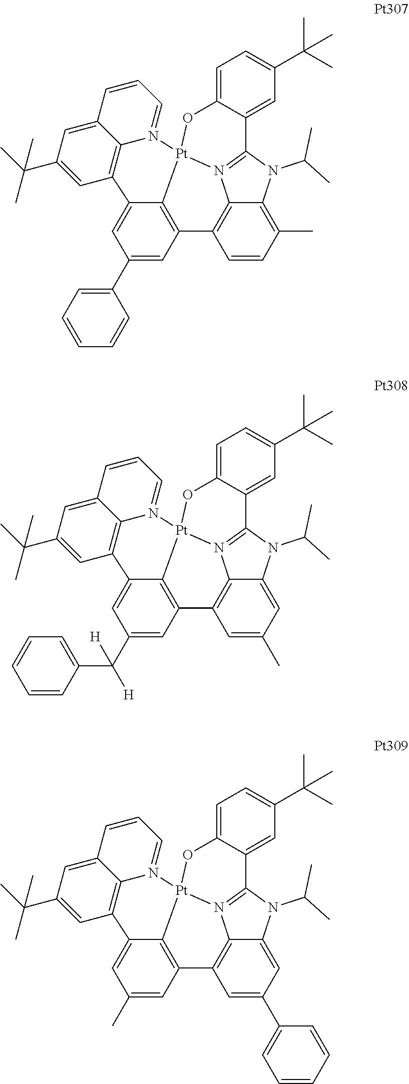

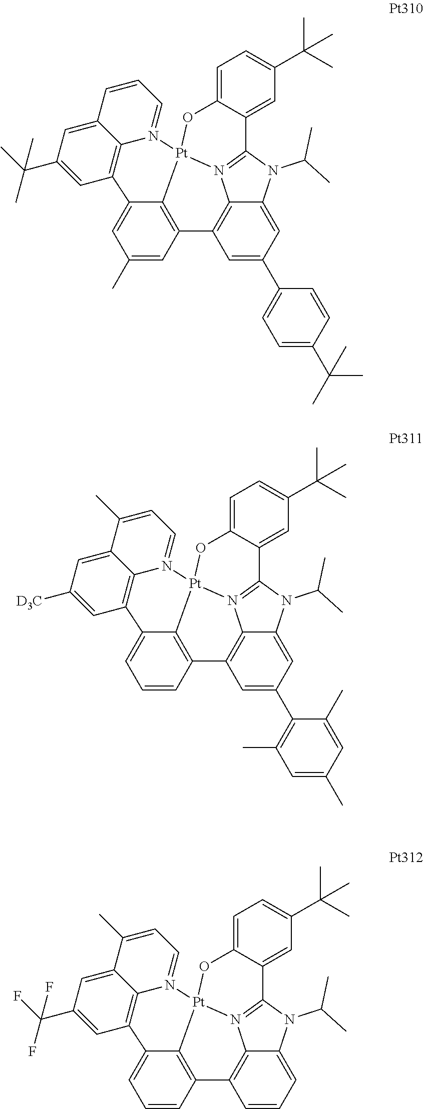

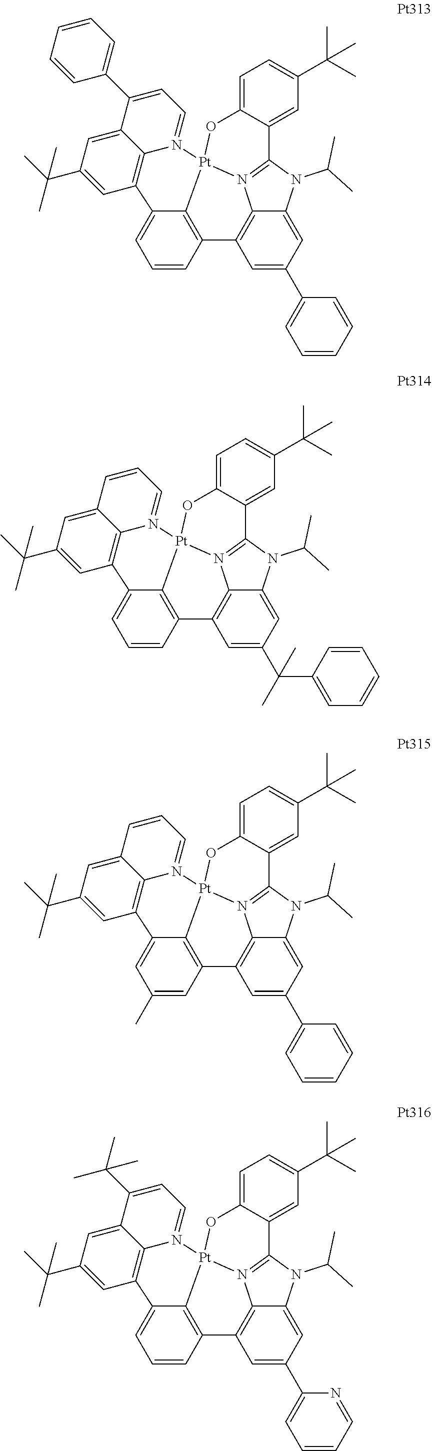

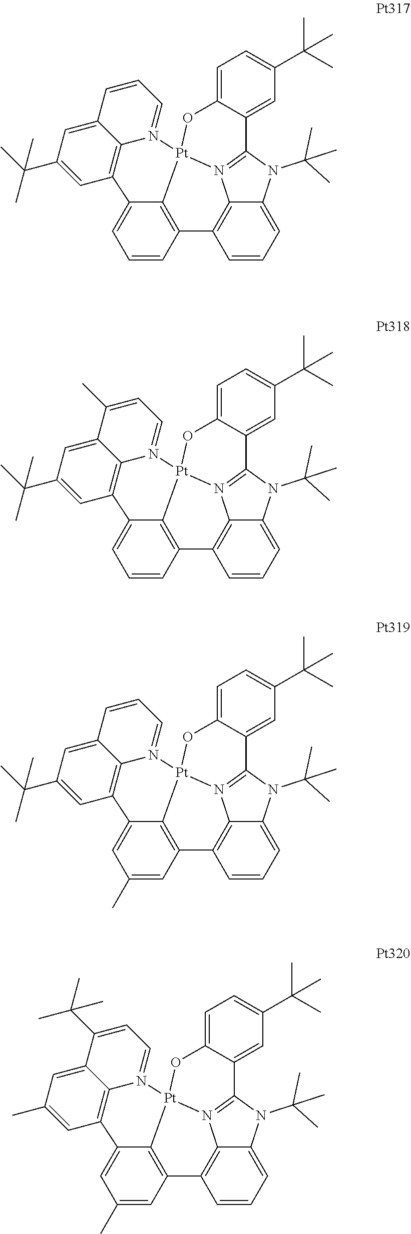

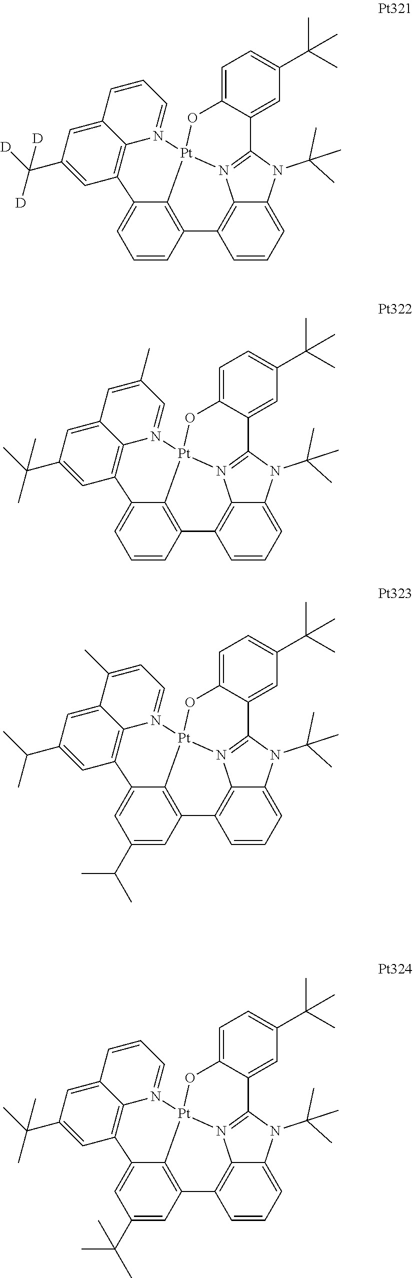

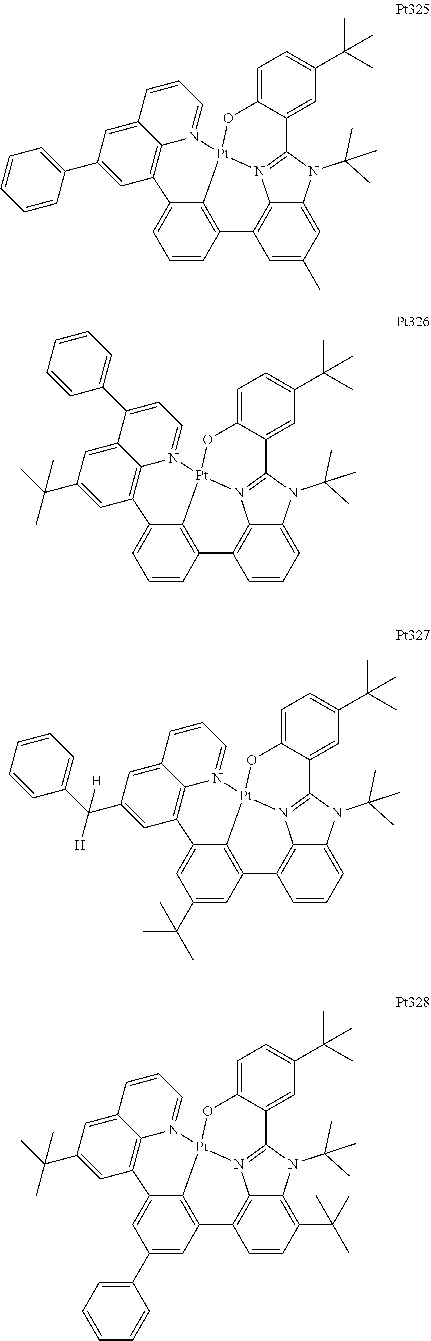

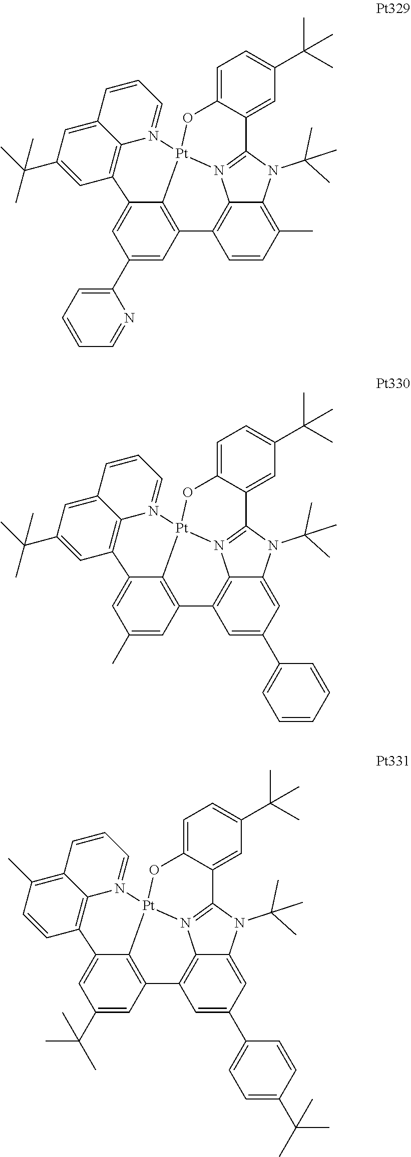

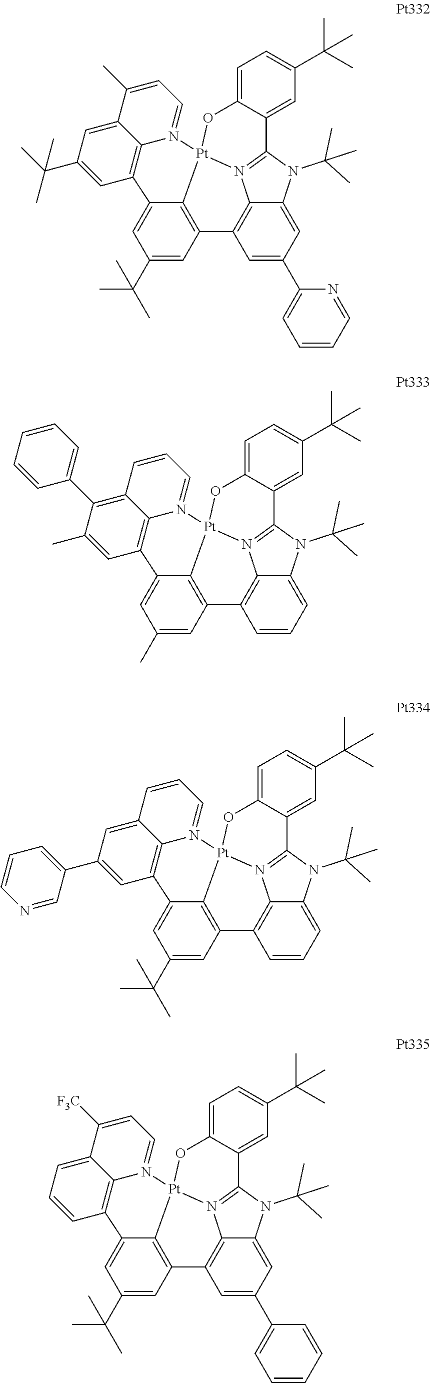

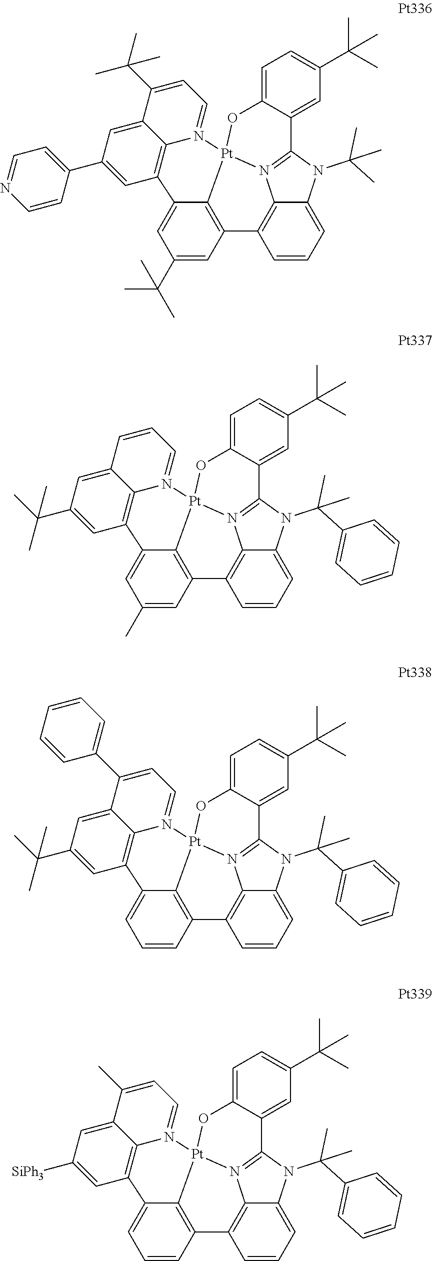

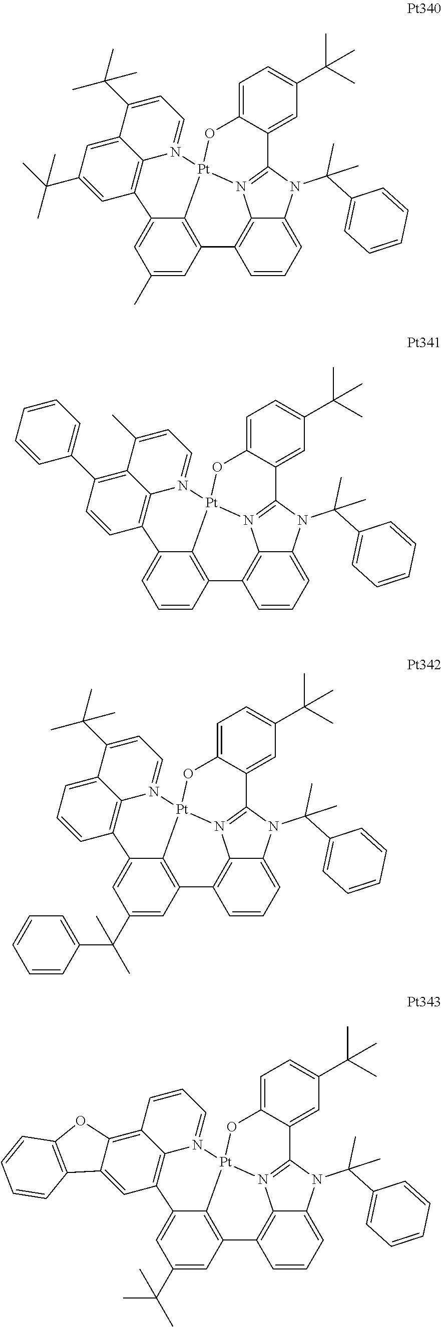

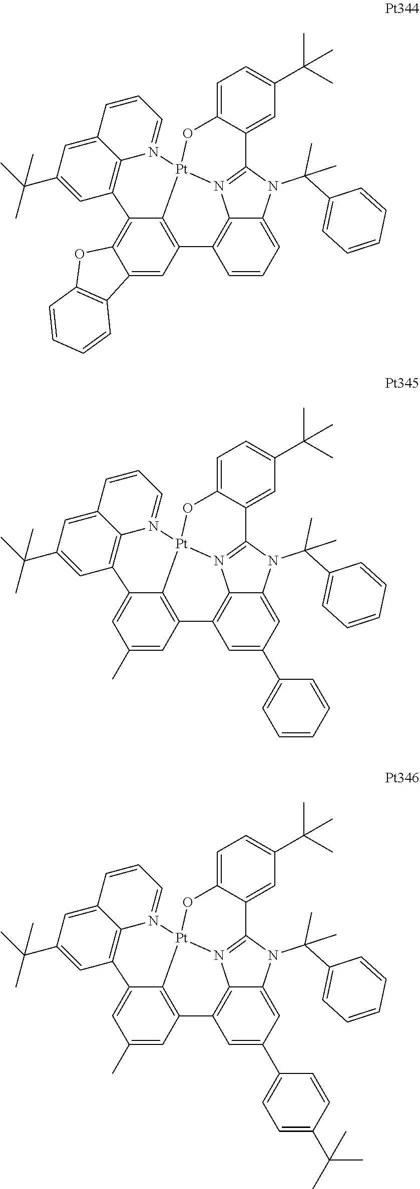

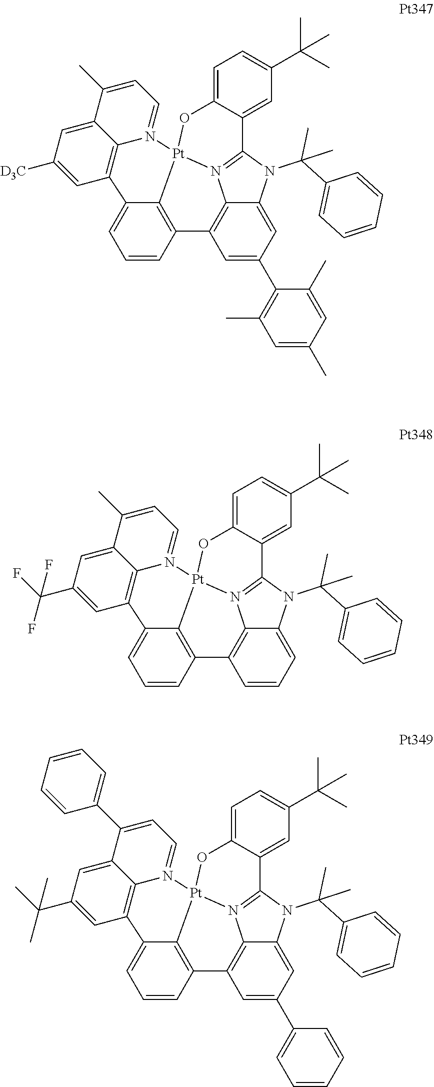

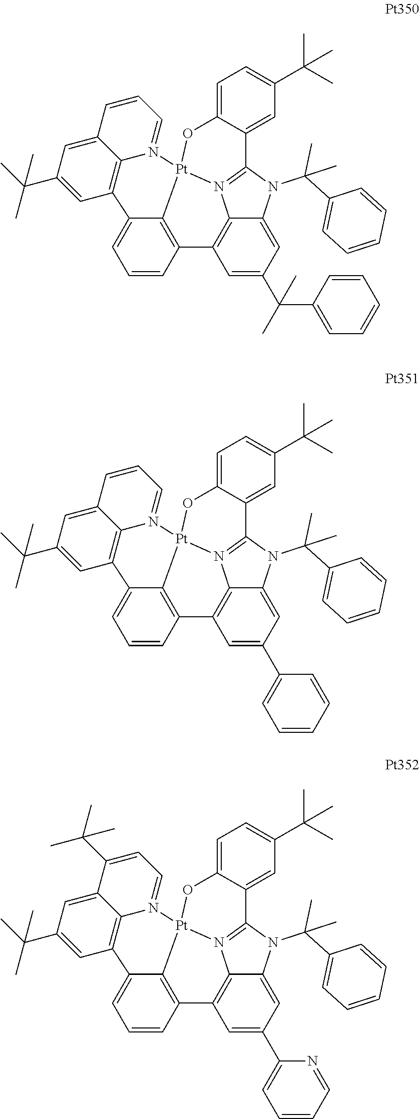

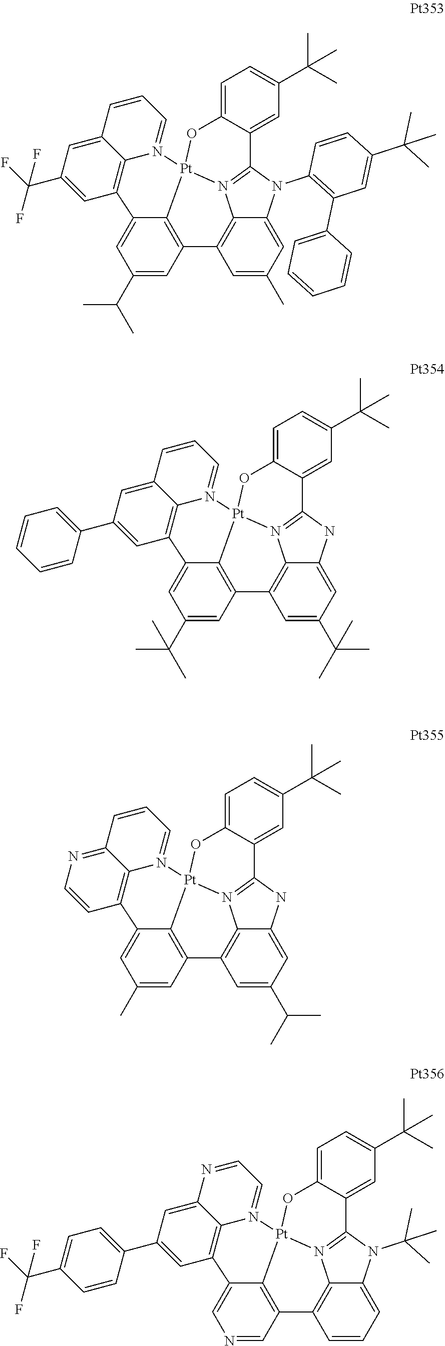

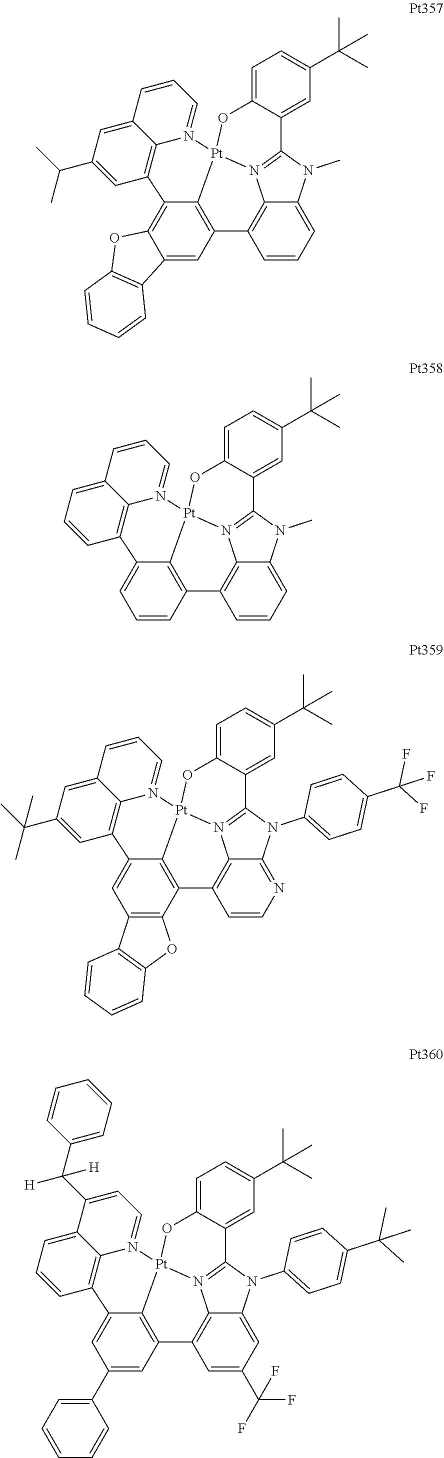

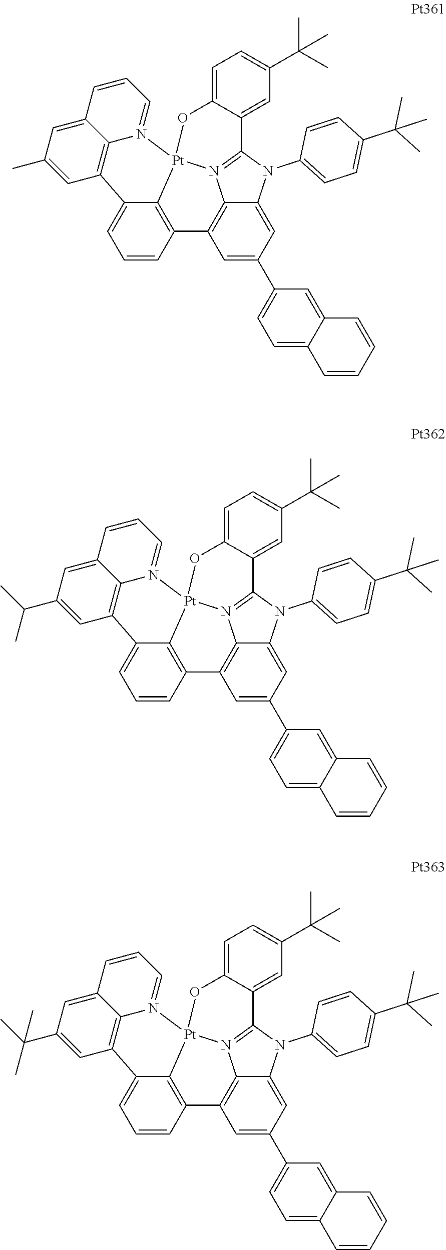

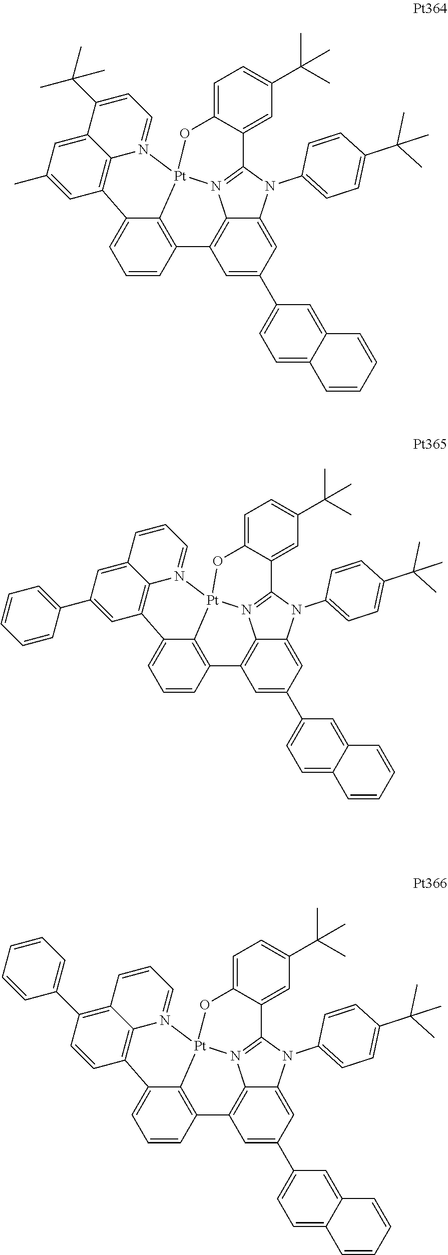

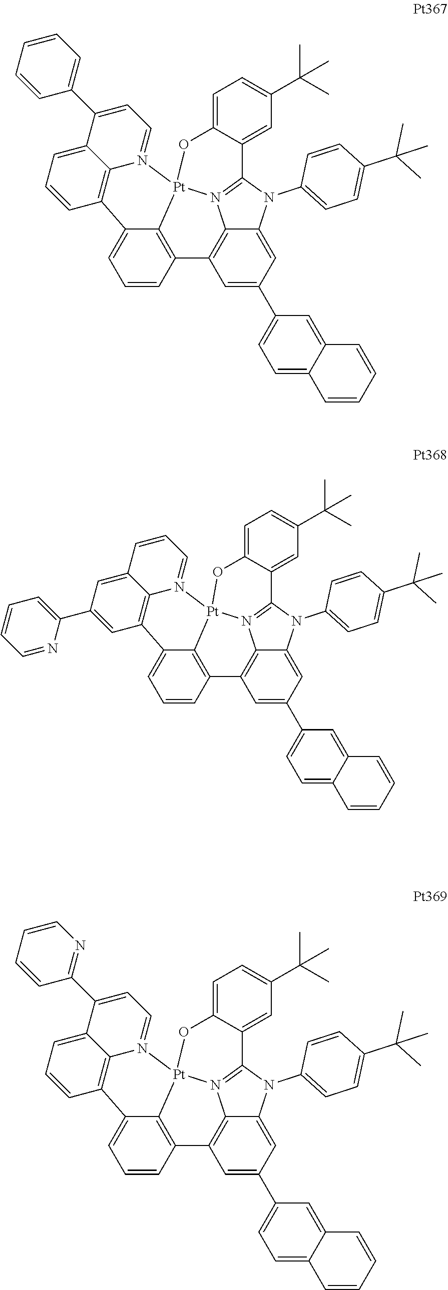

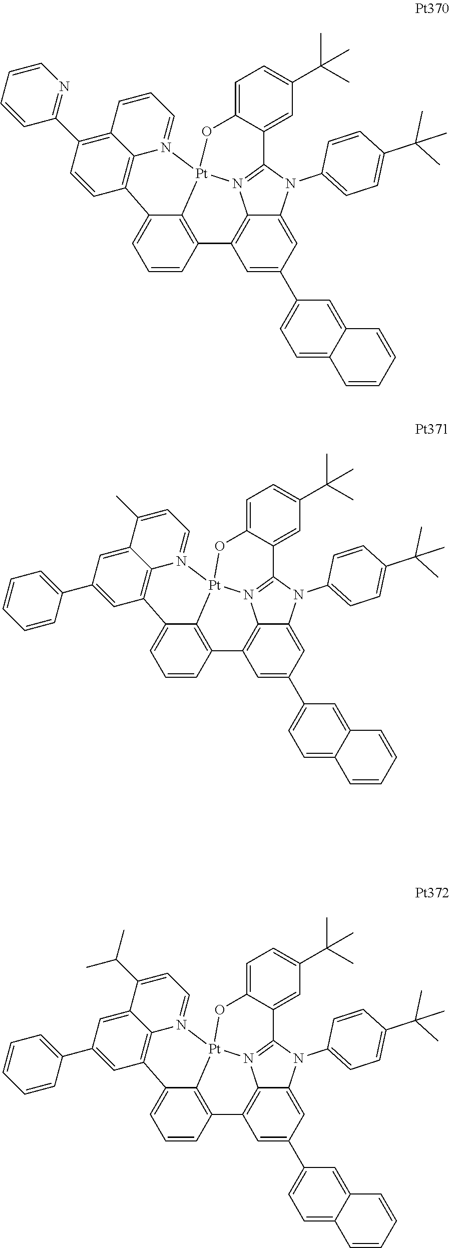

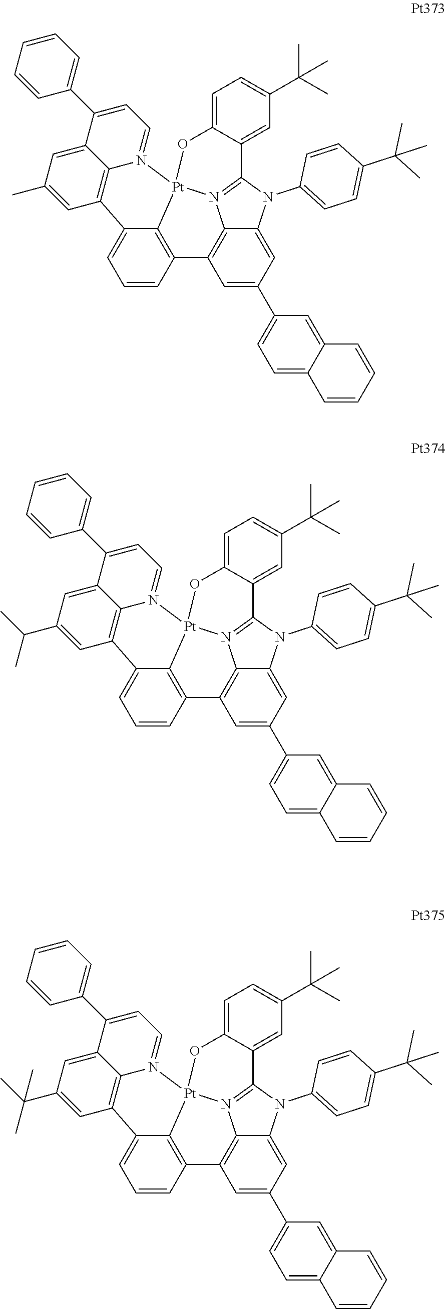

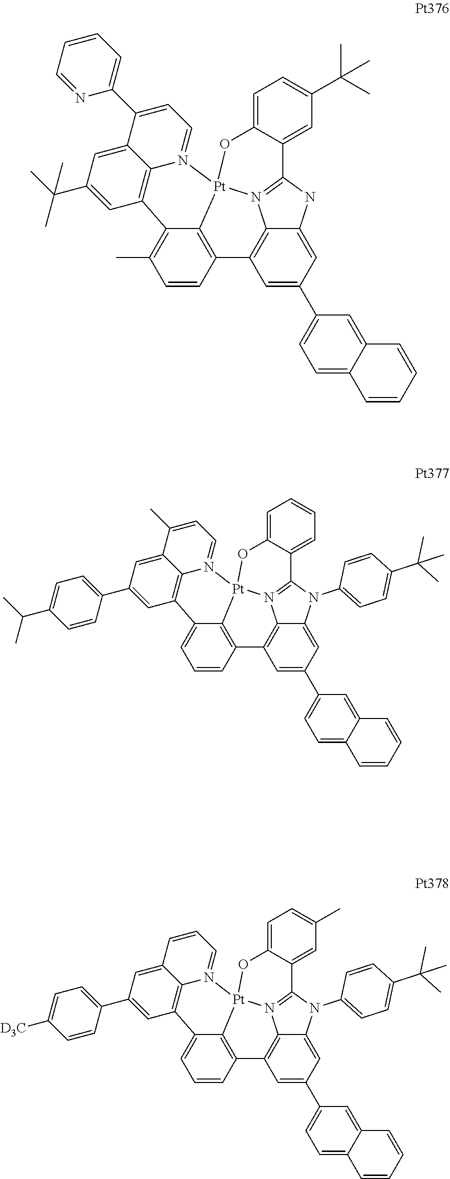

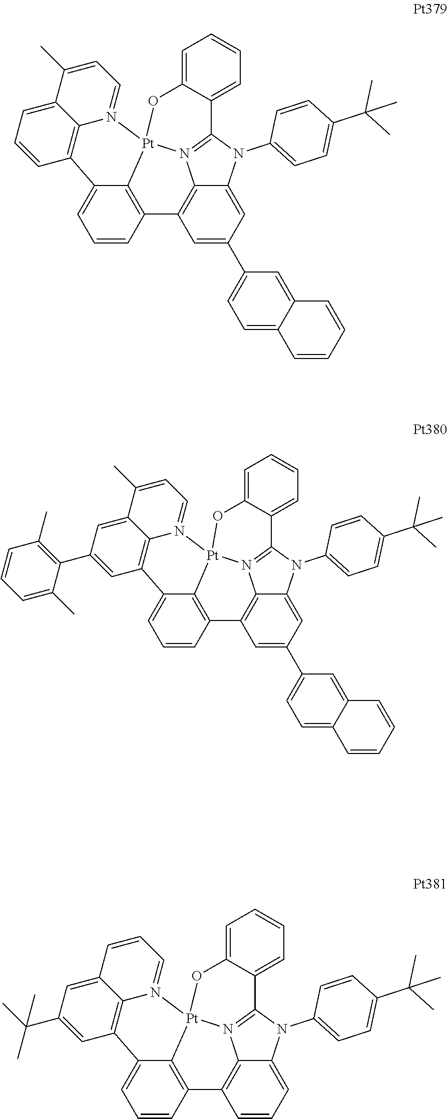

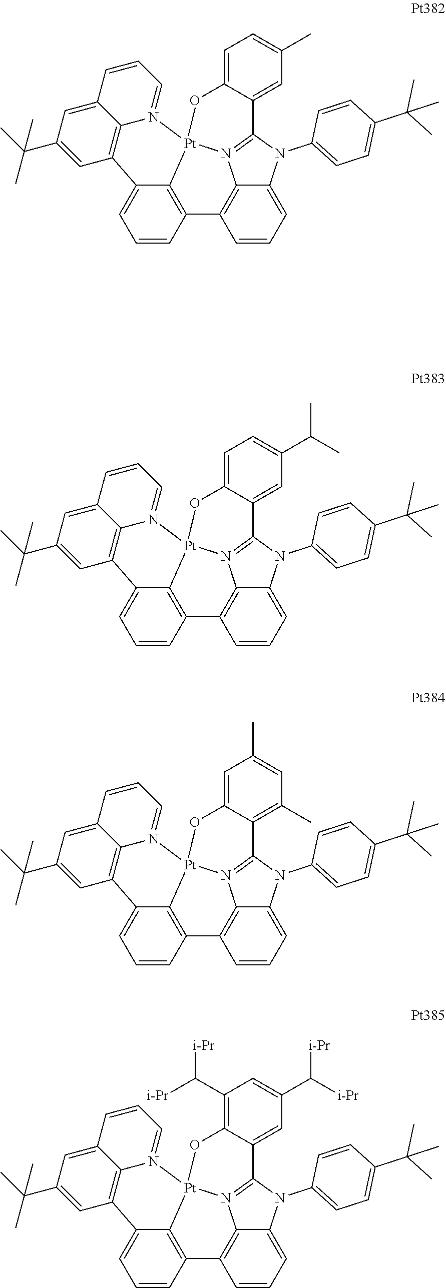

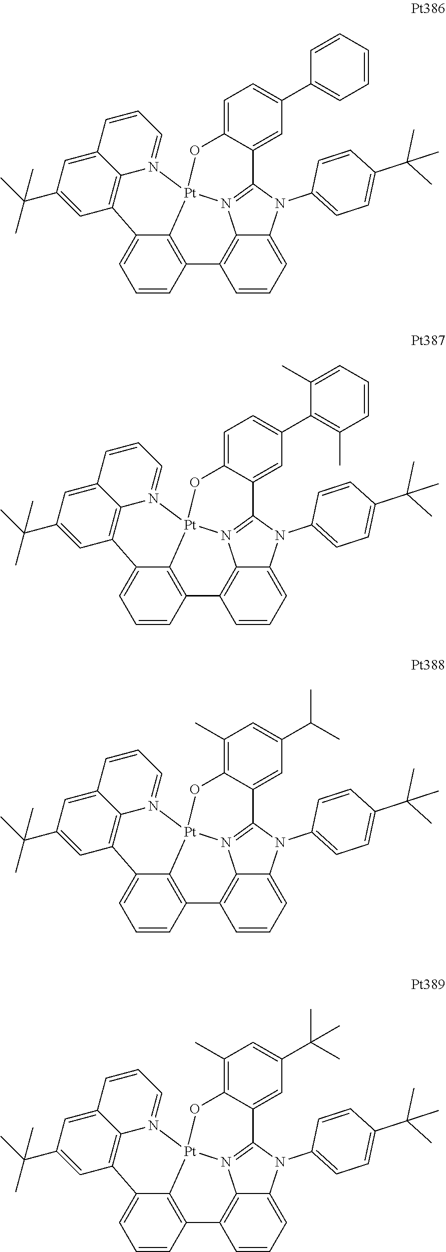

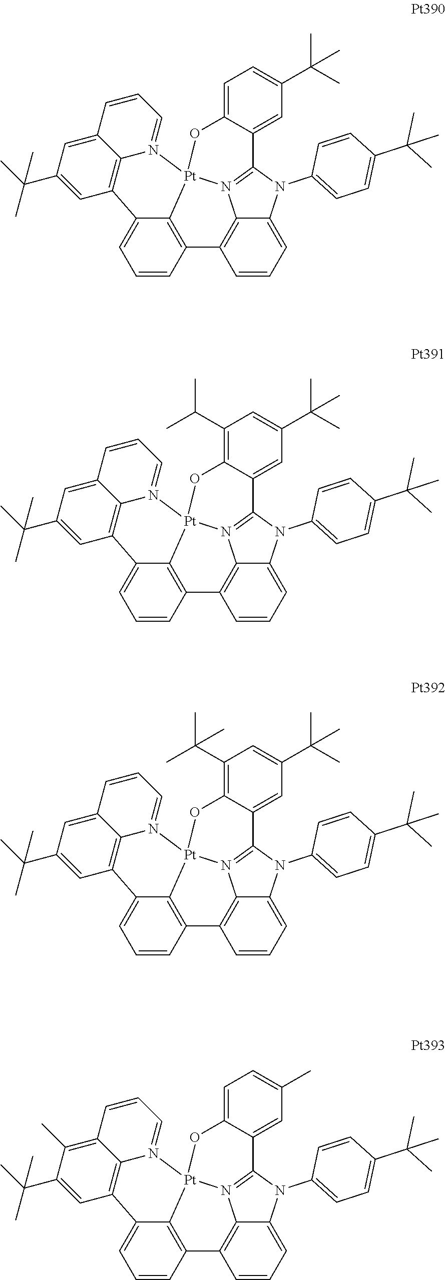

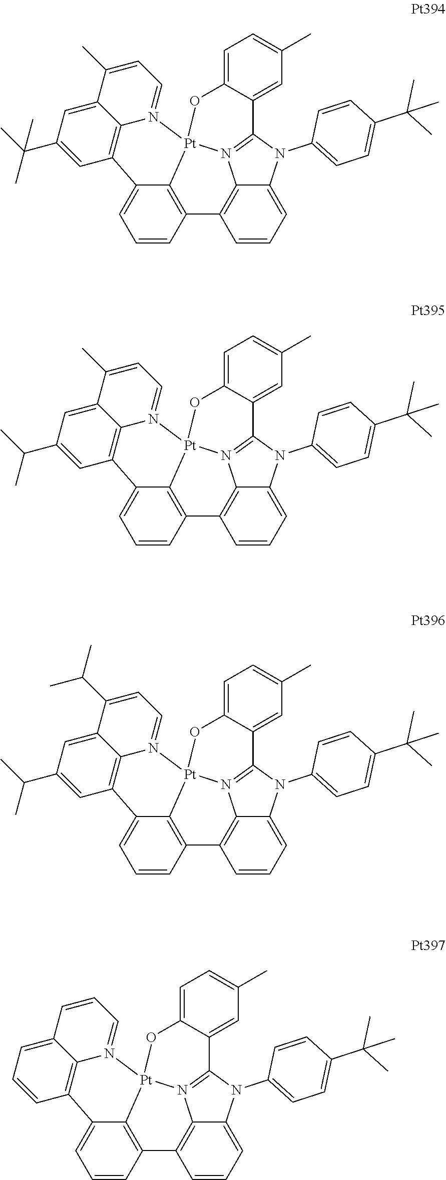

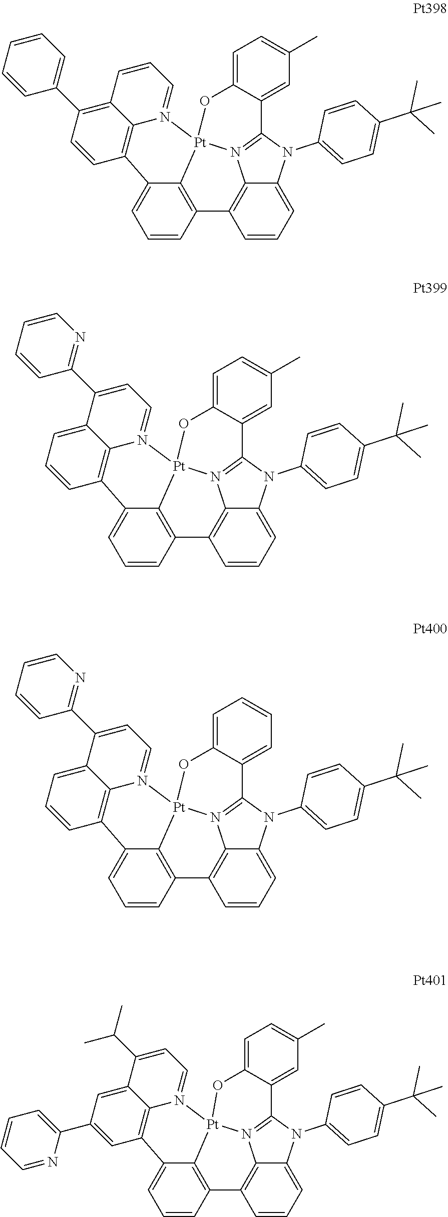

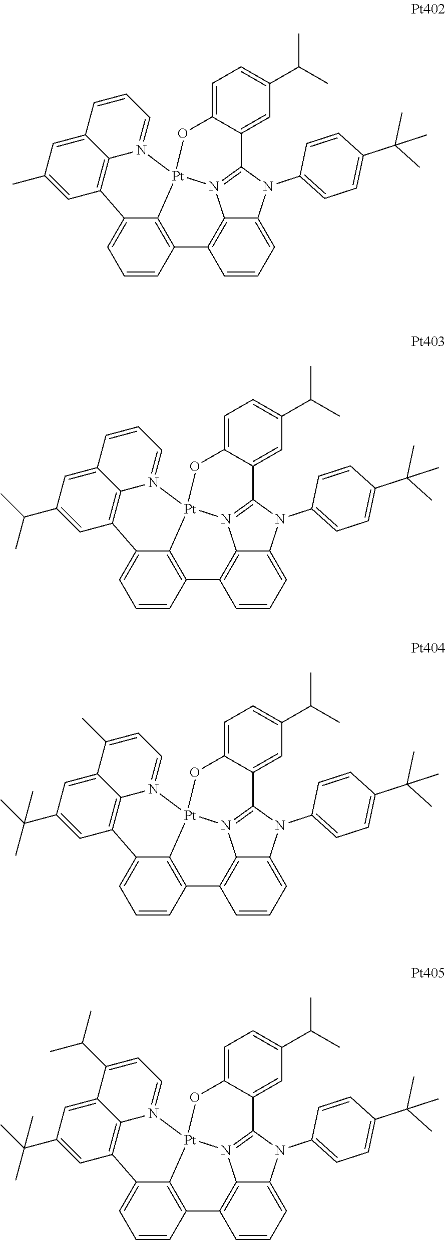

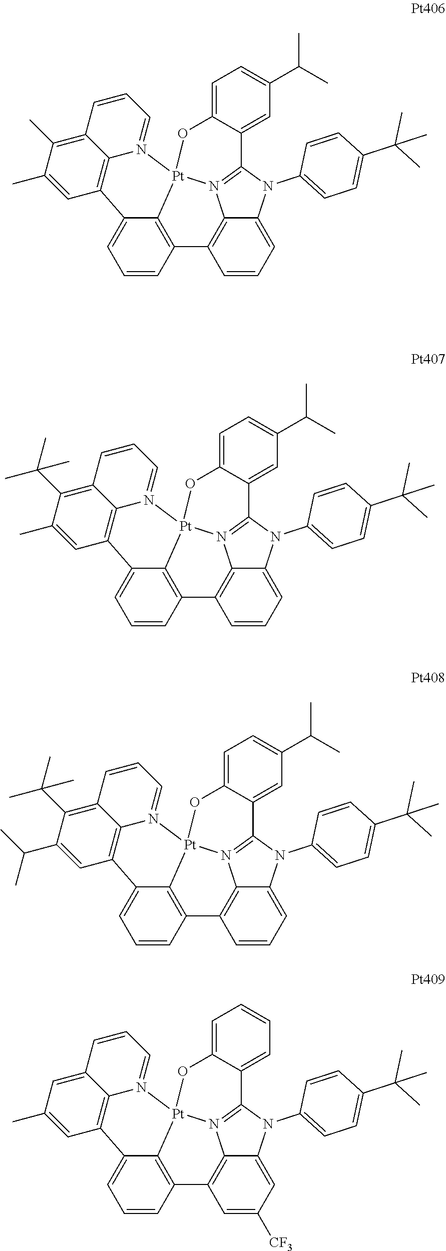

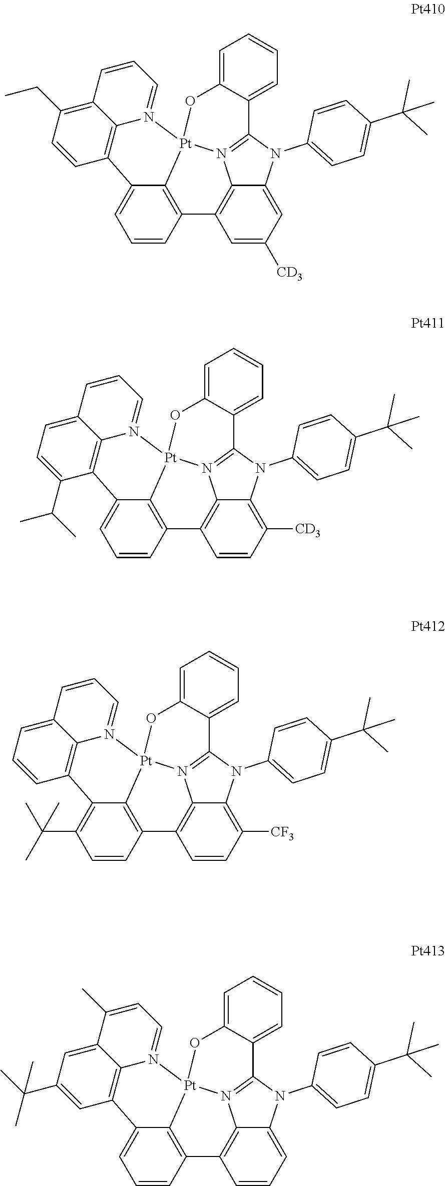

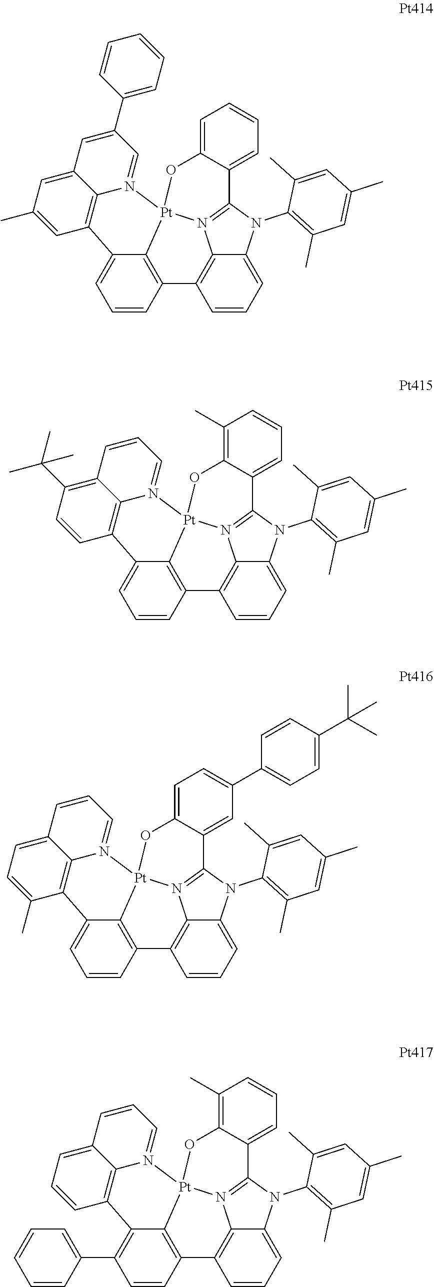

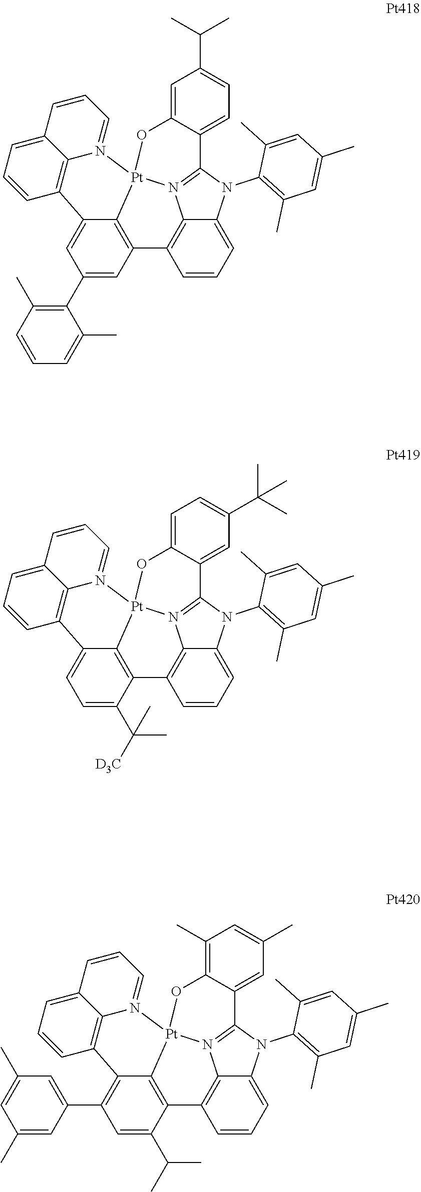

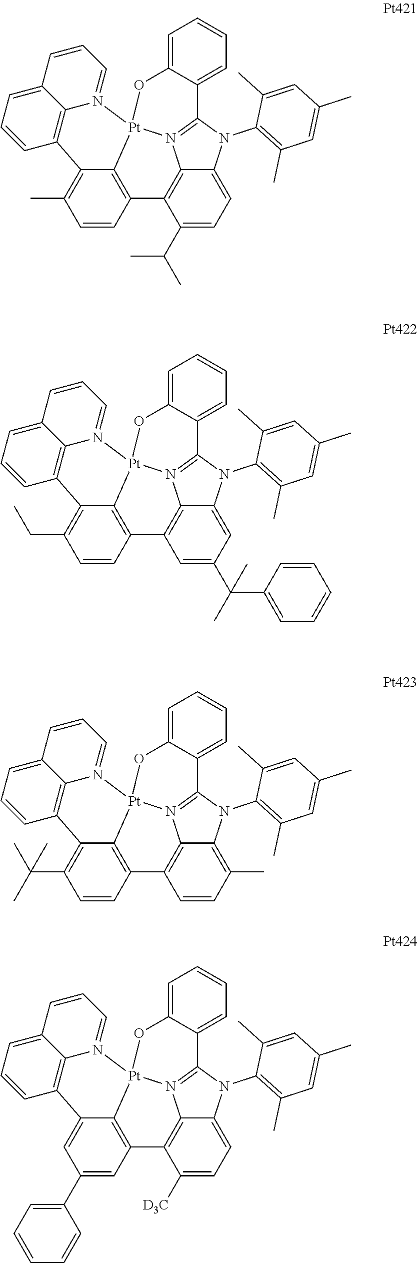

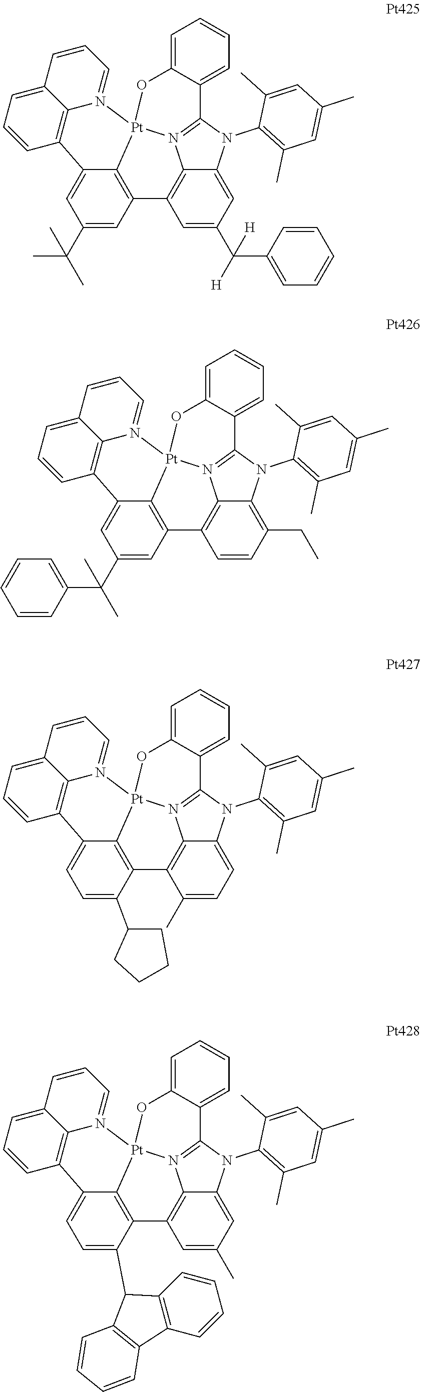

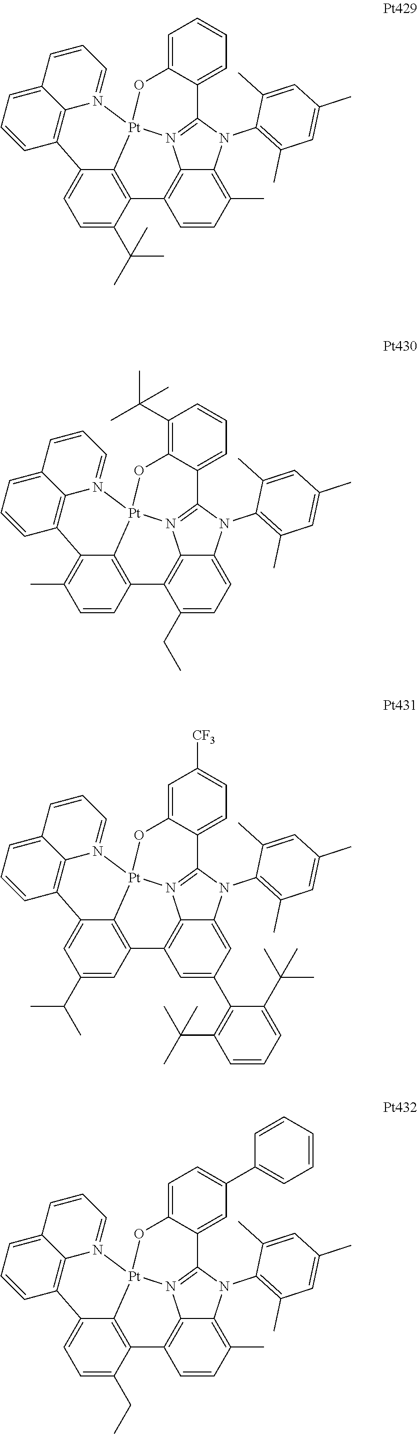

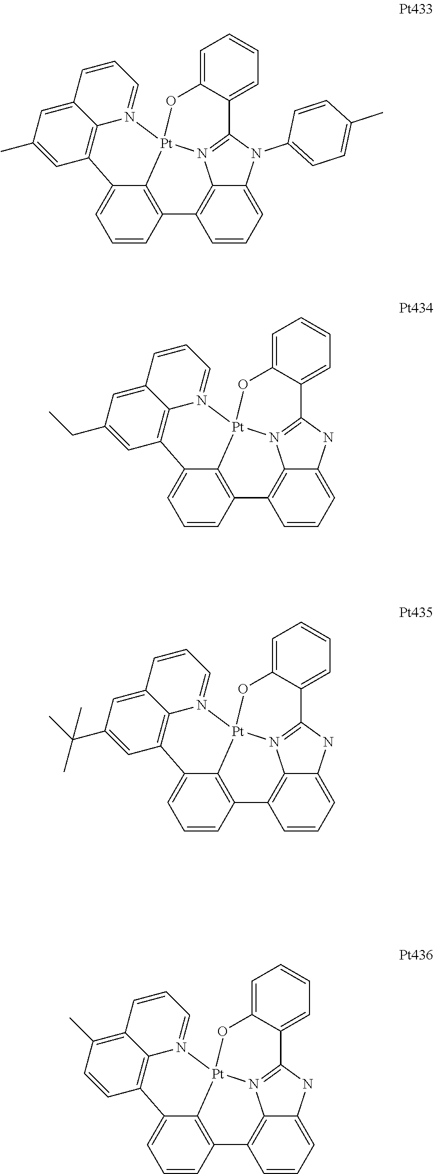

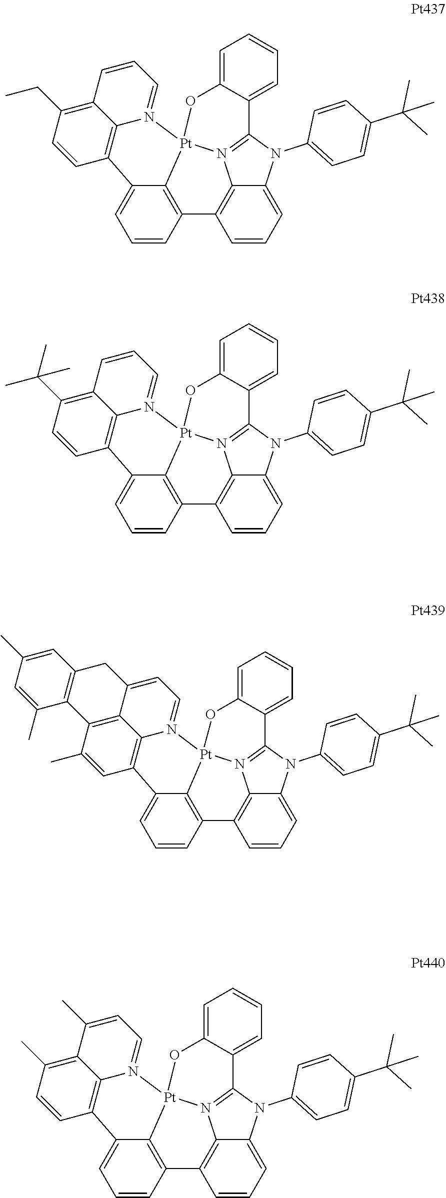

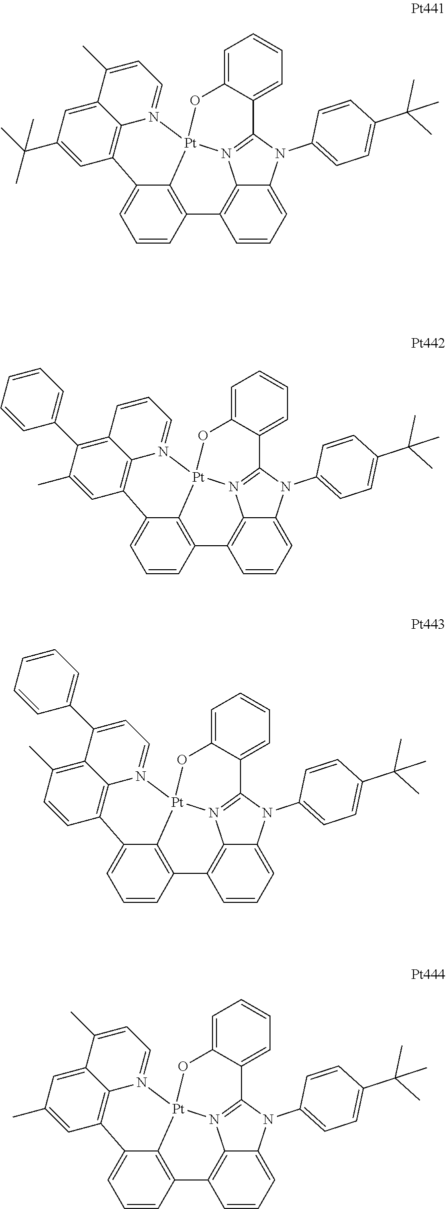

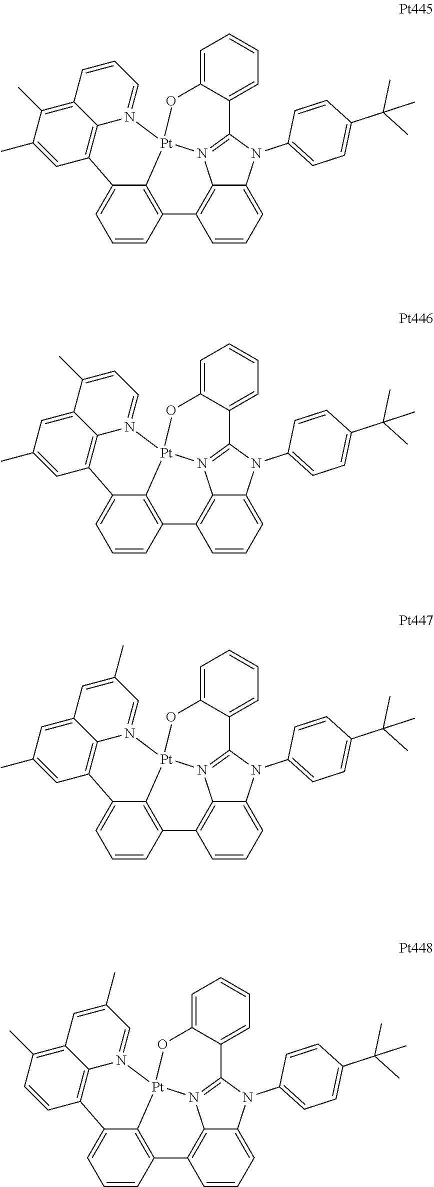

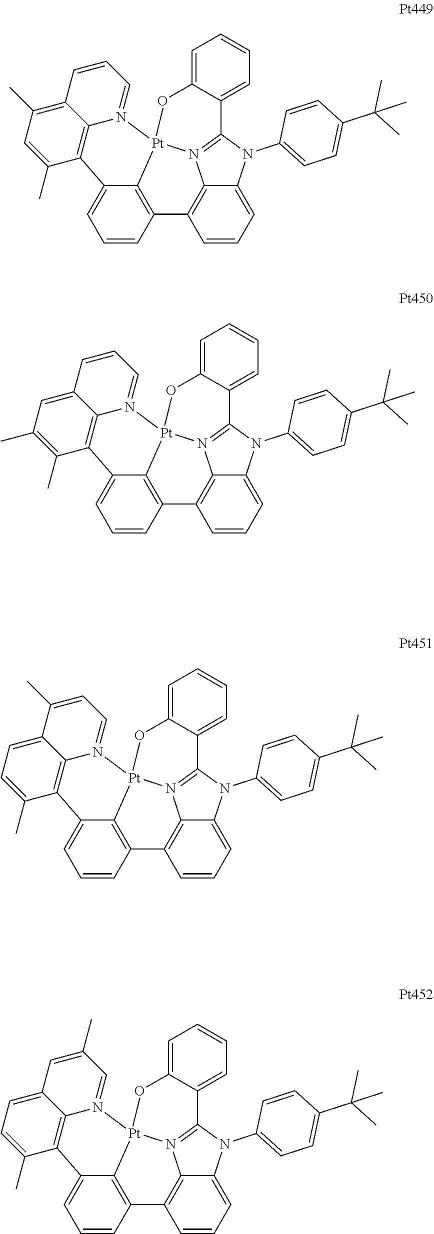

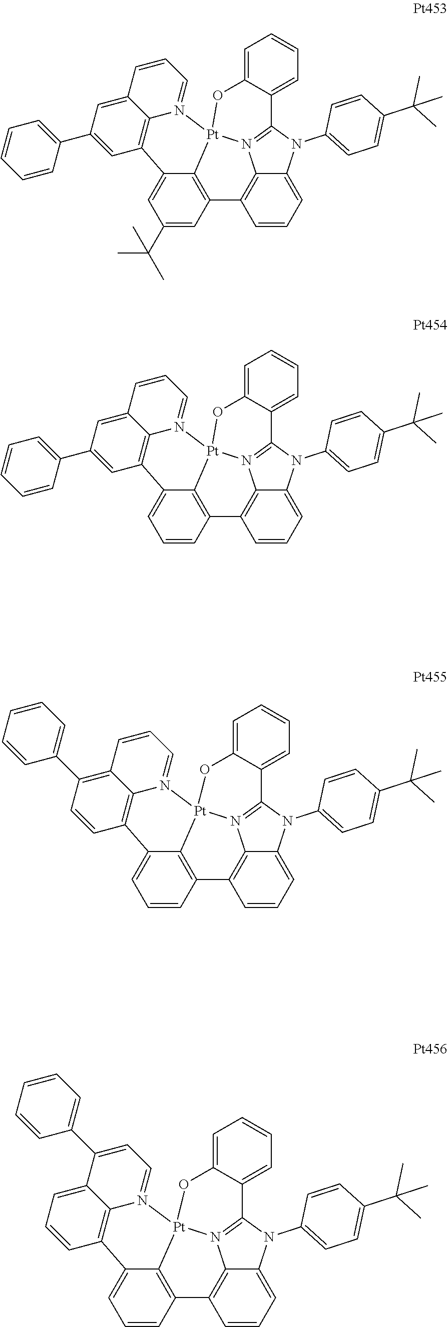

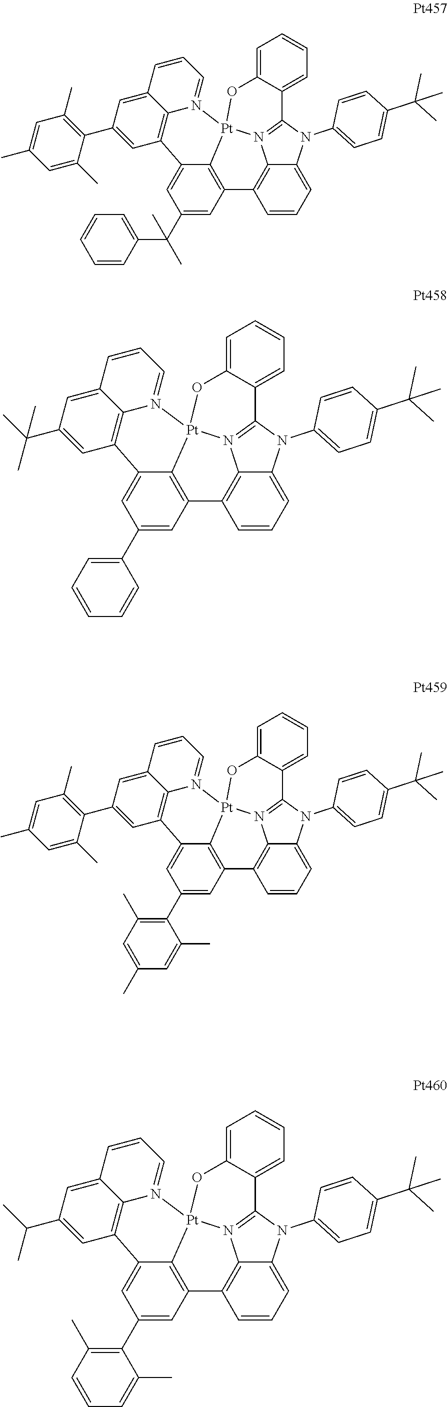

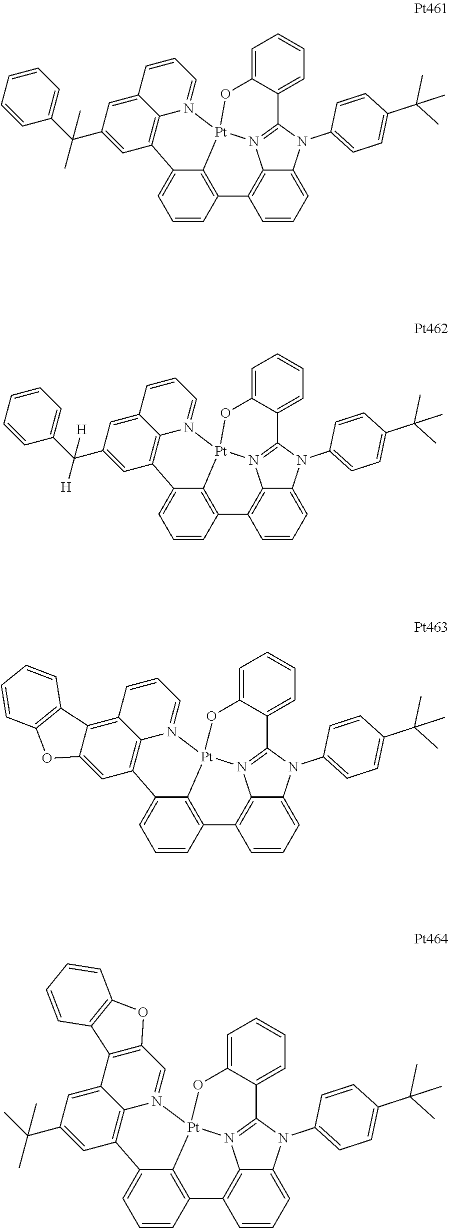

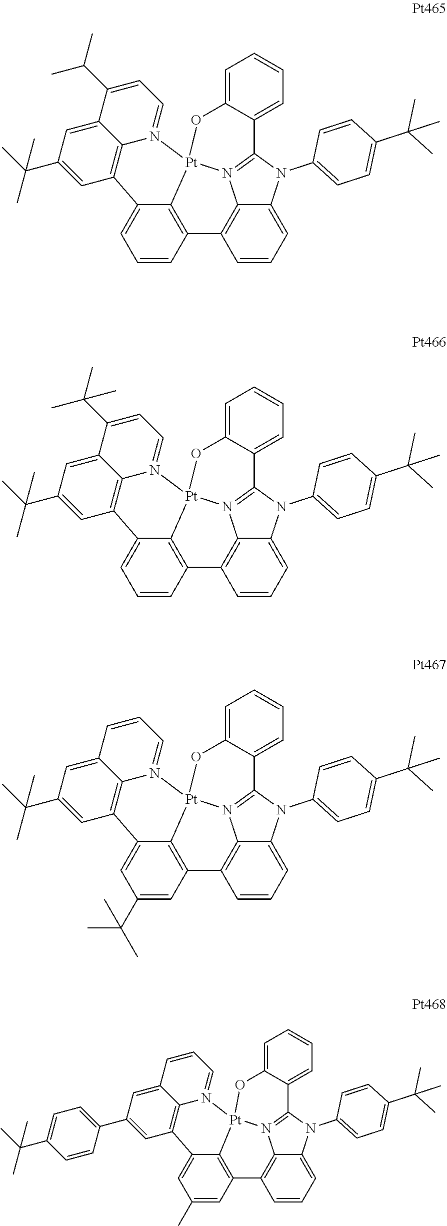

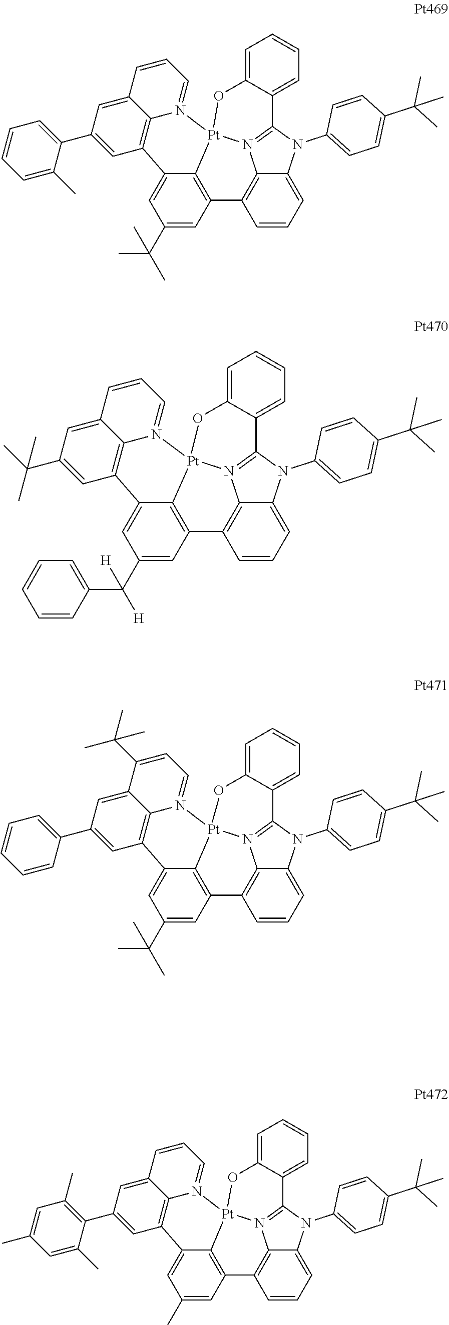

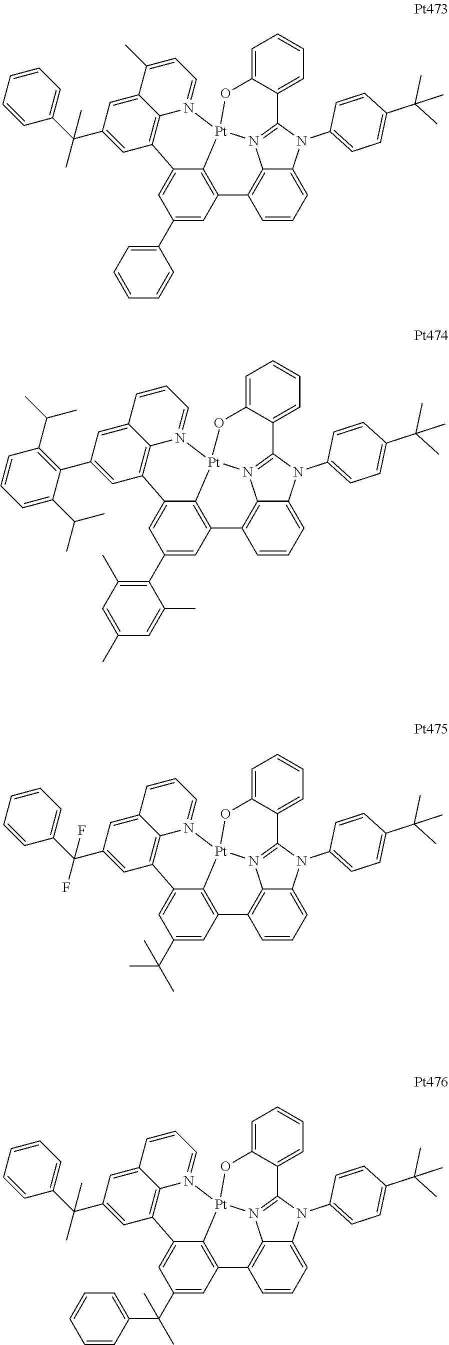

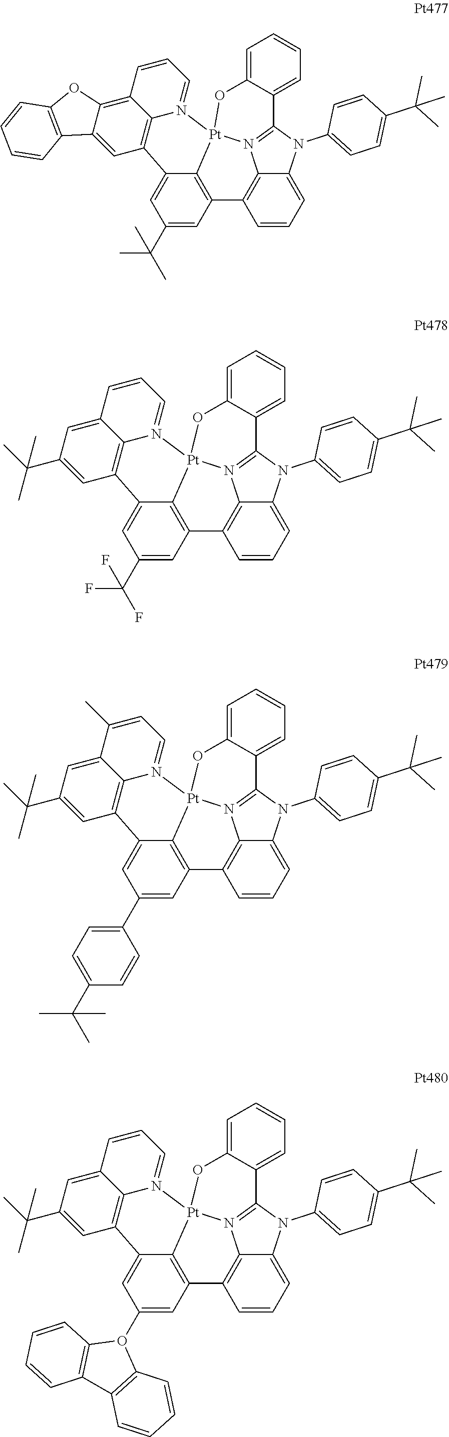

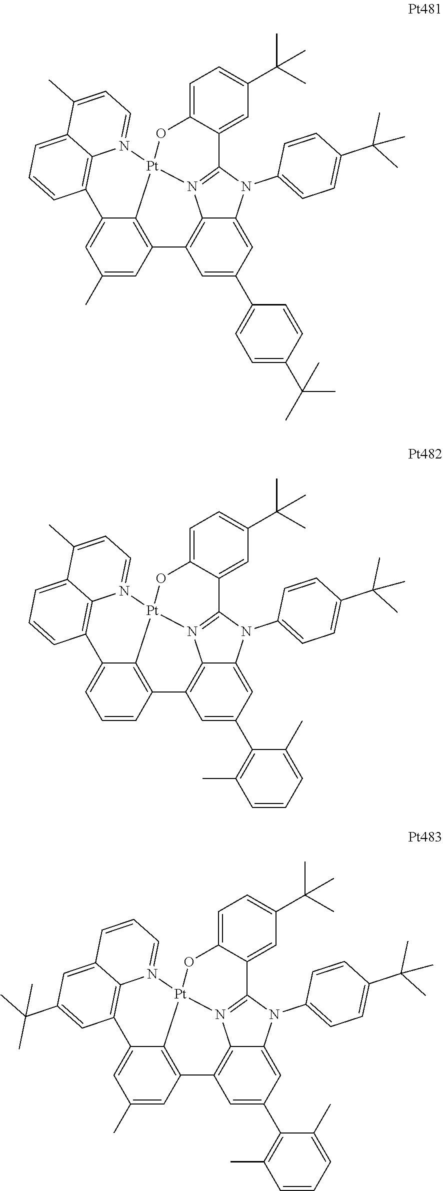

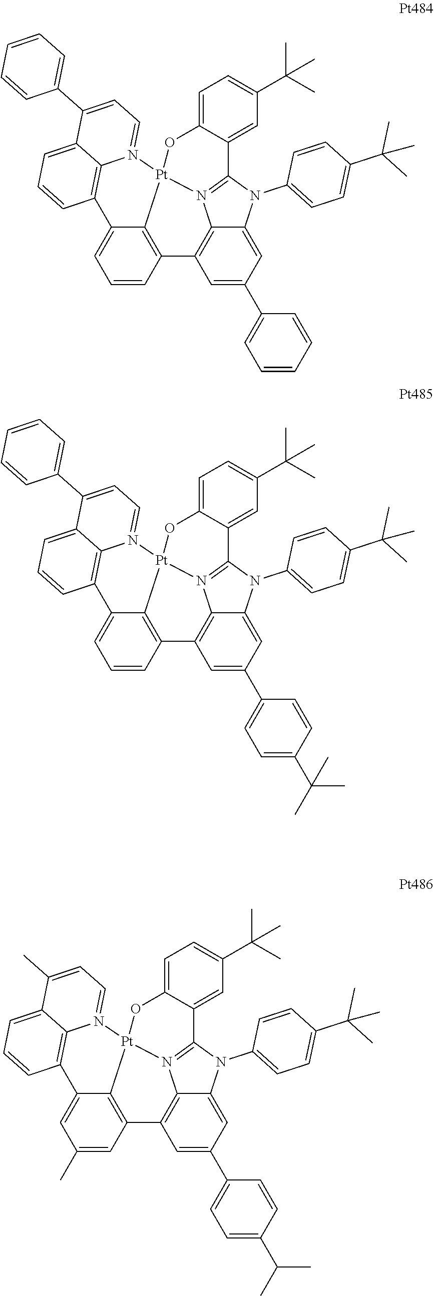

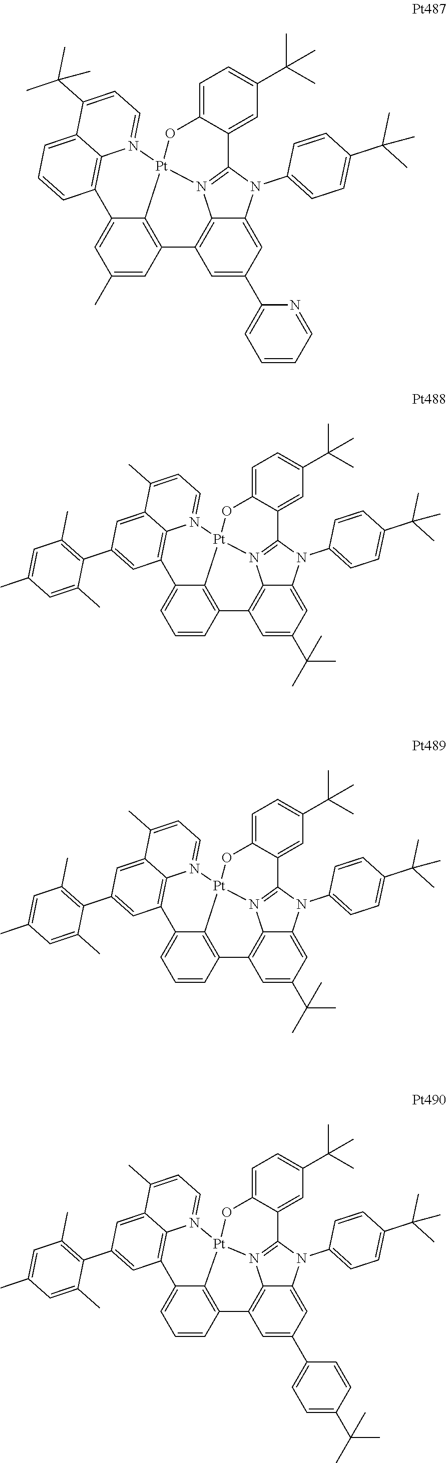

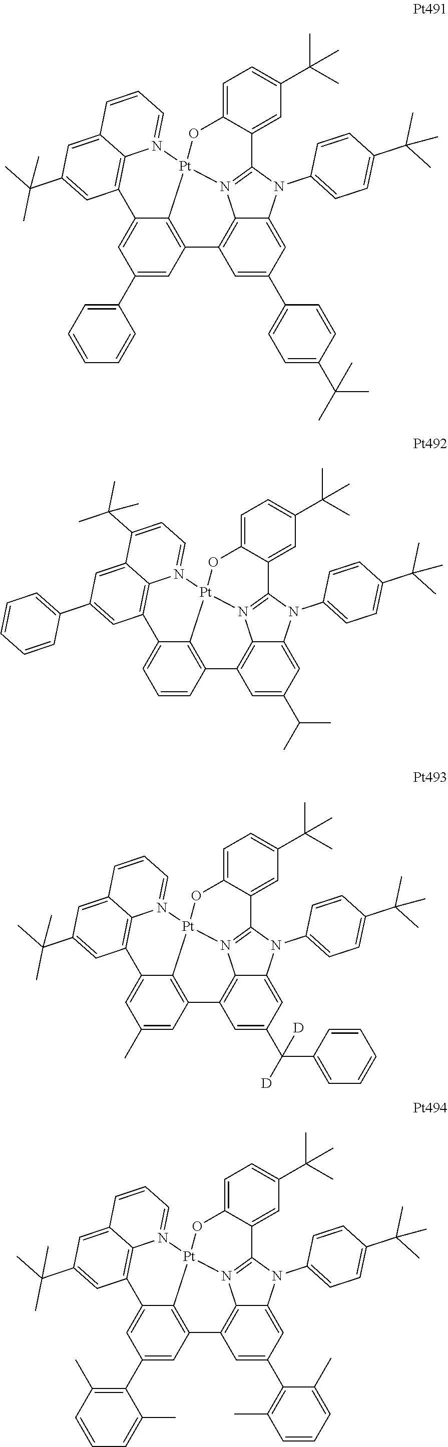

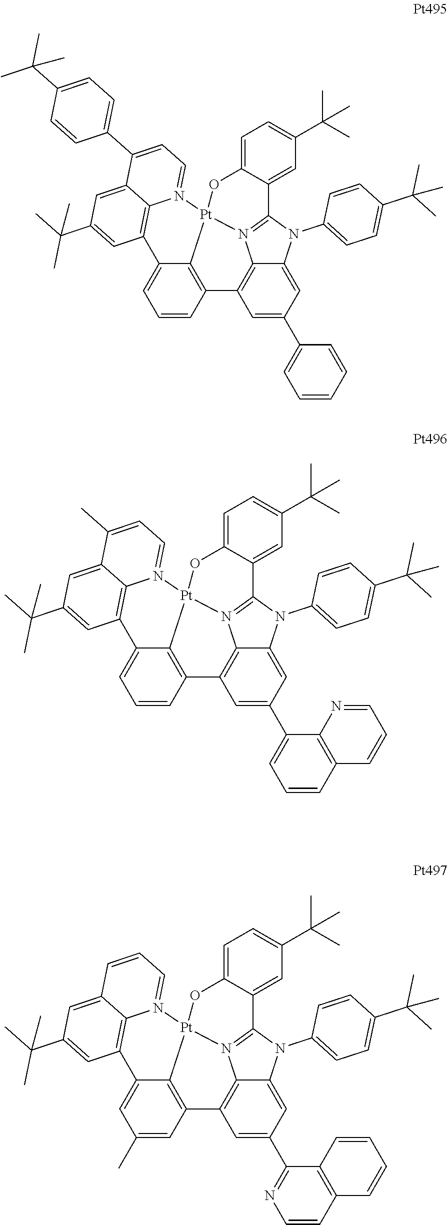

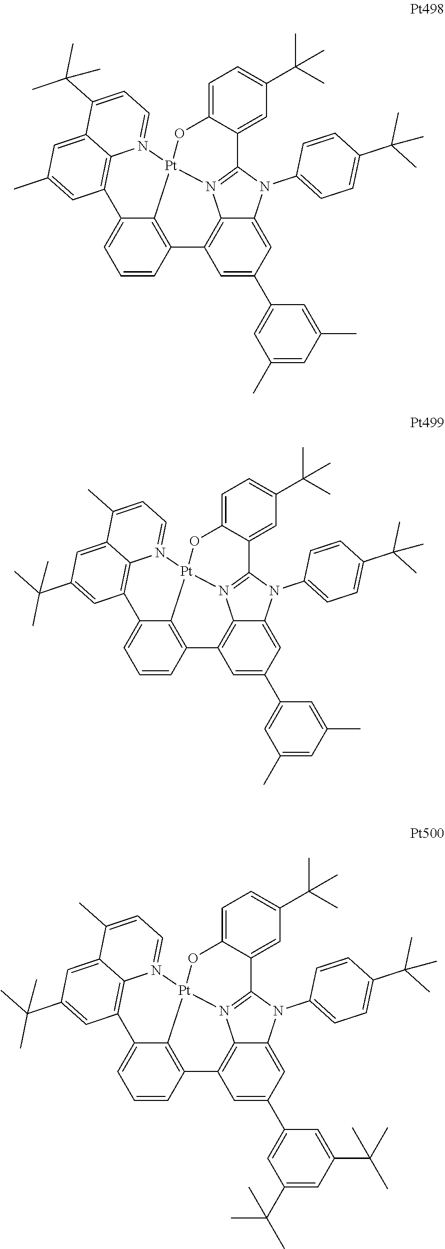

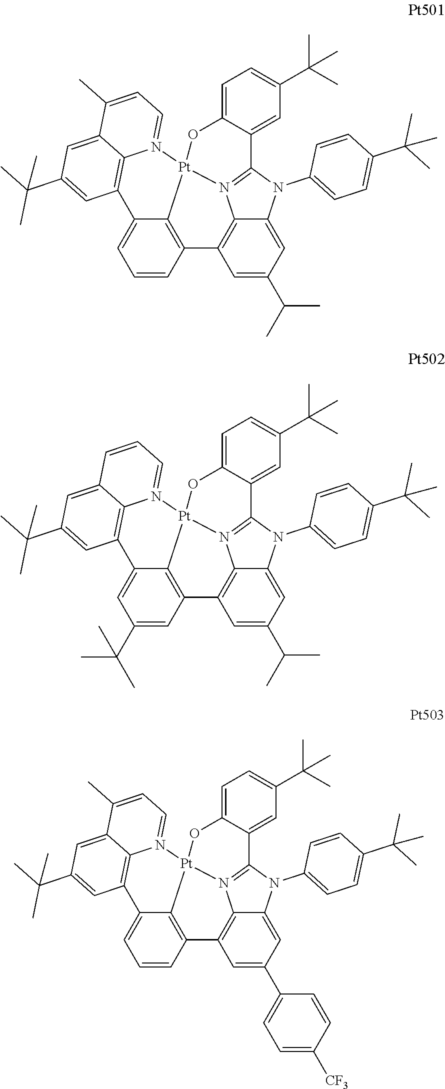

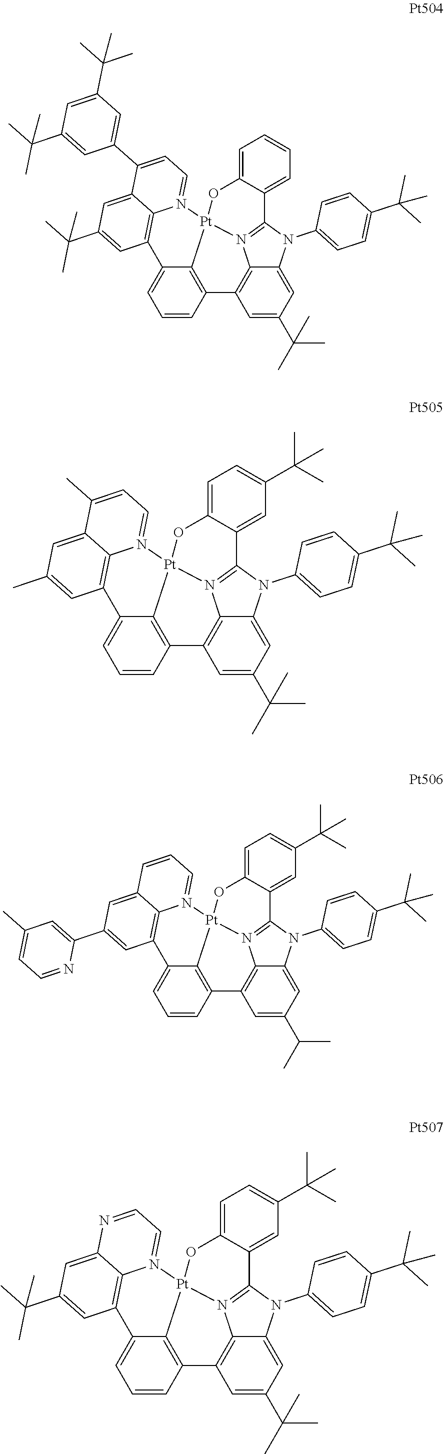

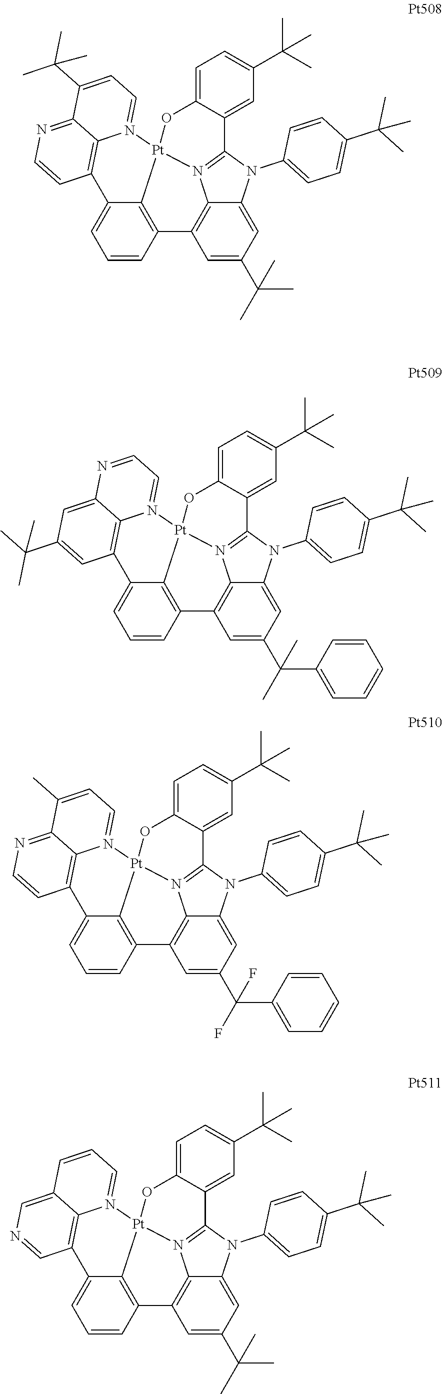

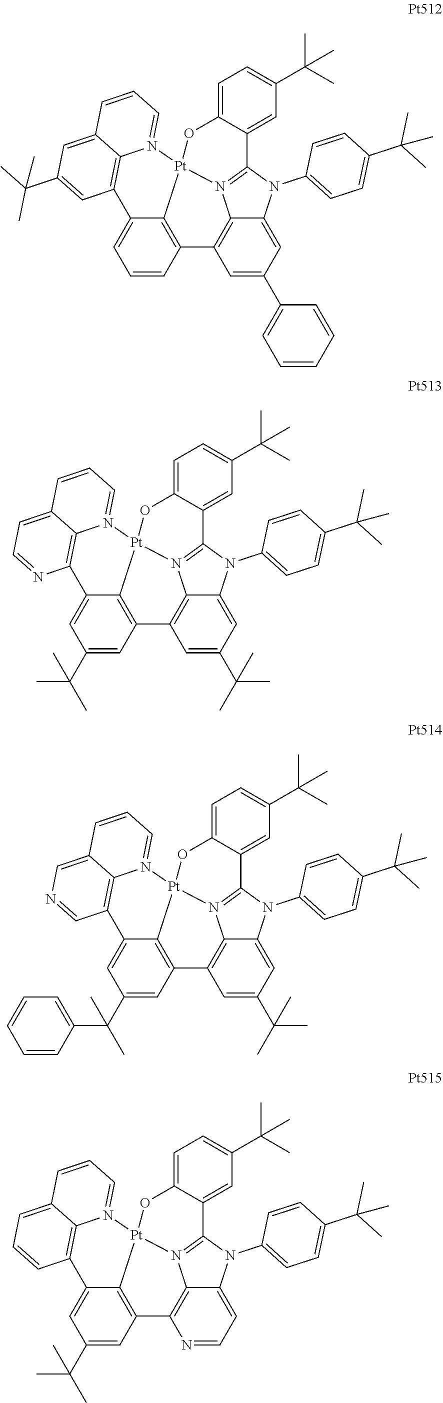

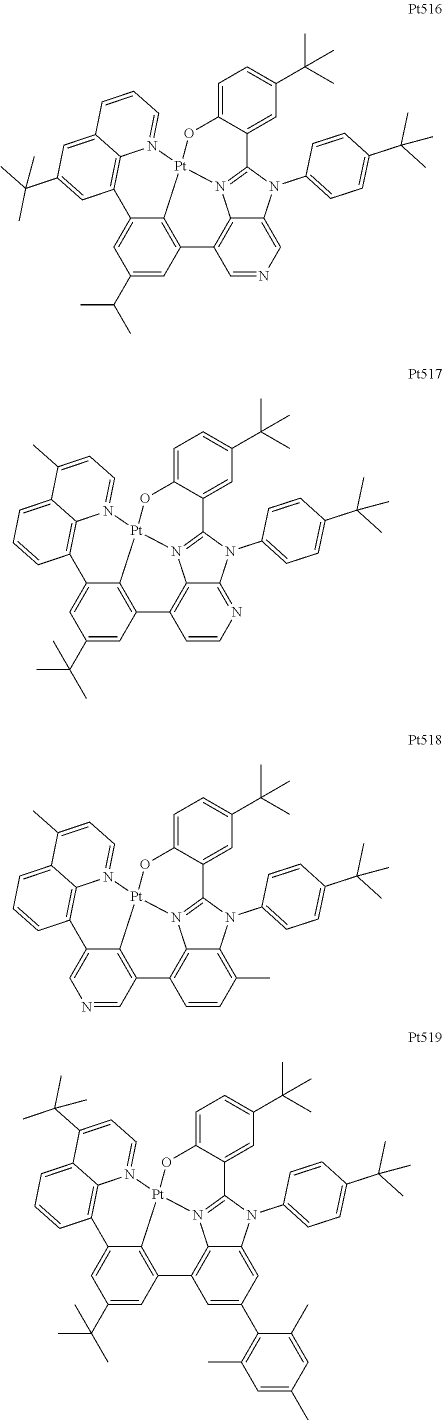

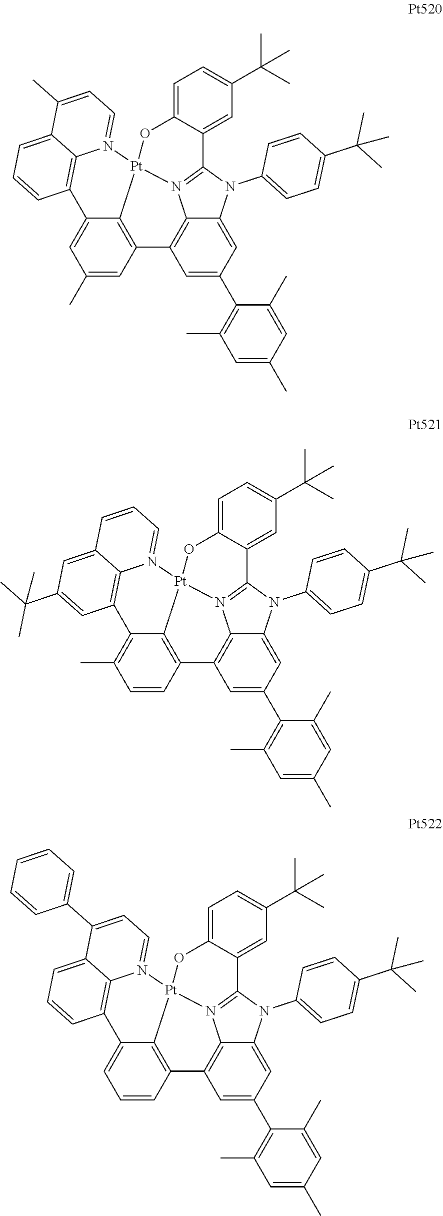

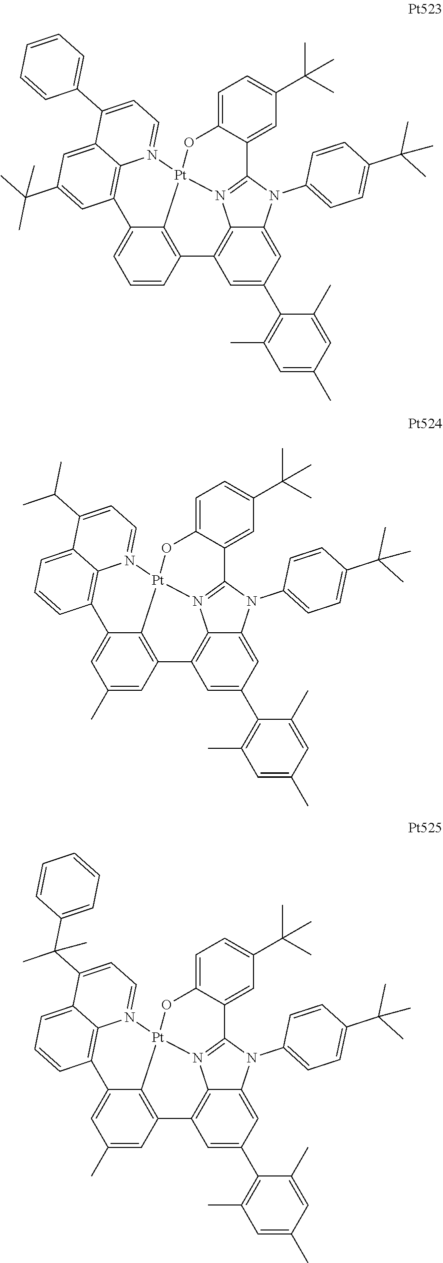

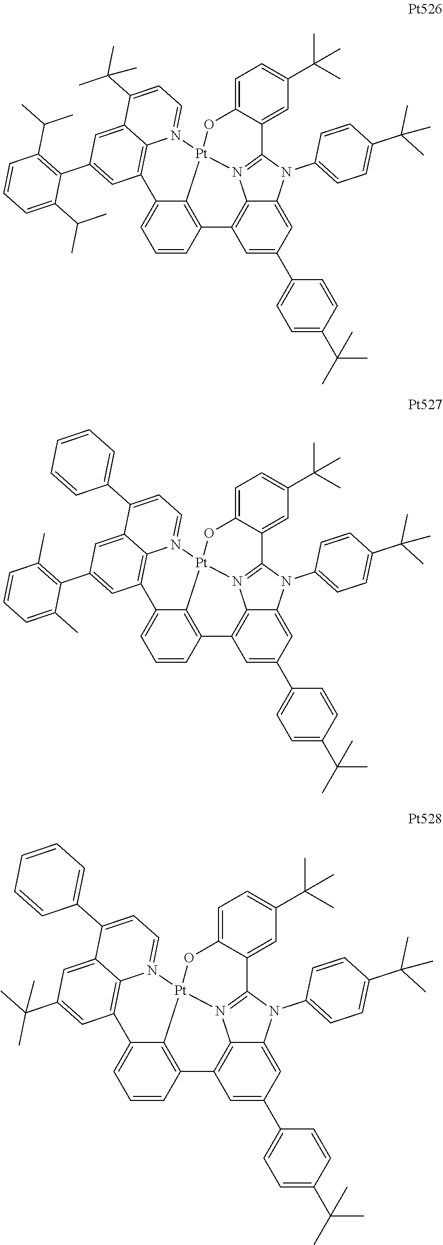

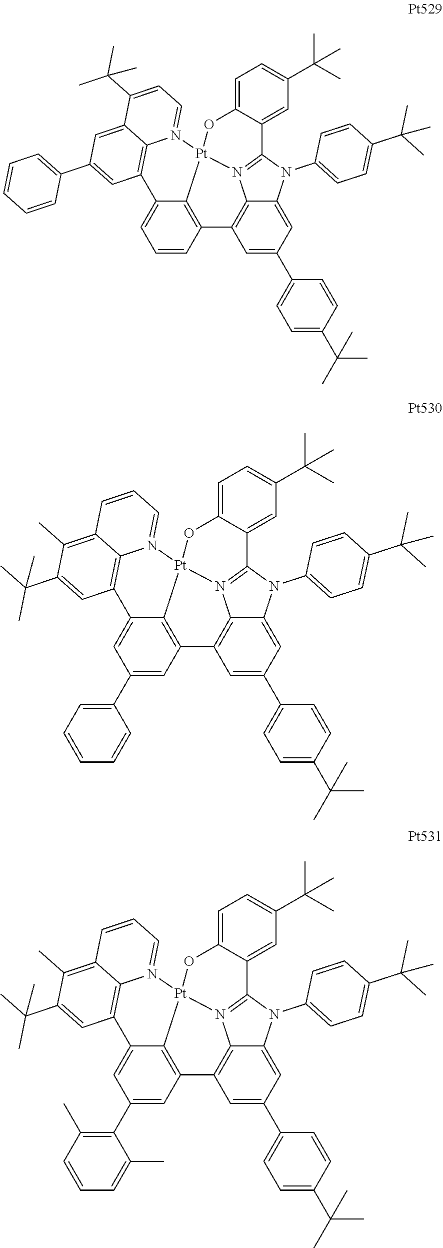

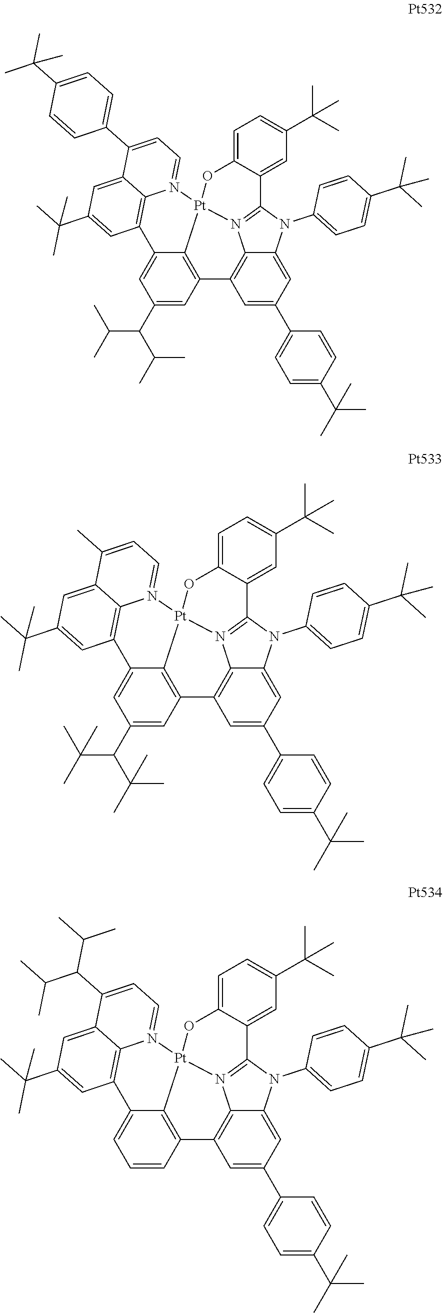

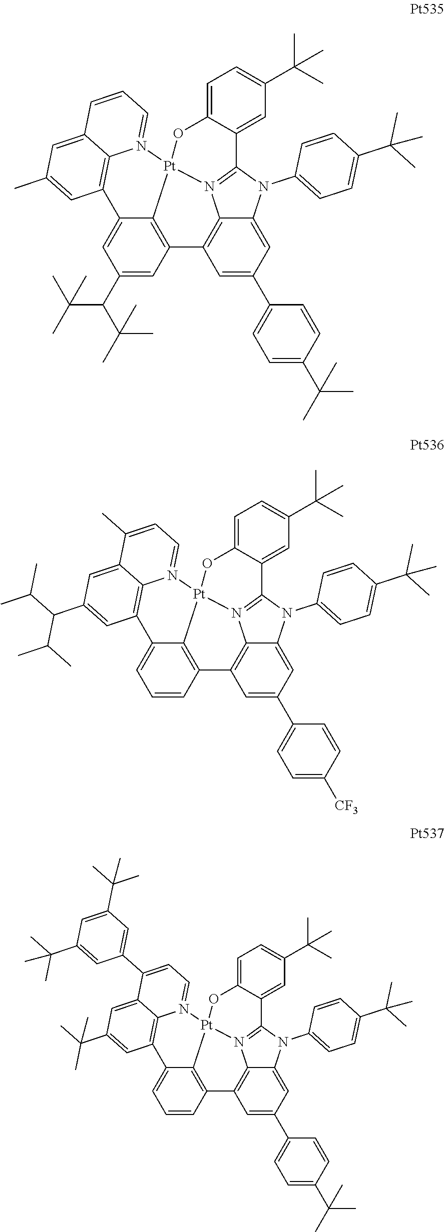

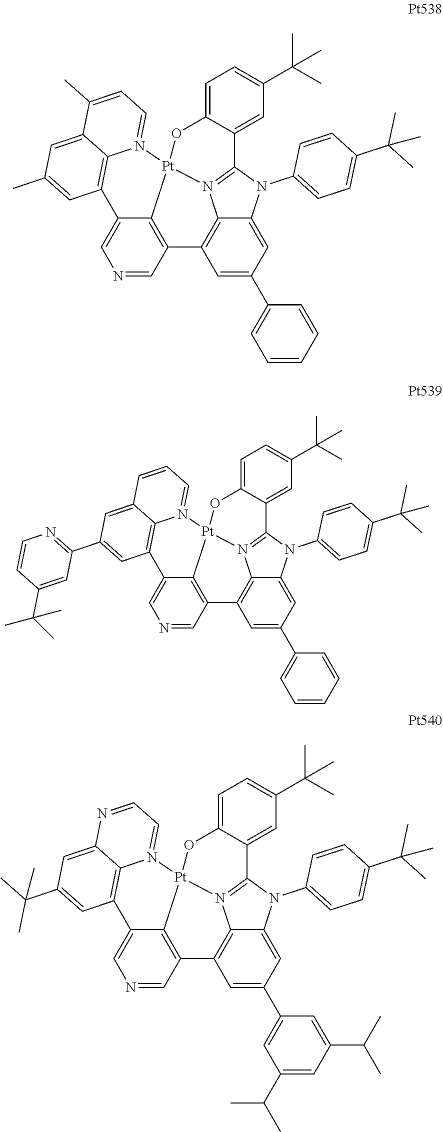

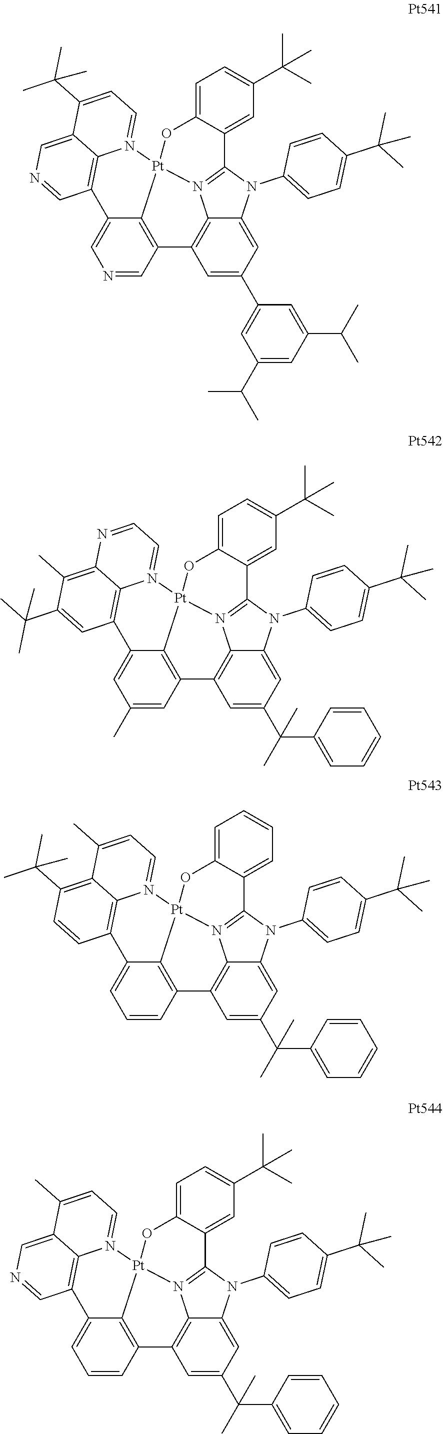

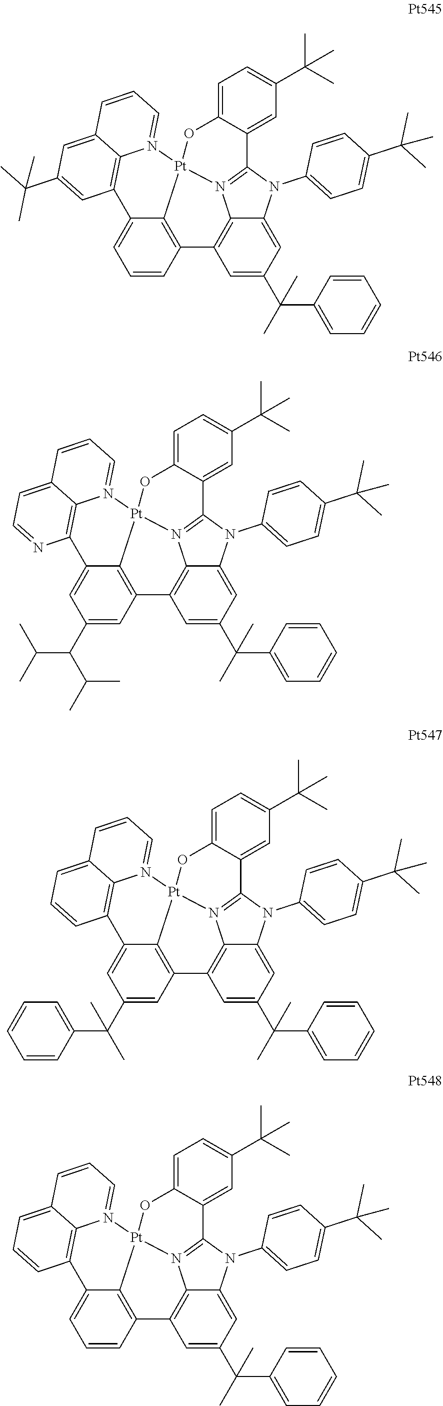

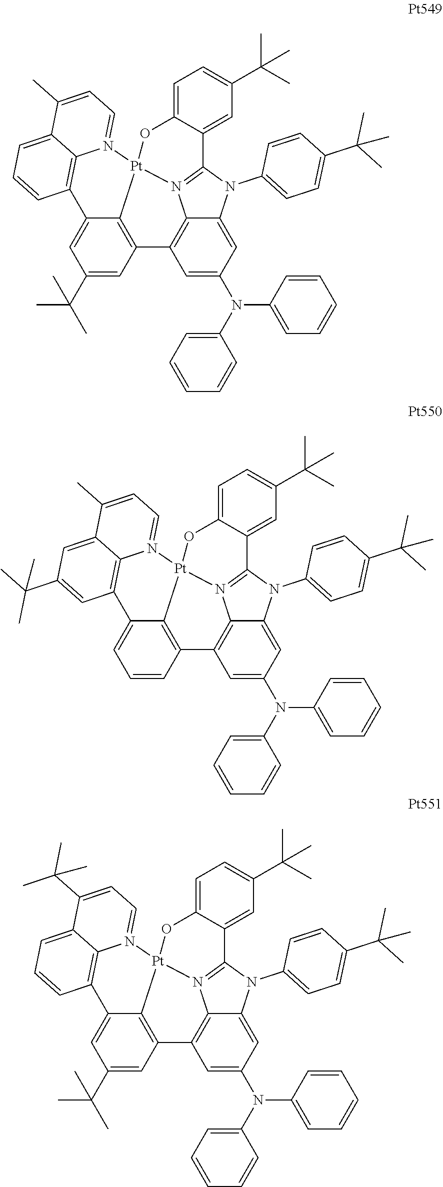

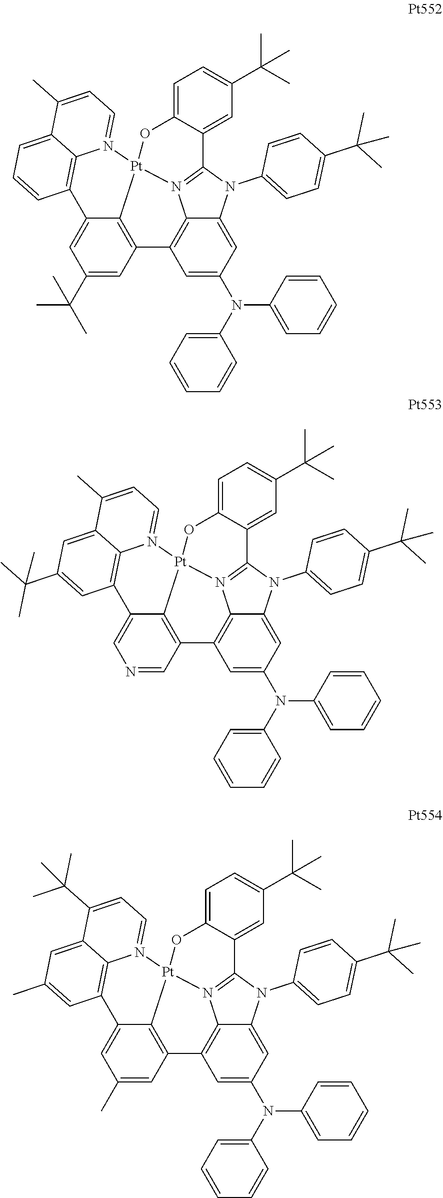

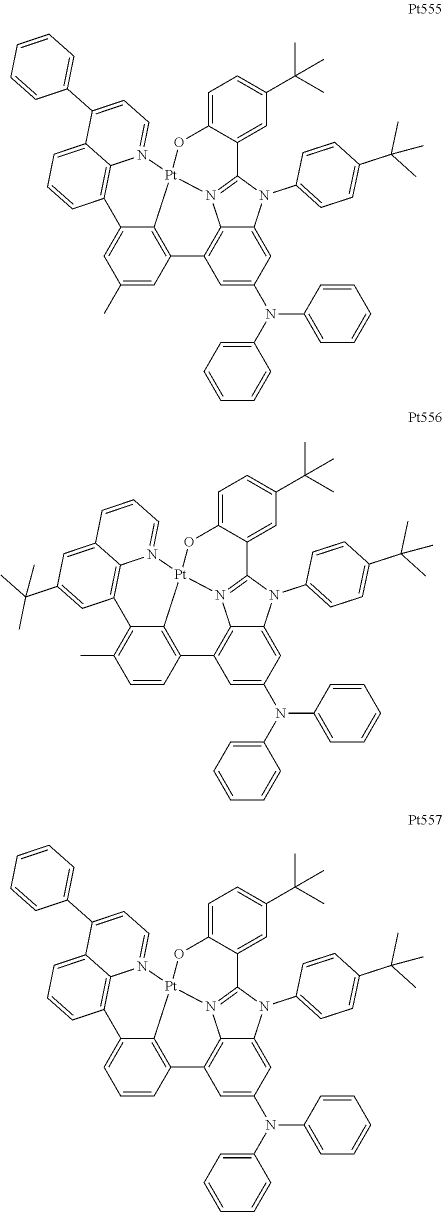

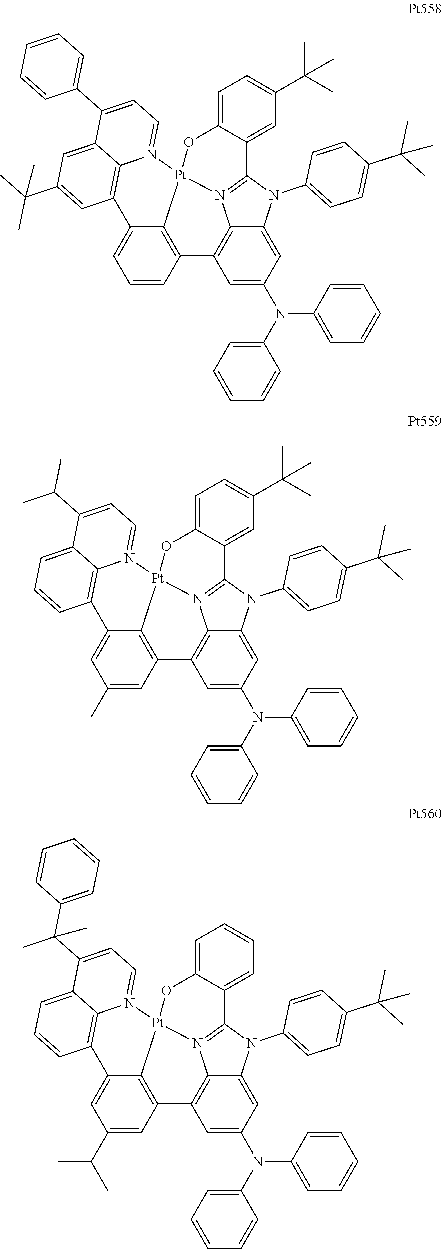

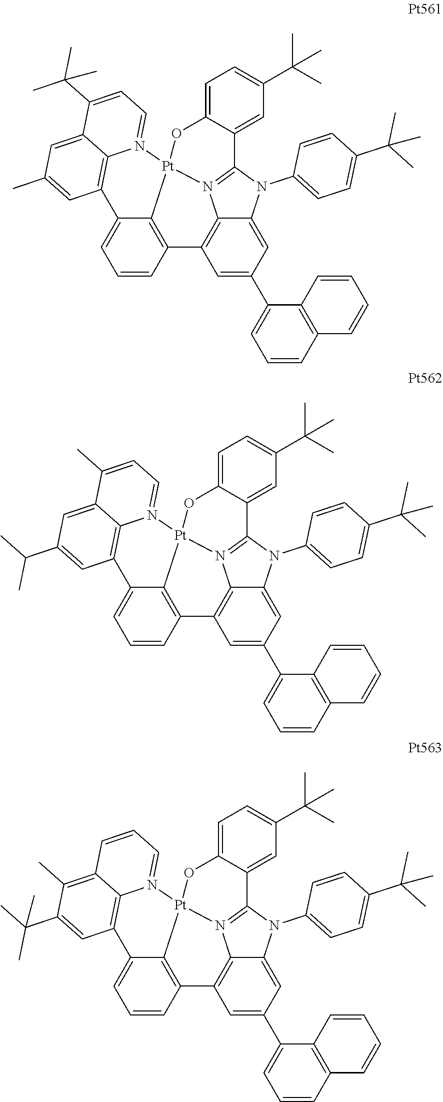

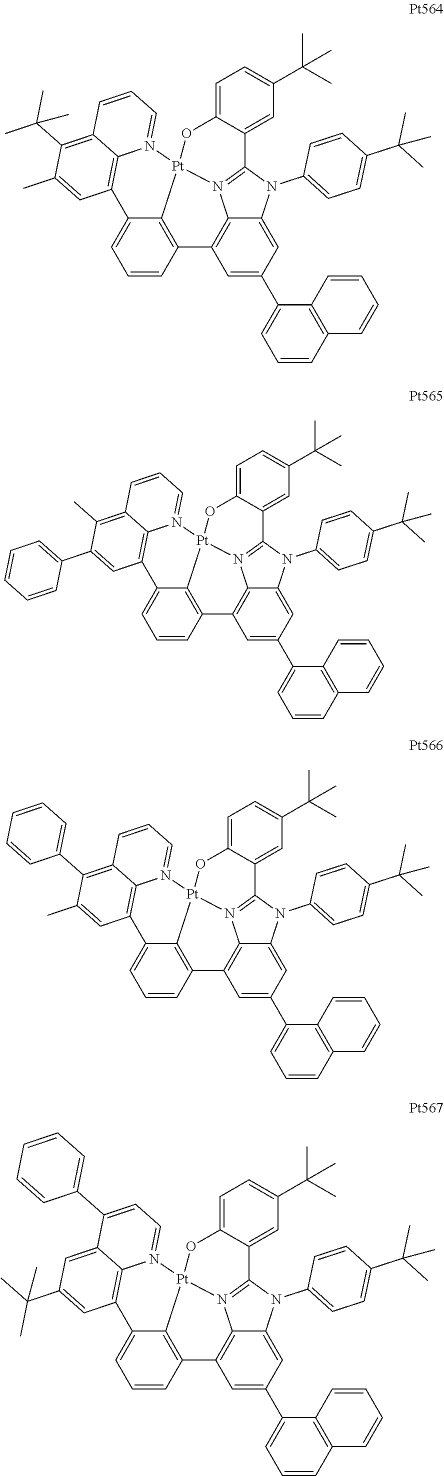

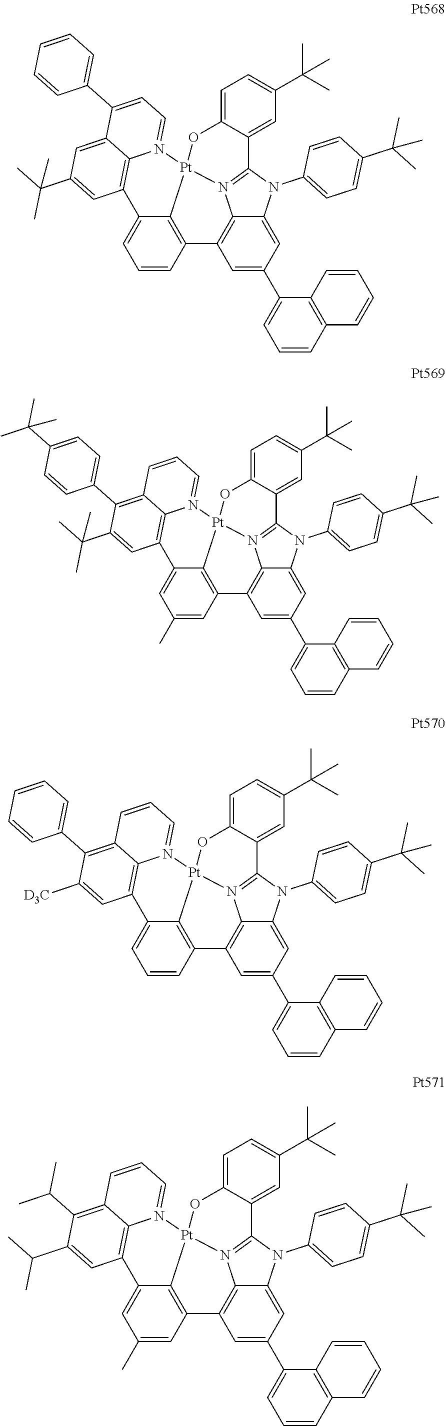

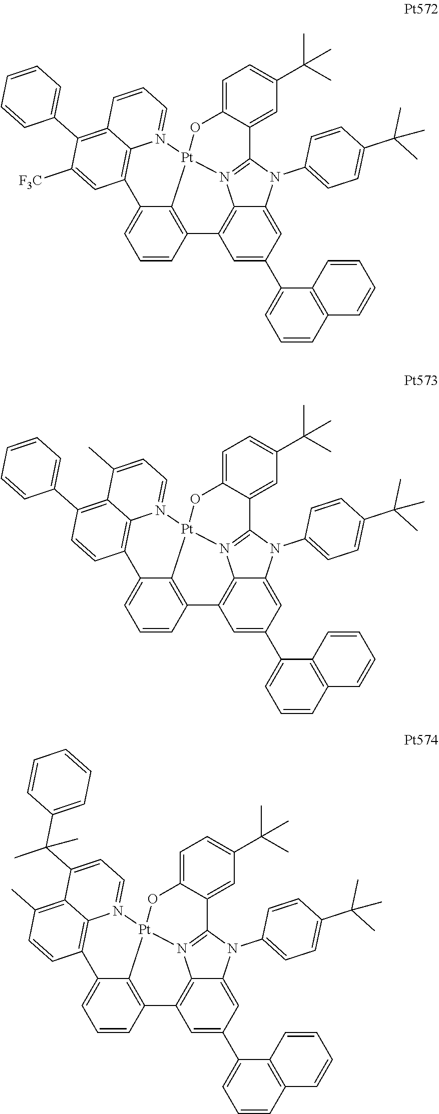

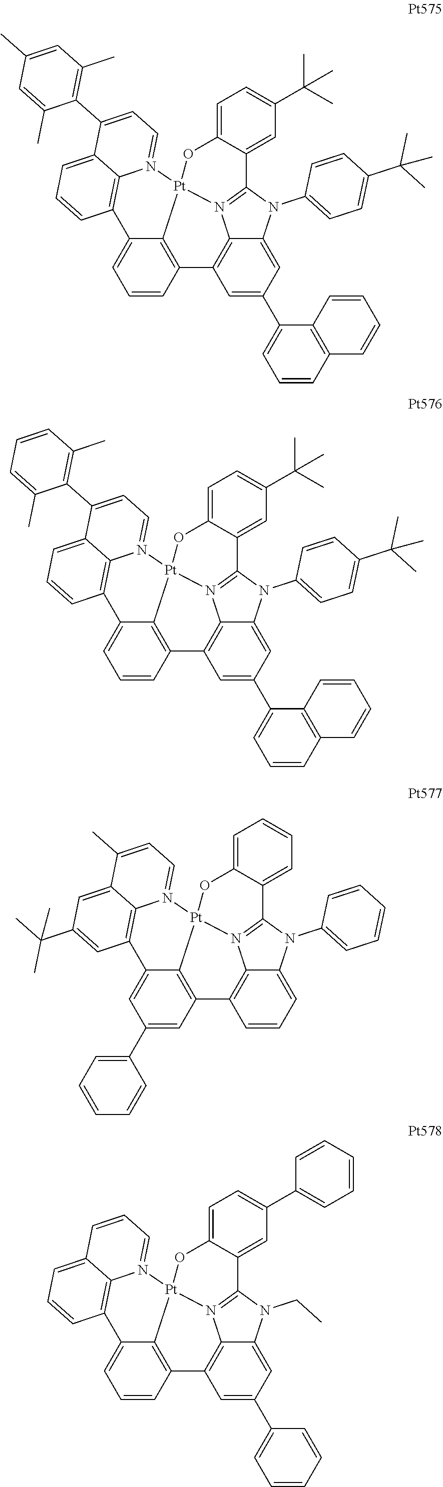

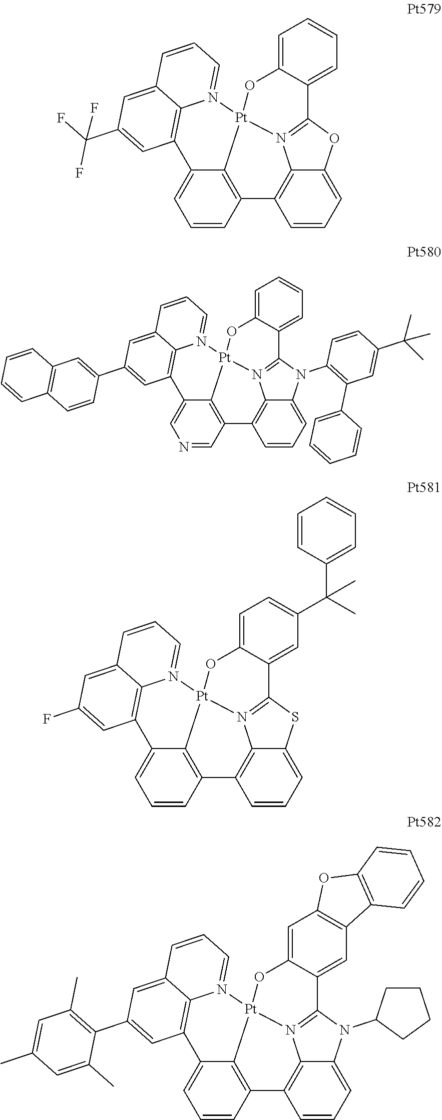

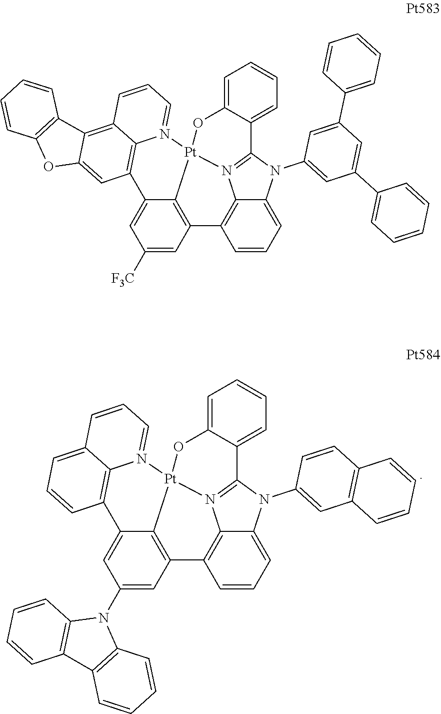

9. Use of the cyclic tetradentate metal platinum (II) complex phosphorescent material according to claim 1 in an electronic device comprising one or more of an organic electroluminescent device, an organic integrated circuit, an organic field effect transistor, an organic thin film transistor, an organic light-emitting transistor, an organic solar cell, an organic optical detector, an organic photoreceptor, an organic field quench device, a light-emitting electrochemical cell, or an organic laser diode.

10. An organic electroluminescent device, comprising a cathode, an anode, and an organic functional layer therebetween; the organic functional layer comprising the cyclic tetradentate metal platinum (II) complex phosphorescent material according to claim 1.

11. The organic electroluminescent device according to claim 9, wherein the organic functional layer comprises a light-emitting layer containing the cyclic tetradentate metal platinum (II) complex phosphorescent material according to claim 1.

12. The organic electroluminescent device according to claim 10, wherein the light-emitting layer also comprises a host material, and the mass percentage of the cyclic tetradentate metal platinum (II) complex phosphorescent material is between 1% and 50%.

13. An organic photoelectric device comprising: a substrate layer; a first electrode on the substrate; an organic light-emitting functional layer on the first electrode; a second electrode on the organic light-emitting functional layer; wherein the organic light-emitting functional layer comprises the cyclic tetradentate metal platinum (II) complex phosphorescent material according to claim 1.

14. A composition comprising the cyclic tetradentate metal platinum (II) complex phosphorescent material according to claim 1.

15. A formulation comprising the cyclic tetradentate metal platinum (II) complex phosphorescent material according to claim 1.

16. A display or lighting device comprising one or more of the organic electroluminescent device according to claim 10.

17. A display or lighting device comprising one or more of the organic electroluminescent device according to claim 11.

18. A display or lighting device comprising one or more of the organic electroluminescent device according to claim 12.
